(19) United States
(12) Patent Application Publication
(10) Pub. No.: US 2026/0223406 A1
(43) Pub. Date: Jul. 30, 2026

(54) SEMICONDUCTOR DEVICE

(71) Applicant: Semiconductor Energy Laboratory Co., Ltd., Atsugi-shi, Kanagawa-ken (JP)

(72) Inventors: Yukinori SHIMA, Tatebayashi (JP); Masami JINTYOU, Shimotsuga (JP); Junichi KOEZUKA, Tochigi (JP)

(21) Appl. No.: 19/149,636

(22) PCT Filed: Feb. 9, 2024
(86) PCT No.: PCT/IB2024/051186

§ 371 Date: Jul. 21, 2025

(30) Foreign Application Priority Data
Feb. 17, 2023 (JP) 2023-023695
Dec. 7, 2023 (JP) 2023-206631

(51) Int. Cl. H10D 30/67; G02F 1/1368; H10D 30/01; H10D 86/01; H10D 86/40; H10D 86/60

(52) U.S. Cl. CPC H10D 30/6755; H10D 30/6728; H10D 30/6731; H10D 30/6757; G02F 1/13685; H10D 30/0318; H10D 30/6734; H10D 30/6736; H10D 86/0231; H10D 86/423; H10D 86/431; H10D 86/451; H10D 86/471; H10D 86/60

(57) ABSTRACT

A semiconductor device including a transistor having a high on-state current is provided. The semiconductor device includes a transistor and a first insulating layer. The transistor includes first to third semiconductor layers, a first conductive layer, and a second conductive layer. The first insulating layer has a first opening reaching the first conductive layer. The second conductive layer includes a second opening in a region overlapping with the first opening. The first semiconductor layer is in contact with a top surface of the first conductive layer, a side surface of the first insulating layer, and a side surface of the second conductive layer. The second semiconductor layer is provided over the first semiconductor layer, and the third semiconductor layer is provided over the second semiconductor layer. The first semiconductor layer contains a first metal oxide, the second semiconductor layer contains a second metal oxide, and the third semiconductor layer contains a third metal oxide. A band gap of the first metal oxide is larger than a band gap of the second metal oxide. A band gap of the third metal oxide is larger than the band gap of the first metal oxide.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device including a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a driving method thereof, and a manufacturing method thereof.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means any device that can function by utilizing semiconductor characteristics. For example, an integrated circuit, a chip including an integrated circuit, and an electronic component including a chip in a package are examples of the semiconductor device. Moreover, a memory device, a display device, a light-emitting apparatus, a lighting device, and an electronic device themselves are semiconductor devices and each of them includes a semiconductor device in some cases.

### BACKGROUND ART

Semiconductor devices including transistors are applied to a wide range of electronic devices. In a display device, for example, when the area occupied by transistors is reduced, the pixel size can be reduced and the definition can be increased. Thus, minute transistors have been required.

As devices requiring high-definition display devices, for example, devices for virtual reality (VR), augmented reality (AR), substitutional reality (SR), and mixed reality (MR) have been actively developed.

As a display device, a light-emitting apparatus including an organic EL (Electro Luminescence) element or a light-emitting diode (LED) has been developed.

Patent Document 1 discloses a high-definition display device using an organic EL element.

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a semiconductor device including a transistor having a minute size. Another object is to provide a semiconductor device including a transistor having a short channel length. Another object is to provide a semiconductor device including a transistor having a high on-state current. Another object is to provide a semiconductor device including a transistor having high field-effect mobility. Another object is to provide a semiconductor device including a transistor having favorable electrical characteristics. Another object is to provide a semiconductor device that operates at high speed. Another object is to provide a semiconductor device that occupies a small area. Another object is to provide a semiconductor device having small wiring resistance. Another object is to provide a semiconductor device or a display device having low power consumption. Another object is to provide a transistor, a semiconductor device, or a display device having high reliability. Another object is to provide a high-definition display device. Another object is to provide a method for manufacturing a semiconductor device or a display device having high productivity. Another object is to provide a novel transistor, a novel semiconductor device, a novel display device, or a manufacturing method thereof.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a transistor and a first insulating layer. The transistor includes a first semiconductor layer, a second semiconductor layer, a third semiconductor layer, a first conductive layer, and a second conductive layer. The first insulating layer is provided over the first conductive layer. The second conductive layer is provided over the first insulating layer. The first insulating layer includes a first opening reaching the first conductive layer. The second conductive layer includes a second opening in a region overlapping with the first opening. In the first opening and the second opening, the first semiconductor layer is in contact with a top surface of the first conductive layer, a side surface of the first insulating layer, and a side surface of the second conductive layer. The second semiconductor layer is provided over the first semiconductor layer. The third semiconductor layer is provided over the second semiconductor layer. The first semiconductor layer contains a first metal oxide. The second semiconductor layer contains a second metal oxide. The third semiconductor layer contains a third metal oxide. A band gap of the first metal oxide is larger than a band gap of the second metal oxide. A band gap of the third metal oxide is larger than the band gap of the first metal oxide. A thickness of the third semiconductor layer is larger than a thickness of the first semiconductor layer. A thickness of the second semiconductor layer is larger than the thickness of the third semiconductor layer.

One embodiment of the present invention is a semiconductor device including a transistor and a first insulating layer. The transistor includes a first semiconductor layer, a second semiconductor layer, a third semiconductor layer, a first conductive layer, and a second conductive layer. The first insulating layer is provided over the first conductive layer. The second conductive layer is provided over the first insulating layer. The first insulating layer includes a first opening reaching the first conductive layer. The second conductive layer includes a second opening in a region overlapping with the first opening. In the first opening and the second opening, the first semiconductor layer is in contact with a top surface of the first conductive layer, a side surface of the first insulating layer, and a side surface of the second conductive layer. The second semiconductor layer is provided over the first semiconductor layer. The third semiconductor layer is provided over the second semiconductor layer. The first semiconductor layer contains a first metal oxide. The second semiconductor layer contains a second metal oxide. The third semiconductor layer contains a third metal oxide. The first metal oxide contains indium, a first element, and zinc. The second metal oxide contains indium. The third metal oxide contains indium, a second element, and zinc. The first element is one or more of gallium, aluminum, and tin. The second element is one or more of gallium, aluminum, and tin. A content percentage of the first element is higher than a sum of content percentages of gallium, aluminum, and tin in the second metal oxide. A content percentage of the second element is higher than the content percentage of the first element. A thickness of the third semiconductor layer is larger than a thickness of the first semiconductor layer. A thickness of the second semiconductor layer is larger than the thickness of the third semiconductor layer.

One embodiment of the present invention is a semiconductor device including a transistor and a first insulating layer. The transistor includes a first semiconductor layer, a second semiconductor layer, a third semiconductor layer, a first conductive layer, and a second conductive layer. The first insulating layer is provided over the first conductive layer. The second conductive layer is provided over the first insulating layer. The first insulating layer includes a first opening reaching the first conductive layer. The second conductive layer includes a second opening in a region overlapping with the first opening. In the first opening and the second opening, the first semiconductor layer is in contact with a top surface of the first conductive layer, a side surface of the first insulating layer, and a side surface of the second conductive layer. The second semiconductor layer is provided over the first semiconductor layer. The third semiconductor layer is provided over the second semiconductor layer. The first semiconductor layer contains a first metal oxide. The second semiconductor layer contains a second metal oxide. The third semiconductor layer contains a third metal oxide. The first metal oxide contains indium, a first element, and zinc. The second metal oxide contains indium and a second element. The third metal oxide contains indium, a third element, and zinc. The first element is one or more of gallium, aluminum, and tin. The second element is one or more of gallium, aluminum, and tin. The third element is one or more of gallium, aluminum, and tin. A content percentage of the first element is higher than a content percentage of the second element. A content percentage of the third element is higher than the content percentage of the first element. A thickness of the third semiconductor layer is larger than a thickness of the first semiconductor layer. A thickness of the second semiconductor layer is larger than the thickness of the third semiconductor layer.

In the above semiconductor device, the first conductive layer and the second conductive layer each preferably contain an oxide conductor.

In the above semiconductor device, the first insulating layer preferably includes a second insulating layer, a third insulating layer over the second insulating layer, and a fourth insulating layer over the third insulating layer. The third insulating layer preferably contains oxygen. The second insulating layer and the fourth insulating layer each preferably contain nitrogen.

In the above semiconductor device, the first insulating layer preferably includes a second insulating layer, a third insulating layer over the second insulating layer, a fourth insulating layer over the third insulating layer, a fifth insulating layer over the fourth insulating layer, and a sixth insulating layer over the fifth insulating layer. The fourth insulating layer preferably contains oxygen. The second insulating layer, the third insulating layer, the fifth insulating layer, and the sixth insulating layer each preferably contain nitrogen. The second insulating layer preferably includes a region with a higher hydrogen content than the third insulating layer. The sixth insulating layer preferably includes a region with a higher hydrogen content than the fifth insulating layer.

The above semiconductor device preferably includes a second insulating layer. A top surface of the second insulating layer is preferably in contact with a bottom surface of the first conductive layer. The first insulating layer preferably includes a third insulating layer, a fourth insulating layer over the third insulating layer, a fifth insulating layer over the fourth insulating layer, and a sixth insulating layer over the fifth insulating layer. The fourth insulating layer preferably contains oxygen. The second insulating layer, the third insulating layer, the fifth insulating layer, and the sixth insulating layer each preferably contain nitrogen. The second insulating layer preferably includes a region with a higher hydrogen content than the third insulating layer. The sixth insulating layer preferably includes a region with a higher hydrogen content than the fifth insulating layer.

### Effect of the Invention

With one embodiment of the present invention, a semiconductor device including a transistor having a minute size can be provided. Alternatively, a semiconductor device including a transistor having a short channel length can be provided. Alternatively, a semiconductor device including a transistor having a high on-state current can be provided. Alternatively, a semiconductor device including a transistor having high field-effect mobility can be provided. Alternatively, a semiconductor device including a transistor having favorable electrical characteristics can be provided. Alternatively, a semiconductor device that operates at high speed can be provided. Alternatively, a semiconductor device that occupies a small area can be provided. Alternatively, a semiconductor device having low wiring resistance can be provided. Alternatively, a semiconductor device or a display device having low power consumption can be provided. Alternatively, a transistor, a semiconductor device, or a display device having high reliability can be provided. Alternatively, a high-definition display device can be provided. Alternatively, a method for manufacturing a semiconductor device or a display device with high productivity can be provided. Alternatively, a novel transistor, a novel semiconductor device, a novel display device, or a manufacturing method thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views illustrating the example of the semiconductor device.

FIG. 2A to FIG. 2D are perspective views illustrating an example of a semiconductor device.

FIG. 3 is a cross-sectional view illustrating an example of a semiconductor device.

FIG. 4A is a top view illustrating an example of a semiconductor device. FIG. 4B is a cross-sectional view illustrating the example of the semiconductor device.

FIG. 5 is a cross-sectional view illustrating an example of a semiconductor device.

FIG. 6A to FIG. 6C are cross-sectional views illustrating examples of a semiconductor device.

FIG. 7 is a cross-sectional view illustrating an example of a semiconductor device.

FIG. 8A and FIG. 8B are cross-sectional views illustrating examples of a semiconductor device.

FIG. 9A to FIG. 9C are cross-sectional views illustrating an example of a semiconductor device.

FIG. 10A to FIG. 10C are cross-sectional views illustrating an example of a semiconductor device.

FIG. 11A and FIG. 11B are cross-sectional views illustrating an example of a semiconductor device.

FIG. 12A and FIG. 12B are cross-sectional views illustrating examples of a semiconductor device.

FIG. 13A and FIG. 13B are cross-sectional views illustrating examples of a semiconductor device.

FIG. 14A to FIG. 14C are cross-sectional views illustrating an example of a semiconductor device.

FIG. 15A is a top view illustrating an example of a semiconductor device. FIG. 15B and FIG. 15C are cross-sectional views illustrating the example of the semiconductor device.

FIG. 16A is a top view illustrating an example of a semiconductor device. FIG. 16B and FIG. 16C are cross-sectional views illustrating the example of the semiconductor device.

FIG. 17 is a cross-sectional view illustrating an example of a semiconductor device.

FIG. 18A to FIG. 18I are circuit diagrams illustrating examples of semiconductor devices.

FIG. 19A is a top view illustrating an example of a semiconductor device. FIG. 19B and FIG. 19C are cross-sectional views illustrating the example of the semiconductor device.

FIG. 20A to FIG. 20C are cross-sectional views illustrating an example of a semiconductor device.

FIG. 21A is a top view illustrating an example of a semiconductor device. FIG. 21B and FIG. 21C are cross-sectional views illustrating the example of the semiconductor device.

FIG. 22A is a top view illustrating an example of a semiconductor device. FIG. 22B and FIG. 22C are cross-sectional views illustrating the example of the semiconductor device.

FIG. 23A is a top view illustrating an example of a semiconductor device. FIG. 23B is a cross-sectional view illustrating the example of the semiconductor device.

FIG. 24A is a top view illustrating an example of a semiconductor device. FIG. 24B is a cross-sectional view illustrating the example of the semiconductor device.

FIG. 25A and FIG. 25B are equivalent circuit diagrams of a semiconductor device. FIG. 25C is a top view illustrating an example of the semiconductor device.

FIG. 26 is a cross-sectional view illustrating an example of a semiconductor device.

FIG. 27 is a perspective view illustrating an example of a semiconductor device.

FIG. 28A to FIG. 28D are perspective views illustrating an example of a semiconductor device.

FIG. 29A and FIG. 29B are equivalent circuit diagrams of a semiconductor device. FIG. 29C is a top view illustrating an example of the semiconductor device.

FIG. 30 is a cross-sectional view illustrating an example of a semiconductor device.

FIG. 31 is a perspective view illustrating an example of a semiconductor device.

FIG. 32A to FIG. 32D are perspective views illustrating an example of a semiconductor device.

FIG. 33A to FIG. 33E are cross-sectional views illustrating an example of a method for manufacturing a semiconductor device.

FIG. 34A to FIG. 34D are cross-sectional views illustrating an example of a method for manufacturing a semiconductor device.

FIG. 35A and FIG. 35B are cross-sectional views illustrating an example of a method for manufacturing a semiconductor device.

FIG. 36A to FIG. 36C are cross-sectional views illustrating an example of a method for manufacturing a semiconductor device.

FIG. 37 is a perspective view illustrating an example of a display device.

FIG. 38A and FIG. 38B are cross-sectional views illustrating examples of display devices.

FIG. 39 is a cross-sectional view illustrating an example of a display device.

FIG. 40A to FIG. 40C are cross-sectional views illustrating examples of a display device.

FIG. 41A and FIG. 41B are cross-sectional views illustrating examples of display devices.

FIG. 42 is a cross-sectional view illustrating an example of a display device.

FIG. 43 is a cross-sectional view illustrating an example of a display device.

FIG. 44 is a cross-sectional view illustrating an example of a display device.

FIG. 45A and FIG. 45B are cross-sectional views illustrating examples of display devices.

FIG. 46A to FIG. 46D are diagrams illustrating examples of electronic devices.

FIG. 47A to FIG. 47F are diagrams illustrating examples of electronic devices.

FIG. 48A to FIG. 48G are diagrams illustrating examples of electronic devices.

FIG. 49 is a diagram showing XRD analysis results in Example.

FIG. 50 is a graph showing etching rates in Example.

FIG. 51A and FIG. 51B are graphs showing results of the Hall effect measurement in Example.

FIG. 52 is a diagram showing XRD analysis results in Example.

FIG. 53 is a graph showing band gaps in Example.

FIG. 54 is a diagram showing Id-Vg characteristics of transistors of Example.

FIG. 55 is a diagram showing reliability of transistors of Example.

FIG. 56 is a diagram showing Id-Vg characteristics of transistors of Example.

FIG. 57 is a diagram showing Id-Vg characteristics of transistors of Example.

FIG. 58 is a diagram showing Id-Vg characteristics of transistors of Example.

FIG. 59 is a diagram showing Id-Vg characteristics of transistors of Example.

FIG. 60 is a graph showing electrical characteristics of transistors of Example.

FIG. 61 is a diagram showing reliability of transistors of Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”.

A transistor is a kind of semiconductor elements and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification.

Functions of a “source” and a “drain” are sometimes switched when a transistor of opposite polarity is used or when the direction of a current is changed in circuit operation, for example. Thus, the terms “source” and “drain” can be used interchangeably in this specification. Note that a source and a drain of a transistor can also be referred to as a source terminal and a drain terminal, a source electrode and a drain electrode, or the like as appropriate depending on the circumstances.

In this specification and the like, the expression “electrically connected” includes the case where components are connected to each other through an “object having any electric action”. There is no particular limitation on an “object having any electric function” as long as electric signals can be transmitted and received between components that are connected through the object. Examples of the “object having any electric function” include a switching element such as a transistor, a resistor, a coil, and other elements with a variety of functions as well as an electrode or a wiring.

Unless otherwise specified, an off-state current in this specification and the like refers to a leakage current between a source and a drain of a transistor in an off state (also referred to as a non-conduction state or a cut-off state). Unless otherwise specified, an off state in an n-channel transistor refers to a state where a voltage Vgs between its gate and source is lower than a threshold voltage Vth (in a p-channel transistor, higher than Vth).

In this specification and the like, the expression “having substantially the same top surface shapes” means that at least outlines of stacked layers partly overlap with each other. For example, the case of processing an upper layer and a lower layer with the use of the same mask pattern or mask patterns that are partly the same is included. The expression “having substantially the same top surface shapes” also sometimes includes the case where the outlines do not completely overlap with each other; for instance, the edge of the upper layer may be positioned on the inner side or the outer side of the edge of the lower layer. The state of “having the same top surface shape” or “having substantially the same top surface shapes” can be rephrased as the state where “end portions are aligned with each other” or “end portions are substantially aligned with each other”.

In this specification and the like, a tapered shape refers to such a shape that at least part of a side surface of a component is inclined with respect to a substrate surface or a formation surface. For example, the tapered shape preferably includes a region where the angle formed by the inclined side surface and the substrate surface or the formation surface (also referred to as a taper angle) is less than 90°. Note that the side surface, the substrate surface, and the formation surface of the component are not necessarily completely flat and may have a substantially planar shape with a small curvature or a substantially planar shape with slight unevenness.

In this specification and the like, a device formed using a metal mask or an FMM (fine metal mask, high-definition metal mask) may be referred to as a device having an MM (metal mask) structure. In this specification and the like, a device formed without using a metal mask or an FMM may be referred to as a device having an MML (metal maskless) structure. Note that a device having the MML structure can be manufactured without using a metal mask, and thus can break through the definition limit due to alignment accuracy of the metal mask. Furthermore, the device having the MML structure can eliminate the need for the manufacturing facilities for metal masks and the washing process for metal masks. In addition, the device having the MML structure can be manufactured at low cost, and thus is suitable for mass production.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

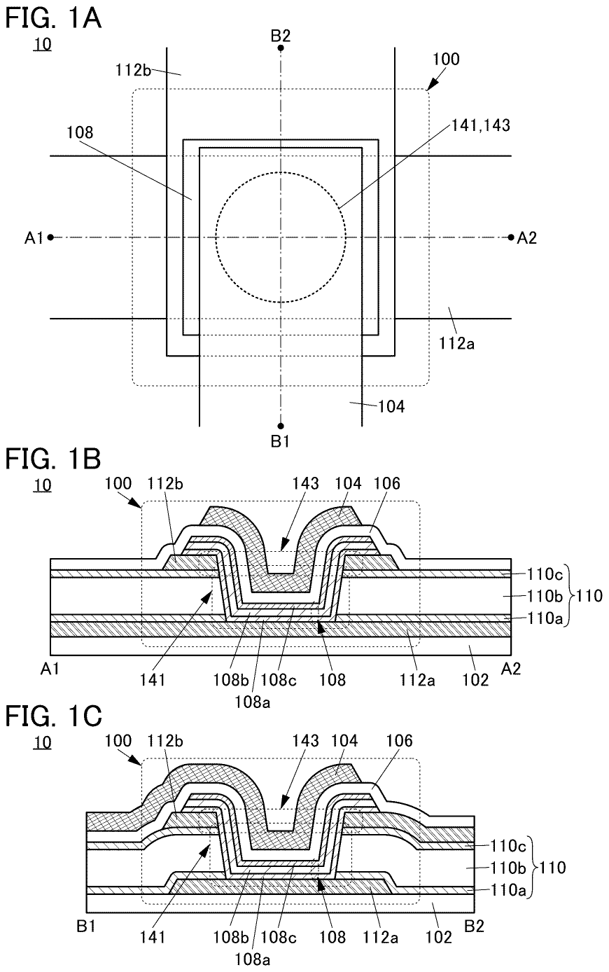

In this embodiment, semiconductor devices of one embodiment of the present invention are described with reference to FIG. 1 to FIG. 32.

One embodiment of the present invention is a semiconductor device including a transistor and a first insulating layer.

The transistor includes a first semiconductor layer, a second semiconductor layer, a third semiconductor layer, a first conductive layer, a second conductive layer, a gate insulating layer, and a gate electrode. The first insulating layer is provided over the first conductive layer. The second conductive layer is provided over the first insulating layer. The first insulating layer includes a first opening reaching the first conductive layer. The second conductive layer includes a second opening in a region overlapping with the first opening. In the first opening and the second opening, the first semiconductor layer is in contact with the top surface of the first conductive layer, the side surface of the first insulating layer, and the side surface of the second conductive layer. The second semiconductor layer is provided over the first semiconductor layer, and the third semiconductor layer is provided over the second semiconductor layer. The gate insulating layer is provided over the third semiconductor layer and the gate electrode is provided over the gate insulating layer. The first conductive layer functions as one of a source electrode and a drain electrode of the transistor, and the second conductive layer functions as the other thereof. The channel length of the transistor can be controlled by the thickness of the first insulating layer interposed between the first conductive layer and the second conductive layer. Accordingly, the transistor can have a short channel length and a high on-state current.

The first semiconductor layer contains a first metal oxide. The second semiconductor layer contains a second metal oxide. The third semiconductor layer contains a third metal oxide. The band gap of the first metal oxide is larger than the band gap of the second metal oxide. The band gap of the third metal oxide is larger than the band gap of the first metal oxide. Accordingly, a buried channel structure can be obtained, and the second semiconductor layer serves as a main current path. The thickness of the third semiconductor layer is larger than that of the first semiconductor layer. The thickness of the second semiconductor layer is larger than that of the third semiconductor layer.

The first insulating layer includes a layer containing oxygen. Regions of the semiconductor layers (the first semiconductor layer to the third semiconductor layer) in contact with the layer functions as a channel formation region of the transistor. Oxygen is supplied from the first insulating layer to the channel formation region. Oxygen released from the first insulating layer is supplied to the second semiconductor layer through the first semiconductor layer. When the thickness of the first semiconductor layer is reduced, oxygen can be efficiently supplied from the first insulating layer to the second semiconductor layer. When the thickness of the third semiconductor layer is larger than the thickness of the first semiconductor layer, damage to the second semiconductor layer at the time of forming the gate insulating layer can be reduced. As a result, the transistor can have favorable electrical characteristics and reliability.

### Structure Example 1

### Structure Example 1-1

The semiconductor device of one embodiment of the present invention will be described. FIG. 1A is a top view (also referred to as a plan view) of a semiconductor device 10. FIG. 1B is a cross-sectional view of a cut plane along the dashed-dotted line A1-A2 in FIG. 1A, and FIG. 1C is a cross-sectional view of a cut plane along the dashed-dotted line B1-B2. Note that in FIG. 1A, some components (e.g., a gate insulating layer) of the semiconductor device 10 are not illustrated. Some components are not illustrated also in the following top views of semiconductor devices, as in FIG. 1A.

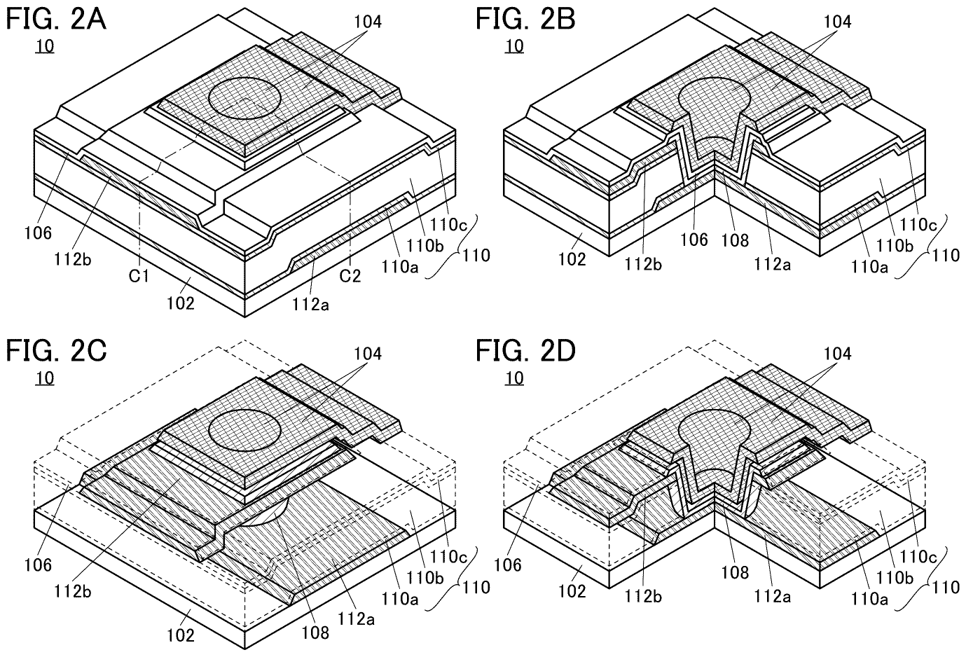

FIG. 2A to FIG. 2D are perspective views of the semiconductor device 10. FIG. 2B illustrates a cut plane along the dashed-dotted line C1-C2 in FIG. 2A. In FIG. 2C, the insulating layer illustrated in FIG. 2A is transparent and its outline is indicated by a dashed line. Similarly, in FIG. 2D, the insulating layer illustrated in FIG. 2B is transparent and its outline is indicated by a dashed line.

The semiconductor device 10 includes a transistor 100 and an insulating layer 110. The semiconductor device 10 is provided over a substrate 102. Alternatively, an insulating film can be provided over the substrate 102 and the semiconductor device 10 can be provided over the insulating film.

The transistor 100 includes a conductive layer 104, an insulating layer 106, a semiconductor layer 108, a conductive layer 112a, and a conductive layer 112b. The conductive layer 104 functions as a gate electrode. Part of the insulating layer 106 functions as a gate insulating layer. The conductive layer 112a functions as one of a source electrode and a drain electrode, and the conductive layer 112b functions as the other of the source electrode and the drain electrode. In the semiconductor layer 108 between the source electrode and the drain electrode, the region overlapping with the gate electrode with the gate insulating layer therebetween functions as a channel formation region. In the semiconductor layer 108, a region in contact with the source electrode functions as a source region, and a region in contact with the drain electrode functions as a drain region.

The conductive layer 112a is provided over the substrate 102, the insulating layer 110 is provided over the conductive layer 112a, and the conductive layer 112b is provided over the insulating layer 110. The insulating layer 110 includes a region interposed between the conductive layer 112a and the conductive layer 112b. The conductive layer 112a includes a region overlapping with the conductive layer 112b with the insulating layer 110 therebetween. The insulating layer 110 includes an opening 141 reaching the conductive layer 112a. It can be said that the conductive layer 112a is exposed in the opening 141. The conductive layer 112b includes an opening 143 in a region overlapping with the conductive layer 112a. The opening 143 is provided in a region overlapping with the opening 141.

The semiconductor layer 108 is provided to cover the opening 141 and the opening 143. The semiconductor layer 108 includes a region in contact with the top surface and the side surface of the conductive layer 112b, the side surface of the insulating layer 110, and the top surface of the conductive layer 112a. The semiconductor layer 108 is electrically connected to the conductive layer 112a through the opening 141 and the opening 143. The semiconductor layer 108 has a shape along the shapes of the top surface and the side surface of the conductive layer 112b, the side surface of the insulating layer 110, and the top surface of the conductive layer 112a.

There is no particular limitation on the semiconductor material used for the semiconductor layer 108. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor (OS). These semiconductor materials may contain an impurity as a dopant.

There is no particular limitation on the crystallinity of a semiconductor material used for the semiconductor layer 108, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

Silicon can be used for the semiconductor layer 108, for example. Examples of silicon include single crystal silicon, polycrystalline silicon, microcrystalline silicon, and amorphous silicon. An example of polycrystalline silicon is low-temperature polysilicon (LTPS). The transistor including amorphous silicon in the channel formation region can be formed over a large glass substrate, and can be manufactured at low cost. A transistor using polycrystalline silicon in the channel formation region has high field-effect mobility and enables high-speed operation. A transistor using microcrystalline silicon in the channel formation region has higher field-effect mobility and enables higher-speed operation than the transistor using amorphous silicon.

The semiconductor layer 108 preferably contains a metal oxide exhibiting semiconductor characteristics (also referred to as an oxide semiconductor). A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can retained for a long period. Furthermore, the power consumption of the semiconductor device can be reduced with the OS transistor.

The semiconductor layer 108 preferably has a stacked-layer structure. FIG. 1B and the like illustrate a structure in which the semiconductor layer 108 has a stacked-layer structure of a semiconductor layer 108a, a semiconductor layer 108b over the semiconductor layer 108a, and a semiconductor layer 108c over the semiconductor layer 108b.

The semiconductor layer 108a, the semiconductor layer 108b, and the semiconductor layer 108c each preferably contain a metal oxide exhibiting semiconductor characteristics. The band gap of a first metal oxide contained in the semiconductor layer 108a, the band gap of a second metal oxide contained in the semiconductor layer 108b, and the band gap of a third metal oxide contained in the semiconductor layer 108c are each preferably higher than or equal to 2.0 eV, further preferably higher than or equal to 2.5 eV.

The first metal oxide and the second metal oxide preferably have different band gaps. The third metal oxide and the second metal oxide preferably have different band gaps. Moreover, the third metal oxide and the first metal oxide further preferably have different band gaps.

The band gap of the first metal oxide is preferably larger than the band gap of the second metal oxide. The band gap of the third metal oxide is preferably larger than the band gap of the second metal oxide. The semiconductor layer 108b is interposed between the semiconductor layer 108a and the semiconductor layer 108c, which have a larger band gap than the semiconductor layer 108b, and thus can have a structure of a buried channel. Thus, the semiconductor layer 108b serves as a main current path in the semiconductor layer 108.

The band gap of the third metal oxide is further preferably larger than the band gap of the first metal oxide. When a material having a larger band gap is used for the semiconductor layer 108c positioned on the conductive layer 104 side functioning as the gate electrode, generation and induction of carriers in the semiconductor layer 108c and at the interface between the semiconductor layer 108c and the gate insulating layer (here, the insulating layer 106) are inhibited, so that the transistor can have high reliability. For example, generation and induction of carriers in the semiconductor layer 108c and its interface by light entering the transistor are inhibited, so that a change in electrical characteristics of the transistor due to light can be inhibited.

The semiconductor layer 108a includes regions in contact with the conductive layer 112a and the conductive layer 112b that function as the source electrode and the drain electrode. When the band gap of the first metal oxide contained in the semiconductor layer 108a is smaller than that of the third metal oxide, the contact resistance between the semiconductor layer 108a and the conductive layer 112a and the contact resistance between the semiconductor layer 108a and the conductive layer 112b can be reduced. Thus, the transistor can have a high on-state current.

The difference between the band gap of the first metal oxide and the band gap of the second metal oxide is preferably greater than or equal to 0.1 eV, further preferably greater than or equal to 0.2 eV, still further preferably greater than or equal to 0.3 eV, still further preferably greater than or equal to 0.5 eV. A difference between the band gap of the third metal oxide and the band gap of the second metal oxide is preferably greater than or equal to 0.1 eV, further preferably greater than or equal to 0.2 eV, still further preferably greater than or equal to 0.3 eV, still further preferably greater than or equal to 0.5 eV. The difference between the band gap of the first metal oxide and the band gap of the third metal oxide is preferably greater than or equal to 0.1 eV, further preferably greater than or equal to 0.2 eV, still further preferably greater than or equal to 0.3 eV.

The conduction band minimum of the first metal oxide is preferably closer to the vacuum level than the conduction band minimum of the second metal oxide. The conduction band minimum of the third metal oxide is preferably closer to the vacuum level than the conduction band minimum of the second metal oxide. In other words, the electron affinity of the first metal oxide is preferably smaller than the electron affinity of the second metal oxide. The electron affinity of the third metal oxide is preferably smaller than the electron affinity of the second metal oxide. Furthermore, the conduction band minimum of the third metal oxide is preferably closer to the vacuum level than the conduction band minimum of the first metal oxide. In other words, the electron affinity of the third metal oxide is preferably smaller than the electron affinity of the first metal oxide.

The band gaps of the first metal oxide, the second metal oxide, and the third metal oxide can be evaluated using optical evaluation with a spectrophotometer, spectroscopic ellipsometry, a photoluminescence method, X-ray photoelectron spectrometry (XPS or ESCA: Electron spectrometry for Chemical Analysis), or an X-ray absorption fine structure (XAFS). Alternatively, these methods may be combined for the analysis. The electron affinity or the conduction band minimum can be obtained from a band gap and an ionization potential, which is the difference between a vacuum level and the energy of valence band maximum. The ionization potential can be evaluated using, for example, an ultraviolet photoelectron spectrometry (UPS).

Here, a trap state due to impurities or defects can be formed at the interface between the insulating layer 110 and the semiconductor layer 108 and in the vicinity thereof. Examples of the impurities include a remaining component of an etchant or an etching gas used in the formation of the opening 141 and components of the conductive layer 112a and the conductive layer 112b attached to the side surface of the insulating layer 110 in the formation of the opening 141. Providing the semiconductor layer 108a between the semiconductor layer 108b and the insulating layer 110 can make the semiconductor layer 108b and the trap state to be distant from each other.

The interface between the insulating layer 106 and the semiconductor layer 108 and the vicinity thereof might be damaged at the time of forming the insulating layer 106. Accordingly, trap states can be formed at the interface between the insulating layer 106 and the semiconductor layer 108 and in the vicinity thereof. Providing the semiconductor layer 108c between the semiconductor layer 108b and the insulating layer 106 can make the semiconductor layer 108b and the trap state to be distant from each other.

When the semiconductor layer 108b, which is the main current path of the semiconductor layer 108, is interposed between the semiconductor layer 108a and the semiconductor layer 108c, the trap states at the interface of the semiconductor layer 108b and the vicinity thereof can be reduced. This structure enables the transistor to have a high-on state and high reliability. Consequently, the semiconductor device can achieve both high-speed operation and high reliability.

The insulating layer 110 preferably includes one or more inorganic insulating layers. Examples of a material that can be used for the inorganic insulating layer include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride. Examples of the oxynitride include silicon oxynitride, aluminum oxynitride, gallium oxynitride, yttrium oxynitride, and hafnium oxynitride. Examples of the nitride oxide include a silicon nitride oxide and an aluminum nitride oxide.

In this specification and the like, an oxynitride refers to a material that contains more oxygen than nitrogen in its composition. A nitride oxide refers to a material that contains more nitrogen than oxygen in its composition.

The insulating layer 110 includes a region in contact with the semiconductor layer 108. In the case where the semiconductor layer 108 is formed using a metal oxide, at least part of the region of the insulating layer 110 that is in contact with the semiconductor layer 108 preferably contains oxygen to improve the characteristics of the interface between the semiconductor layer 108 and the insulating layer 110. Specifically, the portion of the insulating layer 110 that is in contact with the channel formation region of the semiconductor layer 108 preferably contains oxygen. One or more of an oxide and an oxynitride is suitably used for the portion of the insulating layer 110 that is in contact with the channel formation region of the semiconductor layer 108.

In the case where a metal oxide is used for the semiconductor layer 108, at least part of the region of the insulating layer 110 that is in contact with the semiconductor layer 108 preferably releases oxygen by heat application. This enables oxygen supply from the insulating layer 110 to the semiconductor layer 108, so that oxygen vacancies (Vo) and defects in which hydrogen enters oxygen vacancies (hereinafter referred to as VoH) in the semiconductor layer 108 can be reduced.

Oxygen contained in the insulating layer 110 is supplied to the semiconductor layer 108b through the semiconductor layer 108a. Thus, the semiconductor layer 108a preferably transmits oxygen easily. Accordingly, oxygen contained in the insulating layer 110 can be efficiently supplied to the semiconductor layer 108b. This enables reduction in oxygen vacancies (Vo) and VoH in the semiconductor layer 108b, which is the main current path.

The insulating layer 106 functioning as the gate insulating layer of the transistor 100 is provided to cover the opening 141 and the opening 143. The insulating layer 106 is provided over the semiconductor layer 108, the conductive layer 112b, and the insulating layer 110. The insulating layer 106 includes a region in contact with the top surface and the side surface of the semiconductor layer 108, the top surface and the side surface of the conductive layer 112b, and the top surface of the insulating layer 110. The insulating layer 106 has a shape along the shapes of the top surface of the insulating layer 110, the top surface and the side surface of the conductive layer 112b, the top surface and the side surface of the semiconductor layer 108, and the top surface of the conductive layer 112a.

The conductive layer 104 functioning as the gate electrode of the transistor 100 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the top surface and the side surface of the insulating layer 106.

The transistor 100 is what is called a top-gate transistor including the gate electrode above the semiconductor layer 108. Furthermore, since the bottom surface of the semiconductor layer 108 is in contact with the source electrode and the drain electrode, the transistor 100 can be referred to as a TGBC (Top Gate Bottom Contact) transistor. In the transistor 100, the source electrode and the drain electrode are positioned at different levels with respect to the surface of the substrate 102 over which the transistor 100 is formed, and a drain current flows in a direction perpendicular or substantially perpendicular to the surface of the substrate 102. In the transistor 100, the drain current can also be regarded as flowing in the vertical direction or the substantially vertical direction. Accordingly, the transistor of one embodiment of the present invention can be referred to as a vertical-channel transistor, a vertical transistor, or a VFET (Vertical Field-Effect Transistor).

The channel length of the transistor 100 can be controlled by the thickness of the insulating layer 110 provided between the conductive layer 112a and the conductive layer 112b. Accordingly, a transistor with a channel length smaller than the resolution limit of a light-exposure apparatus used for manufacturing the transistor can be manufactured with high accuracy. Furthermore, variations in characteristics among the transistors 100 are also reduced. Accordingly, the semiconductor device 10 can be operated stably and have higher reliability. When the variation in characteristics of the transistors are reduced, the circuit design flexibility is increased and the operation voltage of the semiconductor device can be reduced. Thus, the power consumption of the semiconductor device can be reduced.

In the transistor of one embodiment of the present invention, since the source electrode, the semiconductor layer, and the drain electrode can be provided to overlap with each other, the area occupied by the transistor can be significantly reduced as compared with a so-called planar transistor in which a semiconductor layer is positioned over a flat surface.

The conductive layer 112a, the conductive layer 112b, and the conductive layer 104 can function as wirings, and the transistor 100 can be provided in a region where these wirings overlap with each other. That is, the areas occupied by the transistor 100 and the wirings can be reduced in the circuit including the transistor 100 and the wirings. Accordingly, the area occupied by the circuit can be reduced, which makes it possible to provide a small semiconductor device.

When the semiconductor device of one embodiment of the present invention is used for a pixel circuit of the display device, the area occupied by the pixel circuit can be reduced and the display device can have high definition, for example. When the semiconductor device of one embodiment of the present invention is used for a driver circuit (e.g., one or both of a gate line driver circuit and a source line driver circuit) of the display device, the area occupied by the driver circuit can be reduced and the display device can have a narrow bezel, for example.

Although the semiconductor layer 108, the insulating layer 106, and the conductive layer 104 cover the opening 141 and the opening 143 in the example in FIG. 1B or the like, one embodiment of the present invention is not limited thereto. A step may be formed between the conductive layer 112a and each of the insulating layer 110 and the conductive layer 112b, and the semiconductor layer 108, the insulating layer 106, and the conductive layer 104 may be provided along the step.

### [Semiconductor Layer 108]

Materials that can be used for the semiconductor layer 108 are specifically described.

A metal oxide is preferably used for each of the semiconductor layer 108a, the semiconductor layer 108b, and the semiconductor layer 108c. It is further preferable to use a metal oxide having crystallinity for each of the semiconductor layer 108a, the semiconductor layer 108b, and the semiconductor layer 108c. Examples of the structure of a metal oxide having crystallinity include a CAAC (c-axis aligned crystal) structure, a polycrystalline structure, and a nano-crystal (nc) structure. With use of a metal oxide having crystallinity for the semiconductor layer 108, the density of defect states in the semiconductor layer 108 can be reduced, which enables the semiconductor device to have high reliability.

The CAAC-OS includes a plurality of layered crystals. The c-axis of the crystal is aligned in the normal direction of the formation surface. The semiconductor layer 108 preferably includes layered crystals parallel or substantially parallel to the formation surface. For example, the semiconductor layer 108 preferably includes a layered crystal parallel or substantially parallel to the top surface of the conductive layer 112b in a region in contact with the top surface, and a layered crystal parallel or substantially parallel to the side surface of the insulating layer 110 in a region in contact with the side surface. In particular, the channel formation region preferably includes layered crystals parallel or substantially parallel to the side surface of the insulating layer 110. With such a structure, the layered crystals of the semiconductor layer 108 are formed parallel or substantially parallel to the channel length direction of the transistor 100, so that the on-state current and field-effect mobility of the transistor can be increased. Thus, a semiconductor device that operates at high speed can be obtained.

When a metal oxide having high crystallinity is used for the semiconductor layer 108b, which is the main current path, the density of defect states in the semiconductor layer can be reduced. By contrast, when a metal oxide having low crystallinity is used for the semiconductor layer 108b, a transistor in which a large amount of current can flow can be achieved.

When the first metal oxide having crystallinity is used for the semiconductor layer 108a, the crystallinity of the second metal oxide included in the semiconductor layer 108b formed over the semiconductor layer 108a can be increased in some cases. Similarly, when the second metal oxide having crystallinity is used for the semiconductor layer 108b, the crystallinity of the third metal oxide included in the semiconductor layer 108c formed over the semiconductor layer 108b can be increased in some cases.

As each of the first metal oxide, the second metal oxide, and the third metal oxide, indium oxide, gallium oxide, or zinc oxide can be used, for example. The metal oxide preferably contains at least indium or zinc. The metal oxide preferably contains two or three kinds selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably one or more of aluminum, gallium, and tin. These elements are further preferable because they have high bonding energy with oxygen and have substantially the same ion radius as indium or zinc. In addition, tin is tetravalent and is further preferable because the carrier mobility of the semiconductor layer can be increased. In this specification and the like, a metal element and a metalloid element may be collectively referred to as a “metal element”, and a “metal element” in this specification and the like may refer to a metalloid element.

For example, for each of the first metal oxide, the second metal oxide, and the third metal oxide, an indium zinc oxide (also referred to as In—Zn oxide or IZO (registered trademark)), an indium tin oxide (also referred to as In—Sn oxide or ITO), an indium titanium oxide (In—Ti oxide), an indium gallium oxide (In—Ga oxide), an indium tungsten oxide (also referred to as In—W oxide or IWO), an indium gallium aluminum oxide (In—Ga—Al oxide), an indium gallium tin oxide (also referred to as In—Ga—Sn oxide or IGTO), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (also referred to as In—Sn—Zn oxide or ITZO (registered trademark)), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, IGZAO, or IAGZO) can be used. Alternatively, indium tin oxide containing silicon (also referred to as ITSO), gallium tin oxide (Ga—Sn oxide), aluminum tin oxide (Al—Sn oxide), or the like can be used.

Note that the metal oxide may contain, instead of indium or in addition to indium, one or more kinds of metal elements belonging to a period of a higher number in the periodic table. The larger the overlap between orbits of metal elements is, the more likely it is that the metal oxide will have high carrier conductivity. Thus, a transistor containing a metal element with a large period number can have high field-effect mobility in some cases. Examples of the metal element belonging to a period of a higher number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. By containing a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of indium atoms in the total number of atoms of all the metal elements contained in the metal oxide, the field-effect mobility of the transistor can be increased. In addition, the transistor can have a high on-state current.

In this specification and the like, the proportion of the number of indium atoms in the total number of atoms of all the metal elements contained is sometimes referred to as the content percentage of indium. The same applies to other metal elements.

The metal oxide having an increased zinc content percentage has high crystallinity, whereby diffusion of impurities in the metal oxide can be inhibited. Consequently, a change in electrical characteristics of the transistor can be inhibited, and the reliability of the transistor can be increased.

By increasing the element M content percentage in the metal oxide, the metal oxide can have a large band gap. In addition, formation of oxygen vacancies (Vo) in the metal oxide is inhibited; accordingly, generation of carriers due to oxygen vacancies (Vo) and a shift in the threshold voltage of the transistor can be inhibited. This enables reduction in a drain current which flows at a gate voltage of 0 V (hereinafter also referred to as a cut-off current), so that a normally-off transistor can be obtained. In addition, a transistor with a low off-state current can be provided. Furthermore, a change in electrical characteristics of the transistor is inhibited, and the reliability of the transistor can be increased.

The compositions of the first metal oxide, the second metal oxide, and the third metal oxide are preferably different from each other. Electrical characteristics and reliability of a transistor depend on the composition of the metal oxide used for the semiconductor layer. Thus, by varying the compositions of the first metal oxide, the second metal oxide, and the third metal oxide in accordance with the electrical characteristics and reliability required for the transistor, the semiconductor device can have both excellent electrical characteristics and high reliability.

The second metal oxide used for the semiconductor layer 108b preferably has a high atomic proportion of indium. The atomic proportion of indium is preferably greater than the atomic proportion of the element M in the second metal oxide. In the semiconductor layer 108, when a metal oxide with a high atomic proportion of indium is used for the semiconductor layer 108b, which is the main current path, the on-state current or field-effect mobility of the transistor can be increased.

When the second metal oxide is In-M-Zn oxide, the atomic proportion of In is preferably higher than the atomic proportion of the element M in the In-M-Zn oxide. Examples of the atomic ratio of the metal elements in such In-M-Zn oxide include In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=5:1:9, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and a composition in the neighborhood of any of these atomic ratios. Note that a composition in the neighborhood includes the range of ±30% of a desired atomic ratio. Furthermore, the atomic proportion of In is preferably higher than or equal to that of Zn in the second metal oxide. By increasing the atomic proportion of indium in the metal oxide, the on-state current and field-effect mobility of the transistor can be increased. Note that the atomic proportion of In may be less than the atomic proportion of Zn in the second metal oxide.

In the case where a plurality of elements are contained as the element M, the sum of the proportions of the numbers of atoms of these elements can be the proportion of the number of element M atoms.

The use of a material with a high content percentage of indium for the semiconductor layer 108b, which is the main current path, can increase the on-state current, field-effect mobility, or the like of the transistor. Furthermore, with the element M, generation of oxygen vacancies (Vo) can be inhibited. The content percentage of the element M (the proportion of the number of the element M atoms to the total number of atoms of all the metal elements contained) is preferably greater than or equal to 0.1% and less than or equal to 25%, further preferably greater than or equal to 0.1% and less than or equal to 20%, still further preferably greater than or equal to 0.1% and less than or equal to 10%, yet still further preferably greater than or equal to 0.1% and less than or equal to 8%, yet still further preferably greater than or equal to 0.1% and less than or equal to 6%, yet still further preferably greater than or equal to 0.1% and less than or equal to 4%. Accordingly, a transistor with favorable electrical characteristics can be provided. For example, a metal oxide with In:M:Zn of 40:1:10 or the neighborhood thereof is preferably used. The element M is preferably one or more kinds of the above elements, further preferably one or more kinds selected from aluminum, gallium, tin, and yttrium. Specifically, a metal oxide with In:Sn:Zn of 40:1:10 or the neighborhood thereof can be suitably used. Alternatively, a metal oxide with In:Al:Zn of 40:1:10 or the neighborhood thereof can be suitably used.

Here, in the case where a metal oxide having a polycrystalline structure is used for the semiconductor layer 108, the crystal grain boundary becomes a recombination center and captures carriers and thus decreases the on-state current of the transistor, in some cases. In addition, when a metal oxide having a polycrystalline structure is used for the semiconductor layer 108, unevenness of the surface of the semiconductor layer 108 is increased in some cases. This increases a step in the formation surface of a layer formed over the semiconductor layer 108 (e.g., the insulating layer 106), so that generation of defects such as step disconnection or voids in the layer sometimes occurs. In the case where a metal oxide with a composition that tends to form a polycrystalline structure is used for the semiconductor layer 108 (in particular, the semiconductor layer 108b), the metal oxide preferably contains an element that hinders crystallization. This inhibits the semiconductor layer 108 (in particular, the semiconductor layer 108b) from having a polycrystalline structure, so that a transistor with a high on-state current can be obtained. Accordingly, the coverage with a layer formed over the semiconductor layer 108 (e.g., the insulating layer 106) can be improved, which can prevent defects such as step disconnection or a void from being generated in the layer.

For example, an indium tin oxide containing silicon (ITSO) is less likely to have a polycrystalline structure than an indium tin oxide (ITO), and thus can be suitably used for the semiconductor layer 108 (in particular, the semiconductor layer 108b). In the case where ITSO is used, the content percentage of silicon (the proportion of the number of silicon atoms in the total number of atoms of all the metal elements contained) is preferably higher than or equal to 1% and lower than or equal to 20%, further preferably higher than or equal to 3% and lower than or equal to 20%, further preferably higher than or equal to 3% and lower than or equal to 15%, still further preferably higher than or equal to 5% and lower than or equal to 15%. Specifically, a metal oxide with In:Sn:Si of 45:5:4, In:Sn:Si of 95:5:8, or the neighborhood thereof can be suitably used. In the case where indium tin oxide containing silicon (ITSO) is used for the semiconductor layer 108 (in particular, the semiconductor layer 108b), the semiconductor layer preferably has crystallinity. Note that the semiconductor layer 108 may include an amorphous region or may be amorphous.

The second metal oxide may have a composition not containing the element M. In the case where the second metal oxide is In—Zn oxide, it can be said that the atomic proportion of In is higher than the atomic proportion of the element M in the In—Zn oxide. Examples of the atomic ratio of the metal elements in such In—Zn oxide include In:Zn=1:1, In:Zn=2:1, In:Zn=1:2, In:Zn=3:1, In:Zn=3:2, In:Zn=2:3, In:Zn=4:1, In:Zn=4:3, In:Zn=5:1, In:Zn=5:2, In:Zn=5:3, In:Zn=5:4, In:Zn=5:6, In:Zn=5:7, In:Zn=5:8, In:Zn=5:9, In:Zn=7:1, In:Zn=10:1, In:Zn=10:3, In:Zn=10:7, and a composition in the neighborhood of any of these atomic ratios. Furthermore, the atomic proportion of In is preferably higher than or equal to that of Zn. By increasing the atomic proportion of indium in the metal oxide, the on-state current and field-effect mobility of the transistor can be increased.

The content percentage of indium in the second metal oxide is preferably higher than that in the first metal oxide. The content percentage of indium in the second metal oxide is preferably higher than that in the third metal oxide. Thus, the on-state current and field-effect mobility of the transistor can be increased.

By varying the composition of the metal oxide, the band gap can be adjusted. Each of the first metal oxide and the third metal oxide preferably has a high atomic proportion of the element M. The atomic proportion of the element M is preferably higher than or equal to the atomic proportion of indium in the first metal oxide. Thus, the band gap of the first metal oxide can be increased. Similarly, the atomic proportion of the element M is preferably higher than or equal to the atomic proportion of indium in the third metal oxide. Accordingly, the band gap of the third metal oxide can be increased.

When the first metal oxide is In-M-Zn oxide, the atomic proportion of In is preferably lower than or equal to the atomic proportion of the element M in the In-M-Zn oxide. That is, the atomic proportion of the element M is preferably greater than or equal to the atomic proportion of indium. Examples of the atomic ratio of the metal elements in such In-M-Zn oxide include In:M:Zn=1:1:1, In:M:Zn=1:1:1.2, In:M:Zn=1:3:2, In:M:Zn=1:3:3, In:M:Zn=1:3:6, In:M:Zn=1:3:4, and a composition in the neighborhood of any of these atomic ratios. By increasing the atomic proportion of M in the metal oxide, generation of oxygen vacancies can be inhibited. In addition, the band gap can be increased. The same applies to the third metal oxide.

For example, the content percentage of the element M in the first metal oxide is preferably higher than that of the element M in the second metal oxide. Thus, the band gap of the first metal oxide can be larger than the band gap of the second metal oxide. Similarly, the content percentage of the element M in the third metal oxide is preferably higher than that of the element M in the second metal oxide. Accordingly, the band gap of the third metal oxide can be larger than that of the second metal oxide.

The content percentage of the element M in the third metal oxide is preferably higher than that of the element M in the first metal oxide. Accordingly, the band gap of the third metal oxide can be larger than that of the first metal oxide.

When the content percentage of the element M having a high bonding energy with oxygen is reduced in the first metal oxide, the semiconductor layer 108a can easily transmit oxygen. That is, oxygen contained in the insulating layer 110 can be efficiently supplied to the semiconductor layer 108b through the semiconductor layer 108a. Accordingly, oxygen vacancies (Vo) and VoH in the semiconductor layer 108b, which is the main current path, can be reduced. Thus, the shift of the threshold voltage is inhibited and the transistor can have both a low cut-off current and a high on-state current. The semiconductor device can have both low power consumption and high performance.

Specifically, in the case where the first metal oxide, the second metal oxide, and the third metal oxide are each In-M-Zn oxide, the first metal oxide can have an atomic ratio of In:M:Zn=1:1:1 or in the neighborhood thereof, the second metal oxide can have an atomic ratio of In:M:Zn=40:1:10 or in the neighborhood thereof, and the third metal oxide can have an atomic ratio of In:M:Zn=1:3:4 or in the neighborhood thereof, for example. Alternatively, the first metal oxide can have an atomic ratio of In:M:Zn=1:1:1 or in the neighborhood thereof, the second metal oxide can have an atomic ratio of In:M:Zn=10:1:10 or in the neighborhood thereof, and the third metal oxide can have an atomic ratio of In:M:Zn=1:3:4 or in the neighborhood thereof.

More specifically, the first metal oxide can have an atomic ratio of In:Ga:Zn=1:1:1 or in the neighborhood thereof, the second metal oxide can have an atomic ratio of In:Sn:Zn=40:1:10 or in the neighborhood thereof, and the third metal oxide can have an atomic ratio of In:Ga:Zn=1:3:4 or in the neighborhood thereof. Alternatively, the first metal oxide can have an atomic ratio of In:Ga:Zn=1:1:1 or in the neighborhood thereof, the second metal oxide can have an atomic ratio of In:Sn:Zn=10:1:10 or in the neighborhood thereof, and the third metal oxide can have an atomic ratio of In:Ga:Zn=1:3:4 or in the neighborhood thereof.

The second metal oxide may have a composition not including the element M. For example, the second metal oxide can be In—Zn oxide, and the first metal oxide and the third metal oxide can be In-M-Zn oxide. More specifically, the first metal oxide can have an atomic ratio of In:Ga:Zn=1:1:1 or in the neighborhood thereof, the second metal oxide can have an atomic ratio of In:Zn=4:1 or in the neighborhood thereof, and the third metal oxide can have an atomic ratio of In:Ga:Zn=1:3:4 or in the neighborhood thereof. Alternatively, the first metal oxide can have an atomic ratio of In:Ga:Zn=1:1:1 or in the neighborhood thereof, the second metal oxide can have an atomic ratio of In:Zn=1:1 or in the neighborhood thereof, and the third metal oxide can have an atomic ratio of In:Ga:Zn=1:1:1 or in the neighborhood thereof.

As an analysis of the composition of the first metal oxide, the second metal oxide, and the third metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, these methods may be combined for the analysis. Note that peak separation of a spectrum obtained by the analysis is preferably performed to identify and quantify an element. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage or difficult to quantify, or the element M may be below the lower detection limit.

The case where EDX is used for analysis of the compositions of the first metal oxide, the second metal oxide, and the third metal oxide will be specifically described. In EDX, the proportion of the number of atoms of each element contained in the analysis target can be calculated. A comparison is made of the proportion of the number of indium atoms in the sum of the calculated total number of atoms of all the metal elements (indium content percentage), whereby the difference in indium content percentage can be confirmed. In EDX, the number of counts of characteristic X-rays corresponds to the proportion of an element contained in a metal oxide. Thus, from the peak heights of indium, the difference in indium content percentage can be confirmed. For example, in the case where the content percentage of indium in the second metal oxide is higher than the content percentage of indium in the first metal oxide, the number of counts of characteristic X-rays derived from indium in the second metal oxide is higher than the number of counts of characteristic X-rays derived from indium in the first metal oxide. Note that in EDX, the peak of a certain element refers to a point at which the number of counts of the element reaches a local maximum value in a spectrum where the horizontal axis represents the energy of a characteristic X-ray and the vertical axis represents the number of counts of the characteristic X-ray. Alternatively, the number of counts at an energy of a characteristic X-ray unique to the element may be used to confirm the difference in content percentage. For example, the number of counts at 3.287 keV (In-Lα) can be used for indium.

Although the description has been given by taking the indium content percentage as an example here, the same applies to the content percentages of other elements. In the case where the difference in the content percentage is confirmed using the number of counts at an energy of a characteristic X-ray unique to the element, the number of counts at 9.243 keV (Ga-Kα) can be used for gallium, the number of counts at 8.632 keV (Zn-Kα) can be used for zinc, and the number of counts at 3.444 keV (In-Lα) can be used for tin, for example.

A sputtering method or an atomic layer deposition (ALD) method can be suitably used to form the metal oxide. In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

For the analysis of the crystallinity of the semiconductor layer 108a, the semiconductor layer 108b, and the semiconductor layer 108c, X-ray diffraction (XRD), a transmission electron microscope (TEM), or electron diffraction (ED), can be used, for example. Alternatively, these methods may be combined for the analysis.

Note that the composition of the third metal oxide may be the same as or substantially the same as the composition of the first metal oxide. Employing the metal oxides having the same composition can reduce the manufacturing cost because the semiconductor layer 108a and the semiconductor layer 108c can be formed using the same sputtering target.

In the case where the composition of the first metal oxide is the same as or substantially the same as the composition of the third metal oxide, the crystallinity of the semiconductor layer 108c is preferably higher than that of the semiconductor layer 108a. When the crystallinity of the semiconductor layer 108c is higher than that of the semiconductor layer 108a, the semiconductor layer 108 can be inhibited from being damaged in forming the insulating layer 106. Meanwhile, when the crystallinity of the semiconductor layer 108a is lower than that of the semiconductor layer 108c, the semiconductor layer 108 easily transmits oxygen, so that oxygen contained in the insulating layer 110 can be efficiently supplied to the semiconductor layer 108b.

As the substrate temperature at the time of formation of the metal oxide is higher, the crystallinity of the formed metal oxide can be increased. For example, the substrate temperature at the time of formation can be adjusted by the temperature of the stage on which the substrate is placed at the time of formation. As the proportion of the flow rate of an oxygen gas to the total flow rate of the film formation gas used for formation (hereinafter also referred to as the oxygen flow rate ratio) or the oxygen partial pressure in a processing chamber of a film formation apparatus is higher, the metal oxide can be formed to have higher crystallinity.

The substrate temperature at the time of forming the semiconductor layer 108c is preferably higher than the substrate temperature at the time of forming the semiconductor layer 108a. The oxygen flow rate ratio or the oxygen partial pressure at the time of forming the semiconductor layer 108c is preferably higher than the oxygen flow rate ratio or the oxygen partial pressure at the time of forming the semiconductor layer 108a. Accordingly, the crystallinity of the semiconductor layer 108c can be higher than that of the semiconductor layer 108a.

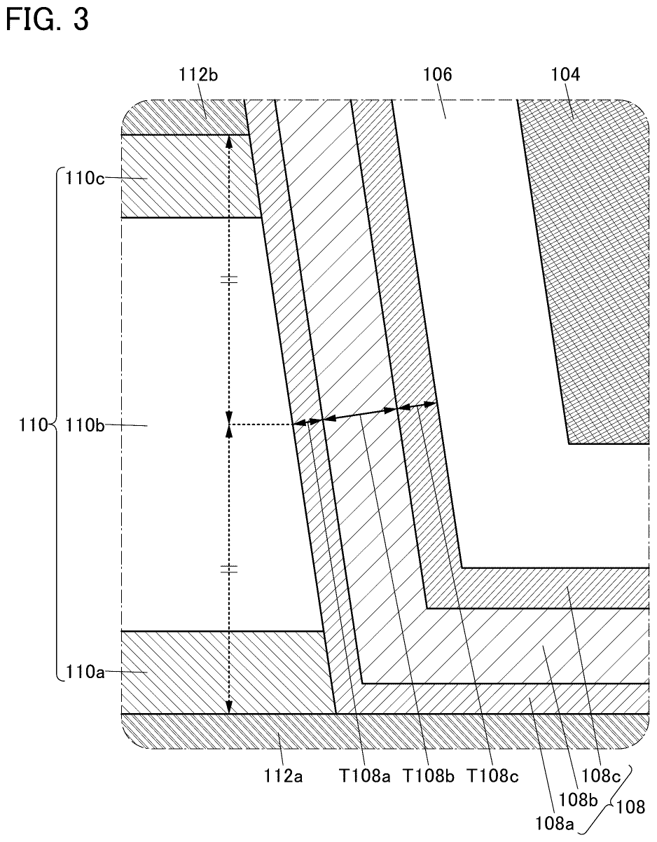

FIG. 3 is an enlarged view of the side surface of the insulating layer 110 and the vicinity thereof. In FIG. 3, a thickness T108a of the semiconductor layer 108a, a thickness T108b of the semiconductor layer 108b, and a thickness T108c of the semiconductor layer 108c are indicated by solid double-headed arrows. Here, the shortest distance between the insulating layer 110 and the insulating layer 106 in the cross-sectional view is the thickness of the semiconductor layer 108. Specifically, FIG. 3 shows the thicknesses of the layers of the semiconductor layer 108 at the midpoint between the level of the top surface and the level of the bottom surface of the insulating layer 110.

When the thickness T108b of the semiconductor layer 108b, which is the main current path, is made thick, the transistor can have a high on-state current. However, in the case where the thickness T108b is too large, the amount of oxygen vacancy (Vo) and VoH in the semiconductor layer 108b might be larger than the amount of oxygen vacancy (Vo) and VoH repaired by oxygen supplied from the insulating layer 110. The thickness T108b of the semiconductor layer 108b is preferably larger than or equal to 1 nm and smaller than or equal to 50 nm, further preferably larger than or equal to 3 nm and smaller than or equal to 30 nm, still further preferably larger than or equal to 3 nm and smaller than or equal to 20 nm, yet still further preferably larger than or equal to 5 nm and smaller than or equal to 20 nm, yet still further preferably larger than or equal to 5 nm and smaller than or equal to 15 nm.

Here, the semiconductor layer 108a positioned on the insulating layer 110 side preferably transmits a substance (e.g., an atom, a molecule, and an ion) more easily than the semiconductor layer 108c positioned on the insulating layer 106 side. In particular, the semiconductor layer 108a preferably transmits oxygen more easily than the semiconductor layer 108c. When oxygen is supplied from the insulating layer 110 to the semiconductor layer 108, oxygen vacancies (Vo) and VoH in the semiconductor layer 108 can be reduced. It is particularly preferable that oxygen be supplied to the semiconductor layer 108b, which is the main current path, to reduce oxygen vacancies (Vo) and VoH in the semiconductor layer 108b. Oxygen contained in the insulating layer 110 is supplied to the semiconductor layer 108b through the semiconductor layer 108a. Thus, a structure of the semiconductor layer 108a that easily transmits oxygen enables efficient supply of oxygen contained in the insulating layer 110 to the semiconductor layer 108b.

When the thickness T108a of the semiconductor layer 108a is large, oxygen supply from the insulating layer 110 to the semiconductor layer 108b becomes difficult in some cases. In addition, the distance between the semiconductor layer 108b and the conductive layer 112a and the conductive layer 112b that function as the source electrode and the drain electrode is increased and thus an on-state current may be reduced in some cases. Meanwhile, when the thickness T108a of the semiconductor layer 108a is too small, the distance between the semiconductor layer 108b, which is the main current path, and the trap states at the interface between the insulating layer 110 and the semiconductor layer 108 and the vicinity thereof is reduced; thus, an on-state current may be reduced. In addition, the reliability of the transistor may be degraded. The thickness T108a of the semiconductor layer 108a is preferably larger than or equal to 0.1 nm and smaller than or equal to 10 nm, further preferably larger than or equal to 0.3 nm and smaller than or equal to 5 nm, still further preferably larger than or equal to 0.5 nm and smaller than or equal to 5 nm, yet still further preferably larger than or equal to 0.5 nm and smaller than or equal to 3 nm.

Note that when the thickness T108a of the semiconductor layer 108a is reduced, impurities contained in the semiconductor layer 108 are diffused to the insulating layer 110 side through the semiconductor layer 108a, so that the effect of reducing the amount of impurities in the semiconductor layer 108 is attained in some cases. In particular, when the amount of impurities in the channel formation region is reduced, the transistor can have favorable electrical characteristics.

The thickness T108c of the semiconductor layer 108c is preferably larger than the thickness T108a. When the thickness T108c is small, the effect of inhibiting damage to the semiconductor layer 108 at the time of forming the insulating layer 106 might be decreased. When the thickness T108c is small, the distance between the semiconductor layer 108b, which is the main current path, and the trap states at the interface between the insulating layer 106 and the semiconductor layer 108 and the vicinity thereof; thus, an on-state current may be reduced. In addition, the reliability of the transistor may be degraded. Meanwhile, when the thickness T108c of the semiconductor layer 108c is too large, the distance between the conductive layer 104 functioning as the gate electrode and the semiconductor layer 108b is increased; thus, an on-state current may be reduced. The thickness T108c of the semiconductor layer 108c is preferably larger than or equal to 1 nm and smaller than or equal to 30 nm, further preferably larger than or equal to 1 nm and smaller than or equal to 20 nm, still further preferably larger than or equal to 1 nm and smaller than or equal to 10 nm, yet still further preferably larger than or equal to 2 nm and smaller than or equal to 10 nm.

When the thicknesses of the semiconductor layer 108a, the semiconductor layer 108b, and the semiconductor layer 108c are each within the above range, the transistor can have a high on-state current and high reliability.

Even in the case where the composition of the first metal oxide and the composition of the third metal oxide are the same or substantially the same, the thickness T108c is preferably larger than the thickness T108a. The thicknesses of the semiconductor layer 108a, the semiconductor layer 108b, and the semiconductor layer 108c are each preferably within the above range. Increasing the thickness of the semiconductor layer 108c can inhibit the semiconductor layer 108 from being damaged at the time of forming the insulating layer 106. Reducing the thickness of the semiconductor layer 108a enables efficient supply of oxygen contained in the insulating layer 110 to the semiconductor layer 108b.

The film density of the semiconductor layer 108a positioned on the insulating layer 110 side is further preferably lower than that of the semiconductor layer 108c. The etching rate of the semiconductor layer 108a with respect to an etchant is further preferably higher than the etching rate of the semiconductor layer 108c. The crystallinity of the semiconductor layer 108a is further preferably lower than that of the semiconductor layer 108c. The content percentage of zinc in the first metal oxide is further preferably lower than that of zinc in the third metal oxide. This can reduce the crystallinity of the semiconductor layer 108a and make the semiconductor layer 108a transmit a substance more easily.

In contrast, the film density of the semiconductor layer 108c positioned on the insulating layer 106 side is further preferably higher than that of the semiconductor layer 108a positioned on the insulating layer 110 side. The etching rate of the semiconductor layer 108c with respect to an etchant is further preferably lower than the etching rate of the semiconductor layer 108a. The crystallinity of the semiconductor layer 108c is further preferably higher than that of the semiconductor layer 108a. The content percentage of zinc in the third metal oxide is further preferably higher than content percentage of zinc in the first metal oxide. Accordingly, the semiconductor layer 108c can have high crystallinity, and the effect of inhibiting the semiconductor layer 108 from being damaged at the time of forming the insulating layer 106 can be increased.

Note that the film density of the semiconductor layer 108c may be lower than or substantially equal to the film density of the semiconductor layer 108a. The etching rate of the semiconductor layer 108c with respect to an etchant may be higher than or substantially equal to the etching rate of the semiconductor layer 108a. Note that the crystallinity of the semiconductor layer 108c may be lower than or substantially equal to that of the semiconductor layer 108a.

The film densities of the semiconductor layer 108a, the semiconductor layer 108b, and the semiconductor layer 108c can be analyzed by Rutherford backscattering spectrometry (RBS) or X-ray reflection (XRR), for example. Alternatively, these methods may be combined for the analysis. The etching rate can be calculated by dividing a difference between the thickness of a target film before the etching and the thickness of the target film after the etching by the etching time. As the etchant, a chemical solution containing one or more of oxalic acid, phosphoric acid, hydrofluoric acid, acetic acid, nitric acid, hydrochloric acid, and sulfuric acid can be used, for example.

In the case where an oxide semiconductor is used for the semiconductor layer 108, hydrogen contained in the oxide semiconductor reacts with oxygen bonded to a metal atom to be water, and thus sometimes forms an oxygen vacancy (Vo) in the oxide semiconductor. In some cases, a defect in which hydrogen enters oxygen vacancies (VoH) functions as a donor and generates an electron serving as a carrier. In some cases, bonding of part of hydrogen to oxygen bonded to a metal atom generates electrons serving as carriers. Thus, a transistor using an oxide semiconductor that contains a large amount of hydrogen is likely to have normally-on characteristics. Moreover, hydrogen in the oxide semiconductor is easily transferred by a stress such as heat or an electric field; thus, a large amount of hydrogen in the oxide semiconductor might reduce the reliability of the transistor.

In the case where an oxide semiconductor is used for the semiconductor layer 108, the amount of VoH in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced VoH, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as VoH is used for the channel formation region of the transistor, the transistor can have stable electrical characteristics. Note that repairing oxygen vacancies by supplying oxygen to an oxide semiconductor is sometimes referred to as oxygen adding treatment. In particular, the amount of VoH is preferably small in the semiconductor layer 108b, which is the main current path.

When an oxide semiconductor is used for the semiconductor layer 108, the carrier concentration of the oxide semiconductor in the region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. The lower limit of the carrier concentration of the oxide semiconductor in the region functioning as the channel formation region is not particularly limited and can be, for example, 1×10⁻⁹ cm⁻³. In the semiconductor layer 108b, the carrier concentration of the region functioning as the channel formation region is particularly preferably low and is preferably within the above-described range.

An OS transistor has much higher field-effect mobility than a transistor including amorphous silicon. In addition, the OS transistor has an extremely low off-state current, and charge accumulated in a capacitor that is connected in series to the transistor can be retained for a long period. Furthermore, the power consumption of the semiconductor device can be reduced with the OS transistor.

A change in electrical characteristics of an OS transistor due to radiation irradiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Examples of silicon that can be used for the semiconductor layer 108 include single crystal silicon, polycrystalline silicon, microcrystalline silicon, and amorphous silicon. An example of polycrystalline silicon is low-temperature polysilicon (LTPS).

The transistor including amorphous silicon in the semiconductor layer 108 can be formed over a large-sized glass substrate, thereby reducing the manufacturing cost. The transistor including polycrystalline silicon in the semiconductor layer 108 has high field-effect mobility and can operate at high speed. The transistor including microcrystalline silicon in the semiconductor layer 108 has higher field-effect mobility and can operate at higher speed than the transistor including amorphous silicon.

The semiconductor layer 108 may include a layered substance functioning as a semiconductor. The layered substance is a general term of a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having high on-state current can be provided.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layer 110]

The insulating layer 110 preferably has a stacked-layer structure. FIG. 1B and the like illustrate an example in which the insulating layer 110 includes an insulating layer 110a, an insulating layer 110b over the insulating layer 110a, and an insulating layer 110c over the insulating layer 110b.

A region of the semiconductor layer 108 that is in contact with the insulating layer 110b functions as a channel formation region. The insulating layer 110b preferably contains oxygen, and is preferably formed using any one or more of the oxides and oxynitrides described above. Specifically, one or both of silicon oxide and silicon oxynitride can be suitably used for the insulating layer 110b.

It is further preferable that a film from which oxygen is released by heat application be used as the insulating layer 110b. When the insulating layer 110b releases oxygen by heat applied during the manufacturing process of the semiconductor device 10, the oxygen can be supplied to the semiconductor layer 108. Supplying oxygen from the insulating layer 110b to the semiconductor layer 108, particularly to the channel formation region of the semiconductor layer 108b, can repair oxygen vacancies (Vo), whereby the amount of oxygen vacancies (Vo) can be reduced. Consequently, a transistor with favorable electrical characteristics and high reliability can be obtained.

For example, the insulating layer 110b can be supplied with oxygen when heat treatment in an atmosphere containing oxygen or plasma treatment in an atmosphere containing oxygen is performed. Alternatively, a film may be formed over the top surface of the insulating layer 110b by a sputtering method in an atmosphere containing oxygen to supply oxygen. After that, the film may be removed. Note that a method for supplying oxygen to the insulating layer 110b will be specifically described in Embodiment 2.

The insulating layer 110b is preferably formed by a deposition method such as a sputtering method or a plasma-enhanced chemical vapor deposition (PECVD, also referred to as plasma CVD) method. In particular, by a sputtering method not using a gas containing hydrogen as a deposition gas, a film having an extremely low hydrogen content can be formed. Thus, supply of hydrogen to the channel formation region can be inhibited and the electrical characteristics of the transistor 100 can be stabilized.

Preferably, a substance is easily diffused in the insulating layer 110b. In other words, the diffusion coefficient of a substance in the insulating layer 110b is preferably high. Preferably, oxygen in particular is easily diffused in the insulating layer 110b. That is, the diffusion coefficient of oxygen in the insulating layer 110b is preferably high. Oxygen contained in the insulating layer 110b is diffused in the insulating layer 110b and supplied to the semiconductor layer 108 through the interface between the insulating layer 110b and the semiconductor layer 108. The insulating layer 110b into which oxygen easily diffuses contributes to the efficient supply of oxygen contained in the insulating layer 110b to the semiconductor layer 108 (channel formation region, in particular).

The diffusion coefficient of oxygen in the insulating layer 110b at 350° C. is preferably higher than or equal to 5×10⁻¹² cm²/sec, further preferably higher than or equal to 1×10⁻¹¹ cm²/sec, further preferably higher than or equal to 5×10⁻¹¹ cm²/sec, still further preferably higher than or equal to 1×10⁻¹⁰ cm²/sec. Accordingly, oxygen contained in the insulating layer 110b can be efficiently supplied to the semiconductor layer 108. Since the diffusion coefficient is preferably as high as possible, the upper limit thereof is not set. Note that the diffusion coefficient of oxygen in the insulating layer 110b is not limited to the above-described range.

The diffusion coefficient can be calculated by thermal desorption spectroscopy (TDS), for example. Alternatively, secondary ion mass spectrometry (SIMS) may be used.

The formation of the insulating layer 110b will be specifically described. Here, an example where silicon oxynitride is formed by a PECVD method is described.

A mixed gas including a deposition gas containing silicon and an oxidizing gas can be used as the source gas of the insulating layer 110b. As the deposition gas containing silicon, one or more of silane (SiH₄), disilane (Si₂H₆), trisilane (Si₃H₈), silane fluoride (SiF₄), and TEOS (Tetraethoxysilane, Si(OC₂H₅)₄) can be used, for example. As the oxidizing gas, a gas containing oxygen can be suitably used. As the oxidizing gas, for example, one or more of oxygen (O₂), ozone (O₃), dinitrogen monoxide (N₂O), nitrogen monoxide (NO), and nitrogen dioxide (N₀₂) can be used. In the case where silane (SiH₄) is used as the deposition gas containing silicon, dinitrogen monoxide (N₂O) is preferably used as the oxidizing gas, in which case the number of particles can be smaller than that of the case where oxygen (O₂) is used. Alternatively, in the case where silicon oxide is formed as the insulating layer 110b and TEOS is used as the deposition gas containing silicon, oxygen (O₂) can be suitably used as the oxidizing gas.

When the plasma density with respect to the flow rate of the deposition gas is reduced, that is, when the ratio of the plasma density to the flow rate of the deposition gas is reduced, in the formation of the insulating layer 110b by a PECVD method, the insulating layer can have a high diffusion coefficient. Here, in the case where an RF power source is used to bring the source gas into a plasma state, the plasma density can be reduced by reducing the power of the RF power source (hereinafter also referred to as RF power). By reducing the RF power with respect to the flow rate of the deposition gas (reducing the ratio of the RF power to the flow rate of the deposition gas), the insulating layer can have a high diffusion coefficient. By reducing the ratio of the RF power to the flow rate of the deposition gas (hereinafter also referred to as an F ratio), the diffusion coefficient of oxygen in the insulating layer 110b is increased, so that oxygen contained in the insulating layer 110b can be efficiently supplied to the semiconductor layer 108 (in particular, the channel formation region). However, in the case where a gas containing hydrogen (e.g., SiH₄) is used as the source gas, too low an F ratio might increase the amount of hydrogen contained in the insulating layer 110b. A large amount of hydrogen contained in the insulating layer 110b might cause the insulating layer 110b to release a large amount of impurities containing hydrogen (e.g., water, hydrogen, and ammonia).

When the unit of the gas flow rate is represented by sccm (Standard Cubic Centimeters Per Minute) and that of the RF power is represented by W (Watt), the F ratio is preferably less than or equal to 12, less than or equal to 10, less than or equal to 9, less than or equal to 8, less than or equal to 7, less than or equal to 6, or less than or equal to 5 and greater than or equal to 2 or greater than or equal to 3. For example, in the case where the flow rate of silane (SiH₄) is 290 sccm and the RF power is 1160 W, the F ratio is 4. When the F ratio is within the above range, oxygen contained in the insulating layer 110b can be efficiently supplied to the semiconductor layer 108 (in particular, the channel formation region) and the amount of impurities released from the insulating layer 110b can be reduced. Note that the F ratio at the time of forming the insulating layer 110b is not limited to the above range.

In this specification and the like, sccm represents a flow rate at 1 atmospheric pressure and 0° C. (273.15 K). Although the F ratio of the case where the unit of a gas flow rate is represented by sccm and the unit of the RF power is represented by W is shown, when a different unit is used, the unit can be converted into the above unit to calculate the F ratio. For example, in the case where the flow rate is 0.3 SLM (Standard Liter Per Minute), the F ratio can be calculated by converting 0.3 SLM into 300 sccm.

The electrical characteristics of the transistor 100 with a shorter channel length are more affected by oxygen vacancies (Vo) and VoH in the channel formation region than those of a transistor with a longer channel length. Thus, it is extremely important to efficiently supply oxygen from the insulating layer 110b to the semiconductor layer 108 (in particular, the channel formation region of the semiconductor layer 108b) and to reduce the amount of impurities released from the insulating layer 110b. When the F ratio in the formation of the insulating layer 110b is within the above range, the transistor can have favorable electrical characteristics and high reliability.

When a gas is released from a film by heat application to the film, diffusion in the film and reaction at the film surface can be the bottleneck processes for the gas release, for example. Diffusion is less likely to be the bottleneck in a film that easily allows diffusion of a substance, and thus the temperature at which a gas starts to be released when heat is applied (hereinafter, also referred to as a release temperature) is low. By contrast, diffusion is the bottleneck in a film that does not easily allow diffusion of a substance, and thus the release temperature of a gas is high. As described above, a film that easily allows diffusion of a substance is preferably used for the insulating layer 110b. Thus, the release temperature of a gas when heat is applied to the insulating layer 110b is preferably low. For example, the release temperature of a gas in TDS of the insulating layer 110b is preferably low. In particular, the release temperature of oxygen (¹⁶O₂, m/z=32) in TDS of the insulating layer 110b is preferably low.

Note that oxygen may be supplied from the insulating layer 110b to the semiconductor layer 108 in the manufacturing process of the semiconductor device 10 to reduce the amount of oxygen that can be released from the insulating layer 110b in the semiconductor device 10 after the manufacturing process. Thus, in the case where TDS is performed on the semiconductor device 10, the amount of released oxygen is sometimes small. Note that in a film that easily allows diffusion of oxygen, a substance other than oxygen is also easily diffused; thus, when the release temperature of a released gas other than oxygen is low, the film is probably a film that easily allows diffusion of oxygen. For example, when the release temperature of nitrogen (¹⁴N₂, m/z=28) is low in TDS of the semiconductor device 10, it is presumed that the release temperature of oxygen is also low and oxygen is easily diffused in the film. In TDS of the semiconductor device 10, the release temperature of nitrogen (¹⁴N₂, m/z=28) is preferably lower than or equal to 250° C., lower than or equal to 200° C., lower than or equal to 180° C., lower than or equal to 170° C., or lower than or equal to 160° C. and higher than or equal to 140° C. In that case, oxygen contained in the insulating layer 110b can be efficiently supplied to the semiconductor layer 108 (in particular, the channel formation region) and the amount of impurities released from the insulating layer 110b can be reduced. Note that in the case where TDS is performed on the semiconductor device 10, the layers above the insulating layer 110b are preferably removed to expose the insulating layer 110b. Note that in this embodiment, the temperature rising rate of the sample surface temperature in TDS is approximately 14° C./min. The temperature rising rate of the stage where the sample is placed can be approximately 32° C./min, for example. Note that the release temperature of nitrogen from the insulating layer 110b is not limited to the above range.

An example of a method for calculating the release temperature in TDS is described. In a graph where the X axis represents the sample surface temperature and the Y axis represents the detection intensity (e.g., current value) of the mass analyzer, a tangent is drawn at a point where the slope on a low temperature side of a peak becomes the maximum, and the intersection of the tangent and the X axis (Y=0) can be the release temperature. The detection intensity of the mass analyzer is preferably subjected to background processing. An example of the background processing is a method in which the minimum value of the detection intensity in the entire temperature range of the measurement is subtracted as a background value from a measured value.

Note that in film formation, the etching rate with respect to an etchant is low when the F ratio is high, whereas the etching rate with respect to an etchant is high when the F ratio is low; thus, the etching rate can be used as an indicator of ease of diffusion. As the etchant, an etchant containing hydrofluoric acid can be used, for example. Specific examples include hydrofluoric acid and BHF (Buffered Hydrofluoric acid). Note that BHF is an etchant containing hydrofluoric acid and a buffer agent (e.g., ammonium fluoride (NH₄F)). Alternatively, any of these etchants to which a surface-active agent is added may be used. For example, in the case where silicon oxide or silicon oxynitride is used for the insulating layer 110b, the etching rate of the insulating layer 110b with respect to 0.5 wt % hydrofluoric acid at 25° C. is preferably higher than or equal to 8 nm/min, higher than or equal to 9 nm/min, higher than or equal to 10 nm/min, higher than or equal to 11 nm/min, or higher than or equal to 12 nm/min and lower than or equal to 15 nm/min. Note that the etching rate of the insulating layer 110b is not limited to the above range.

The use of a material having high electrical conductivity for the semiconductor layer 108 enables the transistor to have a high on-state current. However, the use of a material having high electrical conductivity facilitates the formation of oxygen vacancies (Vo); the increased oxygen vacancies (Vo) in the channel formation region shift the threshold voltage of the transistor, which might increase the drain current which flows at a gate voltage of 0 V (hereinafter, also referred to as cut-off current). For example, a negative shift of the threshold voltage might increase the cut-off current in the case of an n-channel transistor. Providing the insulating layer 110b enables oxygen supply to at least the region of the semiconductor layer 108 that is in contact with the insulating layer 110b, i.e., the channel formation region, whereby the oxygen vacancies (Vo) and VoH in the channel formation region can be reduced. This inhibits the threshold voltage shift and allows the transistor to have both a low cut-off current and a high on-state current. Consequently, the semiconductor device can have both low power consumption and high performance.

In the semiconductor layer 108, the region in contact with the conductive layer 112a functions as one of the source region and the drain region of the transistor 100, and the region in contact with the conductive layer 112b functions as the other of the source region and the drain region. The source region and the drain region have lower electric resistance than the channel formation region. In other words, the source region and the drain region are each a region having a higher carrier concentration or a higher oxygen vacancy density than the channel formation region.

The insulating layer 110a is provided between the insulating layer 110b and the conductive layer 112a. The insulating layer 110c is provided between the insulating layer 110b and the conductive layer 112b. It is preferable that the insulating layer 110a and the insulating layer 110c themselves release a small amount of impurity (e.g., hydrogen and water) and not easily transmit impurities. Thus, the impurities contained in the insulating layer 110a and the insulating layer 110c can be prevented from diffusing into the channel formation region. Consequently, a transistor with favorable electrical characteristics and high reliability can be obtained.

For each of the insulating layer 110a and the insulating layer 110c, a film that does not easily transmit oxygen is preferably used. Accordingly, oxygen contained in the insulating layer 110b can be inhibited from being diffused into the conductive layer 112a through the insulating layer 110a. Similarly, oxygen contained in the insulating layer 110b can be inhibited from being diffused into the conductive layer 112b through the insulating layer 110c. This can inhibit the conductive layer 112a and the conductive layer 112b from being oxidized and thus having high electric resistance. At the same time, oxygen contained in the insulating layer 110b can be inhibited from being diffused to the insulating layer 110a side and the insulating layer 110c side, which increases the amount of oxygen supplied to the channel formation region from the insulating layer 110b and can reduce oxygen vacancies (Vo) and VoH in the channel formation region.

When a film that does not easily allow diffusion of oxygen is used for each of the insulating layer 110a and the insulating layer 110c, oxygen can be effectively supplied from the insulating layer 110b to the channel formation region. Note that one or both of the insulating layer 110a and the insulating layer 110c are not necessarily provided.

It is preferable that the insulating layer 110a and the insulating layer 110c each contain nitrogen and be each formed using any one or more of the nitride and nitride oxide described above. For example, silicon nitride or silicon nitride oxide can be suitably used for each of the insulating layer 110a and the insulating layer 110c. Alternatively, any one or more of oxide and oxynitride may be used for one or both of the insulating layer 110a and the insulating layer 110c. For example, aluminum oxide can be suitably used for each of the insulating layer 110a and the insulating layer 110c. Note that the insulating layer 110a and the insulating layer 110c may be formed using the same material or different materials.

Note that in this specification and the like, different materials mean materials in which some or all of constituent elements are different or materials having the same constituent elements and different compositions.

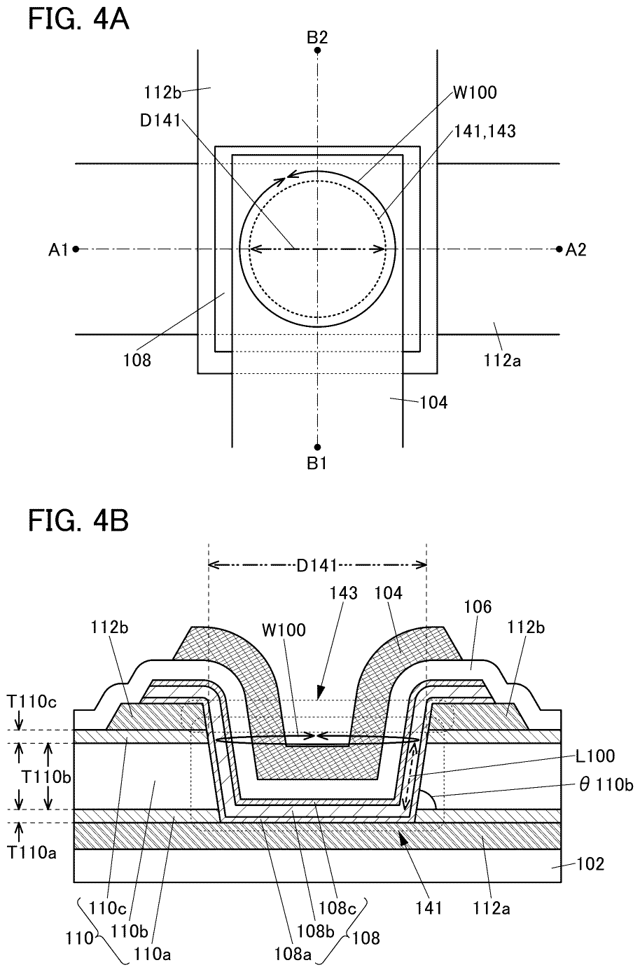

For example, a thickness T110a of the insulating layer 110a can be larger than or equal to 3 nm, larger than or equal to 5 nm, larger than or equal to 10 nm, larger than or equal to 20 nm, larger than or equal to 50 nm, or larger than or equal to 70 nm and can be smaller than 1 m or smaller than or equal to 500 nm, smaller than or equal to 400 nm, smaller than or equal to 300 nm, smaller than or equal to 200 nm, smaller than or equal to 150 nm, or smaller than or equal to 120 nm. As illustrated in FIG. 4B, the thickness T110a can be the shortest distance between the formation surface of the insulating layer 110a (here, the top surface of the conductive layer 112a) and the top surface of the insulating layer 110a in the cross-sectional view.

If the thickness T110a of the insulating layer 110a is large, more impurities might be released from the insulating layer 110a, resulting in an increase in impurities diffused into the channel formation region. Meanwhile, if the thickness T110a is small, oxygen contained in the insulating layer 110b might diffuse into the conductive layer 112a side through the insulating layer 110a, resulting in a reduction in oxygen supplied to the channel formation region. When the thickness T110a is set within the above-described range, the oxygen vacancies (Vo) and VoH in the channel formation region can be reduced. Furthermore, the conductive layer 112a can be prevented from being oxidized by oxygen contained in the insulating layer 110b and from having higher electric resistance.

For example, a thickness T110c of the insulating layer 110c can be larger than or equal to 3 nm, larger than or equal to 5 nm, larger than or equal to 10 nm, larger than or equal to 15 nm, or larger than or equal to 20 nm and can be smaller than or equal to 1 μm, smaller than or equal to 500 nm, smaller than or equal to 300 nm, smaller than or equal to 200 nm, smaller than or equal to 150 nm, smaller than or equal to 120 nm, or smaller than or equal to 100 nm. As illustrated in FIG. 4B, the thickness T110c can be the shortest distance between the formation surface of the insulating layer 110c (here, the top surface of the insulating layer 110b) and the top surface of the insulating layer 110c in the cross-sectional view.

If the thickness T110c of the insulating layer 110c is large, more impurities might be released from the insulating layer 110c, resulting in an increase in impurities diffusing into the channel formation region. Meanwhile, if the thickness T110c is small, oxygen contained in the insulating layer 110b might diffuse into the conductive layer 112b side through the insulating layer 110c, resulting in a reduction in oxygen supplied to the channel formation region. As long as the thickness T110c is set within the above-described range, the oxygen vacancies (Vo) and VoH in the channel formation region can be reduced. Furthermore, the conductive layer 112b can be inhibited from being oxidized by oxygen contained in the insulating layer 110b and from having higher electric resistance.

In the semiconductor layer 108, at least one of the region in contact with the insulating layer 110a and the region in contact with the insulating layer 110c may be a region having lower electrical resistance than the channel formation region (hereinafter, also referred to as a low-resistance region). In other words, the region is a region having a higher carrier concentration or a higher oxygen vacancy density than the channel formation region. When a material that releases an impurity (e.g., water or hydrogen) is used for the insulating layer 110a, the region of the semiconductor layer 108 that is in contact with the insulating layer 110a can be a low-resistance region. In the semiconductor layer 108, the low-resistance region can be formed between the channel formation region and the region in contact with the conductive layer 112a (one of a source region and a drain region). Similarly, when a material that releases an impurity is used for the insulating layer 110c, the region of the semiconductor layer 108 that is in contact with the insulating layer 110c can be a low-resistance region. In the semiconductor layer 108, the low-resistance region can be formed between the channel formation region and the region in contact with the conductive layer 112b (the other of the source region and the drain region). The low-resistance region can function as a buffer region for relieving a drain electric field. These low-resistance regions may function as the source region or the drain region.

Note that impurities released from the insulating layer 110a sometimes diffuse into the channel formation region through the insulating layer 110b or through one of the source region and the drain region of the semiconductor layer 108. Similarly, impurities released from the insulating layer 110c sometimes diffuse into the channel formation region through the insulating layer 110b or through the other of the source region and the drain region of the semiconductor layer 108. However, oxygen is supplied from the insulating layer 110b to at least the region of the semiconductor layer 108 that is in contact with the insulating layer 110b, so that oxygen vacancies (Vo) and VoH in the channel formation region can be reduced. This inhibits the threshold voltage shift and allows the transistor to have both a low cut-off current and a high on-state current. Consequently, the semiconductor device can have both low power consumption and high performance.

Note that in the case where too large an amount of impurities are diffused from the insulating layer 110a and the insulating layer 110c, the amount of oxygen vacancies (Vo) and VoH generated by the impurities might be larger than the amount of oxygen vacancies (Vo) and VoH repaired by oxygen supplied from the insulating layer 110b. Even when a material that releases impurities is used for the insulating layer 110a and the insulating layer 110c, the amount of released impurities is further preferably small.

Note that the insulating layer 110 preferably includes at least the insulating layer 110b. For example, a structure in which one or both of the insulating layer 110a and the insulating layer 110c are not provided may be employed. The insulating layer 110 may have a single-layer structure or a stacked-layer structure of two, four or more layers.

### [Opening 141 and Opening 143]

There is no limitation on the top surface shapes of the opening 141 and the opening 143, and the top surface shapes can each be a circle, an ellipse, a polygon such as a triangle, a quadrangle (including a rectangle, a rhombus, and a square), a pentagon, or any of these polygons with rounded corners, for example. Note that the polygon may be a concave polygon (a polygon at least one of the interior angles of which is greater than 180°) or a convex polygon (a polygon all the interior angles of which are less than or equal to 180°). The top surface shapes of the opening 141 and the opening 143 are each preferably a circle as illustrated in FIG. 1A and the like. When the top surface shapes of the openings are circles, processing accuracy in forming the openings can be high, whereby the openings can be formed to have minute sizes. Note that in this specification and the like, a circle is not necessarily a perfect circle.

In this specification and the like, the top surface shape of the opening 141 refers to the shape of the end portion of the top surface of the insulating layer 110 on the opening 141 side. The top surface shape of the opening 143 refers to the shape of the end portion of the bottom surface of the conductive layer 112b on the opening 143 side.

As illustrated in FIG. 1A and the like, the top surface shape of the opening 141 and the top surface shape of the opening 143 can be the same or substantially the same. In that case, it is preferable that the end portion of the bottom surface of the conductive layer 112b on the opening 143 side be aligned with or substantially aligned with the end portion of the top surface of the insulating layer 110 on the opening 141 side as illustrated in FIG. 1B, FIG. 1C, and the like. The bottom surface of the conductive layer 112b refers to the surface thereof on the insulating layer 110 side. The top surface of the insulating layer 110 refers to the surface thereof on the conductive layer 112b side.

Note that the opening 141 and the opening 143 do not necessarily have the same top surface shapes. In the case where the top surface shapes of the opening 141 and the opening 143 are circular, the opening 141 and the opening 143 may be concentrically arranged, but not necessarily concentrically arranged.

The channel length, channel width, and the like of the transistor 100 are described with reference to FIG. 4A and FIG. 4B. FIG. 4A and FIG. 4B are enlarged views of FIG. 1A and FIG. 1B.

In FIG. 4B, a channel length L100 of the transistor 100 is indicated by a dashed double-headed arrow. The channel length L100 of the transistor 100 corresponds to the length of the side surface of the insulating layer 110b on the opening 141 side in a cross-sectional view. In other words, the channel length L100 depends on a thickness T110b of the insulating layer 110b and an angle θ110b formed by the side surface of the insulating layer 110b on the opening 141 side and the formation surface of the insulating layer 110b (which is the top surface of the insulating layer 110a here). Thus, the channel length L100 can be a value smaller than that of the resolution limit of a light-exposure apparatus, which enables a transistor having a minute size. Specifically, it is possible to form a transistor with an extremely short channel length that cannot be achieved with a conventional light-exposure apparatus for mass production of flat panel displays (the minimum line width: approximately 2 m or approximately 1.5 μm, for example). Moreover, a transistor with a channel length of less than 10 nm can also be achieved without using an extremely expensive light-exposure apparatus used in the latest LSI technology.

The channel length L100 can be, for example, larger than or equal to 5 nm, larger than or equal to 7 nm, or larger than or equal to 10 nm and smaller than 3 μm, smaller than or equal to 2.5 μm, smaller than or equal to 2 μm, smaller than or equal to 1.5 μm, smaller than or equal to 1.2 μm, smaller than or equal to 1 μm, smaller than or equal to 500 nm, smaller than or equal to 300 nm, smaller than or equal to 200 nm, smaller than or equal to 100 nm, smaller than or equal to 50 nm, smaller than or equal to 30 nm, or smaller than or equal to 20 nm. For example, the channel length L100 can be greater than or equal to 100 nm and less than or equal to 1 μm.

The reduction in the channel length L100 can increase the on-state current of the transistor 100. With the use of the transistor 100, a circuit capable of high-speed operation can be manufactured. Furthermore, the area occupied by the circuit can be reduced. Thus, a small semiconductor device can be obtained. The application of the semiconductor device of one embodiment of the present invention to a large display device or a high-definition display device can reduce signal delay in wirings and reduce display unevenness even if the number of wirings is increased, for example. In addition, since the area occupied by the circuit can be reduced, the bezel of the display device can be narrowed.

By adjusting the thickness T110b of the insulating layer 110b and the angle θ110b, the channel length L100 can be controlled.

The thickness T110b of the insulating layer 110b can be, for example, larger than or equal to 5 nm, larger than or equal to 7 nm, or larger than or equal to 10 nm and smaller than 3 m, smaller than or equal to 2.5 μm, smaller than or equal to 2 μm, smaller than or equal to 1.5 μm, smaller than or equal to 1.2 μm, smaller than or equal to 1 μm, smaller than or equal to 500 nm, smaller than or equal to 300 nm, smaller than or equal to 200 nm, smaller than or equal to 100 nm, smaller than or equal to 50 nm, smaller than or equal to 30 nm, or smaller than or equal to 20 nm.

The side surface of the insulating layer 110 on the opening 141 side preferably has a tapered shape. The angle θ110b is preferably less than 90°. By reducing the angle θ110b, the coverage with a layer (e.g., the semiconductor layer 108) formed over the insulating layer 110 can be improved. The smaller the angle θ110b is, the longer the channel length L100 is. The larger the angle θ110b is, the shorter the channel length L100 is.

The angle θ110b can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 700 and less than 90°, less than or equal to 85°, or less than or equal to 80°. The angle θ110b may be less than or equal to 75°, less than or equal to 70°, less than or equal to 65°, or less than or equal to 60°.

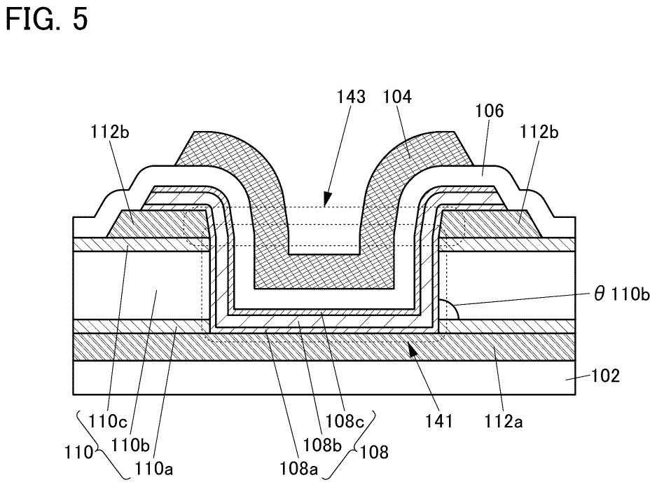

Although the angle θ110b is less than 900 in FIG. 1B and the like, one embodiment of the present invention is not limited thereto. As illustrated in FIG. 5, the angle θ110b may be 900 or approximately 90°. Accordingly, the channel length L100 of the transistor 100 can be made shorter.

Although FIG. 1B and the like show the structure in which the side surface of the insulating layer 110 on the opening 141 side is linear in the cross-sectional view, one embodiment of the present invention is not limited thereto. In the cross-sectional view, the side surface of the insulating layer 110 on the opening 141 side may be curved, or the side surface may include both a linear region and a curved region.

It is preferable that the conductive layer 112b not be provided inside the opening 141. Specifically, it is preferable that the conductive layer 112b not include a region in contact with the side surface of the insulating layer 110 on the opening 141 side. If the conductive layer 112b is also provided inside the opening 141, the channel length L100 of the transistor 100 is shorter than the length of the side surface of the insulating layer 110b and the channel length L100 is difficult to control in some cases. Accordingly, it is preferable that the top surface shape of the opening 143 be the same as the top surface shape of the opening 141, or the opening 143 cover the opening 141 completely in the top view.

In FIG. 4A and FIG. 4B, a width D141 of the opening 141 is indicated by a dashed double-dotted double-headed arrow. FIG. 4A illustrates an example where the top surface shape of the opening 141 is a circle. In this case, the width D141 corresponds to the diameter of the circle and a channel width W100 of the transistor 100 is the length of the circumference of the circle. That is, the channel width W100 is π×D141. Accordingly, in the case where the opening 141 has a circular top surface shape, the channel width W100 of the transistor can be smaller than in the case where the opening 141 has any other shape.

The width D141 of the opening 141 sometimes varies in the depth direction. As the width D141 of the opening 141, for example, the average value of the following three diameters can be used: the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels. For another example, any of the diameter at the highest level of the insulating layer 110b (or the insulating layer 110) in a cross-sectional view, the diameter at the lowest level of the insulating layer 110b (or the insulating layer 110) in a cross-sectional view, and the diameter at the midpoint between these levels can be used as the diameter of the opening 141.

In the case where the opening 141 is formed by a photolithography method, the width D141 of the opening 141 is larger than or equal to the resolution limit of a light-exposure apparatus. The width D141 can be, for example, larger than or equal to 200 nm, larger than or equal to 300 nm, larger than or equal to 400 nm, or larger than or equal to 500 nm and smaller than 5 μm, smaller than or equal to 4.5 μm, smaller than or equal to 4 μm, smaller than or equal to 3.5 μm, smaller than or equal to 3 μm, smaller than or equal to 2.5 μm, smaller than or equal to 2 μm, smaller than or equal to 1.5 μm, or smaller than or equal to 1 μm.

When the channel length L100 of the transistor 100 is short, materials that release a smaller amount of hydrogen are preferably used for the insulating layer 110a and the insulating layer 110c. In the case where the materials used for the insulating layer 110a and the insulating layer 110c release even a small amount of hydrogen, their thicknesses are preferably small. For example, when the channel length L100 is smaller than or equal to 100 nm, the thickness T110a of the insulating layer 110a and the thickness T110c of the insulating layer 110c are each preferably larger than or equal to 1 nm, larger than or equal to 3 nm, or larger than or equal to 5 nm and smaller than or equal to 50 nm, smaller than or equal to 40 nm, smaller than or equal to 30 nm, smaller than or equal to 20 nm, smaller than or equal to 15 nm, or smaller than or equal to 10 nm. Accordingly, the amount of impurities being diffused into the channel formation region can be reduced, and the transistor can have favorable electrical characteristics and high reliability even with the short the channel length L100. Note that the thickness T110a and the thickness T110c are not limited to the above ranges.

Although the structure in which the region of the semiconductor layer 108 that is in contact with the insulating layer 110b functions as the channel formation region is described as an example, one embodiment of the present invention is not limited thereto. The region of the semiconductor layer 108 that is in contact with the insulating layer 110a may also function as a channel formation region. Similarly, the region that is in contact with the insulating layer 110c may function as the channel formation region.

### [Conductive Layer 112a, Conductive Layer 112b, and Conductive Layer 104]

The conductive layer 112a, the conductive layer 112b, and the conductive layer 104 can each have a single-layer structure or a stacked-layer structure of two or more layers. As a material that can be used as each of the conductive layer 112a, the conductive layer 112b, and the conductive layer 104, for example, one or more of chromium, copper, aluminum, gold, silver, zinc, tantalum, titanium, tungsten, manganese, nickel, iron, cobalt, molybdenum, and niobium, or an alloy containing one or more of these metals as its components can be given. For each of the conductive layer 112a, the conductive layer 112b, and the conductive layer 104, a conductive material with low electrical resistivity that contains one or more of copper, silver, gold, and aluminum can be suitably used. Copper or aluminum is particularly preferable because of its high mass-productivity.

For the conductive layer 112a, the conductive layer 112b, and the conductive layer 104, a conductive metal oxide (also referred to as an oxide conductor) can be used. Examples of an oxide conductor (OC) include an indium oxide, a zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. An oxide conductor containing indium is particularly preferable because of its high conduction property.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

Each of the conductive layer 112a, the conductive layer 112b, and the conductive layer 104 may have a stacked-layer structure of a conductive film containing the above-described oxide conductor (the metal oxide) and a conductive film containing a metal or an alloy. The use of the conductive film containing a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, and the conductive layer 104. The use of a Cu—X alloy film enables the manufacturing cost to be reduced because a wet etching method can be used in the processing.

Note that the conductive layer 112a, the conductive layer 112b, and the conductive layer 104 may be formed using the same material or at least one of them may be formed using a different material.

Each of the conductive layer 112a and the conductive layer 112b has a region that is in contact with the semiconductor layer 108. In the case where the semiconductor layer 108 is formed using an oxide semiconductor, when the conductive layer 112a or the conductive layer 112b is formed using a metal that is likely to be oxidized (e.g., aluminum), an insulating oxide (e.g., aluminum oxide) is formed between the conductive layer 112a or the conductive layer 112b and the semiconductor layer 108, which might inhibit electrical continuity between the conductive layer 112a or the conductive layer 112b and the semiconductor layer 108. Thus, a conductive material that is not easily oxidized, a conductive material that maintains low electric resistance even after being oxidized, or an oxide conductor is preferably used for the conductive layer 112a and the conductive layer 112b.

For the conductive layer 112a and the conductive layer 112b, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or materials that maintain low electric resistance even after being oxidized. In the case where the conductive layer 112a or the conductive layer 112b has a stacked-layer structure, at least the layer thereof that is in contact with the semiconductor layer 108 is preferably formed using a conductive material that is less likely to be oxidized.

The above-described oxide conductor can be used for each of the conductive layer 112a and the conductive layer 112b. Specifically, an oxide conductor such as indium oxide, zinc oxide, ITO, In—Zn oxide, In—W oxide, In—W—Zn oxide, In—Ti oxide, In—Ti—Sn oxide, In—Sn oxide containing silicon, or zinc oxide to which gallium is added can be used.

For the conductive layer 112a and the conductive layer 112b, a nitride conductor may be used. Examples of the nitride conductor include tantalum nitride and titanium nitride.

The conductive layer 112a, the conductive layer 112b, and the conductive layer 104 can each have a single-layer structure or a stacked-layer structure of two or more layers.

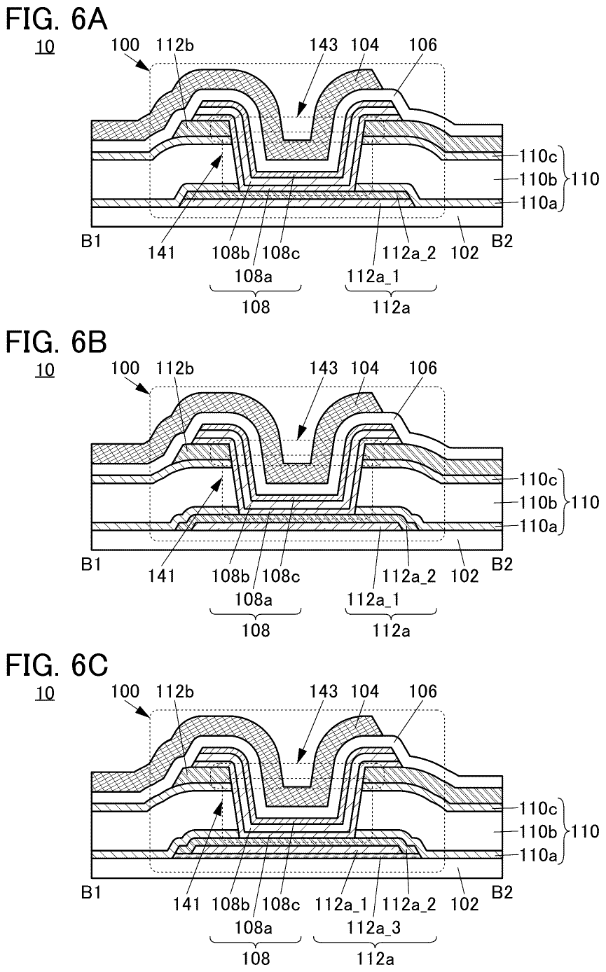

FIG. 6A and FIG. 6B each illustrate a structure where the conductive layer 112a has a two-layer structure of a conductive layer 112a_1 and a conductive layer 112a_2 over the conductive layer 112a_1.

A conductive material that is not easily oxidized, a conductive material that maintains low electric resistance even after being oxidized, or an oxide conductor is preferably used for the conductive layer 112a_2 including a region in contact with the semiconductor layer 108. The description of the conductive layer 112a can be referred to for the material usable for the conductive layer 112a_2.

The conductive layer 112a_1 does not include a region in contact with the semiconductor layer 108 and there is no limitation on the material. For the conductive layer 112a_1, a material having lower electrical resistivity than the conductive layer 112a_2 is preferably used, for example. Thus, electric resistance of the conductive layer 112a can be reduced. For example, In—Sn—Si oxide (ITSO) can be suitably used for the conductive layer 112a_2, and copper or tungsten can be suitably used for the conductive layer 112a_1.

As illustrated in FIG. 6A, the end portion of the conductive layer 112a_2 may be aligned or substantially aligned with the end portion of the conductive layer 112a_1. For example, a first film to be the conductive layer 112a_1 and a second film to be the conductive layer 112a_2 are formed and then the first film and the second film are processed, so that the conductive layer 112a can be formed. Processing the first film and the second film in the same step can reduce the manufacturing cost.

The end portion of the conductive layer 112a_2 is not necessarily aligned with the end portion of the conductive layer 112a_1. As illustrated in FIG. 6B, the conductive layer 112a_2 can be provided to cover the conductive layer 112a_1. The conductive layer 112a_2 is in contact with the top surface and the side surface of the conductive layer 112a_1. It can also be said that the conductive layer 112a_2 includes a portion protruding beyond the end portion of the conductive layer 112a_1. For example, it is possible to form the conductive layer 112a_1, form a film to be the conductive layer 112a_2 over the conductive layer 112a_1, and process the film to form the conductive layer 112a_2. When the conductive layer 112a_2 protrudes beyond the end portion of the conductive layer 112a_1, a step on the formation surface of the layer (e.g., the insulating layer 110) formed over the conductive layer 112a becomes small, so that coverage with the layer can be improved. This can inhibit generation of a defect such as step disconnection or a void in the layer.

Although the thicknesses of the layers forming the conductive layer 112a are the same or substantially the same in FIG. 6A and FIG. 6B, one embodiment of the present invention is not limited thereto. The thicknesses of the layers forming the conductive layer 112a may be different from each other or the thicknesses of some of the layers may be different. For example, the thickness of a layer formed using a material having low electrical resistivity is preferably larger than that of the other layers, in which case the electric resistance of the conductive layer 112a can be reduced. Specifically, the conductive layer 112a_1 may be formed using a material having lower electrical resistivity than the conductive layer 112a_2, and the thickness of the conductive layer 112a_1 may be larger than the thickness of the conductive layer 112a_2. Accordingly, electric resistance of the conductive layer 112a can be reduced.

FIG. 6C illustrates a structure in which the conductive layer 112a has a three-layer structure of a conductive layer 112a_3, the conductive layer 112a_1 over the conductive layer 112a_3, and a conductive layer 112a_2 over the conductive layer 112a_1.

The end portion of the conductive layer 112a_1 is in contact with the top surface of the conductive layer 112a_3. The conductive layer 112a_2 is in contact with the top surface and the side surface of the conductive layer 112a_1 and the top surface of the conductive layer 112a_3. That is, it can also be said that the conductive layer 112a_2 and the conductive layer 112a_3 each include a portion protruding beyond the end portion of the conductive layer 112a_1. In other words, the top surface, the side surface, and the bottom surface of the conductive layer 112a_1 are surrounded by the conductive layer 112a_2 and the conductive layer 112a_3. For the conductive layer 112a_3, a material with high adhesion to the formation surface of the conductive layer 112a_3 (here, the surface of the substrate 102) is preferably used.

As described above, a material with low electrical resistivity is preferably used for the conductive layer 112a_1. However, depending on the material, the adhesion between the conductive layer 112a_1 and the formation surface of the conductive layer 112a_1 (e.g., the surface of the substrate 102) sometimes becomes low, which might lower the manufacturing yield of the semiconductor device. The use of a material having higher adhesion to the formation surface than the conductive layer 112a_1 for the conductive layer 112a_3 can increase the manufacturing yield of the semiconductor device. Note that the thickness of the conductive layer 112a_3 is preferably set so as to have an effect of increasing adhesion to the formation surface of the conductive layer 112a and may be smaller than those of the conductive layer 112a_1 and the conductive layer 112a_2. When the thickness of the conductive layer 112a_3 is reduced, the manufacturing cost can be reduced.

The end portion of the conductive layer 112a_2 may be aligned or substantially aligned with the end portion of the conductive layer 112a_3. For example, a first film to be the conductive layer 112a_3 is formed, the conductive layer 112a_1 is formed over the first film, and a second film to be the conductive layer 112a_2 is formed over the first film and the conductive layer 112a_1. Then, the first film and the second film are processed, whereby the conductive layer 112a including the conductive layer 112a_3, the conductive layer 112a_1, and the conductive layer 112a_2 can be formed. Processing the first film and the second film in the same step can reduce the manufacturing cost.

For example, In—Sn—Si oxide (ITSO), copper, and In—Sn—Si oxide (ITSO) can be suitably used for the conductive layer 112a_3, the conductive layer 112a_1, and the conductive layer 112a_2, respectively. In the case where a glass substrate is used as the substrate 102, the adhesion between the glass substrate and the ITSO film is higher than that between the glass substrate and a copper film. When the conductive layer 112a_2 and the conductive layer 112a_3 are formed using the same material, the conductive layer 112a_2 and the conductive layer 112a_3 can be easily processed in the same step and the manufacturing yield of the semiconductor device can be increased.

Although an example where the conductive layer 112a has a two-layer or three-layer structure is described here, one embodiment of the present invention is not limited to thereto. The conductive layer 112a may have a stacked-layer structure of four or more layers.

Note that the structure of the conductive layer 112a illustrated in FIG. 6A to FIG. 6C can be applied to other structure examples.

### [Insulating Layer 106]

The insulating layer 106 preferably includes one or more inorganic insulating layers. For the insulating layer 106, a material usable for the insulating layer 110 can be used.

The insulating layer 106 includes a region in contact with the semiconductor layer 108, the conductive layer 112b, the conductive layer 104, and the insulating layer 110. In the case where the semiconductor layer 108 is formed using a metal oxide, at least the film that is included in the insulating layer 106 and in contact with the semiconductor layer 108 is preferably formed using any of the above-described oxide and oxynitride. In the case where the insulating layer 106 has a single-layer structure, silicon oxide, silicon oxynitride, or aluminum oxide can be suitably used for the insulating layer 106.

A miniaturized transistor including a thin gate insulating layer might have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

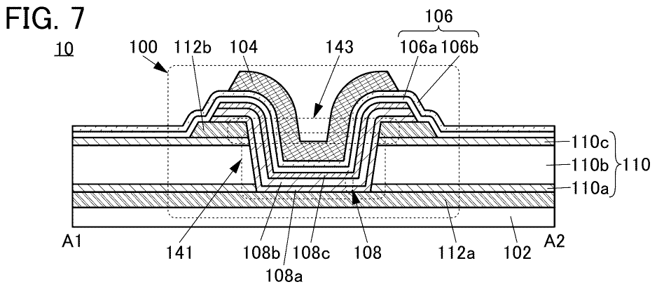

The insulating layer 106 can have a single-layer structure or a stacked-layer structure of two or more layers. FIG. 7 illustrates a structure in which the insulating layer 106 has a two-layer structure of an insulating layer 106a and an insulating layer 106b over the insulating layer 106a.

In the case where the insulating layer 106 has a stacked-layer structure, the insulating layer (here, the insulating layer 106a) on the semiconductor layer 108 side preferably contains an oxide or an oxynitride. For example, one or more of silicon oxide, silicon oxynitride, and aluminum oxide can be suitably used for the insulating layer 106a.

As one or more layers included in the insulating layer 106, a layer which is less likely to transmit a substance is preferably used. It can be said that the layer functions as a barrier film. Providing the layer functioning as the barrier film can inhibit diffusion of a metal component contained in the conductive layer 104 and impurities (e.g., water and hydrogen) contained in the layer formed over the transistor 100 into the semiconductor layer 108 through the insulating layer 106. Furthermore, oxygen contained in the semiconductor layer 108 can be inhibited from diffusing to the conductive layer 104 side through the insulating layer 106. In that case, formation of oxygen vacancies (Vo) in the semiconductor layer 108 can be inhibited. In addition, the conductive layer 104 can be inhibited from being oxidized by oxygen contained in the semiconductor layer 108 and from having increased electric resistance. Consequently, a transistor with favorable electrical characteristics and high reliability can be obtained. One or more of the above-described nitride and nitride oxide are preferably used for the layer functioning as the barrier film. Alternatively, one or more of an oxide and an oxynitride may be used for the layer, and aluminum oxide can be suitably used, for example.

Note that in this specification and the like, a barrier film refers to a film having a barrier property. A barrier property means one or both of a function of inhibiting diffusion of a target substance and thereby inhibiting a film from transmitting the substance (also referred to as low permeability) and a function of capturing or fixing (also referred to as gettering) a target substance. For example, an insulating layer having a barrier property can be referred to as a barrier insulating layer.

In the case where the insulating layer 106 has a stacked-layer structure, silicon oxynitride can be used for the insulating layer 106a and silicon nitride can be used for the insulating layer 106b, for example. Alternatively, silicon oxynitride can be used for the insulating layer 106a and aluminum oxide can be used for the insulating layer 106b. Alternatively, aluminum oxide can be used for the insulating layer 106a and silicon oxynitride can be used for the insulating layer 106b. Alternatively, aluminum oxide can be used for the insulating layer 106a and silicon nitride can be used for the insulating layer 106b.

Although an example where the insulating layer 106 has a two-layer structure is described here, one embodiment of the present invention is not limited thereto. The insulating layer 106 may have a stacked-layer structure of three or more layers.

Note that the structure of the insulating layer 106 described with reference to FIG. 7 can also be used in the other structure examples.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. Note that the shapes of the semiconductor substrate and an insulating substrate may each be a circle or a square.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of a semiconductor device completed thereover can be separated from the substrate 102 and transferred onto another substrate. In that case, the transistor 100 and the like can be transferred onto a substrate having low heat resistance or a flexible substrate as well.

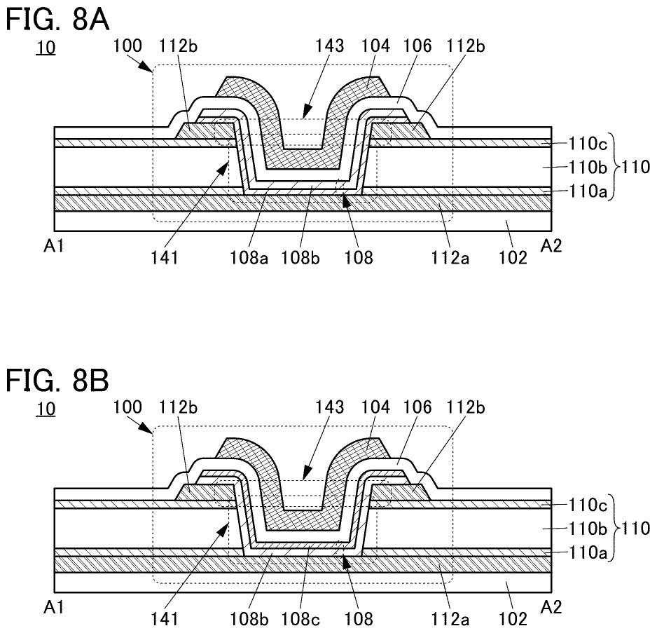

Note that the semiconductor layer 108a may have a stacked-layer structure. The same applies to the semiconductor layer 108b and the semiconductor layer 108c. In addition, although FIG. 1B and the like illustrate an example in which the semiconductor layer 108 has a three-layer structure of the semiconductor layer 108a, the semiconductor layer 108b, and the semiconductor layer 108c, one embodiment of the present invention is not limited thereto. For example, a structure without one or both of the semiconductor layer 108a and the semiconductor layer 108c may be employed. Specifically, as illustrated in FIG. 8A, the semiconductor layer 108 can have a two-layer structure of the semiconductor layer 108a and the semiconductor layer 108b. Alternatively, as illustrated in FIG. 8B, the semiconductor layer 108 can have a two-layer structure of the semiconductor layer 108b and the semiconductor layer 108c.

A structure example of a semiconductor device whose structure is partly different from that of Structure example 1 shown above will be described below. Note that description of the same portions as those in Structure example 1 shown above is omitted below in some cases. Furthermore, in drawings that are referred to later, the same hatching pattern is applied to portions having functions similar to those in Structure example 1 shown above, and the portions are not denoted by reference numerals in some cases.

### Structure Example 1-2

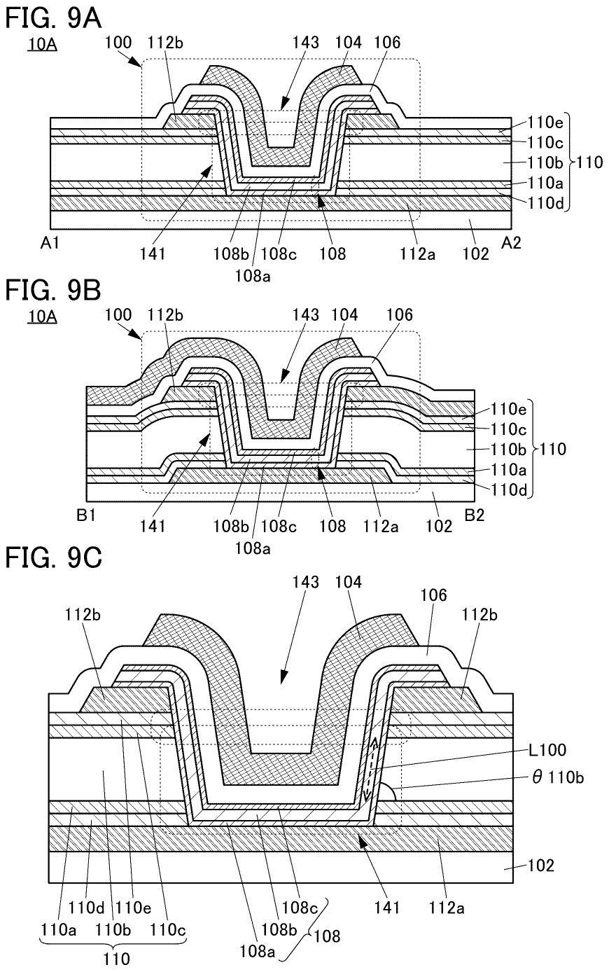

FIG. 9A and FIG. 9B are cross-sectional views of a semiconductor device 10A of one embodiment of the present invention. FIG. 1A can be referred to for a top view of the semiconductor device 10A. FIG. 9A is a cross-sectional view of a cut plane along the dashed-dotted line A1-A2 in FIG. 1A, and FIG. 9B is a cross-sectional view of a cut plane along the dashed-dotted line B1-B2 in FIG. 1A.

The semiconductor device 10A includes the transistor 100 and the insulating layer 110. The semiconductor device 10A is different from the semiconductor device 10 illustrated in FIG. 1B and the like mainly in that the insulating layer 110 includes an insulating layer 110d and an insulating layer 110e.

FIG. 9C is an enlarged view of FIG. 9A. The insulating layer 110 includes the insulating layer 110d, the insulating layer 110a over the insulating layer 110d, the insulating layer 110b over the insulating layer 110a, the insulating layer 110c over the insulating layer 110b, and the insulating layer 110e over the insulating layer 110c. For each of the insulating layer 110d and the insulating layer 110e, the material given as an example for the insulating layer 110a and the insulating layer 110c can be used. For example, silicon nitride or silicon nitride oxide can be suitably used for each of the insulating layer 110d and the insulating layer 110e. Note that the insulating layer 110d and the insulating layer 110e may be formed using the same material or different materials.

The insulating layer 110d is provided between the insulating layer 110a, and the substrate 102 and the conductive layer 112a. The insulating layer 110d is provided to cover the conductive layer 112a. The insulating layer 110d is in contact with the top surface and the side surface of the conductive layer 112a, the top surface of the substrate 102, and the side surface of the semiconductor layer 108.

The insulating layer 110e is provided between the conductive layer 112b and the insulating layer 110c. The insulating layer 110e is in contact with the top surface of the insulating layer 110c, the bottom surface of the conductive layer 112b, the bottom surface of the insulating layer 106, and the side surface of the semiconductor layer 108.

It is further preferable that a material that releases impurities (e.g., water or hydrogen) reducing the electric resistance of the semiconductor layer 108 be used for each of the insulating layer 110d and the insulating layer 110e. Accordingly, the region of the semiconductor layer 108 that is in contact with the insulating layer 110d can be a low-resistance region. In the semiconductor layer 108, the low-resistance region can be formed between the channel formation region and the region in contact with the conductive layer 112a (one of a source region and a drain region). Similarly, when a material that releases impurities is used for the insulating layer 110e, the region of the semiconductor layer 108 that is in contact with the insulating layer 110e can be a low-resistance region. In the semiconductor layer 108, the low-resistance region can be formed between the channel formation region and the region in contact with the conductive layer 112b (the other of the source region and the drain region). The low-resistance region can function as a buffer region for relieving a drain electric field. These low-resistance regions may function as the source region or the drain region.

The low-resistance region between the drain region and the channel formation region inhibits generation of a high electric field in the vicinity of the drain region, so that generation of hot carriers is inhibited to inhibit the degradation of the transistor. For example, in the case where the conductive layer 112a functions as the drain electrode, the conductive layer 112b functions as the source electrode, and the region of the semiconductor layer 108 that is in contact with the insulating layer 110d functions as the low-resistance region, a high electric field is not easily generated in the vicinity of the drain region, and generation of hot carriers and degradation of the transistor can be inhibited. In the case where the conductive layer 112a functions as the source electrode, the conductive layer 112b functions as the drain electrode, and the region of the semiconductor layer 108 that is in contact with the insulating layer 110e functions as the low-resistance region, a high electric field is not easily generated in the vicinity of the drain region, and generation of hot carriers and degradation of the transistor can be inhibited.

In the case where the region of the semiconductor layer 108 that is in contact with the insulating layer 110d functions as the source region or the drain region, the distance from the source region in the semiconductor layer 108 to the gate electrode and the distance from the drain region to the gate electrode can be made more equal. Thus, the electric field of the gate electrode applied to the channel formation region can be more uniform.

It is preferable that the insulating layer 110a itself release a small amount of impurity and not easily transmit impurities. In that case, impurities can be inhibited from being diffused into the channel formation region of the semiconductor layer 108 through the insulating layer 110a and the insulating layer 110b. Similarly, it is preferable that the insulating layer 110c itself release a small amount of impurity and not easily transmit impurities. In that case, impurities can be inhibited from being diffused into the channel formation region of the semiconductor layer 108 through the insulating layer 110c and the insulating layer 110b. Consequently, a transistor with excellent electrical characteristics and high reliability can be provided.

In the case where a metal oxide is used for the semiconductor layer 108, impurities released from the insulating layer 110d and the insulating layer 110e preferably contain hydrogen. Hydrogen reacts with oxygen bonded to a metal atom in the metal oxide to be water, and thus an oxygen vacancy (Vo) is formed. Furthermore, a defect (VoH) in which hydrogen enters an oxygen vacancy (Vo) functions as a donor and generates an electron serving as a carrier. Accordingly, the carrier concentrations of the region of the semiconductor layer 108 in contact with the insulating layer 110d and the region of the semiconductor layer 108 in contact with the insulating layer 110e are increased, so that the electric resistances of these regions can be reduced.

The insulating layer 110d preferably includes a region containing more hydrogen than the insulating layer 110a. The hydrogen content of the insulating layer 110 can be analyzed by secondary ion mass spectrometry (SIMS), for example.

When the film formation conditions for the insulating layer 110d are different from those for the insulating layer 110a, the amount of released hydrogen can be adjusted. Specifically, the film formation conditions for the insulating layer 110d may be different from those for the insulating layer 110a in any one or more of the film formation power (film formation power density), the film formation pressure, the kind of film formation gas, the flow rate ratio of a film formation gas, the film formation temperature, and the distance between the substrate and the electrode during formation. For example, the film formation power density for the insulating layer 110d may be lower than the film formation power density for the insulating layer 110a, in which case the insulating layer 110d can have a higher hydrogen content than the insulating layer 110a. Accordingly, the amount of hydrogen released from the insulating layer 110d due to heat applied thereto can be increased.

The film formation gas used for the formation of the insulating layer 110d preferably contains more hydrogen than the film formation gas used for the formation of the insulating layer 110a. Specifically, when a silicon nitride film or a silicon nitride oxide film is formed as each of the insulating layer 110d and the insulating layer 110a by using a PECVD method, the proportion of a flow rate of an ammonia gas to the whole film formation gas used for the formation of the insulating layer 110d (hereinafter also referred to as ammonia flow rate ratio) is preferably higher than the proportion of a flow rate of an ammonia gas to the whole film formation gas used for the formation of the insulating layer 110a. The formation of the insulating layer 110d under the condition where the ammonia flow rate ratio is high can increase the hydrogen content in the insulating layer 110d. Furthermore, the amount of hydrogen released from the insulating layer 110d due to heat applied thereto can be increased.

The film density of the insulating layer 110a is further preferably higher than the film density of the insulating layer 110d. In that case, hydrogen contained in the insulating layer 110d can be inhibited from being diffused into the channel formation region of the semiconductor layer 108 through the insulating layer 110a and the insulating layer 110b. The film density can be evaluated by Rutherford backscattering spectrometry (RBS) or X-ray reflection (XRR), for example. A difference in film density can be evaluated using a cross-sectional TEM image in some cases. In TEM observation, a transmission electron (TE) image is dark-colored (dark) when the film density is high, and a transmission electron (TE) image is pale (bright) when the film density is low. Thus, the transmission electron (TE) image of the insulating layer 110a is a dark-colored (dark) image compared to the insulating layer 110d in some cases. Note that since the insulating layer 110d and the insulating layer 110a have different film densities even when containing the same materials, it is sometimes possible to identify the boundary between these insulating layers by a difference in contrast in a TEM image of a cross section.

The insulating layer 110e preferably includes a region containing more hydrogen than the insulating layer 110c. The film density of the insulating layer 110c is further preferably higher than the film density of the insulating layer 110e. For the insulating layer 110c and the insulating layer 110e, the description of the insulating layer 110a and the insulating layer 110d can be referred to.

Note that although an example where the insulating layer 110 has a five-layer structure is described here, one embodiment of the present invention is not limited thereto. The insulating layer 110 may have a single-layer structure or a stacked-layer structure of two, three, four, six or more layers.

Note that the structure of the insulating layer 110 described in Structure example 1-2 can also be applied to other structure examples.

### Structure Example 1-3

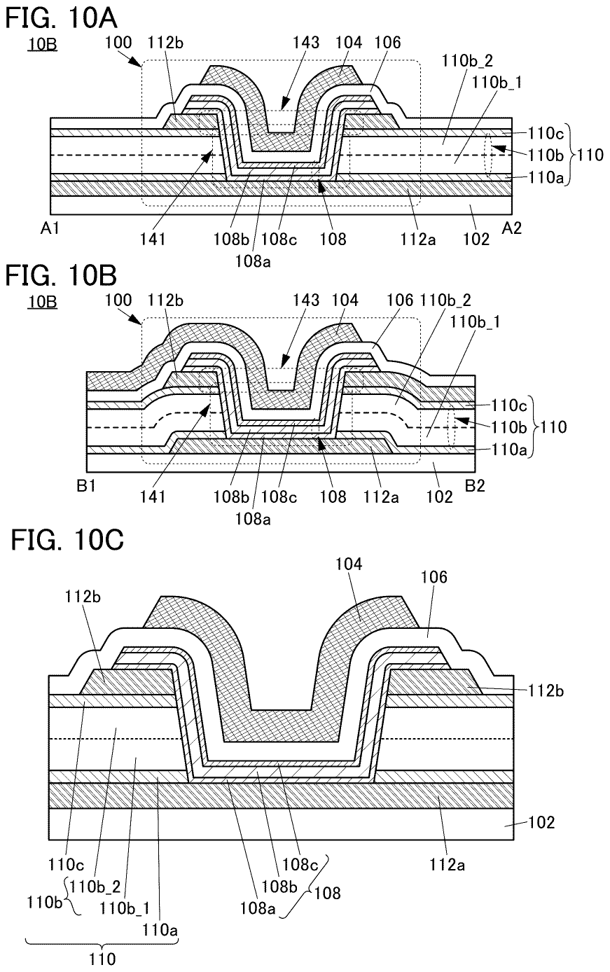

Cross-sectional views of a semiconductor device 10B that is one embodiment of the present invention are illustrated in FIG. 10A and FIG. 10B. FIG. 1A can be referred to for a top view of the semiconductor device 10B. FIG. 10A is a cross-sectional view of a cut plane along the dashed-dotted line A1-A2 in FIG. 1A, and FIG. 10B is a cross-sectional view of a cut plane along the dashed-dotted line B1-B2 in FIG. 1A.

The semiconductor device 10B includes the transistor 100 and the insulating layer 110. The semiconductor device 10B is different from the semiconductor device 10 illustrated in FIG. 1B mainly in that the insulating layer 110b has a stacked-layer structure.

FIG. 10C is an enlarged view of FIG. 10A. The insulating layer 110b includes an insulating layer 110b_1 and an insulating layer 110b_2 over the insulating layer 110b_1. For each of the insulating layer 110b_1 and the insulating layer 110b_2, the material given as an example for the insulating layer 110b can be used. For example, silicon oxide or silicon oxynitride can be suitably used for each of the insulating layer 110b_1 and the insulating layer 110b_2. The insulating layer 110b_1 and the insulating layer 110b_2 may be formed using the same material or different materials.

Note that when the insulating layer 110b_1 and the insulating layer 110b_2 are formed using the same material, the boundary between the insulating layer 110b_1 and the insulating layer 110b_2 cannot be clearly observed in some cases. Thus, the boundaries are denoted by dashed lines in FIG. 10A and the like.

After a first insulating film to be the insulating layer 110b_1 is formed, oxygen is supplied to the first insulating film, and a second insulating film to be the insulating layer 110b_2 can be formed over the first insulating film. Accordingly, a portion where a larger amount of oxygen is supplied is positioned at the interface between the first insulating film (to be the insulating layer 110b_1 later) and the second insulating film (to be the insulating layer 110b_2 later) and the vicinity thereof. Moreover, a larger amount of oxygen can be supplied to the region of the semiconductor layer 108 that is in contact with the portion. For example, when the thickness of the first insulating film is equal to or substantially equal to the thickness of the second insulating film, a larger amount of oxygen is supplied to the center portion of the insulating layer 110b. Thus, oxygen can be supplied more efficiently to the center portion of the channel formation region of the semiconductor layer 108.

Although the insulating layer 110b_1 and the insulating layer 110b_2 have the same thickness here, one embodiment of the present invention is not limited thereto. The insulating layer 110b_1 and the insulating layer 110b_2 may have different thicknesses. The insulating layer 110b may have a stacked-layer structure of three or more layers or a single-layer structure. In the case where the insulating layer 110b has a stacked-layer structure of three or more layers, oxygen may be supplied after formation of the insulating films to be the insulating layer 110b.

The structure of the insulating layer 110b described in Structure example 1-3 can also be applied to other structure examples.

### Structure Example 1-4

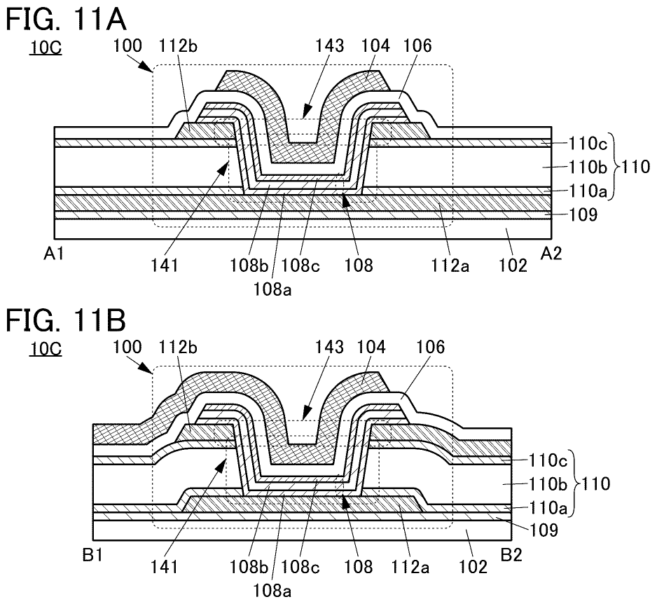

FIG. 11A and FIG. 11B are cross-sectional views of a semiconductor device 10C of one embodiment of the present invention. FIG. 1A can be referred to for a top view of the semiconductor device 10C. FIG. 11A is a cross-sectional view of a cut plane along the dashed-dotted line A1-A2 in FIG. 1A, and FIG. 11B is a cross-sectional view of a cut plane along the dashed-dotted line B1-B2 in FIG. 1A.

The semiconductor device 10C includes the transistor 100, the insulating layer 110, and an insulating layer 109. The semiconductor device 10C is different from the semiconductor device 10 illustrated in FIG. 1B and the like mainly in including the insulating layer 109 between the substrate 102 and the conductive layer 112a.

The insulating layer 109 is provided over the substrate 102, the conductive layer 112a is provided over the insulating layer 109, and the insulating layer 110 is provided over the conductive layer 112a. The insulating layer 109 is in contact with the bottom surface of the conductive layer 112a and the bottom surface of the insulating layer 110. The conductive layer 112a includes a region interposed between the insulating layer 109 and the insulating layer 110. The insulating layer 110 is in contact with the top surface and the side surface of the conductive layer 112a, the top surface of the insulating layer 109, the side surface of the semiconductor layer 108, the bottom surface of the conductive layer 112b, and the bottom surface of the insulating layer 106.

For the insulating layer 109, a material that releases impurities (e.g., water or hydrogen) reducing the resistance of the semiconductor layer 108 is preferably used. For the insulating layer 109, a material that can be used for the insulating layer 110d and the insulating layer 110e can be used. For example, silicon nitride or silicon nitride oxide can be suitably used for the insulating layer 109.

Impurities released from the insulating layer 109 diffuse into a region of the conductive layer 112a that is in contact with the insulating layer 109. Impurities diffused into the conductive layer 112a diffuse into a region of the semiconductor layer 108 that is in contact with the conductive layer 112a. Accordingly, the resistance of the region of the semiconductor layer 108 that is in contact with the conductive layer 112a, i.e., one of the source region and the drain region, can be reduced. Accordingly, the transistor with a high on-state current and the semiconductor device that operates at high speed can be obtained.

In the case where a metal oxide is used for the semiconductor layer 108, the impurities released from the insulating layer 109 further preferably contain hydrogen. Hydrogen diffused from the insulating layer 109 into the semiconductor layer 108 through the conductive layer 112a increases the carrier concentration of the region of the semiconductor layer 108 in contact with the conductive layer 112a, so that the resistance of one of the source region and the drain region can be reduced.

For the insulating layer 109, a material that releases impurities reducing the resistance of the conductive layer 112a is further preferably used. Thus, the resistance of the conductive layer 112a can be reduced. For example, in the case where a metal oxide is used for the conductive layer 112a, the impurities preferably contain hydrogen. Accordingly, the carrier concentration of the conductive layer 112a is increased, so that the resistance can be reduced. The conductive layer 112a can function as a wiring and thus the semiconductor device can have the low wiring resistance. Note that the impurities reducing the resistance of the conductive layer 112a may be the same as or different from the impurities reducing the resistance of the semiconductor layer 108.

Materials that can be used for the conductive layer 112a are as described above. Note that it is further preferable that the conductive layer 112a be likely to transmit impurities. It is further preferable that the conductive layer 112a be less likely to adsorb impurities.

The insulating layer 110a is in contact with the top surface of the insulating layer 109 and the top surface and the side surface of the conductive layer 112a. Thus, impurities contained in the insulating layer 109 and the conductive layer 112a can be inhibited from diffusing into the channel formation region of the semiconductor layer 108 through the insulating layer 110b.

The insulating layer 109 preferably includes a region containing more hydrogen than the insulating layer 110a. The film density of the insulating layer 110a is preferably higher than the film density of the insulating layer 109. For the insulating layer 109, the description of the insulating layer 110d and the insulating layer 110e can be referred to.

Note that impurities released from the insulating layer 109 diffuse into the channel formation region through the conductive layer 112a and one of the source region and the drain region of the semiconductor layer 108 in some cases. However, oxygen is supplied from the insulating layer 110b to at least the region of the semiconductor layer 108 that is in contact with the insulating layer 110b, so that oxygen vacancies (Vo) and VoH in the channel formation region can be reduced. This inhibits the threshold voltage shift and allows the transistor to have both a low cut-off current and a high on-state current. Consequently, the semiconductor device can have both low power consumption and high performance.

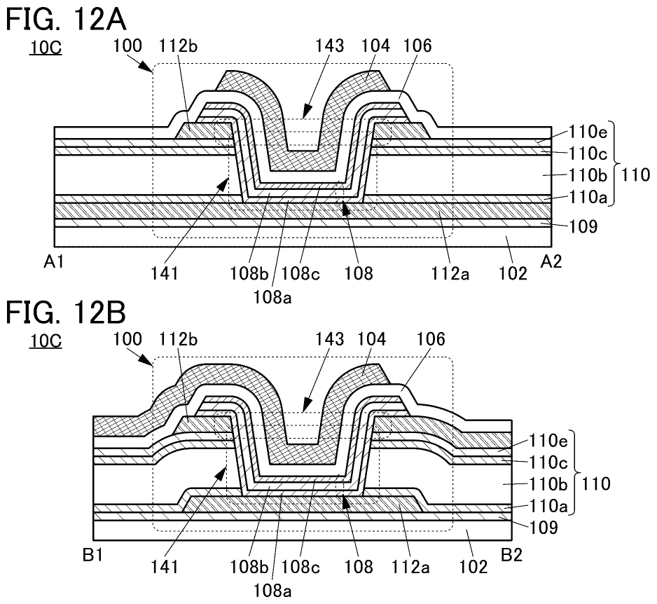

Although FIG. 11A and the like illustrate the structure where the insulating layer 110 has a three-layer structure of the insulating layer 110a to the insulating layer 110c, one embodiment of the present invention is not limited thereto. For example, as illustrated in FIG. 12A and FIG. 12B, the insulating layer 110 may include the insulating layer 110e. For the insulating layer 110e, a material that releases impurities reducing the resistance of the conductive layer 112b is further preferably used. In this case, the resistance of the conductive layer 112b can be reduced. For example, in the case where a metal oxide is used for the conductive layer 112b, the impurities preferably contain hydrogen. Accordingly, the carrier concentration of the conductive layer 112b is increased, so that the resistance can be reduced. The conductive layer 112b can function as a wiring and thus the semiconductor device can have the low wiring resistance. The insulating layer 110 may include the insulating layer 110d.

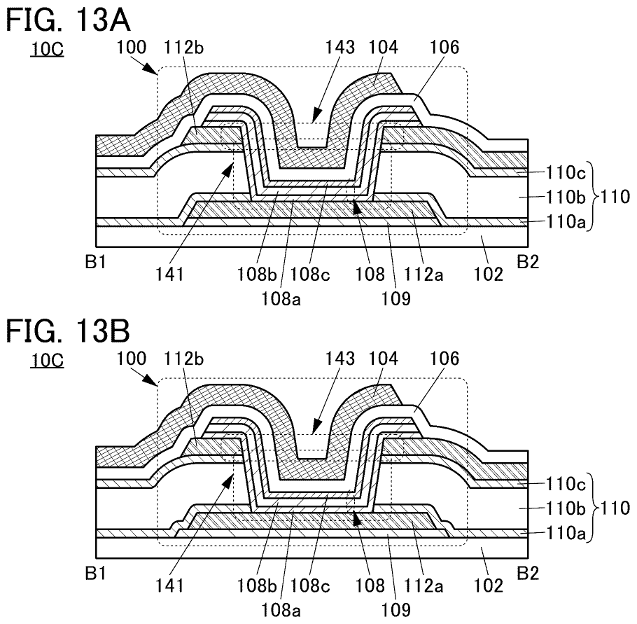

As illustrated in FIG. 13A, the insulating layer 110 may be in contact with the side surface of the insulating layer 109. The end portion of the insulating layer 109 may be aligned or substantially aligned with the end portion of the conductive layer 112a. For example, an insulating film to be the insulating layer 109 and a conductive film to be the conductive layer 112a are formed and processed, whereby the insulating layer 109 and the conductive layer 112a can be formed. By processing the insulating film and the conductive film in the same step, manufacturing cost can be reduced.

The end portion of the insulating layer 109 and the end portion of the conductive layer 112a are not necessarily aligned with each other. As illustrated in FIG. 13B, the insulating layer 109 may include a portion protruding beyond the end portion of the conductive layer 112a. The end portion of the conductive layer 112a is in contact with the top surface of the insulating layer 109. With such a structure, a step on the formation surface of a layer (e.g., the insulating layer 110) formed over the conductive layer 112a and the insulating layer 109 is reduced, so that coverage with the layer can be improved. This can inhibit generation of a defect such as step disconnection or a void in the layer.

Note that the structure of the insulating layer 109 described in Structure example 1-4 can also be applied to other structure examples.

### Structure Example 1-5

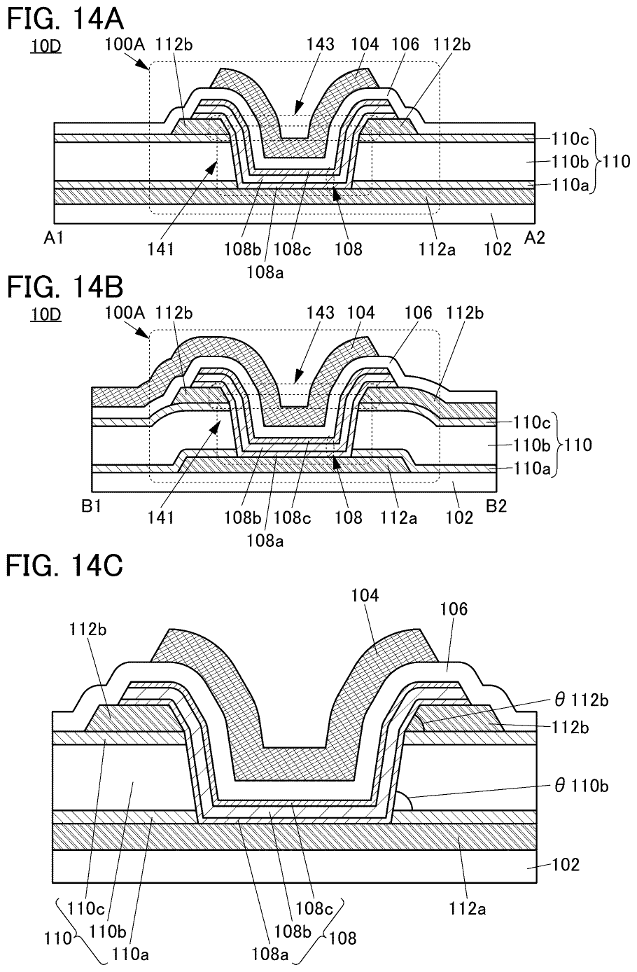

FIG. 14A and FIG. 14B are cross-sectional views of a semiconductor device 10D of one embodiment of the present invention. FIG. 1A can be referred to for a top view of the semiconductor device 10D. FIG. 14A is a cross-sectional view of a cut plane along the dashed-dotted line A1-A2 in FIG. 1A, and FIG. 14B is a cross-sectional view of a cut plane along the dashed-dotted line B1-B2 in FIG. 1A.

The semiconductor device 10D includes a transistor 100A and the insulating layer 110. The transistor 100A is different from the transistor 100 illustrated in FIG. 1B and the like mainly in that the angle formed by the side surface of the conductive layer 112b on the opening 143 side and the formation surface of the conductive layer 112b (here, the top surface of the insulating layer 110) is different from the angle formed by the side surface of the insulating layer 110 on the opening 141 side and the formation surface of the insulating layer 110 (here, the top surface of the conductive layer 112a).

FIG. 14C is an enlarged view of FIG. 14A. As illustrated in FIG. 14C, an angle θ112b formed by the side surface of the conductive layer 112b on the opening 143 side and the formation surface of the conductive layer 112b (here, the top surface of the insulating layer 110) is preferably smaller than the angle θ110b in the cross-sectional view. When the angle θ112b is smaller than the angle θ110b, a step of the formation surface of the layer (e.g., the semiconductor layer 108) formed over the conductive layer 112b and the insulating layer 110 is reduced, so that coverage with the layer can be improved. This can inhibit generation of a defect such as step disconnection or a void in the layer.

For example, by employing different methods for formation of the opening 141 and the opening 143, the angle θ112b of the conductive layer 112b and the angle θ110b of the insulating layer 110 can be made different from each other. For example, when a wet etching method is used for the formation of the opening 143 and a dry etching method is used for the formation of the opening 141, the angle θ112b can be made smaller than the angle θ110b.

The structures of the insulating layer 110 and the conductive layer 112b described in Structure example 1-5 can be applied to other structure examples.

### Structure Example 1-6

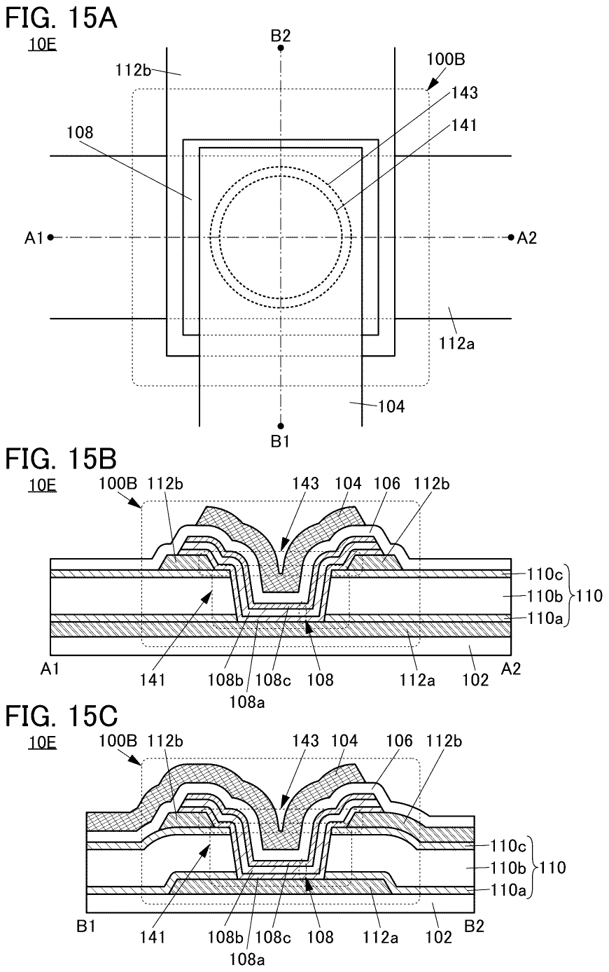

FIG. 15A is a top view of a semiconductor device 10E of one embodiment of the present invention. FIG. 15B is a cross-sectional view of a cut plane along the dashed-dotted line A1-A2 in FIG. 15A, and FIG. 15C is a cross-sectional view of a cut plane along the dashed-dotted line B1-B2.

The semiconductor device 10E includes a transistor 100B and the insulating layer 110. The transistor 100B is different from the transistor 100 illustrated in FIG. 1B and the like mainly in that the top surface shape of the opening 141 is not the same as the top surface shape of the opening 143.

As illustrated in FIG. 15A, in the top view, the opening 143 preferably covers the opening 141 completely. As illustrated in FIG. 15B and FIG. 15C, the insulating layer 110 preferably includes a region protruding beyond the conductive layer 112b on the opening 141 side in the cross-sectional view. With such a structure, a step on the formation surface of a layer (e.g., the semiconductor layer 108) formed over the conductive layer 112b and the insulating layer 110 is reduced, so that coverage with the layer can be improved. This can inhibit generation of a defect such as step disconnection or a void in the layer.

The semiconductor layer 108 includes a region in contact with the top surface and the side surface of the conductive layer 112b, the top surface and the side surface of the insulating layer 110, and the top surface of the conductive layer 112a. The semiconductor layer 108 has a shape along the shapes of the top surface and the side surface of the conductive layer 112b, the top surface and the side surface of the insulating layer 110, and the top surface of the conductive layer 112a.

Note that in the case where the top surface shapes of the opening 141 and the opening 143 are circular, the opening 141 and the opening 143 may be concentrically arranged, but not necessarily concentrically arranged.

The structures of the opening 141 and the opening 143 described in Structure example 1-6 can also be used in the other structure examples.

### Structure Example 1-7

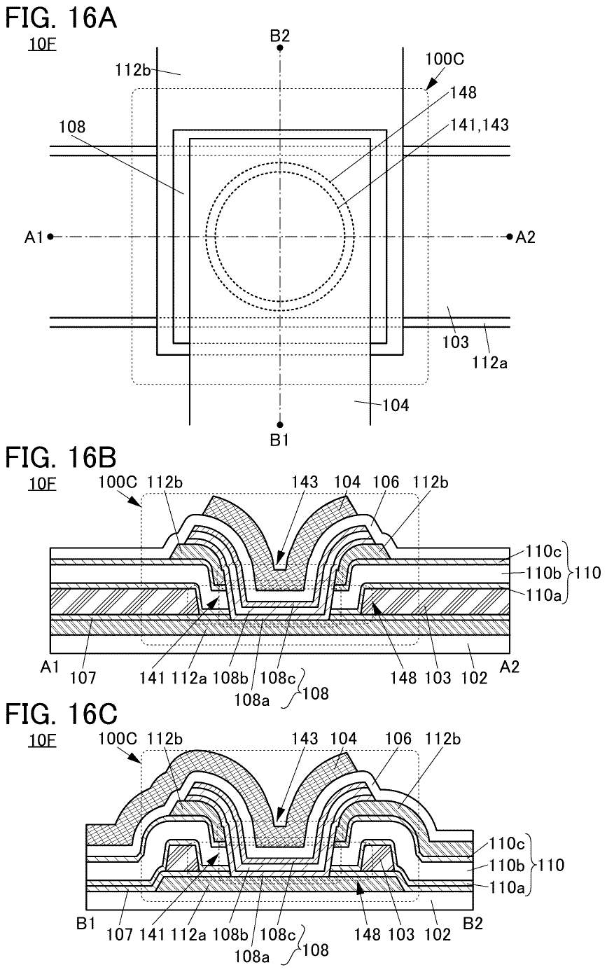

FIG. 16A is a top view of a semiconductor device 10F of one embodiment of the present invention. FIG. 16B is a cross-sectional view of a cut plane along the dashed-dotted line A1-A2 in FIG. 16A, and FIG. 16C is a cross-sectional view of a cut plane along the dashed-dotted line B1-B2.

The semiconductor device 10F includes a transistor 100C and the insulating layer 110. The transistor 100C is different from the transistor 100 illustrated in FIG. 1B and the like mainly in including a conductive layer 103 and an insulating layer 107.

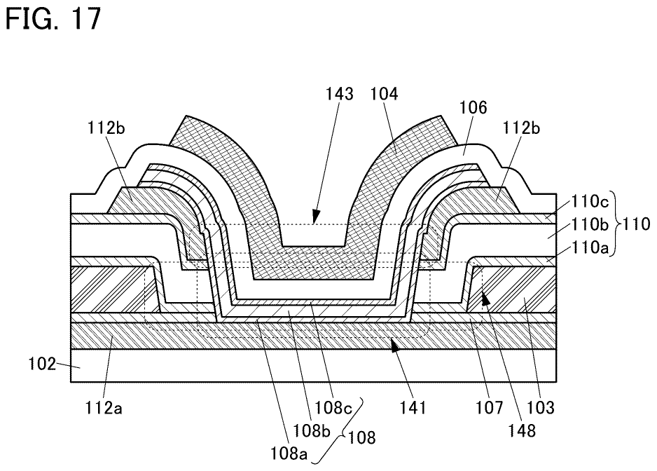

FIG. 17 is an enlarged view of FIG. 16B. As illustrated in FIG. 17, the transistor 100C includes the conductive layer 103 and the insulating layer 107 between the conductive layer 112a and the insulating layer 110.

The insulating layer 107 is positioned over the conductive layer 112a. The insulating layer 107 is provided so as to cover the top surface and the side surface of the conductive layer 112a.

The conductive layer 103 is positioned over the insulating layer 107. The conductive layer 112a and the conductive layer 103 are electrically insulated from each other by the insulating layer 107. In the conductive layer 103, an opening 148 reaching the insulating layer 107 is provided in a region overlapping with the conductive layer 112a.

The insulating layer 110 is provided over the insulating layer 107 and the conductive layer 103. The insulating layer 110 is provided so as to cover the tope surface and the side surface of the conductive layer 103 and the top surface of the insulating layer 107. The opening 141 reaching the conductive layer 112a is provided in the insulating layer 110 and the insulating layer 107.

The insulating layer 110a is positioned over the insulating layer 107 and the conductive layer 103. The insulating layer 110a is provided to cover the top surface and the side surface of the conductive layer 103. In addition, the insulating layer 110a is provided to cover part of the opening 148. The insulating layer 110a is in contact with the insulating layer 107 in the opening 148.

There is no particular limitation on the top surface shape of the opening 148. As the top surface shape of the opening 148, the shapes that can be used for the opening 141 and the opening 143 can be employed. The top surface shapes of the opening 141, the opening 143, and the opening 148 are preferably circular as illustrated in FIG. 16A. When the top surface shapes of the openings are circles, processing accuracy in forming the openings can be high, whereby the openings can be formed to have minute sizes.

In this specification and the like, the top surface shape of the opening 148 refers to the shape of an end portion on the opening 148 side of the top surface or the bottom surface of the conductive layer 103.

When the top surface shapes of the opening 141 and the opening 148 are circles, the opening 141 and the opening 148 are preferably concentrically arranged. In that case, the shortest distances between the semiconductor layer 108 and the conductive layer 103 on the left and right sides of the opening 141 can be the same in the cross-sectional view. The opening 141 and the opening 148 are not concentrically arranged in some cases.

In the transistor 100C, the semiconductor layer 108 includes a region overlapping with the conductive layer 104 with the insulating layer 106 therebetween and overlapping with the conductive layer 103 with part of the insulating layer 110 (specifically, the insulating layer 110a and the insulating layer 110b) therebetween. In other words, the semiconductor layer 108 includes a region interposed between the conductive layer 104 and the conductive layer 103 with the insulating layer 106 positioned between the region and the conductive layer 104 and with part of the insulating layer 110 (specifically, the insulating layer 110a and the insulating layer 110b) positioned between the region and the conductive layer 103.

The conductive layer 104 functions as a gate electrode (also referred to as a first gate electrode) of the transistor 100C. Part of the insulating layer 106 functions as a gate insulating layer (also referred to as a first gate insulating layer). The conductive layer 103 functions as a back gate electrode (also referred to as a second gate electrode). Part of the insulating layer 110 functions as a back gate insulating layer (also referred to as a second gate insulating layer). The conductive layer 103 can be formed using a material that can be used for the conductive layer 112a, the conductive layer 112b, and the conductive layer 104. Note that the conductive layer 103 is not necessarily provided.

When the transistor 100C includes a back gate electrode, the potential of the semiconductor layer 108 on the back gate electrode side (also referred to as back channel side) is fixed, so that the saturation of the Id-Vd characteristics can be improved.

In this specification and the like, the state where the change in a current is small in the saturation region of the Id-Vd characteristics of a transistor is sometimes described using the expression “high saturation”.

Since the transistor 100C includes the back gate electrode, the potential on the back channel side of the semiconductor layer 108 can be fixed and a shift of the threshold voltage can be inhibited. A shift in the threshold voltage of the transistor might increase the drain current which flows at a gate voltage of 0 V (hereinafter, also referred to as cut-off current). When a shift of the threshold voltage is inhibited, the cut-off current can be reduced in the transistor. Accordingly, a semiconductor device with low power consumption can be provided.

For the insulating layer 107, a material that can be used for the insulating layer 110 can be used. An insulating layer containing nitrogen is preferably used as the insulating layer 107 in contact with the conductive layer 112a and the conductive layer 103. For the insulating layer 107, a material that can be used for the insulating layer 110a and the insulating layer 110c can be suitably used. For example, silicon nitride can be suitably used for the insulating layer 107. Although the insulating layer 107 has a single-layer structure in this embodiment, one embodiment of the present invention is not limited thereto. The insulating layer 107 may have a stacked-layer structure of two or more layers.

The conductive layer 103 and the conductive layer 112a may be electrically connected to each other. For example, when an opening is provided in a region of the insulating layer 107 overlapping with the conductive layer 112a and the conductive layer 103 is provided to cover the opening, the conductive layer 103 and the conductive layer 112a can be in contact with each other. When the conductive layer 112a functioning as the source electrode or the drain electrode and the conductive layer 103 functioning as the back gate electrode are electrically connected to each other, the back gate electrode can have the same potential as the source electrode or the drain electrode. For example, in the case where the conductive layer 112a functions as the source electrode, a shift of the threshold voltage of the transistor 100C can be inhibited. Furthermore, the reliability of the transistor 100C can be improved. Note that the conductive layer 103 may be formed in contact with the top surface of the conductive layer 112a without providing the insulating layer 107.

The conductive layer 103 and the conductive layer 112b may be electrically connected to each other. For example, when an opening is provided in a region of the insulating layer 110 which overlaps with the conductive layer 103 and the conductive layer 112b is provided to cover the opening, the conductive layer 103 and the conductive layer 112b can be in contact with each other.

The conductive layer 103 may be electrically connected to the conductive layer 104. For example, when an opening is provided in regions of the insulating layer 106 and the insulating layer 110 overlapping with the conductive layer 103 and the conductive layer 104 is provided to cover the opening, the conductive layer 103 and the conductive layer 104 can be in contact with each other. When the conductive layer 104 functioning as the gate electrode and the conductive layer 103 functioning as the back gate electrode are electrically connected to each other, the back gate electrode and the gate electrode can have the same potential, so that the on-state current of the transistor 100C can be increased.

The thickness of the conductive layer 103 may be larger than the thickness of the insulating layer 110. Accordingly, the potential of the semiconductor layer 108 on the back channel side can be fixed in a wide range between the source region and the drain region of the semiconductor layer 108.

The transistor 100C includes a region where the conductive layer 103, the insulating layer 110, the semiconductor layer 108, the insulating layer 106, and the conductive layer 104 are stacked in this order with no any other layer provided between these layers. The direction can be a direction perpendicular to the channel length direction. When the above region is wide, the potential of the semiconductor layer 108 on the back channel side can be more surely controlled.

The thickness of the conductive layer 103 can be larger than the sum of the thickness of a portion of the semiconductor layer 108 that is in contact with the conductive layer 112a inside the opening 141 and the thickness of the insulating layer 106 in contact with the portion.

The structures of the conductive layer 103 and the insulating layer 107 described in Structure example 1-7 can also be applied to other structure examples.

### Structure Example 2

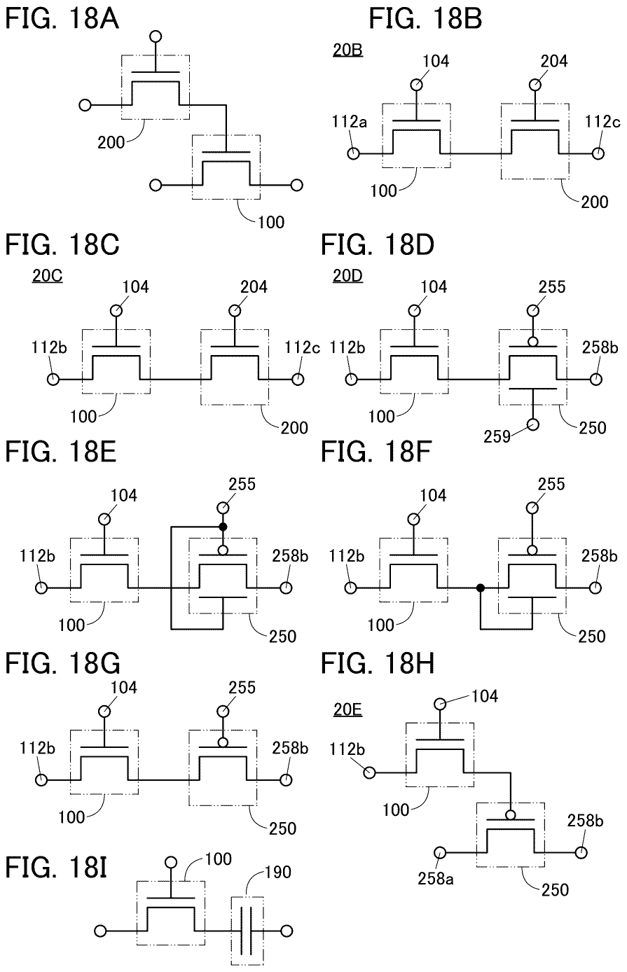

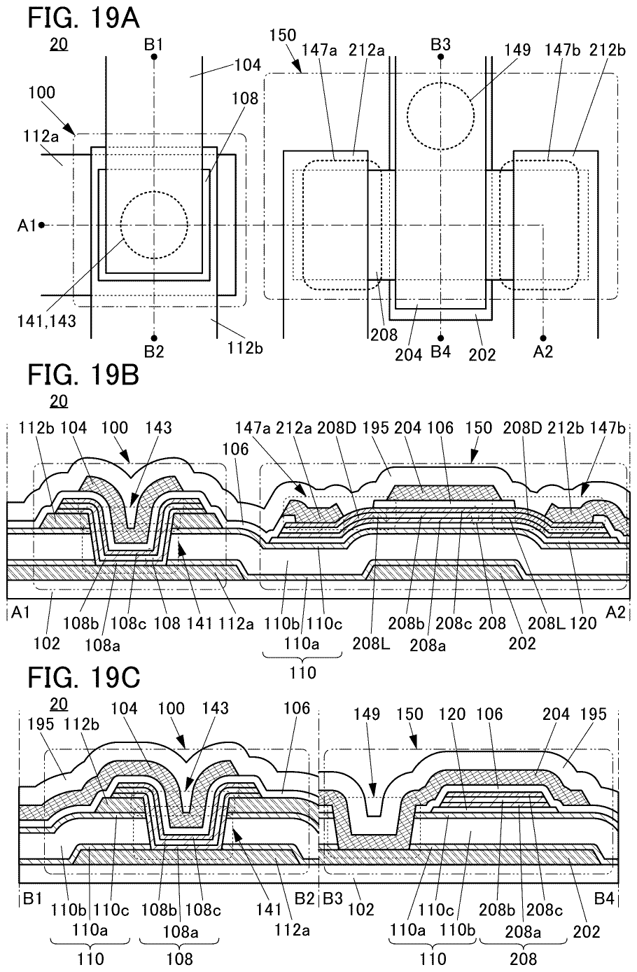

FIG. 18A to FIG. 18I are circuit diagrams of the semiconductor device of one embodiment of the present invention. FIG. 19 to FIG. 24 illustrate top views and cross-sectional views of semiconductor devices of one embodiment of the present invention. In the following description, the transistor 100 is mainly used as an example of the transistor included in the semiconductor device of one embodiment of the present invention. Without limitation to this, the semiconductor devices of one embodiment of the present invention may include any one or more of the transistor 100A to the transistor 100C described above.

The semiconductor device of one embodiment of the present invention includes at least two transistors, and any of a gate, a source, and a drain of one transistor is electrically connected to any of a gate, a source, and a drain of another transistor.

For example, the semiconductor device in FIG. 18A includes the transistor 100 and a transistor 200. One of a source and a drain of the transistor 200 is electrically connected to a gate of the transistor 100.

Although the transistor 100 and the transistor 200 are illustrated as n-channel transistors in FIG. 18A to FIG. 18C, one embodiment of the present invention is not limited thereto. One or both of the transistor 100 and the transistor 200 may be a p-channel transistor(s).

### Structure Example 2-1

FIG. 19A is a top view of a semiconductor device 20 of one embodiment of the present invention. FIG. 19B illustrates a cross-sectional view of a cross section along the dashed-dotted line A1-A2 in FIG. 19A, and FIG. 19C illustrates a cross-sectional view of cross sections along the dashed-dotted line B1-B2 and the dashed-dotted line B3-B4 in FIG. 19A.

The semiconductor device 20 includes the transistor 100 and a transistor 150. In the semiconductor device 20, any of the gate, the source, and the drain of the transistor 100 can be electrically connected to any of a gate, a source, and a drain of the transistor 150. In FIG. 19A to FIG. 19C, the electrical connection between the transistor 100 and the transistor 150 is omitted.

The transistor 100 and the transistor 150 are provided over the substrate 102.

The above description can be referred to for the transistor 100; thus, the detailed description thereof is omitted.

The transistor 150 includes a conductive layer 202, the insulating layer 110, an insulating layer 120, a semiconductor layer 208, the insulating layer 106, a conductive layer 204, a conductive layer 212a, and a conductive layer 212b. The layers included in the transistor 150 may each have a single-layer structure or a stacked-layer structure.

The conductive layer 202 is provided over the substrate 102. The conductive layer 202 functions as a back gate electrode of the transistor 150. The conductive layer 202 can be formed using the same material as the conductive layer 112a included in the transistor 100. The conductive layer 202 can be formed in the same step as the conductive layer 112a. For example, a film to be the conductive layer 112a and the conductive layer 202 is formed and then processed, whereby the conductive layer 112a and the conductive layer 202 can be formed. Note that the conductive layer 202 may be formed in a step different from that of the conductive layer 112a. By forming in different steps, a material different from that for the conductive layer 112a can be used for the conductive layer 202. The conductive layer 202 includes neither a region in contact with the semiconductor layer 108 nor a region in contact with the semiconductor layer 208, and thus there is no particular limitation on the material to be used. For example, for the conductive layer 202, a material having lower electrical resistivity than the conductive layer 112a is preferably used. In this case, the electric resistance of the conductive layer 202 can be reduced. For example, In—Sn—Si oxide (ITSO) can be suitably used for the conductive layer 112a and copper or tungsten can be suitably used for the conductive layer 202. In the case where the conductive layer 112a has a stacked-layer structure as illustrated in FIG. 6A and the like, for example, In—Sn—Si oxide (ITSO) can be suitably used for the conductive layer 112a_2 and copper or tungsten can be suitably used for the conductive layer 112a_1 and the conductive layer 202. Note that the transistor 150 does not necessarily include a back gate electrode.

The insulating layer 110 is provided to cover the conductive layer 202, and the insulating layer 120 is provided over the insulating layer 110. The insulating layer 110 and the insulating layer 120 function as a back gate insulating layer of the transistor 150. The insulating layer 120 is a layer in contact with a channel formation region of the semiconductor layer 208 and thus is preferably an insulating layer containing oxygen. For the insulating layer 120, for example, a material suitable for the insulating layer 110b can be used.

The semiconductor layer 208 is provided over the insulating layer 120. The semiconductor layer 208 includes a region overlapping with the conductive layer 202 with the insulating layer 110 and the insulating layer 120 therebetween. The semiconductor layer 208 can be formed using the same material as the semiconductor layer 108. The semiconductor layer 208 can be formed in the same step as the semiconductor layer 108.

FIG. 19B and FIG. 19C each illustrate a structure in which the semiconductor layer 208 has a stacked-layer structure of a semiconductor layer 208a, a semiconductor layer 208b over the semiconductor layer 208a, and a semiconductor layer 208c over the semiconductor layer 208b. For example, a film to be the semiconductor layer 108 and the semiconductor layer 208 is formed and then processed, whereby the semiconductor layer 108 and the semiconductor layer 208 can be formed. The semiconductor layer 208a can be formed using the same material as the semiconductor layer 108a. The semiconductor layer 208b can be formed using the same material as the semiconductor layer 108b. The semiconductor layer 208c can be formed using the same material as the semiconductor layer 108c.

The insulating layer 106 is provided to cover the insulating layer 120 and the semiconductor layer 208. The insulating layer 106 functions as a gate insulating layer of the transistor 150. Furthermore, the insulating layer 106 includes an opening 147a and an opening 147b reaching the semiconductor layer 208.

The conductive layer 204, the conductive layer 212a, and the conductive layer 212b are provided over the insulating layer 106. The conductive layer 204, the conductive layer 212a, and the conductive layer 212b can be formed using the same material as the conductive layer 104. The conductive layer 204, the conductive layer 212a, and the conductive layer 212b can be formed in the same step as the conductive layer 104. For example, a film to be the conductive layer 104, the conductive layer 204, the conductive layer 212a, and the conductive layer 212b is formed and the film is processed, whereby the conductive layer 104, the conductive layer 204, the conductive layer 212a, and the conductive layer 212b can be formed.

The conductive layer 212a is provided to cover at least part of the opening 147a and the conductive layer 212b is provided to cover at least part of the opening 147b. Each of the conductive layer 212a and the conductive layer 212b has a region that is in contact with the semiconductor layer 208. The conductive layer 212a is electrically connected to the semiconductor layer 208 through the opening 147a. The conductive layer 212b is electrically connected to the semiconductor layer 208 through the opening 147b. The conductive layer 212a functions as one of the source electrode and the drain electrode and the conductive layer 212b functions as the other thereof in the transistor 150.

The conductive layer 204 includes a region overlapping with the semiconductor layer 208 with the insulating layer 106 therebetween. The conductive layer 204 functions as a gate electrode of the transistor 150.

As illustrated in FIG. 19C, the conductive layer 204 and the conductive layer 202 may be in contact with each other and electrically connected to each other. In that case, the conductive layer 204 and the conductive layer 202 can be supplied with the same potential. When the same potentials are supplied to the conductive layer 204 and the conductive layer 202, the amount of current that can flow through the transistor 150 in the on state can be increased. A structure can be employed in which the conductive layer 204 is electrically connected to the conductive layer 202 through an opening 149 provided in the insulating layer 106 and the insulating layer 110.

The conductive layer 212a or the conductive layer 212b may be electrically connected to the conductive layer 202. The same potential is supplied to the source and the back gate, whereby the potential of the back channel can be stabilized and the saturation in the Id-Vd characteristics of the transistor can be improved. A structure can be employed in which the conductive layer 212a or the conductive layer 212b is in contact with the conductive layer 202 through the opening provided in the insulating layer 106 and the insulating layer 110.

A structure may be employed in which the conductive layer 202 is not electrically connected to any of the conductive layer 204, the conductive layer 212a, and the conductive layer 212b. For example, a constant potential is supplied to the back gate, and a signal for driving the transistor 150 can be supplied to the gate. Accordingly, the potential supplied to the back gate enables control of the threshold voltage in driving the transistor 150.

In the semiconductor layer 208 between the source electrode and the drain electrode, the region overlapping with the gate electrode with the gate insulating layer therebetween functions as a channel formation region. The semiconductor layer 208 includes a pair of regions 208L between which a channel formation region is interposed and a pair of regions 208D outside the pair of regions 208L.

The region 208D can also be referred to as a region having a higher carrier concentration or a lower resistance than the channel formation region. In the semiconductor layer 208, a region in contact with the conductive layer 212a and the region 208D adjacent to the region function as one of a source region and a drain region. In the semiconductor layer 208, a region in contact with the conductive layer 212b and the region 208D adjacent to the region function as the other of the source region and the drain region.

The region 208L can be referred to as a region whose electric resistance is substantially equal to or lower than that of the channel formation region, a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. Moreover, the region 208L can be referred to as a region whose electric resistance is substantially equal to or higher than the resistance of the region 208D, a region whose carrier concentration is substantially equal to or lower than the carrier concentration of the region 208D, a region whose oxygen vacancy density is substantially equal to or lower than the oxygen vacancy density of the region 208D, or a region whose impurity concentration is substantially equal to or lower than the impurity concentration of the region 208D.

The region 208L functions as a buffer region that relieves a drain electric field. The region 208L is a region not overlapping with the conductive layer 204 and thus is a region where a channel is hardly formed by application of gate voltage to the conductive layer 204. The region 208L preferably has a higher carrier concentration than the channel formation region. Thus, the region 208L can function as an LDD (Lightly Doped Drain) region. The region 208L functioning as the LDD region provided between the channel formation region and the region 208D enables the transistor 150 to have a high drain breakdown voltage.

For example, after the conductive layer 204, the conductive layer 212a, and the conductive layer 212b are formed, an impurity element is added to the semiconductor layer 208 using these conductive layers as masks, whereby the region 208L and the region 208D can be formed. The region 208L is a region that is of the semiconductor layer 208, overlaps with the insulating layer 106, and does not overlap with the conductive layer 204. The region 208D is a region that is of the semiconductor layer 208 and overlaps with neither the insulating layer 106 nor the conductive layer 204.

As illustrated in FIG. 19A and FIG. 19B, it is preferable that end portions of the conductive layer 212a and the conductive layer 212b be partly positioned inside the opening 147a and the opening 147b, respectively. In other words, it is preferable that the end portions of the conductive layer 212a and the conductive layer 212b be partly in contact with the semiconductor layer 208 in the opening 147a and the opening 147b, respectively. Accordingly, the region in contact with the conductive layer 212a can be adjacent to one of the pair of regions 208D, and the region in contact with the conductive layer 212b can be adjacent to the other of the pair of regions 208D. There is no limitation on the top surface shapes of the opening 147a and the opening 147b.

The region 208L and the region 208D contain an impurity element. As the impurity element, one or more of hydrogen, boron, carbon, nitrogen, fluorine, phosphorus, sulfur, arsenic, aluminum, magnesium, silicon, and a noble gas can be used. Typical examples of the noble gas include helium, neon, argon, krypton, and xenon. It is particularly preferable to use one or more of boron, phosphorus, aluminum, magnesium, and silicon as the impurity element.

When the region 208L and the region 208D are formed by adding the impurity element to the semiconductor layer 208, the impurity element may be supplied to the semiconductor layer 108 through the insulating layer 106 with use of the conductive layer 104 as a mask. Consequently, a region containing the impurity element is formed in the region of the semiconductor layer 108 not overlapping with the conductive layer 104. Here, in the transistor 100, a region of the semiconductor layer 108 in contact with the conductive layer 112b functions as the source region or the drain region. Thus, the region containing the impurity element is formed in part of the source region or the drain region.

The transistor 150 is what is called a top-gate transistor including the gate electrode above the semiconductor layer 208. For example, an impurity element is added to the semiconductor layer 208 with the conductive layer 204 functioning as the gate electrode used as a mask, so that the source region and the drain region can be formed in a self-aligned manner. The transistor 150 can be referred to as a TGSA (Top Gate Self-Aligned) transistor.

The channel length of the transistor 150 can be controlled by the width of the conductive layer 204 in the channel length direction. Accordingly, the channel length of the transistor 150 is greater than or equal to the resolution limit of a light exposure apparatus used for manufacturing the transistor. The transistor with a long channel length can have favorable saturation.

An insulating layer 195 is provided to cover the transistor 100 and the transistor 150. The insulating layer 195 functions as a protective layer. For the insulating layer 195, a material that does not easily allow diffusion of impurities is preferably used. Providing the insulating layer 195 can effectively inhibit diffusion of impurities into the transistors from the outside and can increase the reliability of the semiconductor device. Examples of the impurities include water and hydrogen. The insulating layer 195 includes, for example, one or both of an inorganic insulating layer and an organic insulating layer. The insulating layer 195 may have a stacked-layer structure of an inorganic insulating layer and an organic insulating layer.

For the inorganic insulating layer in the insulating layer 195, a material that can be used for the insulating layer 110 can be used. Specifically, one or more of silicon nitride, silicon nitride oxide, silicon oxynitride, aluminum oxide, aluminum oxynitride, aluminum nitride, hafnium oxide, and hafnium aluminate can be used for the insulating layer 195. For example, one or more of an acrylic resin and a polyimide resin can be used for the organic insulating layer in the insulating layer 195.

In manufacturing the semiconductor device 20, the transistor 100 with a short channel length and the transistor 150 with a long channel length can be formed over the same substrate by the formation steps some of which are shared. For example, the transistor 100 is used as the transistor required to have a high on-state current and the transistor 150 is used as the transistor required to have favorable saturation, thereby providing a high-performance semiconductor device.

Although the structure in which the conductive layer 212a and the conductive layer 212b are formed in the same step as the conductive layer 104 and the conductive layer 204 is described here, one embodiment of the present invention is not limited thereto. For example, the conductive layer 212a and the conductive layer 212b may be formed after the formation of the insulating layer 195. Specifically, a structure in which the conductive layer 212a and the conductive layer 212b are electrically connected to the semiconductor layer 208 may be formed in the following manner: after the insulating layer 195 is provided to cover the conductive layer 104 and the conductive layer 204, an opening reaching the semiconductor layer 208 is provided in the insulating layer 195 and the insulating layer 106, and the conductive layer 212a and the conductive layer 212b are provided to cover the opening. Note that by adding an impurity element to the semiconductor layer 208 with the conductive layer 204 as a mask after the formation of the conductive layer 204, a low-resistance region may be formed in the semiconductor layer 208.

### Structure Example 2-2

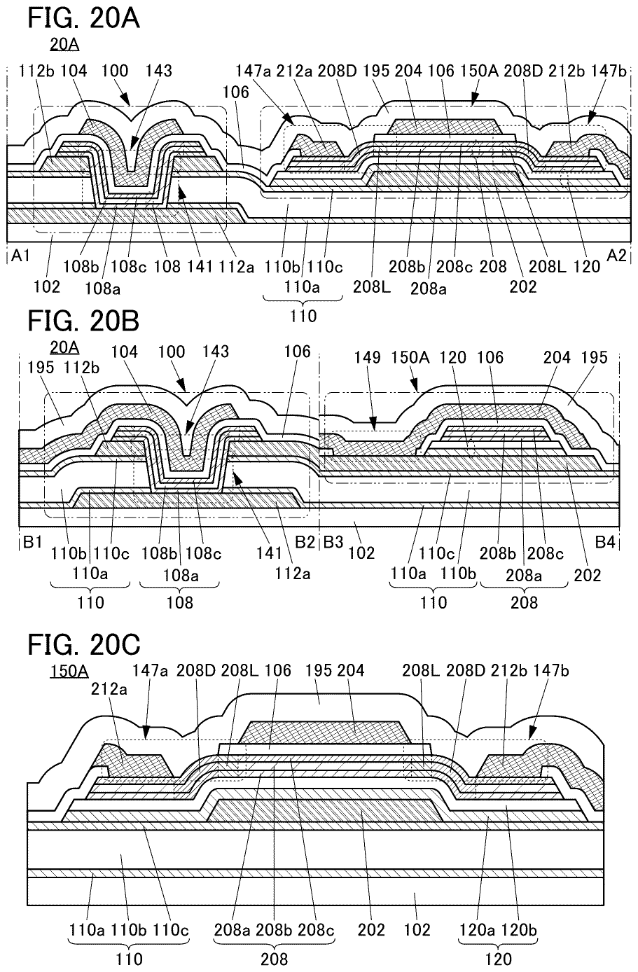

FIG. 20A and FIG. 20B illustrate cross-sectional views of a semiconductor device 20A of one embodiment of the present invention. FIG. 19A can be referred to for a top view of the semiconductor device 20A. FIG. 20A is a cross-sectional view of a cross section along the dashed-dotted line A1-A2 in FIG. 19A, and FIG. 20B is a cross-sectional view of cross sections along the dashed-dotted line B1-B2 and the dashed-dotted line B3-B4 in FIG. 19A.

The semiconductor device 20A includes the transistor 100 and a transistor 150A. The transistor 150A is different from the transistor 150 illustrated in FIG. 19B and the like mainly in that the conductive layer 202 is provided between the insulating layer 110 and the insulating layer 120.

FIG. 20C is an enlarged view of FIG. 20A. The conductive layer 202 is provided over the insulating layer 110. The conductive layer 202 can be formed using the same material as the conductive layer 112b. The conductive layer 202 can be formed in the same step as the conductive layer 112b.

The insulating layer 120 is provided over the conductive layer 202. The insulating layer 120 is provided so as to cover the top surface and the side surface of part of the conductive layer 202. The insulating layer 120 is provided at least in a region where the semiconductor layer 208 and the conductive layer 204 overlap with each other. In the transistor 150A, part of the insulating layer 120 functions as a back gate insulating layer. When the conductive layer 202 is provided between the insulating layer 110 and the insulating layer 120, the thickness of the back gate insulating layer of the transistor 150A can be reduced. Thus, the electric field of the back gate electrode can be intensified. Furthermore, the saturation of the Id-Vd characteristics of the transistor 150A can be improved. Moreover, a shift of the threshold voltage can be inhibited; accordingly, the cut-off current of the transistor can be reduced.

The insulating layer 120 preferably has a stacked-layer structure. FIG. 20A and the like illustrate an example in which the insulating layer 120 has a stacked-layer structure of an insulating layer 120a and an insulating layer 120b over the insulating layer 120a.

For the insulating layer 120a provided in contact with the conductive layer 202, a material that does not easily allow diffusion of a metal element contained in the conductive layer 202 is preferably used. This inhibits the metal element contained in the conductive layer 202 from being diffused into the channel formation region in the semiconductor layer 208. For the insulating layer 120a, a material that can be used for the insulating layer 110a and the insulating layer 110c can be suitably used. For the insulating layer 120a, silicon nitride can be suitably used, for example.

As the insulating layer 120b in contact with the channel formation region of the semiconductor layer 208, an insulating layer containing oxygen is preferably used. For the insulating layer 120b, a material that can be suitably used for the insulating layer 110b can be used. For example, silicon oxynitride can be suitably used for the insulating layer 120b.

The above description can be referred to for the transistor 100; thus, the detailed description thereof is omitted.

### Structure Example 2-3

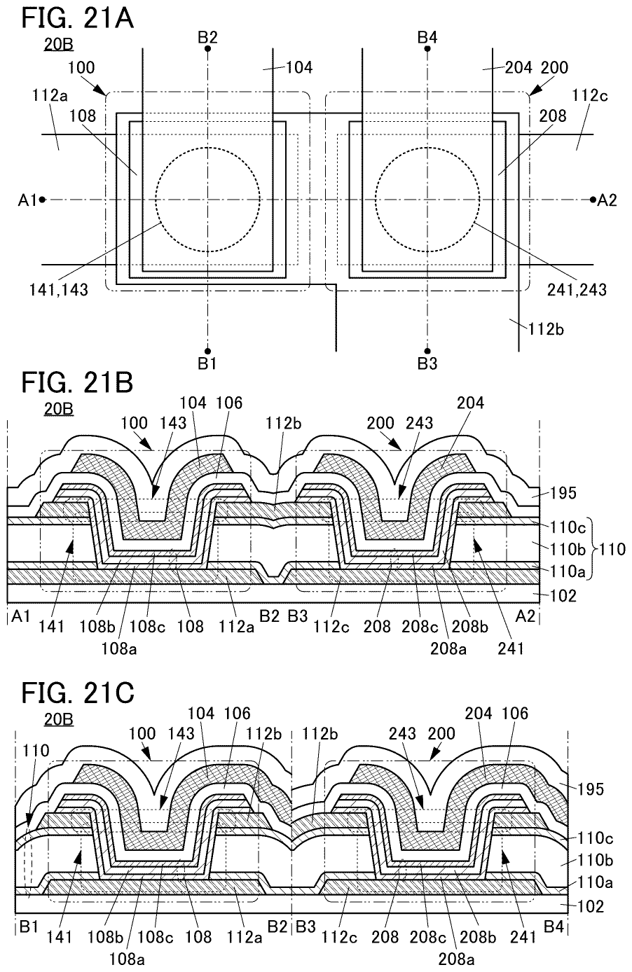

FIG. 18B is a circuit diagram of a semiconductor device 20B of one embodiment of the present invention. FIG. 21A illustrates a top view of the semiconductor device 20B. FIG. 21B illustrates a cross-sectional view of a cross section along the dashed-dotted line A1-A2 in FIG. 21A, and FIG. 21C illustrates a cross-sectional view of cross sections along the dashed-dotted line B1-B2 and the dashed-dotted line B3-B4 in FIG. 21A.

The semiconductor device 20B includes the transistor 100 and the transistor 200. The other of the source and the drain of the transistor 200 is electrically connected to the other of the source and the drain of the transistor 100.

The transistor 100 and the transistor 200 are provided over the substrate 102.

The above description can be referred to for the transistor 100; thus, the detailed description thereof is omitted.

The transistor 200 includes the conductive layer 112b, a conductive layer 112c, the semiconductor layer 208, the insulating layer 106, and the conductive layer 204. The transistor 200 can have a structure similar to that of the transistor 100.

The conductive layer 112c functions as one of a source electrode and a drain electrode of the transistor 200. The conductive layer 112b functions as the other of the source electrode and the drain electrode of the transistor 100 and also functions as the other of the source electrode and the drain electrode of the transistor 200. Since the transistor 100 and the transistor 200 share the conductive layer 112b, the semiconductor device occupies a smaller area. Part of the insulating layer 106 functions as a gate insulating layer of the transistor 200. The conductive layer 204 functions as a gate electrode of the transistor 200.

For the conductive layer 112c, the same material as the conductive layer 112a can be used. The conductive layer 112c can be formed in the same step as the conductive layer 112a. The insulating layer 110 includes an opening 241 reaching the conductive layer 112c. The opening 241 can be formed in the same step as the opening 141. The conductive layer 112b includes an opening 243 in a region overlapping with the opening 241. The opening 243 can be formed in the same step as the opening 143. Although the top surface shapes of the opening 241 and the opening 243 are not limited, the shapes are preferably circular. Although the top surface shape of the opening 241 and the top surface shape of the opening 243 are the same here, one embodiment of the present invention is not limited thereto. The opening 241 and the opening 243 do not necessarily have the same top surface shapes.

The width of the opening 141 may be different from the width of the opening 241. When the openings have different widths, two transistors with different channel widths can be manufactured.

The semiconductor layer 208 is provided to cover the opening 241 and the opening 243. The semiconductor layer 208 can be formed in the same step as the semiconductor layer 108. The insulating layer 106 is provided over the semiconductor layer 208, and the conductive layer 204 is provided over the insulating layer 106. The conductive layer 204 can be formed in the same step as the conductive layer 104.

Although FIG. 21A and the like have a structure where the semiconductor layer is divided into the semiconductor layer 108 in the transistor 100 and the semiconductor layer 208 in the transistor 200, one embodiment of the present invention is not limited thereto. The semiconductor layer may be shared between the transistor 100 and the transistor 200.

### Structure Example 2-4

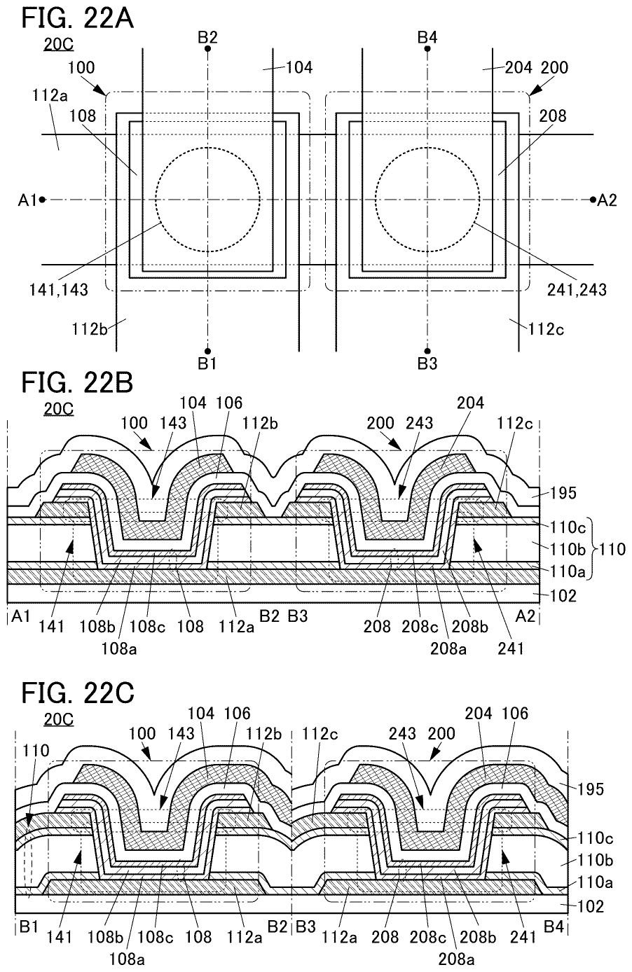

FIG. 18C illustrates a circuit diagram of a semiconductor device 20C of one embodiment of the present invention. FIG. 22A illustrates a top view of the semiconductor device 20C. FIG. 22B is a cross-sectional view of a cross section along the dashed-dotted line A1-A2 in FIG. 22A, and FIG. 22C is a cross-sectional view of cross sections along the dashed-dotted line B1-B2 and the dashed-dotted line B3-B4 in FIG. 22A.

The semiconductor device 20C includes the transistor 100 and the transistor 200. One of the source and the drain of the transistor 200 is electrically connected to one of the source and the drain of the transistor 100.

The transistor 100 and the transistor 200 are provided over the substrate 102.

The above description can be referred to for the transistor 100; thus, the detailed description thereof is omitted.

The transistor 200 includes the conductive layer 112a, the conductive layer 112c, the semiconductor layer 208, the insulating layer 106, and the conductive layer 204.

The conductive layer 112c functions as one of source electrode and the drain electrode of the transistor 200. The conductive layer 112a functions as one of the source electrode and the drain electrode of the transistor 100 and also functions as the other of the source electrode and the drain electrode of the transistor 200. Since the transistor 100 and the transistor 200 share the conductive layer 112a, the semiconductor device occupies a smaller area.

For the conductive layer 112c, the same material as the conductive layer 112b can be used. The conductive layer 112c can be formed in the same step as the conductive layer 112b.

### Structure Example 2-5

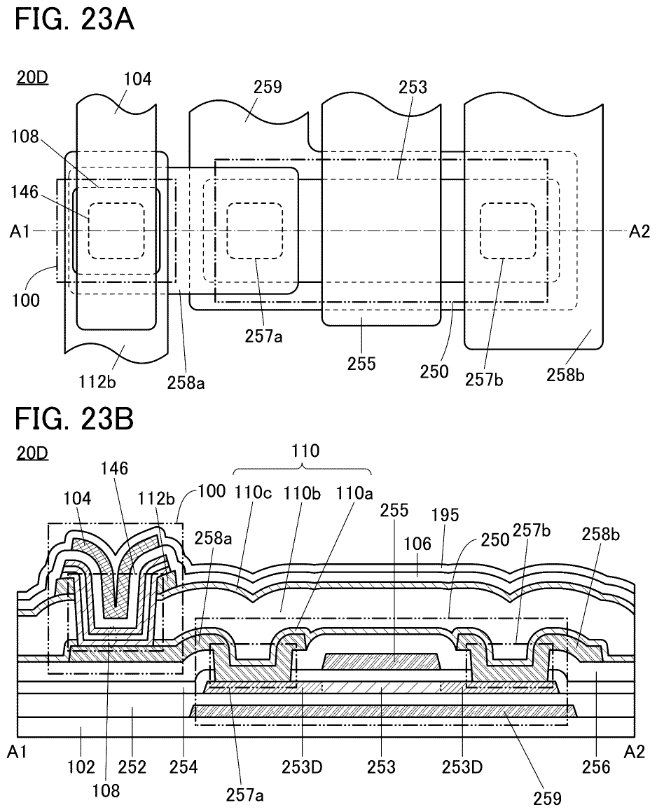

FIG. 18D is a circuit diagram of a semiconductor device 20D of one embodiment of the present invention. FIG. 23A is a top view of the semiconductor device 20D. FIG. 23B illustrates a cross-sectional view of a cross section along the dashed-dotted line A1-A2 in FIG. 23A.

The semiconductor device 20D includes the transistor 100 and a transistor 250. One of a source and a drain of the transistor 250 is electrically connected to one of the source and the drain of the transistor 100.

The transistor 100 and the transistor 250 are provided over the substrate 102.

The semiconductor device 20D includes a conductive layer 259 over the substrate 102, an insulating layer 252 over the substrate 102 and the conductive layer 259, and a semiconductor layer 253 over the insulating layer 252. Furthermore, an insulating layer 254 is provided over the insulating layer 252 and the semiconductor layer 253, and a conductive layer 255 is provided over the insulating layer 254. The semiconductor layer 253 and the conductive layer 255 overlap with each other in a region. The conductive layer 259 functions as a back gate electrode of the transistor 250, and the insulating layer 252 functions as a back gate insulating layer. The insulating layer 254 functions as a gate insulating layer, and the conductive layer 255 functions as a gate electrode.

An insulating layer 256 is provided over the insulating layer 254 and the conductive layer 255. The insulating layer 254 and the insulating layer 256 are provided with an opening 257a in a region overlapping with part of the semiconductor layer 253. The insulating layer 254 and the insulating layer 256 are provided with an opening 257b in a region overlapping with another part of the semiconductor layer 253.

A conductive layer 258a is provided over the insulating layer 256 and the opening 257a, and a conductive layer 258b is provided over the insulating layer 256 and the opening 257b. The conductive layer 258a is electrically connected to the semiconductor layer 253 in the opening 257a. The conductive layer 258b is electrically connected to the semiconductor layer 253 in the opening 257b.

The region of the semiconductor layer 253 that overlaps with the conductive layer 255 functions as a channel formation region. The semiconductor layer 253 includes a pair of regions 253D between which the channel formation region is interposed. One of the pair of regions 253D functions as one of a source region and a drain region and is electrically connected to the conductive layer 258a. The other of the pair of regions 253D functions as the other of the source region and the drain region and is electrically connected to the conductive layer 258b.

The insulating layer 110 is provided over the insulating layer 256, the conductive layer 258a, and the conductive layer 258b, and the conductive layer 112b is provided over the insulating layer 110.

The conductive layer 112b and the insulating layer 110 include an opening 146 in a region overlapping with part of the conductive layer 258a (FIG. 23A). The semiconductor layer 108 is provided to cover the opening 146.

The insulating layer 106 is provided over the insulating layer 110, the conductive layer 112b, and the semiconductor layer 108, and the conductive layer 104 is provided over the insulating layer 106. The insulating layer 195 is provided over the insulating layer 106 and the conductive layer 104.

It is preferable that the conductive layer 259 overlap with the channel formation region and extend beyond the end portion of the channel formation region. That is, the conductive layer 259 is preferably larger than the channel formation region. The conductive layer 259 preferably extends beyond the end portion of the semiconductor layer 253. That is, the conductive layer 259 is preferably larger than the semiconductor layer 253.

The gate electrode and the back gate electrode are placed so that a channel formation region of the semiconductor layer is interposed therebetween. By changing the potential of the back gate electrode, the threshold voltage of a transistor can be changed. The potential of the back gate electrode may be a ground potential or a given potential.

The back gate electrode can be formed using a material and a method similar to those used for the gate electrode, a source electrode, a drain electrode, or the like. The gate electrode and the back gate electrode are conductive layers and thus each have a function of preventing an electric field generated outside the transistor from affecting the semiconductor layer in which the channel is formed (in particular, an electric field blocking function against static electricity). That is, the variation in the electrical characteristics of the transistor due to the influence of an external electric field such as static electricity can be prevented. By providing the back gate electrode, the amount of change in threshold voltage of the transistor between before and after a BT (Bias Temperature) stress test can be reduced. By providing the back gate electrode, the variation in the characteristics of the transistor can be reduced and the reliability of a semiconductor device can be increased.

As illustrated in FIG. 18E, a back gate and a gate of the transistor 250 may be electrically connected to each other. As illustrated in FIG. 18F, the back gate of the transistor 250 and the source or the drain thereof may be electrically connected to each other. As illustrated in FIG. 18G, the transistor 250 does not necessarily include a back gate.

Although the transistor 100 is illustrated as an n-channel transistor and the transistor 250 is illustrated as a p-channel transistor in FIG. 18D to FIG. 18H, one embodiment of the present invention is not limited to thereto. Both the transistor 100 and the transistor 250 may be n-channel transistors or p-channel transistors. Alternatively, the transistor 100 may be a p-channel transistor and the transistor 250 may be an n-channel transistor.

Like the transistor 100, the transistor 250 may be an OS transistor.

Here, for the semiconductor layer 108 and the semiconductor layer 253, the same material or different materials may be used. For the structures of the semiconductor layer 108 and the semiconductor layer 253, the description of the semiconductor layer 108 and the semiconductor layer 208 of the semiconductor device 20 can be referred to.

A transistor including silicon in a channel formation region (hereinafter also referred to as a Si transistor) may be used as the transistor 250.

Examples of silicon include single crystal silicon, polycrystalline silicon, and amorphous silicon. In particular, a transistor including LTPS in a semiconductor layer (hereinafter also referred to as an LTPS transistor) can be used. The LTPS transistor has high field-effect mobility and excellent frequency characteristics.

The structure of the transistor 100 is the same as the above-described structure (see FIG. 1) except that the conductive layer 258a is provided instead of the conductive layer 112a.

The conductive layer 258a functions as one of the source electrode and the drain electrode of the transistor 100 and also functions as one of the source electrode and the drain electrode of the transistor 250. Since the transistor 100 and the transistor 250 share the conductive layer 258a, the semiconductor device occupies a smaller area.

As described above, the transistor 100 is a vertical-channel transistor. Meanwhile, in the semiconductor layer of the transistor 250, a current flows in the lateral direction, i.e., the direction parallel or substantially parallel to a surface of the substrate 102. Such a transistor can be called a lateral-channel transistor.

As described above, the semiconductor device of one embodiment of the present invention may include not only a vertical-channel transistor but also a lateral-channel transistor.

Note that the transistor 100 may be formed in a region overlapping with the opening 257a. Specifically, the opening 146 can be provided in a region overlapping with the opening 257a, and the conductive layer 258a and the semiconductor layer 108 can be in contact with each other in the opening 257a. Furthermore, a structure may be employed in which the conductive layer 258a is not provided and the region 253D and the semiconductor layer 108 are in contact with each other in the opening 257a. With such a structure, a semiconductor device that occupies a smaller area can be provided.

### Structure Example 2-6

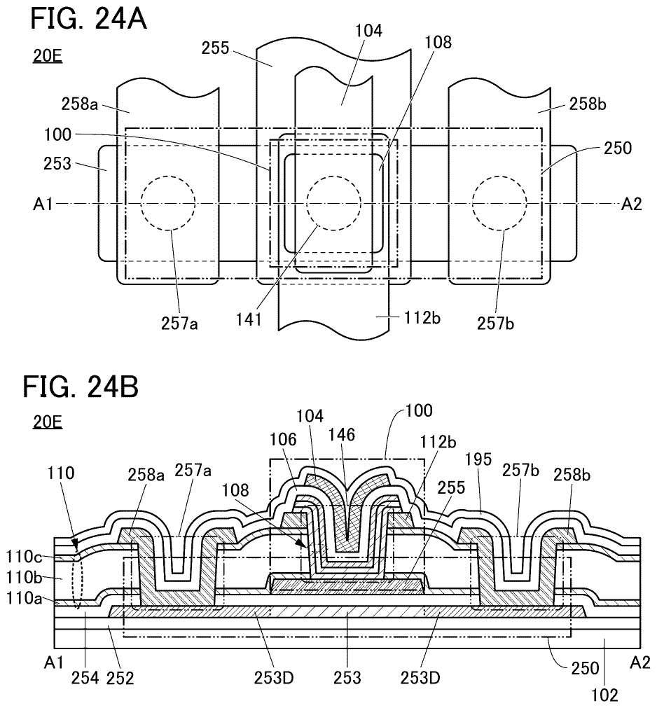

FIG. 18H is a circuit diagram of a semiconductor device 20E of one embodiment of the present invention. FIG. 24A is a top view of the semiconductor device 20E. FIG. 24B illustrates a cross-sectional view of a cross section along the dashed-dotted line A1-A2 in FIG. 24A.

The semiconductor device 20E includes the transistor 100 and the transistor 250. The gate of the transistor 250 is electrically connected to one of the source and the drain of the transistor 100.

The semiconductor device 20E is different from the semiconductor device 20D mainly in that the opening 146 overlaps with the conductive layer 255 functioning as the gate electrode of the transistor 250. Accordingly, in the semiconductor device 20D, the transistor 100 is provided over the gate electrode of the transistor 250.

Although the opening 146 overlaps with the channel formation region in FIG. 24A and FIG. 24B, one embodiment of the present invention is not limited thereto. A structure may be employed in which the opening 146 does not overlap with the channel formation region but overlaps with the conductive layer 255. In the semiconductor device 20E, the conductive layer 255 functions as the gate electrode of the transistor 250 and one of the source electrode and the drain electrode of the transistor 100.

When the transistor 100 and the transistor 250 are provided to overlap with each other, a semiconductor device that occupies a smaller area can be provided.

The semiconductor device 20E is different from the semiconductor device 20D in the structures of the opening 257a, the opening 257b, the conductive layer 258a, and the conductive layer 258b.

The opening 257a and the opening 257b are each formed by selectively removing part of the insulating layer 254 and part of the insulating layer 110 in a region overlapping with the region 253D of the semiconductor layer 253. The conductive layer 258a and the conductive layer 258b are provided over the insulating layer 110 and electrically connected to the regions 253D through the opening 257a and the opening 257b.

In the semiconductor device 20E, the conductive layer 258a and the conductive layer 258b can be formed in the same step as the conductive layer 112b. Formation processes of the conductive layer 258a, the conductive layer 258b, and the conductive layer 112b are not necessarily separate; thus, the manufacturing process of the semiconductor device can be shortened and the productivity of the semiconductor device can be increased.

The semiconductor device of one embodiment of the present invention includes at least one transistor and at least one capacitor, and a source or a drain of the transistor are electrically connected to one of a pair of electrodes of the capacitor. In FIG. 18I, the source or the drain of the transistor 100 is electrically connected to one electrode of a capacitor 190.

In the transistor of one embodiment of the present invention, which is a kind of vertical transistor, a source electrode, a semiconductor layer, and a drain electrode can be provided to overlap with each other; thus, the area occupied by the transistor can be significantly smaller than the area occupied by a planar transistor. When a planar transistor is used as a p-channel Si transistor and a vertical transistor is used as an n-channel OS transistor, a CMOS (Complementary Metal Oxide Semiconductor) circuit can be formed. When the planar transistor and the vertical transistor are provided to overlap with each other in this structure, the area occupied by the CMOS circuit can be reduced.

### Structure Example 2-7

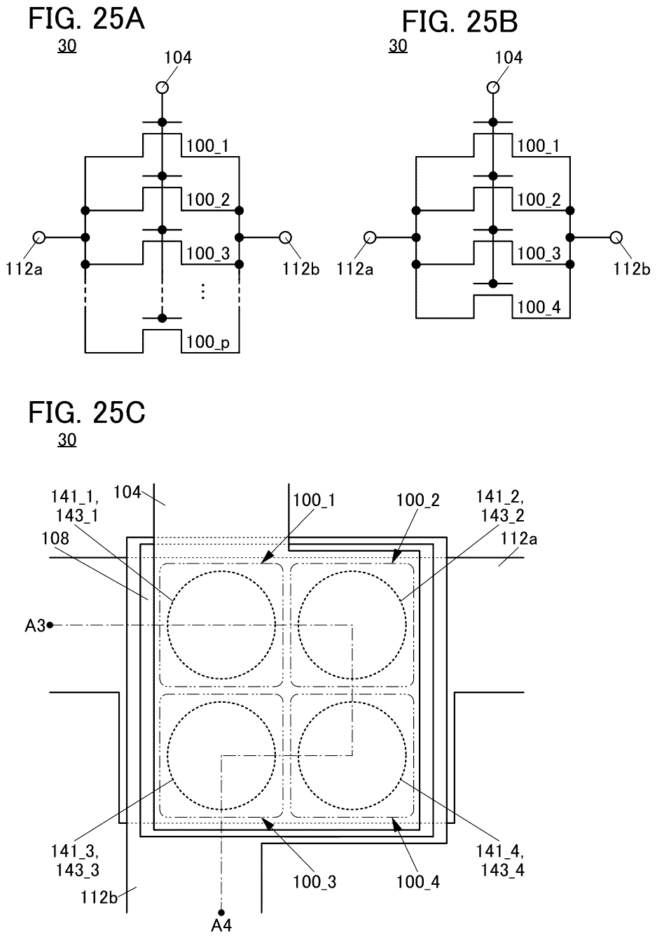

FIG. 25A illustrates an equivalent circuit diagram of a semiconductor device 30 of one embodiment of the present invention. The semiconductor device 30 includes a transistor 100_1 to a transistor 100_p (p is an integer greater than or equal to 2). The semiconductor device 30 can be regarded as one transistor, in which the transistor 100_1 to the transistor 100p are connected in parallel.

Gate electrodes of the transistor 100_1 to the transistor 100p are electrically connected to one another. Source electrodes of the transistor 100_1 to the transistor 100p are electrically connected to one another. Drain electrodes of the transistor 100_1 to the transistor 100p are electrically connected to one another.

Although the transistor 100_1 to the transistor 100_p are illustrated as n-channel transistors in FIG. 25A, one embodiment of the present invention is not limited thereto. The transistor 100_1 to the transistor 100_p may be p-channel transistors.

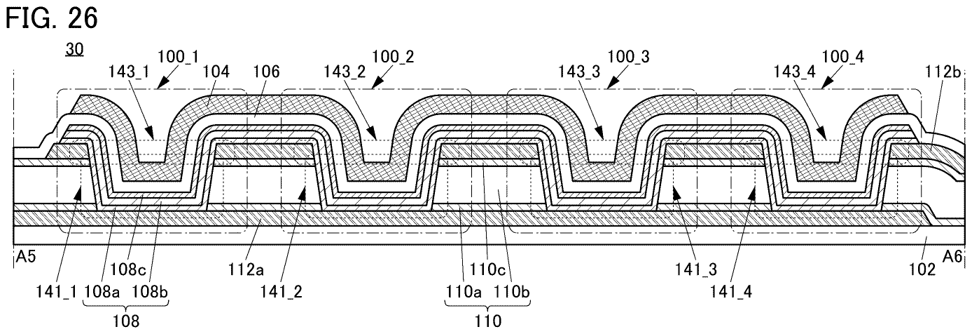

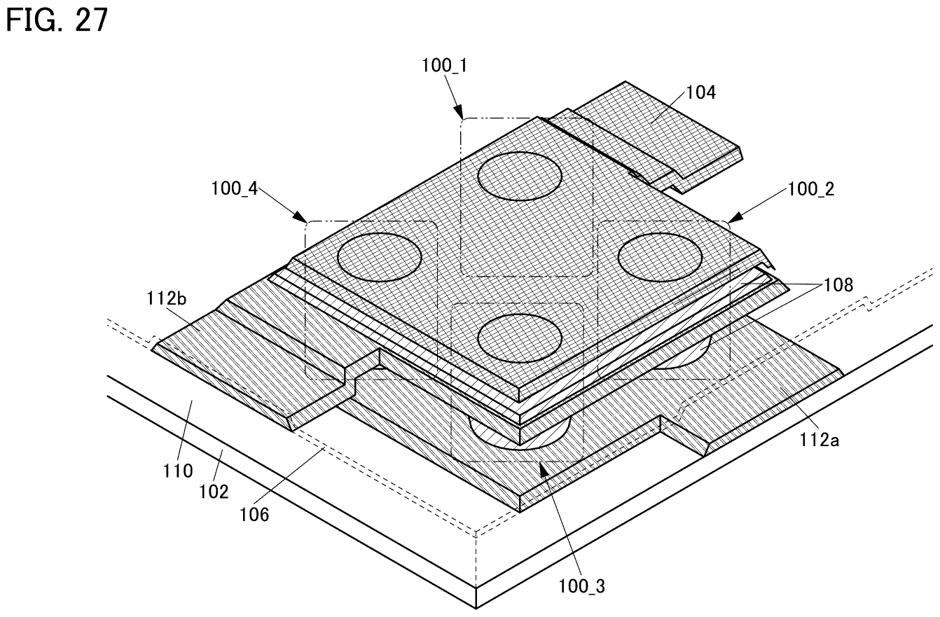

The case where p is 4 is specifically described as an example. FIG. 25B is an equivalent circuit diagram of the semiconductor device 30 of one embodiment of the present invention. FIG. 25C is a top view of the semiconductor device 30. FIG. 26 illustrates a cross-sectional view of a cross section along the dashed-dotted line A3-A4 in FIG. 25C. FIG. 27 is a perspective view of the semiconductor device 30.

The semiconductor device 30 includes the transistor 100_1 to a transistor 100_4. The transistor 100_1 to the transistor 100_4 can each employ the above-described structure of the transistor 100. Although the transistor 100 is described as an example here, one embodiment of the present invention is not limited thereto. Any of the transistor 100A to the transistor 100C may be used as the transistor 100_1 to the transistor 100_4.

Although FIG. 20C and the like illustrate a structure in which the transistor 100_1 to the transistor 100_4 are arranged in two rows and two columns, there is no limitation on the transistor arrangement. For example, the transistor 100_1 to the transistor 100_4 may be arranged in one row and four columns.

The transistor 100_1 to the transistor 100_4 each include the conductive layer 104, the insulating layer 106, the semiconductor layer 108, the conductive layer 112a, and the conductive layer 112b. The conductive layer 104 functions as the gate electrode of each of the transistor 100_1 to the transistor 100_4. Part of the insulating layer 106 functions as a gate insulating layer of each of the transistor 100_1 to the transistor 100_4. The conductive layer 112a functions as one of the source electrode and the drain electrode, and the conductive layer 112b functions as the other thereof in each of the transistor 100_1 to the transistor 100_4.

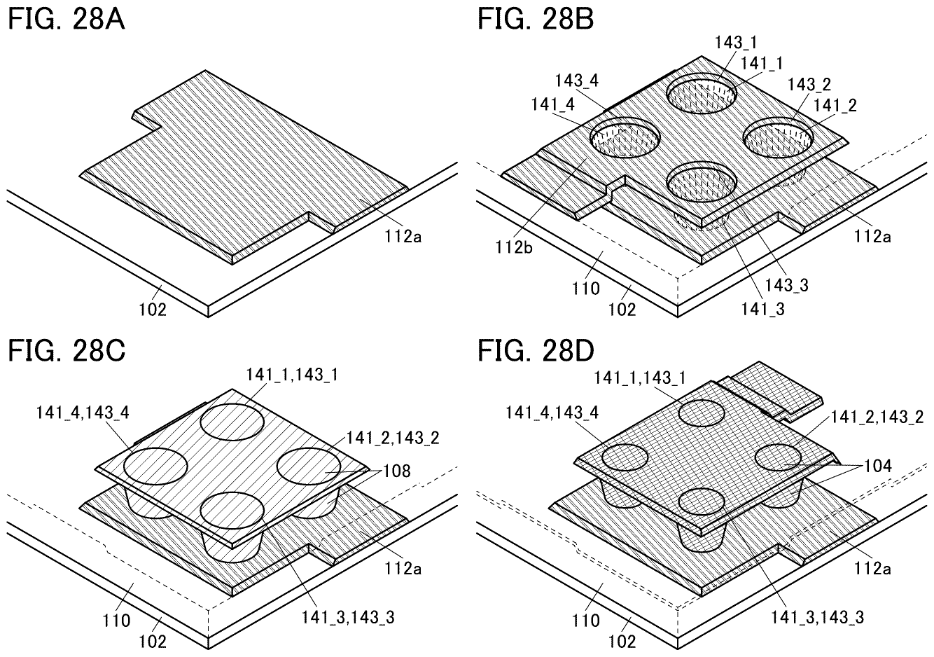

FIG. 28A is a perspective view selectively illustrating the conductive layer 112a.

FIG. 28B is a perspective view selectively illustrating the conductive layer 112a, the conductive layer 112b, an opening 1411 to an opening 1414, and an opening 143_1 to an opening 1434. The opening 1411 to the opening 1414 provided in the insulating layer 110 are indicated by dashed lines. The description of the opening 141 and the opening 143 can be referred to for the opening 1411 to the opening 1414 and the opening 143_1 to the opening 143_4; thus, the detailed description thereof is omitted.

In the case where the semiconductor device 30 is regarded as one transistor, the channel width of the transistor is the sum of the channel widths of the transistor 100_1 to the transistor 100_4. For example, in the case where the top surface shapes of the opening 141_1 to the opening 141_4 are circular shapes and the width D141 corresponds to the width of each of the opening 141_1 to the opening 1414, the semiconductor device 30 can be regarded as a transistor having a channel width of “D141×π×4” (see FIG. 4A and FIG. 4B). The semiconductor device 30 composed of p transistors can be regarded as a transistor having a channel width of “D141×π×p”. The semiconductor device 30 can be regarded as a transistor having the channel length L100 (see FIG. 4B). A plurality of transistors connected in parallel can have a larger channel width and a higher on-state current. By adjusting the number (p) of transistors connected in parallel, the channel width can be changed. The number (p) of transistors connected in parallel is determined so that desired on-state current is obtained.

FIG. 28C is a perspective view selectively illustrating the conductive layer 112a and the semiconductor layer 108. The semiconductor layer 108 is provided to cover the opening 141_1 to the opening 141_4 and the opening 1431 to the opening 143_4. Although FIG. 28C and the like illustrates the structure in which the transistor 100_1 to the transistor 100_4 share the semiconductor layer 108, one embodiment of the present invention is not limited thereto. The semiconductor layer 108 may be separated for each of the transistor 100_1 to the transistor 100_4.

FIG. 28D is a perspective view selectively illustrating the conductive layer 112a and the conductive layer 104. The conductive layer 104 is provided to cover the opening 141_1 to the opening 1414 and the opening 143_1 to the opening 143_4.

Note that the structure of the semiconductor device 30 described in Structure example 2-7 can also be applied to other structure examples. For example, the semiconductor device 30 may be used as one or more transistors included in the semiconductor device illustrated in FIG. 18A to FIG. 18I.

### Structure Example 2-8

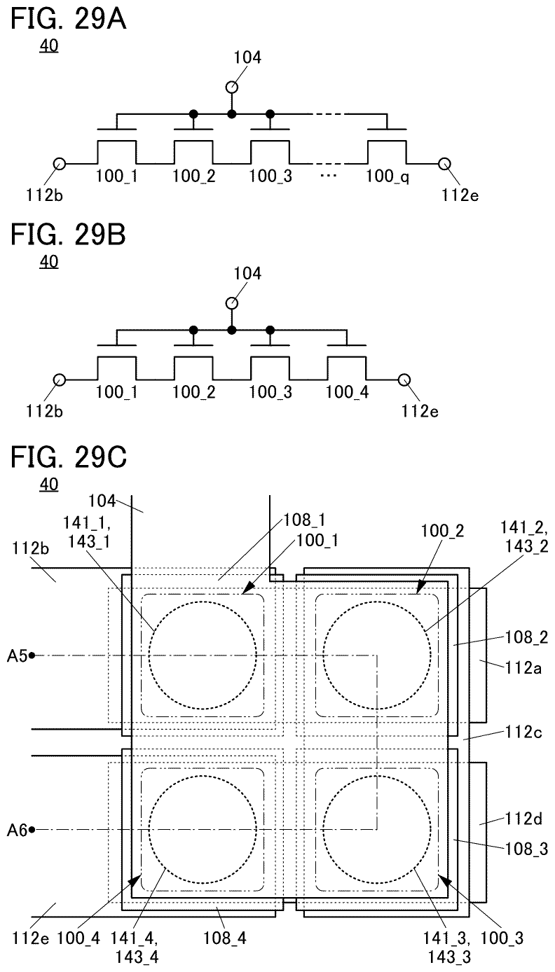

FIG. 29A is an equivalent circuit diagram of a semiconductor device 40 of one embodiment of the present invention. The semiconductor device 40 includes the transistor 100_1 to a transistor 100_q (q is an integer greater than or equal to 2). The semiconductor device 40 can be regarded as one transistor, in which the transistor 100_1 to the transistor 100_q are connected in series.

Although the transistor 100_1 to the transistor 100_q are illustrated as n-channel transistors in FIG. 29A, one embodiment of the present invention is not limited thereto. The transistor 100_1 to the transistor 100_q may be p-channel transistors.

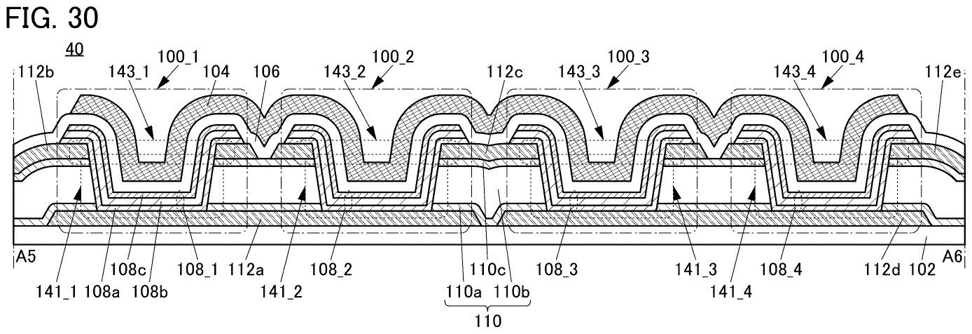

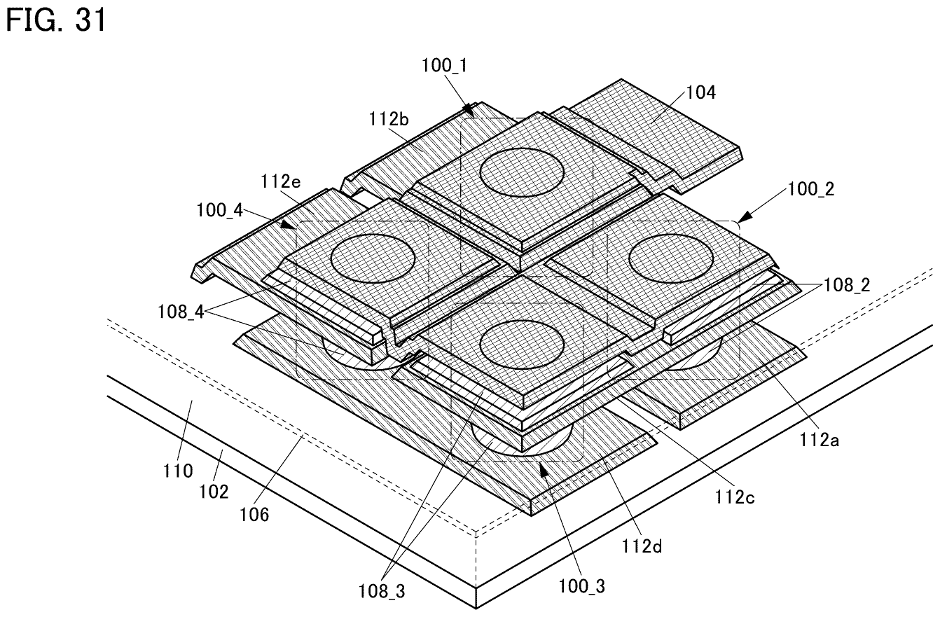

The case where q is 4 is specifically described as an example. FIG. 29B is an equivalent circuit diagram of the semiconductor device 40 of one embodiment of the present invention. FIG. 29C is a top view of the semiconductor device 40. FIG. 30 is a cross-sectional view of a cross section along the dashed-dotted line A5-A6 in FIG. 29C. FIG. 31 illustrates a perspective view of the semiconductor device 40.

The semiconductor device 40 includes the transistor 100_1 to the transistor 100_4. The transistor 100_1 to the transistor 100_4 can each employ the above-described structure of the transistor 100. Although the transistor 100 is described as an example here, one embodiment of the present invention is not limited thereto. Any of the transistor 100A to the transistor 100C may be used as the transistor 100_1 to the transistor 100_4.

Although FIG. 29C and the like illustrate a structure in which the transistor 100_1 to the transistor 100_4 are arranged in two rows and two columns, there is no limitation on the transistor arrangement. For example, the transistor 100_1 to the transistor 100_4 may be arranged in one row and four columns.

The transistor 100_1 includes the conductive layer 104, the insulating layer 106, a semiconductor layer 108_1, the conductive layer 112a, and the conductive layer 112b. The conductive layer 112a functions as one of the source electrode and the drain electrode of the transistor 100_1, and the conductive layer 112b functions as the other of the source and the drain of the transistor 100_1.

The transistor 100_2 includes the conductive layer 104, the insulating layer 106, a semiconductor layer 1082, the conductive layer 112a, and the conductive layer 112c. The conductive layer 112a functions as one of the source electrode and the drain electrode and the conductive layer 112c functions as the other thereof in the transistor 100_2. The conductive layer 112a is shared by the transistor 100_1 and the transistor 100_2.

The transistor 100_3 includes the conductive layer 104, the insulating layer 106, a semiconductor layer 1083, the conductive layer 112c, and a conductive layer 112d. The conductive layer 112c functions as one of the source electrode and the drain electrode and the conductive layer 112d functions as the other thereof in the transistor 100_3. The conductive layer 112c is shared by the transistor 100_2 and the transistor 100_3.

The transistor 100_4 includes the conductive layer 104, the insulating layer 106, a semiconductor layer 108_4, the conductive layer 112d, and a conductive layer 112e. The conductive layer 112d functions as one of the source electrode and the drain electrode and the conductive layer 112e functions as the other thereof in the transistor 100_4. The conductive layer 112d is shared by the transistor 100_3 and the transistor 100_4.

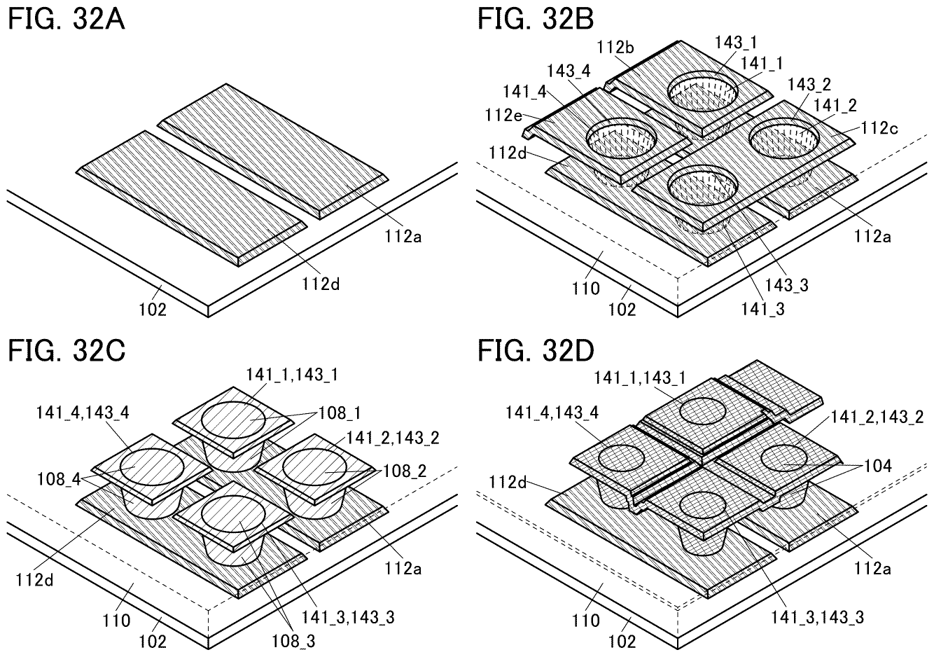

FIG. 32A is a perspective view selectively illustrating the conductive layer 112a and the conductive layer 112d. The conductive layer 112a and the conductive layer 112d can be formed in the same step.

FIG. 32B is a perspective view selectively illustrating the conductive layer 112a, the conductive layer 112b, the conductive layer 112c, the conductive layer 112d, the conductive layer 112e, the opening 1411 to the opening 1414, and the opening 143_1 to the opening 143_4. The conductive layer 112a to the conductive layer 112e can be formed in the same step. The opening 143_1 is provided in the conductive layer 112b, the opening 143_2 and an opening 1433 are provided in the conductive layer 112c, and the opening 143_4 is provided in the conductive layer 112e.

FIG. 32C is a perspective view selectively illustrating the conductive layer 112a, the conductive layer 112d, and the semiconductor layer 108_1 to the semiconductor layer 108_4. The semiconductor layer 108_1 to the semiconductor layer 108_4 can be formed in the same step.

FIG. 32D is a perspective view selectively illustrating the conductive layer 112a, the conductive layer 112d, and the conductive layer 104. The conductive layer 104 functions as a gate electrode of each of the transistor 100_1 to the transistor 100_4.

One of the source electrode and the drain electrode of the transistor 100_1 is electrically connected to one of the source electrode and the drain electrode of the transistor 100_2. The other of the source electrode and the drain electrode of the transistor 100_2 is electrically connected to one of the source electrode and the drain electrode of the transistor 100_3. The other of the source electrode and the drain electrode of the transistor 100_3 is electrically connected to one of the source electrode and the drain electrode of the transistor 100_4.

In the case where the semiconductor device 40 is regarded as one transistor, the channel length of the transistor is the sum of the channel lengths of the transistor 100_1 to the transistor 100_4. For example, in the case where the channel length L100 corresponds to the channel length of each of the transistor 100_1 to the transistor 1004, the semiconductor device 40 can be regarded as a transistor having a channel length of “L100×4” (see FIG. 4B). The semiconductor device 40 composed of q transistors can be regarded as a transistor having a channel length of “L100×q”. Note that the semiconductor device 40 can be regarded as a transistor having the channel width W100 (see FIG. 4A and FIG. 4B). A plurality of transistors connected in series can have a larger channel length and favorable saturation. By adjusting the number (q) of transistors connected in series, the channel length can be changed. The number (q) of transistors connected in series is determined so that desired saturation is obtained.

The structure of the semiconductor device 40 described in Structure example 2-8 can also be applied to other structure examples. For example, the semiconductor device 40 may be used as one or more transistors included in the semiconductor device illustrated in FIG. 18A to FIG. 18I.

The semiconductor device 40 may be used as each of the transistors included in the semiconductor device 30. That is, the groups of transistors connected in parallel can further be connected in series (hereinafter also referred to as series-parallel connection).

This embodiment can be combined with the other embodiments as appropriate. In this specification, in the case where a plurality of structure examples are shown in one embodiment, the structure examples can be combined as appropriate.

### Embodiment 2

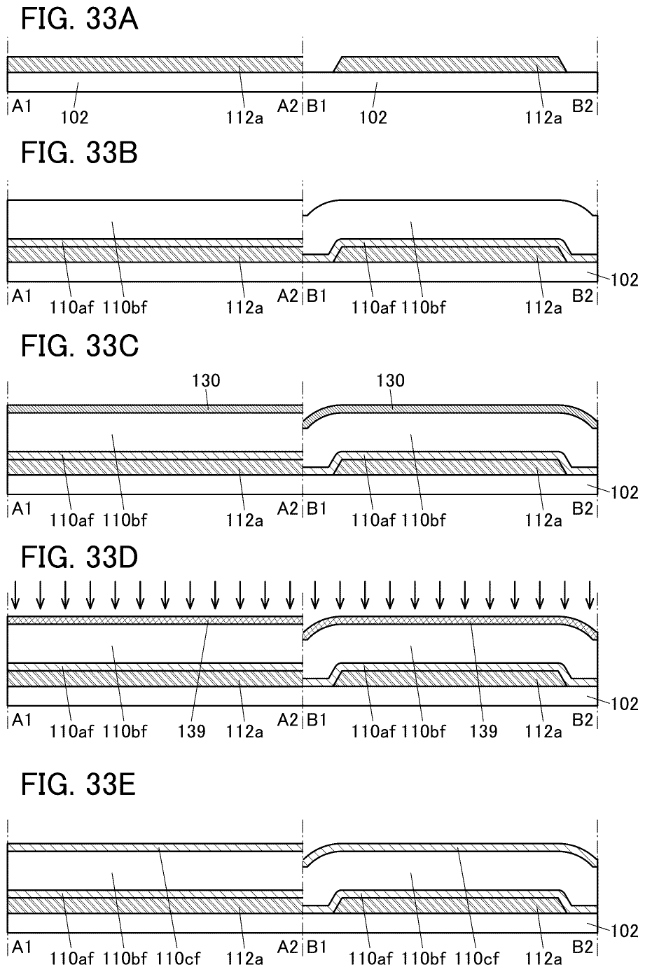

In this embodiment, methods for manufacturing the semiconductor device of one embodiment of the present invention will be described with reference to FIG. 33A to FIG. 35B. Note that as for materials and formation methods of components, portions similar to the portions described above in Embodiment 1 are not described in some cases.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a PECVD method and a thermal CVD method. As an example of the thermal CVD method, a metal organic chemical vapor deposition (MOCVD) method is given.

Thin films included in the semiconductor device (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

When the thin films included in the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a blocking mask such as a metal mask.

There are two typical examples of a photolithography method. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. In addition, light exposure may be performed by liquid immersion exposure technique. As the light used for the light exposure, extreme ultraviolet (EUV) light or X-rays may be used. Instead of the light used for the light exposure, an electron beam can be used. Extreme ultraviolet light, X-rays, or an electron beam is preferably used, in which case extremely minute processing can be performed. Note that a photomask is not needed when the light exposure is performed by scanning with a beam such as an electron beam.

For etching of thin films, one or more selected from a dry etching method, a wet etching method, and a sandblasting method can be used.

### Manufacturing Method Example 1

An example of a method for manufacturing the semiconductor device 10 illustrated in FIG. 1A to FIG. 1C is described with reference to FIG. 33A to FIG. 35B. FIG. 33A to FIG. 35B each illustrate, side by side, a cross section along the dashed-dotted line A1-A2 and a cross section along the dashed-dotted line B1-B2 in FIG. 1A.

First, a conductive film to be the conductive layer 112a is formed over the substrate 102 and the conductive film is processed, whereby the conductive layer 112a is formed (FIG. 33A). A sputtering method can be suitably used for the formation of the conductive film.

Next, an insulating film 110af to be the insulating layer 110a and an insulating film 110bf to be the insulating layer 110b are formed over the conductive layer 112a (FIG. 33B).

A sputtering method or a PECVD method can be suitably used for the formation of the insulating film 110af and the insulating film 110bf. It is preferable that the insulating film 110bf be formed after the formation of the insulating film 110af, without exposure of the surface of the insulating film 110af to the air. Such formation can inhibit attachment of impurities derived from the air to the surface of the insulating film 110af. Examples of the impurities include water and organic substances. For example, after the insulating film 110af is formed, the insulating film 110bf is preferably formed successively using the same apparatus.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af and the insulating film 110bf are in the above range, the amount of impurities (e.g., water and hydrogen) released from the insulating films themselves can be reduced, which inhibits diffusion of the impurities to the semiconductor layer 108. Consequently, a transistor with favorable electrical characteristics and high reliability can be obtained.

Note that since the insulating film 110af and the insulating film 110bf are formed earlier than the semiconductor layer 108, there is no need to consider the probability of oxygen release from the semiconductor layer 108 due to heat applied thereto at the time of forming the insulating film 110af and the insulating film 110bf.

After the insulating film 110af and the insulating film 110bf are formed, heat treatment may be performed. By the heat treatment, impurities (e.g., water and hydrogen) can be released from the insulating film 110af and the insulating film 110bf and the surface of the insulating film 110bf.

After the insulating film 110bf is formed, oxygen may be supplied to the insulating film 110bf. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include a PECVD apparatus, a plasma etching apparatus, and a plasma ashing apparatus. The plasma treatment is preferably performed in an atmosphere containing oxygen. For example, plasma treatment is preferably performed in an atmosphere containing one or more of oxygen, dinitrogen monoxide (N₂O), nitrogen dioxide (NO₂), carbon monoxide, and carbon dioxide.

The plasma treatment may be performed after the formation of the insulating film 110bf, without exposure of the surface of the insulating film 110bf to the air. For example, in the case where a PECVD apparatus is used for forming the insulating film 110bf, the plasma treatment is preferably performed with the PECVD apparatus. Accordingly, the productivity can be increased. Specifically, after the insulating film 110bf is formed with the PECVD apparatus, N₂O plasma treatment can be successively performed.

Next, a film 130 is preferably formed over the insulating film 110bf (FIG. 33C). When the film 130 is formed in an oxygen-containing atmosphere, oxygen can be supplied to the insulating film 110bf.

There is no limitation on the conductivity of the film 130. As the film 130, at least one type of insulating films, semiconductor films, and conductive films can be used. For the film 130, aluminum oxide, hafnium oxide, hafnium aluminate, indium oxide, indium tin oxide (ITO), or indium tin oxide containing silicon (ITSO) can be used, for example.

An oxide material containing one or more elements that are the same as those in the semiconductor layer 108 is preferably used for the film 130. It is particularly preferable to use an oxide semiconductor that can be used for the semiconductor layer 108.

At the time of forming the film 130, the amount of oxygen supplied into the insulating film 110bf can be increased with a higher oxygen flow rate ratio of the film formation gas introduced into a processing chamber of a film formation apparatus or with a higher oxygen partial pressure in the processing chamber. The oxygen flow rate ratio or oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the film 130 is formed by a sputtering method in an atmosphere containing oxygen in the above manner, oxygen can be supplied to the insulating film 110bf and release of oxygen from the insulating film 110bf can be prevented at the time of the formation of the film 130. As a result, a large amount of oxygen can be enclosed in the insulating film 110bf. Moreover, a large amount of oxygen can be supplied to the semiconductor layer 108 by heat treatment performed later. Consequently, the amounts of oxygen vacancies and VoH in the semiconductor layer 108 can be reduced, whereby a transistor with favorable electrical characteristics and high reliability can be obtained.

After the film 130 is formed, heat treatment may be performed. By performing the heat treatment after the film 130 is formed, oxygen can be effectively supplied from the film 130 to the insulating film 110bf.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As an atmosphere containing nitrogen or an atmosphere containing oxygen, clean dry air (CDA) may be used. The content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating film 110af and the insulating film 110bf can be prevented as much as possible. An oven, a rapid thermal annealing (RTA) apparatus, or the like can be used for the heat treatment. With the RTA apparatus, the heat treatment time can be shortened.

After the formation of the film 130 or after the above-described heat treatment, oxygen may be further supplied to the insulating film 110bf through the film 130. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Next, the film 130 is removed. There is no particular limitation on a method for removing the film 130, and a wet etching method can be suitably used. With use of a wet etching method, the insulating film 110bf can be inhibited from being etched during the removal of the film 130. This can inhibit a reduction in the thickness of the insulating film 110bf and the thickness of the insulating layer 110b can be uniform.

The treatment for supplying oxygen to the insulating film 110bf is not necessarily performed in the above-described manner. For example, an oxygen radical, an oxygen atom, an oxygen atomic ion, or an oxygen molecular ion is supplied to the insulating film 110bf by an ion doping method, an ion implantation method, or plasma treatment. Alternatively, a film that inhibits oxygen release may be formed over the insulating film 110bf, and then oxygen may be supplied to the insulating film 110bf through the film. After the supply of oxygen, the film is preferably removed. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

After the film 130 is removed, oxygen may be further supplied to the insulating film 110bf. The above description can be referred to for a method for supplying oxygen. For example, as illustrated in FIG. 33D, a film 139 may be formed over the insulating film 110bf and oxygen may be supplied to the insulating film 110bf through the film 139. As the treatment, plasma treatment in an atmosphere containing oxygen can be used. FIG. 33D schematically illustrates a state where oxygen is supplied to the insulating film 110bf by arrows.

As the film 139, a conductive film or a semiconductor film is preferably used. For the film 139, a metal oxide, a metal, or an alloy can be used. The film 139 is preferably formed using a metal oxide in an atmosphere containing oxygen by a sputtering method or the like, in which case oxygen can be supplied to the insulating film 110bf also at the time of forming the film 139.

The thickness of the film 139 is preferably small. Specifically, the thickness of the film 139 is preferably larger than or equal to 1 nm, larger than or equal to 2 nm, or larger than or equal to 3 nm and smaller than or equal to 20 nm, smaller than or equal to 15 nm, or smaller than or equal to 10 nm. Typically, the thickness can be approximately 5 nm.

The substrate temperature at the time of forming the film 139 is preferably lower than or equal to 350° C., further preferably lower than or equal to 340° C., still further preferably lower than or equal to 330° C., yet still further preferably lower than or equal to 300° C. Accordingly, the amount of oxygen supplied to the insulating film 110bf can be increased.

With the film 139, when a bias voltage is applied between the pair of electrodes in oxygen supply, ionized oxygen is easily drawn. Accordingly, the amount of oxygen supplied to the insulating film 110bf can be increased.

As a treatment apparatus for supplying oxygen, a dry etching apparatus, an ashing apparatus, or a PECVD apparatus can be suitably used. In particular, an ashing apparatus is preferably used. When a bias voltage is applied between a pair of electrodes in the treatment apparatus, the bias voltage can be higher than or equal to 10 V and lower than or equal to 1 kV, for example. The power density of the bias can be higher than or equal to 1 W/cm² and lower than or equal to 5 W/cm², for example.

Next, the film 139 is removed. For the removal of the film 139, a wet etching method can be suitably used.

Next, an insulating film 110cf to be the insulating layer 110c is formed over the insulating film 110bf (FIG. 33E). The description of the formation of the insulating film 110af and the insulating film 110bf can be referred to for the formation of the insulating film 110cf; thus, the detailed description thereof is omitted.

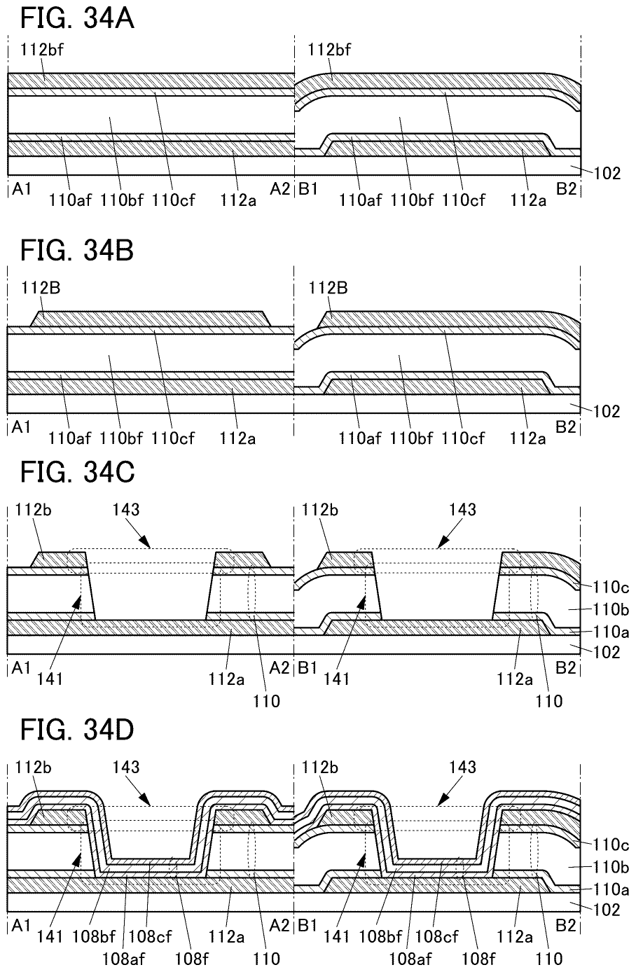

Then, a conductive film 112bf to be the conductive layer 112b is formed over the insulating film 110cf (FIG. 34A). For the formation of the conductive film 112bf, a sputtering method can be suitably used, for example.

Next, the conductive film 112bf is processed to form a conductive layer 112B (FIG. 34B). The conductive layer 112B becomes the conductive layer 112b later. For the formation of the conductive layer 112B, a wet etching method can be suitably used, for example.

Next, the conductive layer 112B is partly removed, so that the conductive layer 112b including the opening 143 is formed. A wet etching method can be suitably used to form the conductive layer 112b.

Next, the insulating film 110af, the insulating film 110bf, and the insulating film 110cf are partly removed, so that the insulating layer 110 including the opening 141 is formed (FIG. 34C). The opening 141 is provided in a region overlapping with the opening 143. The conductive layer 112a is exposed by the formation of the opening 141. For the formation of the insulating layer 110, a dry etching method can be suitably used.

The opening 141 can be formed using the resist mask used for the formation of the opening 143, for example. Specifically, a resist mask is formed over the conductive layer 112B, the conductive layer 112B is partly removed with use of the resist mask to form the opening 143, and the insulating film 110af, the insulating film 110bf, and the insulating film 110cf are partly removed with use of the resist mask, whereby the opening 141 can be formed. The opening 141 may be formed using a resist mask that is different from the resist mask used for the formation of the opening 143.

Subsequently, a metal oxide film 108f to be the semiconductor layer 108 is formed to cover the opening 141 and the opening 143 (FIG. 34D). Here, as the metal oxide film 108f, a metal oxide film 108af to be the semiconductor layer 108a and a metal oxide film 108bf to be the semiconductor layer 108b, and a metal oxide film 108cf to be the semiconductor layer 108c are stacked. The metal oxide film 108f is provided to be in contact with the top surface and the side surface of the conductive layer 112b, the top surface and the side surface of the insulating layer 110, and the top surface of the conductive layer 112a.

The metal oxide film 108af, the metal oxide film 108bf, and the metal oxide film 108cf are each preferably formed by a sputtering method using a metal oxide target. Alternatively, each of the metal oxide film 108af, the metal oxide film 108bf, and the metal oxide film 108cf are preferably formed by an ALD method. After the formation of the metal oxide film 108af, the metal oxide film 108bf is preferably formed successively without exposure of the surface of the metal oxide film 108af to the air. Similarly, after the formation of the metal oxide film 108bf, the metal oxide film 108cf is preferably formed successively without exposure of the surface of the metal oxide film 108bf to the air. When the metal oxide film 108af, the metal oxide film 108bf, and the metal oxide film 108cf are successively formed, attachment of impurities derived from the air to the surface of the metal oxide film 108af can be inhibited. Examples of the impurities include water and organic substances. Note that the metal oxide film 108af, the metal oxide film 108bf, and the metal oxide film 108cf may be formed using different apparatuses. The metal oxide film 108af, the metal oxide film 108bf, and the metal oxide film 108cf may be formed by different formation methods. For example, the metal oxide film 108af and the metal oxide film 108cf may be formed by an ALD method and the metal oxide film 108bf may be formed by a sputtering method.

An ALD method provides high coverage, and thus can be suitably used for forming one or more of the metal oxide film 108af, the metal oxide film 108bf, and the metal oxide film 108cf that are provided to cover the opening 141 and the opening 143. By an ALD method, a metal oxide film can be formed also on the side surface of the insulating layer 110 with high coverage. In an ALD method, the deposition rate can be easily controlled, so that a thin film can be formed with high yield. Thus, an ALD method can be suitably used particularly for forming the metal oxide film 108af to be the semiconductor layer 108a having a small thickness. Alternatively, instead of a sputtering method and an ALD method, a CVD method may be used for forming any one or more of the metal oxide film 108af, the metal oxide film 108bf, and the metal oxide film 108cf.

The metal oxide film 108af, the metal oxide film 108bf, and the metal oxide film 108cf are each preferably a dense film with as few defects as possible. The metal oxide film 108af, the metal oxide film 108bf, and the metal oxide film 108cf are each preferably a highly purified film in which impurities including a hydrogen element are reduced as much as possible. It is particularly preferable to use a metal oxide film having crystallinity as each of the metal oxide film 108af, the metal oxide film 108bf, and the metal oxide film 108cf.

In forming the metal oxide film 108af, the metal oxide film 108bf, and the metal oxide film 108cf, an oxygen gas is preferably used. In particular, in the case of using an oxygen gas at the time of forming the metal oxide film 108af, oxygen can be suitably supplied into the insulating layer 110. For example, in the case of using an oxide or an oxynitride for the insulating layer 110b, oxygen can be suitably supplied into the insulating layer 110b.

The oxygen supply to the insulating layer 110b enables the semiconductor layer 108 to be supplied with oxygen in a later step, so that the amounts of oxygen vacancies and VoH in the semiconductor layer 108 can be reduced.

In forming the metal oxide film 108af, the metal oxide film 108bf, and the metal oxide film 108cf, an oxygen gas and an inert gas (e.g., a helium gas, an argon gas, or a xenon gas) may be mixed. At the time of forming the metal oxide film, the crystallinity of the metal oxide film can be increased and a transistor with higher reliability can be obtained with a higher oxygen flow rate ratio to the film formation gas or with a higher oxygen partial pressure. On the other hand, when the oxygen flow rate ratio or the oxygen partial pressure is lower, the metal oxide film can have lower crystallinity and higher electrical conductivity and the transistor can have a higher on-state current. In particular, when the oxygen flow rate ratio or the oxygen partial pressure is reduced in forming the metal oxide film 108bf serving as the main current path, the transistor can have a high on-state current. When the oxygen flow rate ratios or the oxygen partial pressures in forming the metal oxide film 108af, the metal oxide film 108bf, and the metal oxide film 108cf are different from each other, the crystallinity can be varied among the metal oxide film 108af, the metal oxide film 108bf, and the metal oxide film 108cf.

For example, the oxygen flow rate ratio or the oxygen partial pressure in forming the metal oxide film 108bf may be lower than the oxygen flow rate ratio or the oxygen partial pressure in forming the metal oxide film 108cf. Accordingly, the crystallinity of the metal oxide film 108bf (to be the semiconductor layer 108b later) can be made low and the semiconductor layer 108b can have high electrical conductivity, so that the transistor can have a high on-state current. Note that the oxygen flow rate ratio or the oxygen partial pressure in forming the metal oxide film 108bf may be higher than the oxygen flow rate ratio or the oxygen partial pressure in forming the metal oxide film 108cf. Thus, a highly reliable transistor can be achieved. Alternatively, these oxygen flow rate ratios or the oxygen partial pressures may be the same.

For example, the oxygen flow rate ratio or the oxygen partial pressure in forming the metal oxide film 108af may be lower than the oxygen flow rate ratio or the oxygen partial pressure in forming the metal oxide film 108cf. Accordingly, the crystallinity of the metal oxide film 108af (to be the semiconductor layer 108a later) can be made low, and oxygen contained in the insulating layer 110 can be efficiently supplied to the semiconductor layer 108b through the semiconductor layer 108a. Note that the oxygen flow rate ratio or the oxygen partial pressure in forming the metal oxide film 108af may be higher than or the same as the oxygen flow rate ratio or the oxygen partial pressure in forming the metal oxide film 108cf.

Here, when the oxygen flow rate ratio or the oxygen partial pressure is high, the metal oxide film has a polycrystalline structure in some cases. In the case of a metal oxide film having a polycrystalline structure, the grain boundary becomes a recombination center and captures carriers and thus might reduce the on-state current of the transistor. Thus, the oxygen flow rate ratio or the oxygen partial pressure is preferably adjusted for each of the metal oxide film 108af, the metal oxide film 108bf, and the metal oxide film 108cf so that they do not have a polycrystalline structure. Since the ease of forming the polycrystalline structure depends on the composition of the metal oxide film, the oxygen flow rate ratio or the oxygen partial pressure is varied depending on the compositions of the metal oxide film 108af, the metal oxide film 108bf, and the metal oxide film 108cf.

For example, in the case where a material that easily has a polycrystalline structure is used for the metal oxide film 108bf, the oxygen flow rate ratio or the oxygen partial pressure in forming the metal oxide film 108bf is preferably lower than the oxygen flow rate ratios or the oxygen partial pressures in forming the metal oxide film 108af and the metal oxide film 108cf.

When the substrate temperature is higher in forming the metal oxide film, a denser metal oxide film having higher crystallinity can be formed. On the other hand, as the substrate temperature is lower, a metal oxide film having lower crystallinity and a higher electrical conduction property can be formed. Note that the substrate temperature in forming the metal oxide film 108af, the substrate temperature in forming the metal oxide film 108bf, and the substrate temperature in forming the metal oxide film 108cf may be the same or different from each other. With different substrate temperatures, the crystallinity can be made different between the metal oxide film 108af, the metal oxide film 108bf, and the metal oxide film 108cf.

For example, the substrate temperature in forming the metal oxide film 108bf may be lower than the substrate temperature in forming the metal oxide film 108cf. Accordingly, the crystallinity of the metal oxide film 108bf (to be the semiconductor layer 108b later) can be made low and the semiconductor layer 108b can have high electrical conductivity, so that the transistor can have a high on-state current. Note that the substrate temperature in forming the metal oxide film 108bf may be higher than the substrate temperature in forming the metal oxide film 108cf. Thus, a highly reliable transistor can be achieved. Alternatively, these substrate temperatures may be the same.

For example, the substrate temperature in forming the metal oxide film 108af may be lower than the substrate temperature in forming the metal oxide film 108cf. Accordingly, the crystallinity of the metal oxide film 108af (to be the semiconductor layer 108a later) can be made low, and oxygen contained in the insulating layer 110 can be efficiently supplied to the semiconductor layer 108b through the semiconductor layer 108a. Note that the substrate temperature in forming the metal oxide film 108af may be higher than or the same as the substrate temperature in forming the metal oxide film 108cf.

The substrate temperatures at the time of forming the metal oxide film 108af, the metal oxide film 108bf, and the metal oxide film 108cf are each preferably higher than or equal to room temperature and lower than or equal to 250° C., further preferably higher than or equal to room temperature and lower than or equal to 200° C., still further preferably higher than or equal to room temperature and lower than or equal to 140° C. For example, the substrate temperature is preferably set higher than or equal to room temperature and lower than or equal to 140° C. to increase the productivity. Furthermore, when the metal oxide film is formed with the substrate temperature set at room temperature or without heating the substrate, the crystallinity can be made low.

Note that when the substrate temperature is high, the metal oxide film has a polycrystalline structure in some cases. The substrate temperature is preferably adjusted for each of the metal oxide film 108af, the metal oxide film 108bf, and the metal oxide film 108cf so that they do not have a polycrystalline structure. The substrate temperature is varied depending on the compositions of materials used for the metal oxide film 108af, the metal oxide film 108bf, and the metal oxide film 108cf.

For example, in the case where a material that easily has a polycrystalline structure is used for the metal oxide film 108bf, the substrate temperature in forming the metal oxide film 108bf is preferably lower than the substrate temperature in forming the metal oxide film 108af and the substrate temperature in forming the metal oxide film 108cf.

Here, two or more of the metal oxide film 108af, the metal oxide film 108bf, and the metal oxide film 108cf can be formed using the same sputtering target; thus, the manufacturing cost can be reduced. Furthermore, when two or more of the metal oxide film 108af, the metal oxide film 108bf, and the metal oxide film 108cf are formed at the same substrate temperature, the metal oxide films can be formed with high productivity in the same treatment chamber. For example, it is preferable that the metal oxide film 108bf and the metal oxide film 108cf be successively formed in the same treatment chamber using the same sputtering target. In that case, the substrate temperature is preferably the same, and the oxygen flow rate ratio or the oxygen partial pressure in forming the metal oxide film 108bf is preferably different from the oxygen flow rate ratio or the oxygen partial pressure in forming the metal oxide film 108cf.

In the case of employing an ALD method, a deposition method such as a thermal ALD method or a PEALD (Plasma Enhanced ALD) is preferably employed. The thermal ALD method is preferable because of its capability of offering extremely high coverage. The PEALD method is preferable because of its capability of forming a film at low temperatures, in addition to its capability of offering high coverage.

For example, the metal oxide film can be formed by an ALD method using a precursor containing a constituent metal element and an oxidizer.

For example, in the case where In—Ga—Zn oxide is formed, three precursors of a precursor containing indium, a precursor containing gallium, and a precursor including zinc can be used. Alternatively, two precursors of a precursor containing indium and a precursor containing gallium and zinc may be used.

Examples of the precursor containing indium include triethylindium, trimethylindium, tris(2,2,6,6-tetramethyl-3,5-heptanedionato)indium, cyclopentadienylindium, indium(III) chloride, (3-(dimethylamino)propyl)dimethylindium, and [1,1,1-trimethyl-N-(trimethylsilyl)amide]-indium.

Examples of the precursor containing gallium include trimethylgallium, triethylgallium, gallium trichloride, tris(dimethylamido)gallium(III), gallium(III) acetylacetonate, tris(2,2,6,6-tetramethyl-3,5-heptanedionato)gallium, dimethylchlorogallium, and diethylchlorogallium.

Examples of the precursor containing aluminum include aluminum chloride and trimethylaluminum.

Examples of the precursor containing tin include tin(IV) chloride and tetrakis(dimethylamido)tin.

Examples of the precursor containing zinc include dimethylzinc, diethylzinc, bis(2,2,6,6-tetramethyl-3,5-heptanedionato)zinc, and zinc chloride.

Examples of the oxidizer include ozone, oxygen, and water.

As a method for controlling the composition of a film to be obtained, adjusting one or more of the kinds of source gases, the flow rate ratio of source gases, the flowing time of the source gases, and the order in which the source gases flow is given. By adjusting these, the compositions of the metal oxide film 108af, the metal oxide film 108bf, and the metal oxide film 108cf can be controlled. Moreover, by adjusting these, a film whose composition is continuously changed can also be formed. The compositions of one or more of the metal oxide film 108af, the metal oxide film 108bf, and the metal oxide film 108bf may be continuously changed.

For example, each of a precursor used for forming the metal oxide film 108af and a precursor used for forming the metal oxide film 108cf preferably has a higher gallium content percentage than and a precursor used for forming the metal oxide film 108bf. Alternatively, a precursor that does not include gallium may be used for the formation of the metal oxide film 108bf, and a precursor that includes gallium may be used for the formation of the metal oxide film 108af and the metal oxide film 108cf. Although gallium is given as the element M here, one embodiment of the present invention is not limited thereto. Instead of gallium or in addition to gallium, any one or more of the above elements M may be used. Furthermore, a precursor used for forming the metal oxide film 108cf preferably has a higher gallium content percentage than a precursor used for forming the metal oxide film 108af.

It is preferable to perform at least one of treatment for desorbing water, hydrogen, an organic substance, and the like adsorbed onto the surface of the insulating layer 110 and treatment for supplying oxygen into the insulating layer 110 before the formation of the metal oxide film 108f (specifically, the metal oxide film 108af). For example, heat treatment can be performed at a temperature higher than or equal to 70° C. and lower than or equal to 200° C. in a reduced-pressure atmosphere. Alternatively, plasma treatment in an atmosphere containing oxygen may be performed. Alternatively, oxygen may be supplied to the insulating layer 110 by performing plasma treatment in an atmosphere containing an oxidizing gas such as dinitrogen monoxide (N₂O). When plasma treatment is performed using a dinitrogen monoxide gas, an organic substance on the surface of the insulating layer 110 can be suitably removed and oxygen can be supplied. The metal oxide film 108f is preferably formed successively after such treatment without exposure of the surface of the insulating layer 110 to the air.

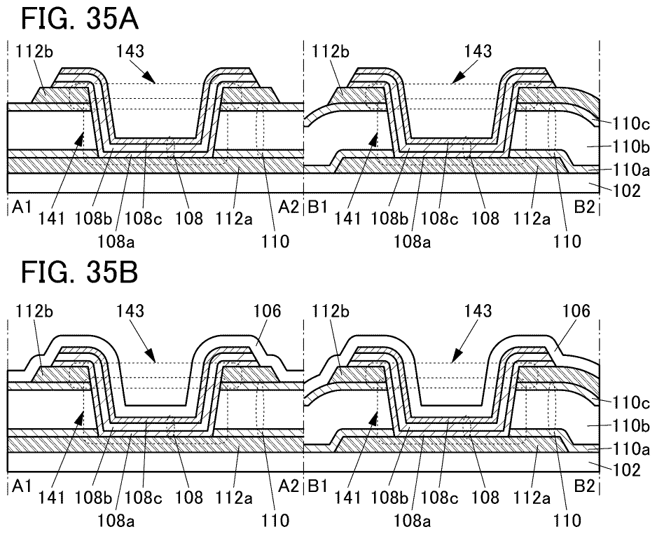

Next, the metal oxide film 108f is processed into an island shape to form the semiconductor layer 108 (FIG. 35A).

For the formation of the semiconductor layer 108, a wet etching method can be suitably used. At this time, part of the conductive layer 112b in the region that does not overlap with the semiconductor layer 108 is etched and thinned in some cases. In a similar manner, part of the insulating layer 110 in the region that does not overlap with the semiconductor layer 108 or the conductive layer 112b is etched and thinned in some cases. For example, in the insulating layer 110, the insulating layer 110c is removed by etching and the surface of the insulating layer 110b is exposed, in some cases. Note that in etching of the metal oxide film 108f, a reduction in the thickness of the insulating layer 110c can be inhibited when a material having high selectivity with respect to the insulating layer 110c is used.

It is preferable that heat treatment be performed after the metal oxide film 108f is formed or after the metal oxide film 108f is processed into the semiconductor layer 108. By the heat treatment, hydrogen or water contained in the metal oxide film 108f or the semiconductor layer 108 or adsorbed on a surface thereof can be removed. Furthermore, the film quality of the metal oxide film 108f or the semiconductor layer 108 is improved (e.g., the number of defects is reduced or the crystallinity is increased) by the heat treatment in some cases.

Oxygen can be supplied from the insulating layer 110b to the metal oxide film 108f or the semiconductor layer 108 by heat treatment. In this case, it is further preferable that the heat treatment be performed before the semiconductor film 108f is processed into the semiconductor layer 108. The above description can be referred to for the heat treatment; thus, the detailed description thereof is omitted.

The heat treatment is not necessarily performed when not needed. The heat treatment is not necessarily performed in this step, and heat treatment performed in a later step may also serve as the heat treatment in this step. In some cases, heat application treatment in a later step (e.g., a film formation step) or the like can serve as the heat treatment in this step.

Then, the insulating layer 106 is formed to cover the semiconductor layer 108, the conductive layer 112b, and the insulating layer 110 (FIG. 35B). For the formation of the insulating layer 106, for example, a PECVD method, s sputtering method, or an ALD method can be suitably used.

In the case where the semiconductor layer 108 is formed using an oxide semiconductor, the insulating layer 106 preferably functions as a barrier film that inhibits release of oxygen from the semiconductor layer 108. When the insulating layer 106 has a function of inhibiting diffusion of oxygen, oxygen in the semiconductor layer 108 is inhibited from diffusing into the conductive layer 104 through the insulating layer 106, so that oxidation of the conductive layer 104 can be inhibited. Consequently, a transistor with favorable electrical characteristics and high reliability can be obtained.

When the temperature at the time of forming the insulating layer 106 functioning as the gate insulating layer is increased, an insulating layer with few defects can be obtained. However, a high temperature at the time of forming the insulating layer 106 sometimes allows release of oxygen from the semiconductor layer 108, which increases the amounts of oxygen vacancies and VoH in the semiconductor layer 108. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 108 can be inhibited while the defects in the insulating layer 106 can be reduced. Consequently, a transistor with favorable electrical characteristics and high reliability can be obtained.

Before the formation of the insulating layer 106, a surface of the semiconductor layer 108 may be subjected to plasma treatment. By the plasma treatment, impurities such as water adsorbed on the surface of the semiconductor layer 108 can be reduced. Accordingly, impurities at the interface between the semiconductor layer 108 and the insulating layer 106 can be reduced, enabling formation of a highly reliable transistor. The plasma treatment is particularly favorable in the case where the surface of the semiconductor layer 108 is exposed to the air after the formation of the semiconductor layer 108 but before the formation of the insulating layer 106. The plasma treatment can be performed in, for example, an atmosphere of oxygen, ozone, nitrogen, dinitrogen monoxide, argon, or the like. The plasma treatment and the formation of the insulating layer 106 are preferably performed successively without exposure to the air.

Next, the conductive layer 104 is formed over the insulating layer 106 (FIG. 1B and FIG. 1C). For the formation of a conductive film to be the conductive layer 104, a sputtering method, a thermal CVD method (including an MOCVD method), or an ALD method can be suitably used, for example.

Through the above steps, the semiconductor device 10 of one embodiment of the present invention can be manufactured.

### Manufacturing Method Example 2

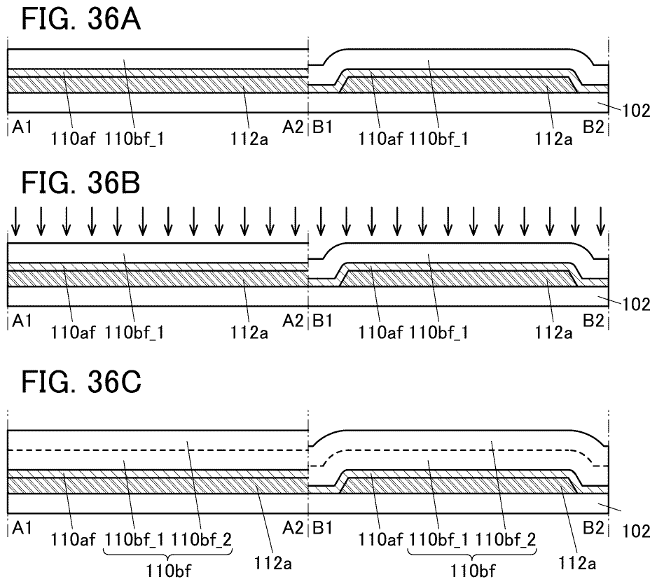

An example of a method for manufacturing the semiconductor device 10B illustrated in FIG. 10A to FIG. 10C will be described. FIG. 36A to FIG. 36C each illustrate, side by side, a cross section along the dashed-dotted line A1-A2 and a cross section along the dashed-dotted line B1-B2 in FIG. 1A.

First, as in <Manufacturing method example 1>, formation of the conductive layer 112a is performed. The description of FIG. 33A can be referred to for the formation of the conductive layer 112a; thus, the detailed description thereof is omitted.

Next, the insulating film 110af to be the insulating layer 110a and an insulating film 110bf_1 to be the insulating layer 110b_1 are formed over the conductive layer 112a (FIG. 36A).

Then, oxygen is supplied to the insulating film 110bf_1. The above description can be referred to for a method for supplying oxygen. For example, plasma treatment is preferably performed in an atmosphere containing one or more of oxygen, dinitrogen monoxide (N₂O), nitrogen dioxide (NO₂), carbon monoxide, and carbon dioxide. FIG. 36B schematically shows a state where oxygen is supplied to the insulating film 110bf_1 by arrows.

After the insulating film 110bf_1 is formed, the plasma treatment may be performed without exposure of the surface of the insulating film 110bf_1 to the air. For example, in the case where a PECVD apparatus is used for forming the insulating film 110bf_1, the plasma treatment is preferably performed with the PECVD apparatus. Accordingly, the productivity can be increased. Specifically, after the insulating film 110bf_1 is formed with the PECVD apparatus, plasma treatment can be successively performed.

Next, an insulating film 110bf_2 to be the insulating layer 110b_2 is formed over the insulating film 110bf_1 (FIG. 36C). Thus, the insulating film 110bf including the insulating film 110bf_1 and the insulating film 110bf_2 is formed.

Note that it is further preferable that formation of the insulating film 110bf_1, oxygen supply to the insulating film 110bf_1, and formation of the insulating film 110bf_2 be successively performed. In addition, it is further preferable that formation of the insulating film 110af, formation of the insulating film 110bf_1, oxygen supply to the insulating film 110bf_1, and formation of the insulating film 110bf_2 be successively performed. Performing these treatments successively in the same apparatus increases the productivity. Impurities derived from the air can be inhibited from attaching to the interfaces of these films. For example, a PECVD apparatus can be suitably used for these treatments.

After the insulating film 110bf is formed, oxygen may be supplied to the insulating film 110bf. The above description can be referred to for a method for supplying oxygen.

Next, the insulating film 110cf to be the insulating layer 110c is formed over the insulating film 110bf. The above description in Manufacturing method example 1 can be referred to for the steps after the formation of the insulating film 110cf, thus, the detailed description thereof is omitted.

Through the above process, the semiconductor device 10B of one embodiment of the present invention can be manufactured.

This embodiment can be combined with the other embodiments as appropriate.

### Embodiment 3

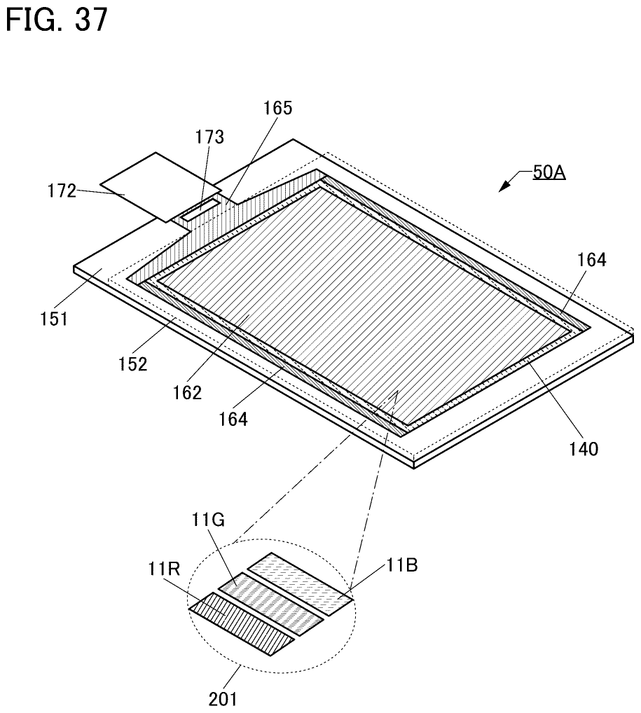

In this embodiment, display devices of one embodiment of the present invention are described with reference to FIG. 37 to FIG. 45.

The display device of this embodiment can be a high-resolution display device or a large-sized display device. Accordingly, the display device of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

The display device of this embodiment can be a high-definition display device. Accordingly, the display device of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display device or a module including the display device. Examples of the module including the display device are a module in which a connector such as a flexible printed circuit board (hereinafter referred to as an FPC) or a tape carrier package (TCP) is attached to the display device and a module in which the display device is mounted with an integrated circuit (IC) by a chip on glass (COG) method, a chip on film (COF) method, or the like.

The display device of this embodiment may have a function of a touch panel. The display device can employ any of a variety of sensing elements (also referred to as sensor elements) that can sense approach or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of a mutual capacitive type is preferable because multiple points can be detected simultaneously.

Examples of a touch panel include an out-cell touch panel, an on-cell touch panel, and an in-cell touch panel. Note that an in-cell touch panel has a structure in which an electrode included in a sensing element is provided on one or both of a substrate supporting a display element and a counter substrate.

### [Display Device 50A]

FIG. 37 illustrates a perspective view of a display device 50A.

In the display device 50A, a substrate 152 and a substrate 151 are attached to each other. In FIG. 37, the substrate 152 is denoted by a dashed line.

The display device 50A includes a display portion 162, a connection portion 140, a circuit portion 164, a conductive layer 165, and the like. FIG. 37 illustrates an example in which an IC 173 and an FPC 172 are mounted on the display device 50A. Thus, the structure illustrated in FIG. 37 can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 37 illustrates an example in which the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and power to the display portion 162 and the circuit portion 164. The signal and power are input to the conductive layer 165 from the outside through the FPC 172 or input to the conductive layer 165 from the IC 173.

FIG. 37 illustrates an example where the IC 173 is provided on the substrate 151 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method or the like.

The semiconductor device of one embodiment of the present invention can be used for one or both of the display portion 162 and the circuit portion 164 of the display device 50A, for example. An oxide semiconductor (OS) can be suitably used for a channel formation region of a transistor included in the display device. By using an OS transistor, a display device can have low power consumption. Alternatively, the semiconductor device of one embodiment of the present invention can be used for both the display portion 162 and the circuit portion 164, that is, all the transistors included in the display device can be OS transistors. When all the transistors included in the display device are OS transistors in this manner, an effect of reducing the manufacturing cost can be obtained.

When the semiconductor device of one embodiment of the present invention is used for a pixel circuit of the display device, the area occupied by the pixel circuit can be reduced and the display device can have high definition, for example. When the semiconductor device of one embodiment of the present invention is used for a driver circuit (e.g., one or both of a gate line driver circuit and a source line driver circuit) of the display device, the area occupied by the driver circuit can be reduced and the display device can have a narrow bezel, for example. Since the semiconductor device of one embodiment of the present invention has favorable electrical characteristics, a display device can have increased reliability by using the semiconductor device.

The display portion 162 of the display device 50A is a region where an image is to be displayed, and includes a plurality of pixels 201 that are periodically arranged. An enlarged view of one pixel 201 is illustrated in FIG. 37.

There is no particular limitation on the arrangement of the pixels in the display device of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 201 illustrated in FIG. 37 includes a subpixel 11R that emits red light, a subpixel 11G that emits green light, and a subpixel 11B that emits blue light. Note that there is no particular limitation on the number of subpixels included in one pixel.

The subpixels 11R, 11G, and 11B each include a display element and a circuit for controlling the driving of the display element.

A variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (quantum-dot LED) employing a light source and color conversion technology using quantum dot materials may be used.

As examples of a display device using a liquid crystal element, a transmissive liquid display device, a reflective liquid display device, and a transflective liquid display device can be given.

Examples of a mode that can be used for a display device using a liquid crystal element include a vertical alignment (VA) mode, an FFS (Fringe Field Switching) mode, an IPS (In-Plane Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for a liquid crystal element include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of the light-emitting element include a self-luminous light-emitting element such as an LED (Light Emitting Diode), an OLED (Organic LED), and a semiconductor laser. As the LED, for example, a mini LED, a micro LED, or the like can be used.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The light-emitting element can emit infrared, red, green, blue, cyan, magenta, yellow, or white light, for example. When the light-emitting element has a microcavity structure, higher color purity can be achieved.

One of the pair of electrodes of the light-emitting element functions as an anode, and the other electrode functions as a cathode.

The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

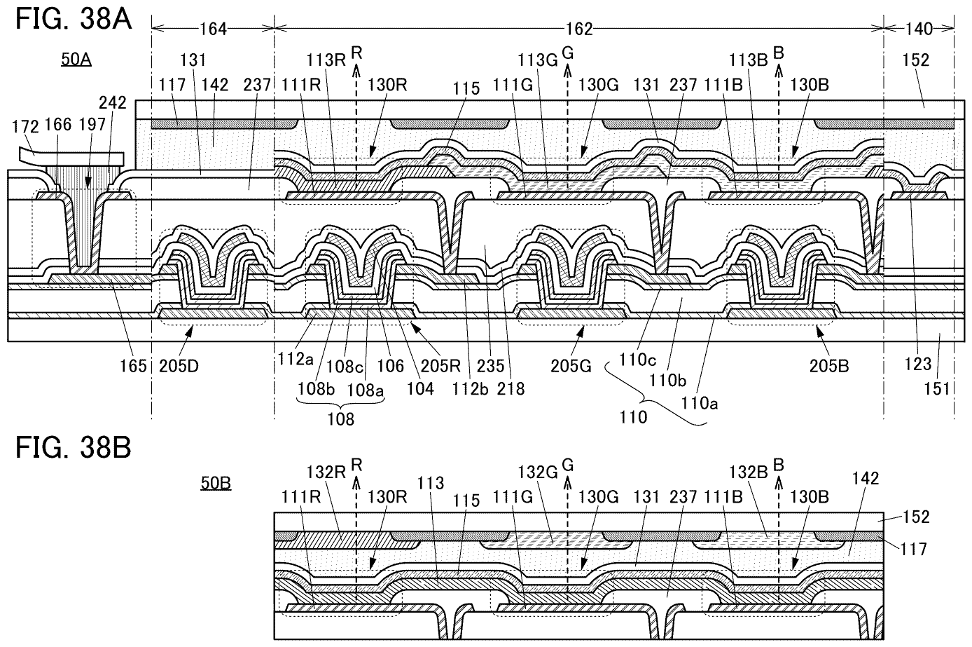

FIG. 38A illustrates an example of cross sections of part of a region including the FPC 172, part of the circuit portion 164, part of the display portion 162, part of the connection portion 140, and part of a region including the end portion of the display device 50A.

The display device 50A illustrated in FIG. 38A includes transistors 205D, 205R, 205G, and 205B, a light-emitting element 130R, a light-emitting element 130G, a light-emitting element 130B, and the like between the substrate 151 and the substrate 152. The light-emitting element 130R is a display element included in the subpixel 11R that emits red light, the light-emitting element 130G is a display element included in the subpixel 11G that emits green light, and the light-emitting element 130B is a display element included in the subpixel 11B that emits blue light.

The display device 50A employs an SBS structure. The SBS structure can optimize materials and structures of light-emitting elements and thus can extend freedom of choice of materials and structures, whereby the luminance and the reliability can be easily improved.

The display device 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

The transistor 205D, the transistor 205R, the transistor 205G, and the transistor 205B are each formed over the substrate 151. These transistors can be formed using the same material in the same step. Note that the transistors having different structures can be used for the transistor 205D, the transistor 205R, the transistor 205G, and the transistor 205B.

This embodiment describes an example where OS transistors are used as the transistors 205D, 205R, 205G, and 205B. The transistor of one embodiment of the present invention can be used as each of the transistors 205D, 205R, 205G, and 205B. In other words, the display device 50A includes any of the transistors of embodiments of the present invention in both the display portion 162 and the circuit portion 164. When the display portion 162 includes the transistor of one embodiment of the present invention, the pixel size can be reduced and high definition can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

Specifically, the transistors 205D, 205R, 205G, and 205B each include the conductive layer 104 functioning as a gate, the insulating layer 106 functioning as a gate insulating layer, the conductive layer 112a and the conductive layer 112b functioning as a source and a drain, the semiconductor layer 108 containing a metal oxide, and the insulating layer 110. Here, a plurality of layers obtained by processing the same conductive film are shown with the same hatching pattern. The insulating layer 110 is positioned between the conductive layer 112a and the conductive layer 112b. The insulating layer 106 is positioned between the conductive layer 104 and the semiconductor layer 108.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include any one or more of a planar transistor, a staggered transistor, and an inverted staggered transistor. A transistor included in the display device of this embodiment may have a top-gate structure or a bottom-gate structure. Gates may be provided above and below a semiconductor layer where a channel is formed.

A Si transistor may be included in the display device of this embodiment.

To increase the emission luminance of the light-emitting element included in the pixel circuit, it is necessary to increase the amount of current flowing through the light-emitting element. To increase the amount of current, the source-drain voltage of a driving transistor included in the pixel circuit needs to be increased. Since an OS transistor has a higher breakdown voltage between the source and the drain than a Si transistor, a high voltage can be applied between the source and the drain of the OS transistor. Thus, with the use of an OS transistor as a driving transistor included in the pixel circuit, the amount of current flowing through the light-emitting element can be increased, resulting in an increase in emission luminance of the light-emitting element.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be set minutely by a change in gate-source voltage; hence, the amount of current flowing through the light-emitting element can be controlled. Thus, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made to flow through an OS transistor than through a Si transistor. Thus, by using an OS transistor as the driving transistor, stable current can be made to flow through a light-emitting element even when the current-voltage characteristics of a light-emitting element vary, for example. In other words, when the OS transistor operates in the saturation region, the source-drain current hardly changes with a change in the source-drain voltage; hence, the emission luminance of the light-emitting element can be stable.

The transistor included in the circuit portion 164 and the transistor included in the display portion 162 may have the same structure or different structures. One structure or two or more kinds of structures may be employed for a plurality of transistors included in the circuit portion 164. Similarly, one structure or two or more kinds of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. Note that a structure in which an LTPS transistor and an OS transistor are used in combination is referred to as LTPO in some cases. As a more suitable example, a structure in which the OS transistor is used as a transistor or the like functioning as a switch for controlling conduction or non-conduction between wirings, and the LTPS transistor is used as a transistor or the like for controlling current, is given.

For example, one transistor included in the display portion 162 functions as a transistor for controlling a current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

An insulating layer 218 is provided to cover the transistors 205D, 205R, 205G, and 205B and an insulating layer 235 is provided over the insulating layer 218.

The insulating layer 218 preferably functions as a protective layer of the transistors. A material that does not easily allow diffusion of impurities such as water and hydrogen is preferably used for the insulating layer 218. Accordingly, the insulating layer 218 can function as a barrier film. Such a structure can effectively inhibit diffusion of impurities into the transistors from the outside and increase the reliability of the display device.

The insulating layer 218 preferably includes one or more inorganic insulating layers. For the insulating layer 218, a material that can be used for the insulating layer 195 can be used.

The insulating layer 235 preferably has a function of a planarization layer, and an organic insulating film is suitably used. Examples of a material usable for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. In that case, the formation of a depression in the insulating layer 235 can be inhibited in processing pixel electrodes 111R, 111G, and 111B, for example. Alternatively, a depression may be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 38A emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 38A emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 38A emits blue light (B). The EL layer 113B includes a light-emitting layer that emits blue light.

Although the EL layers 113R, 113G, and 113B have the same thickness in FIG. 38A, the present invention is not limited thereto. The EL layers 113R, 113G, and 113B may have different thicknesses. For example, the thicknesses of the EL layers 113R, 113G, and 113B are preferably set in accordance with an optical path length that intensifies light emitted from each EL layer. In that case, a microcavity structure is obtained, and the color purity of light emitted from each light-emitting element can be improved.

The pixel electrode 111R is electrically connected to the conductive layer 112b included in the transistor 205R through an opening provided in the insulating layer 106, the insulating layer 218, and the insulating layer 235. In a similar manner, the pixel electrode 111G is electrically connected to the conductive layer 112b included in the transistor 205G and the pixel electrode 111B is electrically connected to the conductive layer 112b included in the transistor 205B.

End portions of the pixel electrodes 111R, 111G, and 111B are covered with insulating layers 237. The insulating layer 237 functions as a partition. The insulating layer 237 can be provided to have a single-layer structure or a stacked-layer structure using one or both of an inorganic insulating material and an organic insulating material. A material that can be used for the insulating layer 218 and a material that can be used for the insulating layer 235 can be used for the insulating layer 237, for example. The insulating layer 237 can electrically isolate the pixel electrode and the common electrode. Furthermore, the insulating layer 237 can electrically isolate light-emitting elements adjacent to each other.

The insulating layer 237 is provided in at least the display portion 162. The insulating layer 237 may be provided in not only the display portion 162 but also the connection portion 140 and the circuit portion 164. The insulating layer 237 may be provided to extend to the end portion of the display device 50A.

The common electrode 115 is one continuous film shared by the light-emitting elements 130R, 130G, and 130B. The common electrode 115 shared by the light-emitting elements is electrically connected to a conductive layer 123 provided in the connection portion 140. For the conductive layer 123, a conductive layer formed using the same material in the same step as the pixel electrodes 111R, 111G, and 111B is preferably used.

In the display device of one embodiment of the present invention, a conductive film transmitting visible light is used for the electrode through which light is extracted, which is either the pixel electrode or the common electrode. A conductive film reflecting visible light is preferably used for the electrode through which light is not extracted.

A conductive film transmitting visible light may be used also for the electrode through which light is not extracted. In that case, this electrode is preferably provided between a reflective layer and the EL layer. In other words, light emitted by the EL layer may be reflected by the reflective layer to be extracted from the display device.

As a material that forms the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above as an example (e.g., lithium, cesium, calcium, or strontium), a rare earth metal such as europium or ytterbium, an alloy containing an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layers 113R, 113G, and 113B are each provided to have an island shape. In FIG. 38A, the end portion of the EL layer 113R and the end portion of the EL layer 113G that are adjacent to each other overlap with each other, the end portion of the EL layer 113G and the end portion of the EL layer 113B that are adjacent to each other overlap with each other, and the end portion of the EL layer 113R and the end portion of the EL layer 113B that are adjacent to each other overlap with each other. When island-shaped EL layers are formed using a fine metal mask, end portions of the EL layers adjacent to each other may overlap with each other as illustrated in FIG. 38A; however, the present invention is not limited thereto. That is, it is also possible that the EL layers adjacent to each other do not overlap with each other and are apart from each other. It is also possible that the display device includes both a portion where the EL layers adjacent to each other overlap with each other and a portion where the EL layers adjacent to each other do not overlap with each other and are apart from each other.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellow green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As the one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably contains a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a substance with a bipolar property and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure can also be referred to as a stack structure.

In the case of using a light-emitting element having a tandem structure in FIG. 38A, it is preferable that the EL layer 113R include a plurality of light-emitting units emitting red light, the EL layer 113G include a plurality of light-emitting units emitting green light, and the EL layer 113B include a plurality of light-emitting units emitting blue light.

A protective layer 131 is provided over the light-emitting elements 130R, 130G, and 130B. The protective layer 131 and the substrate 152 are bonded to each other with an adhesive layer 142. The substrate 152 is provided with a light-blocking layer 117. For example, a solid sealing structure or a hollow sealing structure can be employed to seal the light-emitting elements. In FIG. 38A, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting element. Furthermore, the space may be filled with a resin other than the frame-shaped adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is also preferable that the protective layer 131 be provided to extend to the end portion of the display device 50A. Meanwhile, a connection portion 197 has a portion not provided with the protective layer 131 so that the FPC 172 and a conductive layer 166 are electrically connected to each other.

By providing the protective layer 131 over the light-emitting elements 130R, 130G, and 130B, the reliability of the light-emitting elements can be increased.

The protective layer 131 can have a single-layer structure or a stacked-layer structure of two or more layers. There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

The protective layer 131 preferably includes one or more inorganic insulating layers. For the protective layer 131, a material that can be used for the insulating layer 110 can be used. In particular, the protective layer 131 is preferably formed using a nitride or a nitride oxide, and further preferably formed using a nitride.

An inorganic film containing ITO, In—Zn oxide, Ga—Zn oxide, Al—Zn oxide, IGZO, or the like can also be used as the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) to the EL layer side.

Furthermore, the protective layer 131 may include an organic film. For example, the protective layer 131 may include both an organic film and an inorganic film. Examples of an organic film usable for the protective layer 131 include organic insulating films usable for the insulating layer 235.

The connection portion 197 is provided in a region of the substrate 151 not overlapping with the substrate 152. In the connection portion 197, the conductive layer 165 is electrically connected to the FPC 172 through the conductive layer 166 and a connection layer 242. An example is illustrated in which the conductive layer 165 has a single-layer structure of a conductive layer obtained by processing the same conductive film as the conductive layer 112b. An example is illustrated in which the conductive layer 166 is a single conductive layer obtained by processing the same conductive film as the pixel electrodes 111R, 111G, and 111B. A structure similar to that of the connection portion between the pixel electrode 111 and the conductive layer 112b can be applied to the connection portion between the conductive layer 165 and the conductive layer 166. Specifically, FIG. 38A illustrates an example in which an opening is provided in the upper layer of the conductive layer 165 and the conductive layer 166 is in contact with the top surface of the conductive layer 165 through the opening. On the top surface of the connection portion 197, the conductive layer 166 is exposed. Thus, the connection portion 197 and the FPC 172 can be electrically connected to each other through the connection layer 242.

The display device 50A has a top-emission structure. Light from the light-emitting element is emitted toward the substrate 152. For the substrate 152, a material having a high visible-light-transmitting property is preferably used. The pixel electrodes 111R, 111G, and 111B contain a material that reflects visible light, and the counter electrode (the common electrode 115) contains a material that transmits visible light.

The light-blocking layer 117 is preferably provided on the surface of the substrate 152 on the substrate 151 side. The light-blocking layer 117 can be provided between adjacent light-emitting elements, in the connection portion 140, in the circuit portion 164, and the like.

A coloring layer such as a color filter may be provided on the surface of the substrate 152 on the substrate 151 side or over the protective layer 131. When the color filter is provided so as to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter transmitting light in the red wavelength range, a green (G) color filter transmitting light in the green wavelength range, a blue (B) color filter transmitting light in the blue wavelength range, or the like can be used. For each coloring layer, one or more of a metal material, a resin material, a pigment, and a dye can be used. Each coloring layer is formed in a desired position by a printing method, an inkjet method, an etching method using a photolithography method, or the like.

A variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, a glass layer or a silica layer (SiOₓ layer) is preferably provided as the surface protective layer to inhibit the surface contamination and damage. For the surface protective layer, DLC (diamond-like carbon), aluminum oxide (AlOₓ), a polyester-based material, a polycarbonate-based material, or the like may be used. The surface protective layer is preferably formed using a material having high visible light transmittance. The surface protective layer is preferably formed using a material with high hardness.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 151 and the substrate 152 are formed using a flexible material, the flexibility of the display device can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of a highly optically isotropic film include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

As the connection layer 242, an anisotropic conductive film (ACF), an anisotropic conductive paste (ACP), or the like can be used.

### [Display Device 50B]

FIG. 38B illustrates an example of a cross section of the display portion 162 of a display device 50B. The display device 50B is different from the display device 50A mainly in that the subpixels of different colors include respective coloring layers (e.g., color filters) and the light-emitting elements which share the EL layer 113. The structure illustrated in FIG. 38B can be combined with the structure illustrated in FIG. 38A of the region including the FPC 172, the circuit portion 164, the stacked-layer structure from the substrate 151 to the insulating layer 235 in the display portion 162, the connection portion 140, and the end portion. Note that in the following description of display devices, the description of portions similar to those of the above-described display device may be omitted.

The display device 50B illustrated in FIG. 38B includes the light-emitting elements 130R, 130G, and 130B, a coloring layer 132R transmitting red light, a coloring layer 132G transmitting green light, a coloring layer 132B transmitting blue light, and the like.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 50B through the coloring layer 132B.

The EL layer 113 and the common electrode 115 are shared between the light-emitting elements 130R, 130G, and 130B. The number of manufacturing processes can be smaller in the case where the EL layer 113 is shared between the subpixels of different colors than the case where the subpixels of different colors include different EL layers.

The light-emitting elements 130R, 130G, and 130B illustrated in FIG. 38B emit white light, for example. When white light emitted from the light-emitting elements 130R, 130G, and 130B passes through the coloring layers 132R, 132G, and 132B, light of desired colors can be obtained.

In the light-emitting element that emits white light, two or more light-emitting layers are preferably included. When two light-emitting layers are used to obtain white light, two light-emitting layers that emit light of complementary colors can be selected. For example, when the emission colors of a first light-emitting layer and a second light-emitting layer are made complementary, the light-emitting element can be configured to emit white light as a whole. In the case where three or more light-emitting layers are used to obtain white light, the light-emitting element can be configured to emit white light as a whole by combining emission colors of the three or more light-emitting layers.

For example, the EL layer 113 preferably includes a light-emitting layer containing a light-emitting substance that emits blue light and a light-emitting layer containing a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are stacked in this order; and a three-unit tandem structure in which a light-emitting unit that emits blue light, a light-emitting unit that emits yellow, yellow-green, or green light and red light, and a light-emitting unit that emits blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting element configured to emit white light has a microcavity structure, light with a specific wavelength such as red, green, or blue is sometimes intensified and emitted.

Alternatively, the light-emitting elements 130R, 130G, and 130B illustrated in FIG. 38B emit blue light, for example. In this case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the desired color can be absorbed by the coloring layer, and color purity of light exhibited by a subpixel can be improved.

### [Display Device 50C]

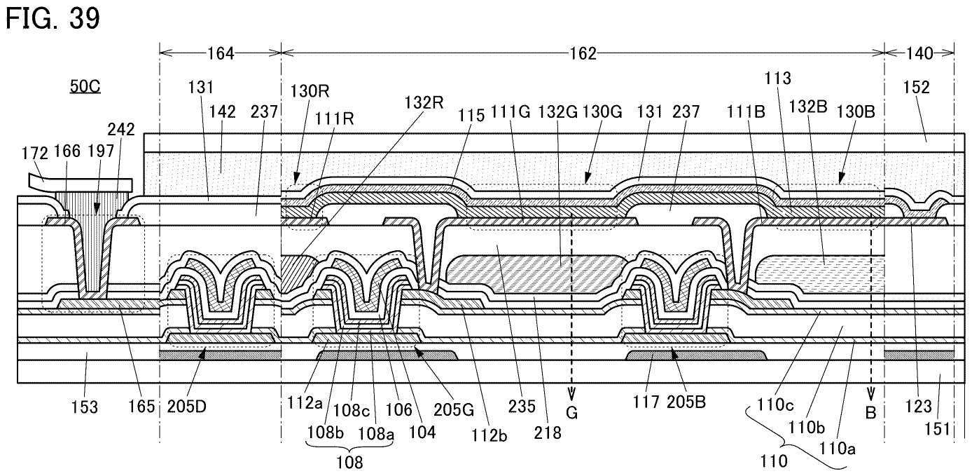

A display device 50C illustrated in FIG. 39 is different from the display device 50B mainly in having a bottom-emission structure.

Light from the light-emitting element is emitted toward the substrate 151. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 39 illustrates an example where the light-blocking layers 117 are provided over the substrate 151, the insulating layer 153 is provided over the light-blocking layers 117, and the transistor 205D, the transistor 205R (not illustrated), the transistor 205G, the transistor 205B, and the like are provided over the insulating layer 153. In addition, the coloring layer 132R, the coloring layer 132G, and the coloring layer 132B are provided over the insulating layer 218 and the insulating layer 235 is provided over the coloring layer 132R, the coloring layer 132G, and the coloring layer 132B.

The light-emitting element 130R overlapping with the coloring layer 132R includes the pixel electrode 111R, the EL layer 113, and the common electrode 115.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a high visible-light-transmitting property is used for each of the pixel electrodes 111R, 111G, and 111B. A material that reflects visible light is preferably used for the common electrode 115. In the display device having a bottom-emission structure, a metal or the like having low electrical resistivity can be used for the common electrode 115; thus, a voltage drop due to the electric resistance of the common electrode 115 can be inhibited and a high display quality can be achieved.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 50D]

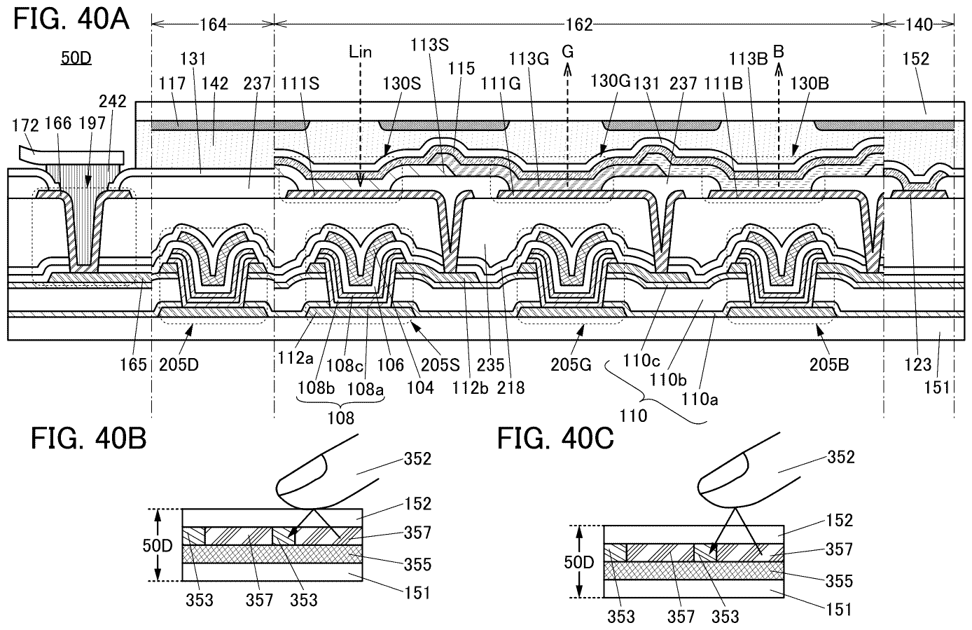

A display device 50D illustrated in FIG. 40A is different from the display device 50A mainly in including a light-receiving element 130S.

The display device 50D includes light-emitting elements and a light-receiving element in a pixel. In the display device 50D, organic EL elements are preferably used as the light-emitting elements and an organic photodiode is preferably used as the light-receiving element. The organic EL elements and the organic photodiodes can be formed over the same substrate. Thus, the organic photodiodes can be incorporated in a display device including the organic EL elements.

In the display device 50D including light-emitting elements and a light-receiving element in each pixel, the pixel has a light-receiving function; thus, the display device can detect a contact or approach of an object while displaying an image. Accordingly, the display portion 162 has one or both of an image capturing function and a sensing function in addition to a function of displaying an image. For example, an image can be displayed by using all the subpixels included in the display device 50D; alternatively, light can be emitted by some of the subpixels as a light source, light can be detected by some other subpixels, and an image can be displayed by using the remaining subpixels.

Accordingly, a light-receiving portion and a light source do not need to be provided separately from the display device 50D; hence, the number of components of an electronic device can be reduced. For example, it is unnecessary to separately provide a biometric authentication device provided in the electronic device, a capacitive touch panel for scroll operation, or the like. Thus, with the use of the display device 50D, an electronic device can be provided at lower manufacturing costs.

When the light-receiving elements are used for an image sensor, the display device 50D can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

The light-receiving element can be used for a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect the object even when the object is not in contact with the display device.

The light-receiving element 130S includes a pixel electrode 111S over the insulating layer 235, a functional layer 113S over the pixel electrode 111S, and the common electrode 115 over the functional layer 113S. Light Lin from outside the display device 50D enters the functional layer 113S.

The pixel electrode 111S is electrically connected to the conductive layer 112b included in a transistor 205S through an opening provided in the insulating layer 106, the insulating layer 218, and the insulating layer 235.

An end portion of the pixel electrode 111S is covered with the insulating layer 237.

The common electrode 115 is one continuous film shared by the light-receiving element 130S, the light-emitting element 130R (not shown), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer contains a semiconductor. Examples of the semiconductor include an inorganic semiconductor such as silicon and an organic semiconductor including an organic compound. This embodiment describes an example where an organic semiconductor is used as the semiconductor contained in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer containing a substance having a high hole-transport property, a substance having a high electron-transport property, a substance having a bipolar property, or the like. Without limitation to the above, the functional layer 113S may further include a layer containing a substance having a high hole-injection property, a hole-blocking material, a substance having a high electron-injection property, an electron-blocking material, or the like. The functional layer 113S can be formed using a material that can be used for the light-emitting element, for example.

Either a low molecular compound or a high molecular compound can be used in the light-receiving element, and an inorganic compound may also be included. Each layer included in the light-receiving element can be formed by an evaporation method (including a vacuum evaporation method), a transfer method, a printing method, an inkjet method, a coating method, or the like.

In the display device 50D illustrated in FIG. 40B and FIG. 40C, a layer 353 including a light-receiving element, a circuit layer 355, and a layer 357 including a light-emitting element are provided between the substrate 151 and the substrate 152.

The layer 353 includes the light-receiving element 130S, for example. The layer 357 includes the light-emitting elements 130R, 130G, and 130B, for example.

The circuit layer 355 includes a circuit for driving a light-receiving element and a circuit for driving a light-emitting element. The circuit layer 355 includes the transistors 205R, 205G, and 205B, for example. The circuit layer 355 can further include one or more of a switch, a capacitor, a resistor, a wiring, a terminal, and the like.

FIG. 40B illustrates an example where the light-receiving element 130S is used as a touch sensor. Light emitted from the light-emitting element in the layer 357 is reflected by a finger 352 that touches the display device 50D as illustrated in FIG. 40B, and the light-receiving element in the layer 353 detects the reflected light. Thus, the touch of the finger 352 on the display device 50D can be detected.

FIG. 40C illustrates an example where the light-receiving element 130S is used as a contactless sensor. Light emitted from the light-emitting element in the layer 357 is reflected by the finger 352 that is approaching (i.e., that does not touch) the display device 50D as illustrated in FIG. 40C, and the light-receiving element in the layer 353 detects the reflected light.

### [Display Device 50E]

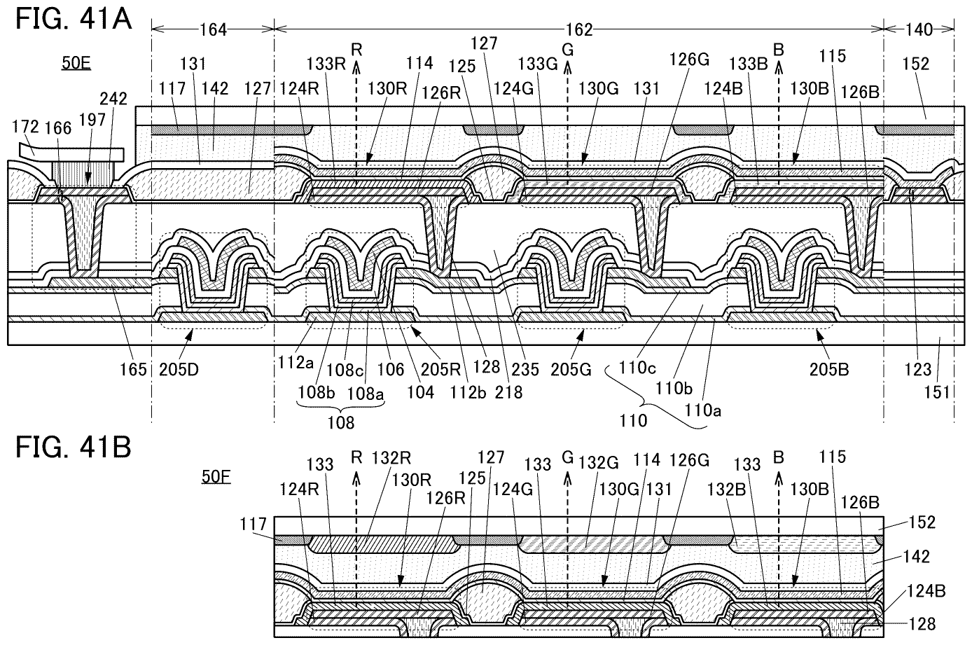

A display device 50E illustrated in FIG. 41A is an example of a display device having an MML (metal maskless) structure. In other words, the display device 50E includes a light-emitting element that is formed without using a fine metal mask.

An island-shaped light-emitting layer of the light-emitting element included in the display device having the MML structure is formed in the following manner: a light-emitting layer is formed on the entire surface, and then, the light-emitting layer is processed by a photolithography method. Accordingly, a high-definition display device or a display device with a high aperture ratio, which has been difficult to be formed so far, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

Note that a device having an MML structure can be manufactured without using a metal mask, and thus can break through the definition limit due to alignment accuracy of the metal mask. Furthermore, manufacturing a device without using a metal mask can eliminate the need for the manufacturing facilities for metal masks and the washing process for metal masks. Furthermore, for processing by photolithography, an apparatus that is the same as or similar to that used for manufacturing a transistor can be used; thus, there is no need to introduce a special apparatus to manufacture the device having an MML structure. An MML structure can reduce the manufacturing cost as described above, and thus is suitable for mass production of the device.

It is not necessary to conduct a pseudo improvement in definition by employing a unique pixel arrangement such as a PenTile arrangement in a display device employing an MML structure; thus, the display device can achieve high definition (e.g., higher than or equal to 500 ppi, higher than or equal to 1000 ppi, higher than or equal to 2000 ppi, higher than or equal to 3000 ppi, or higher than or equal to 5000 ppi) while having what is called a stripe arrangement where R, G, and B subpixels are arranged in one direction.

Providing a sacrificial layer over the light-emitting layer can reduce damage to the light-emitting layer in the manufacturing process of the display device, resulting in an increase in reliability of the light-emitting element.

Employing a film formation process using an area mask and a processing process using a resist mask enables a light-emitting element to be manufactured by a relatively easy process.

The stacked-layer structure from the substrate 151 to the insulating layer 235 and the stacked-layer structure from the protective layer 131 to the substrate 152 are similar to those in the display device 50A; thus, the description thereof is omitted.

In FIG. 41A, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 41A emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 41A emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 41A emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the light-emitting elements is referred to as the common layer 114. Note that in this specification and the like, only the layer 133R, the layer 133G, and the layer 133B are sometimes referred to as island-shaped EL layers, EL layers formed in an island shape, or the like, in which case the common layer 114 is not included in the EL layer. The light-emitting elements formed without using a metal mask do not necessarily include a common layer, and all the layers included in the EL layer may be formed in island shapes.

The layer 133R, the layer 133G, and the layer 133B are isolated from each other. When the EL layer is provided to have an island shape for each light-emitting element, a leakage current between adjacent light-emitting elements can be inhibited. This can prevent unintended light emission due to crosstalk, so that a display device with extremely high contrast can be obtained.

Although the layers 133R, 133G, and 133B have the same thickness in FIG. 41A, the present invention is not limited thereto. The layers 133R, 133G, and 133B may have different thicknesses.

The conductive layer 124R is electrically connected to the conductive layer 112b included in the transistor 205R through an opening provided in the insulating layer 106, the insulating layer 218, and the insulating layer 235. In a similar manner, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressions of the conductive layers 124R, 124G, and 124B.

The layer 128 has a function of filling the depressions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressions of the conductive layers 124R, 124G, and 124B can also be used as the light-emitting regions, increasing the aperture ratio of the pixels. As each of the conductive layer 124R and the conductive layer 126R, a conductive layer functioning as a reflective electrode is preferably used.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Note that although FIG. 41A illustrates an example where the top surface of the layer 128 includes a planar portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

The end portion of the conductive layer 126R may be aligned with the end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle greater than 0° and less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted.

The top surface and side surface of the conductive layer 126R are covered with the layer 133R. Similarly, the top surface and side surface of the conductive layer 126G are covered with the layer 133G, and the top surface and side surface of the conductive layer 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layer 133R, the layer 133G, and the layer 133B are covered with insulating layers 125 and 127. The common layer 114 is provided over the layer 133R, the layer 133G, the layer 133B, and the insulating layers 125, and 127, and the common electrode 115 is provided over the common layer 114. The common layer 114 and the common electrode 115 are each a continuous film provided to be shared by a plurality of light-emitting elements.

In FIG. 41A, the insulating layer 237 illustrated in FIG. 38A or the like is not provided between the conductive layer 126R and the layer 133R. That is, an insulating layer (also referred to as a partition wall, a bank, a spacer, or the like) that is in contact with the pixel electrode and covers an upper end portion of the pixel electrode is not provided in the display device 50E. Thus, the distance between adjacent light-emitting elements can be extremely short. Accordingly, the display device can have high definition or high resolution. In addition, a mask for forming the insulating layer is not needed, which leads to a reduction in manufacturing cost of the display device.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may be a stack of an electron-transport layer and an electron-injection layer, or may be a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depression defined by the insulating layer 125. The insulating layer 127 preferably covers at least part of the side surface of the insulating layer 125.

The insulating layer 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, a step is generated due to a level difference between a region where the pixel electrode and the island-shaped EL layer are provided and a region where neither the pixel electrode nor the island-shaped EL layer is provided (a region between the light-emitting elements). In the display device of one embodiment of the present invention, the step can be eliminated with the insulating layer 125 and the insulating layer 127, and the coverage with the common layer 114 and the common electrode 115 can be improved. Thus, poor connection caused by step disconnection can be inhibited. In addition, an increase in electric resistance, which is caused by local thinning of the common electrode 115 due to the step, can be inhibited.

The top surface of the insulating layer 127 preferably has a shape with higher planarity. The top surface of the insulating layer 127 may include at least one of a flat surface, a convex surface, and a concave surface. For example, the top surface of the insulating layer 127 preferably has a convex shape with a large radius of curvature.

The insulating layer 125 can have a single-layer structure or a stacked-layer structure of two or more layers. The insulating layer 125 preferably includes one or more inorganic insulating layers. For the insulating layer 125, a material that can be used for the insulating layer 110 can be used. In particular, aluminum oxide is preferable because it has high selectivity with respect to the EL layer in etching and has a function of protecting the EL layer in formation of the insulating layer 127. In particular, when an inorganic insulating film such as an aluminum oxide film, a hafnium oxide film, or a silicon oxide film is formed by an ALD method as the insulating layer 125, the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (gettering) at least one of water and oxygen.

When the insulating layer 125 has a function of the barrier insulating layer, entry of impurities (typically, at least one of water and oxygen) that may diffuse into the light-emitting elements from the outside can be inhibited. With this structure, a highly reliable light-emitting element and a highly reliable display device can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has a sufficiently low hydrogen concentration or a sufficiently low carbon concentration, and further preferably has both a sufficiently low hydrogen concentration and a sufficiently low carbon concentration.

The insulating layer 127 provided over the insulating layer 125 has a function of filling large unevenness of the insulating layer 125, which is formed between the adjacent light-emitting elements. In other words, the insulating layer 127 has an effect of improving the planarity of the formation surface of the common electrode 115.

As the insulating layer 127, an insulating layer containing an organic material can be suitably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymer in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. The insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive-type material or a negative-type material may be used.

The insulating layer 127 may be formed using a material absorbing visible light. When the insulating layer 127 absorbs light emitted from the light-emitting element, light leakage (stray light) from the light-emitting element to the adjacent light-emitting element through the insulating layer 127 can be inhibited. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferable to enhance the effect of blocking visible light. In particular, mixing color filter materials of three or more colors enables the formation of a black or nearly black resin layer.

### [Display Device 50F]

FIG. 41B illustrates an example of a cross section of the display portion 162 of a display device 50F. The display device 50F is different from the display device 50E mainly in that the subpixels of different colors are provided with coloring layers (e.g., color filters). The structure illustrated in FIG. 41B can be combined with the structure illustrated in FIG. 41A of the region including the FPC 172, the circuit portion 164, the stacked-layer structure from the substrate 151 to the insulating layer 235 in the display portion 162, the connection portion 140, and the end portion.

The display device 50F illustrated in FIG. 41B includes the light-emitting elements 130R, 130G, and 130B, the coloring layer 132R transmitting red light, the coloring layer 132G transmitting green light, the coloring layer 132B transmitting blue light, and the like.

Light emitted from the light-emitting element 130R is extracted as red light to the outside of the display device 50F through the coloring layer 132R. Similarly, light emitted from the light-emitting element 130G is extracted as green light to the outside of the display device 50F through the coloring layer 132G. Light emitted from the light-emitting element 130B is extracted as blue light to the outside of the display device 50F through the coloring layer 132B.

The light-emitting elements 130R, 130G, and 130B each include the layer 133. The three layers 133 are formed using the same material in the same step. The three layers 133 are apart from each other. When the EL layer is provided to have an island shape for each light-emitting element, a leakage current between adjacent light-emitting elements can be inhibited. This can prevent unintended light emission due to crosstalk, so that a display device with extremely high contrast can be obtained.

The light-emitting elements 130R, 130G, and 130B illustrated in FIG. 41B emit white light, for example. When white light emitted from the light-emitting elements 130R, 130G, and 130B passes through the coloring layers 132R, 132G, and 132B, light of desired colors can be obtained.

Alternatively, the light-emitting elements 130R, 130G, and 130B illustrated in FIG. 41B emit blue light, for example. In this case, the layer 133 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the desired color can be absorbed by the coloring layer, and color purity of light exhibited by a subpixel can be improved.

### [Display Device 50G]

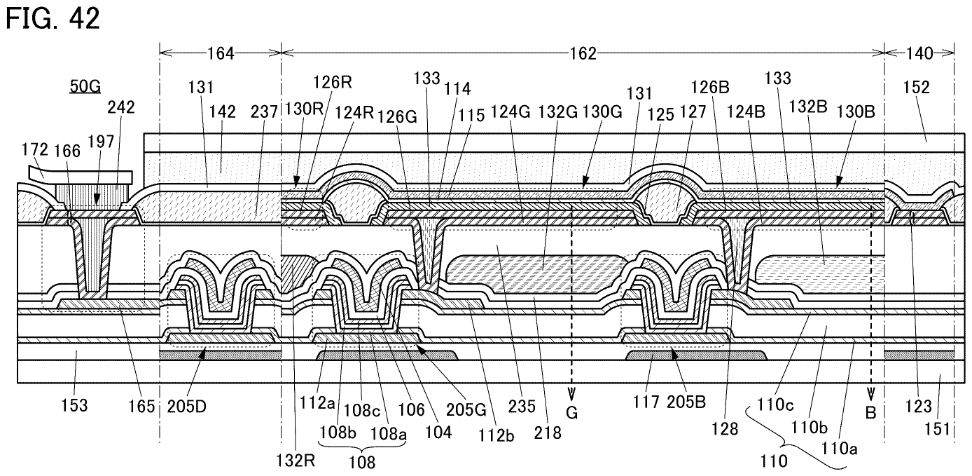

A display device 50G illustrated in FIG. 42 is different from the display device 50F mainly in having a bottom-emission structure.

Light from the light-emitting element is emitted toward the substrate 151. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 42 illustrates an example where the light-blocking layers 117 are provided over the substrate 151, the insulating layer 153 is provided over the light-blocking layers 117, and the transistor 205D, the transistor 205R (not illustrated), the transistor 205G, the transistor 205B, and the like are provided over the insulating layer 153. In addition, the coloring layer 132R, the coloring layer 132G, and the coloring layer 132B are provided over the insulating layer 218 and the insulating layer 235 is provided over the coloring layer 132R, the coloring layer 132G, and the coloring layer 132B.

The light-emitting element 130R overlapping with the coloring layer 132R includes the conductive layer 124R, the conductive layer 126R, the layer 133, the common layer 114, and the common electrode 115.

The light-emitting element 130G overlapping with the coloring layer 132G includes the conductive layer 124G, the conductive layer 126G, the layer 133, the common layer 114, and the common electrode 115.

The light-emitting element 130B overlapping with the coloring layer 132B includes the conductive layer 124B, the conductive layer 126B, the layer 133, the common layer 114, and the common electrode 115.

A material having a high visible-light-transmitting property is used for each of the conductive layers 124R, 124G, 124B, 126R, 126G, and 126B. A material that reflects visible light is preferably used for the common electrode 115. In the display device having a bottom-emission structure, a metal or the like having low electrical resistivity can be used for the common electrode 115; thus, a voltage drop due to the electric resistance of the common electrode 115 can be inhibited and a high display quality can be achieved.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 50H]

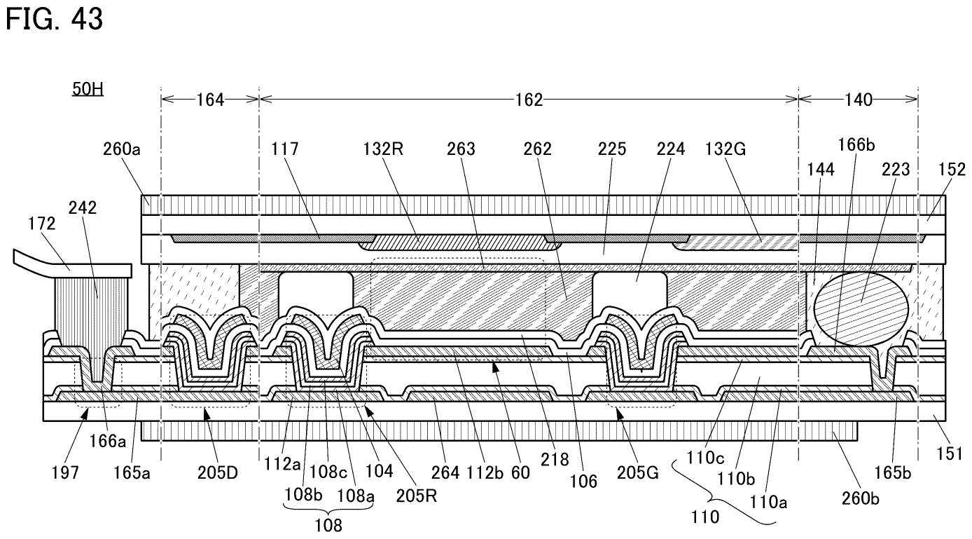

A display device 50H illustrated in FIG. 43 is a liquid crystal display device in a VA mode.

The substrate 151 and the substrate 152 are attached to each other with an adhesive layer 144. A liquid crystal 262 is sealed in a region that is surrounded by the substrate 151, the substrate 152, and the adhesive layer 144. A polarizing plate 260a is positioned on the outer surface of the substrate 152, and a polarizing plate 260b is positioned on the outer surface of the substrate 151. Although not illustrated, a backlight can be provided outside the polarizing plate 260a or the polarizing plate 260b.

The substrate 151 is provided with the transistors 205D, 205R, and 205G, the connection portion 197, a spacer 224, and the like. The transistor 205D is provided in the circuit portion 164, and the transistors 205R and 205G are provided in the display portion 162. The conductive layers 112b included in the transistor 205R and the transistor 205G each function as a pixel electrode of a liquid crystal element 60.

The substrate 152 is provided with the coloring layer 132R, the coloring layer 132G, the light-blocking layer 117, an insulating layer 225, a conductive layer 263, and the like. The conductive layer 263 functions as a common electrode of the liquid crystal element 60.

The transistors 205D, 205R, and 205G each include the conductive layer 112a, the semiconductor layer 108, the insulating layer 106, the conductive layer 104, and the conductive layer 112b. The conductive layer 112a functions as one of a source electrode and a drain electrode and the conductive layer 112b functions as the other of the source electrode and the drain electrode. The conductive layer 104 functions as a gate electrode. Part of the insulating layer 106 functions as a gate insulating layer.

As described above, this embodiment describes an example in which OS transistors are used as the transistors 205D, 205R, and 205G. The transistor of one embodiment of the present invention can be used as the transistors 205D, 205R, and 205G. In other words, the display device 50H includes the transistor of one embodiment of the present invention in both the display portion 162 and the circuit portion 164. When the display portion 162 includes the transistor of one embodiment of the present invention, the pixel size can be reduced and high definition can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

The transistors 205D, 205R, and 205G are covered with the insulating layer 218. The insulating layer 218 has a function of a protective layer of the transistors 205D, 205R, and 205G.

A subpixel included in the display portion 162 includes a transistor, the liquid crystal element 60, and a coloring layer. For example, a subpixel that emits red light includes the transistor 205R, the liquid crystal element 60, and the coloring layer 132R that transmits red light. A subpixel that emits green light includes the transistor 205G, the liquid crystal element 60, and the coloring layer 132G that transmits green light. Similarly, although not illustrated, a subpixel that emits blue light includes a transistor, the liquid crystal element 60, and a coloring layer that transmits blue light.

The liquid crystal element 60 includes the conductive layer 112b, the conductive layer 263, and the liquid crystal 262 interposed therebetween.

Over the substrate 151, a conductive layer 264 positioned on the same plane as the conductive layer 112a is provided. The conductive layer 264 includes a portion overlapping with the conductive layer 112b with the insulating layer 110 (the insulating layer 110a, the insulating layer 110b, and the insulating layer 110c) therebetween. The conductive layer 112b, the conductive layer 264, and the insulating layer 110 positioned therebetween form a storage capacitor. Note that any one or two layers included in the insulating layer 110 may be removed by etching as long as at least one insulating layer is provided between the conductive layer 112b and the conductive layer 264.

The insulating layer 225 is provided on the substrate 152 side to cover the coloring layers 132R and 132G and the light-blocking layer 117. The insulating layer 225 may have a function of a planarization layer. The conductive layer 263 can have a substantially flat surface owing to the insulating layer 225, resulting in a uniform alignment state of the liquid crystal 262.

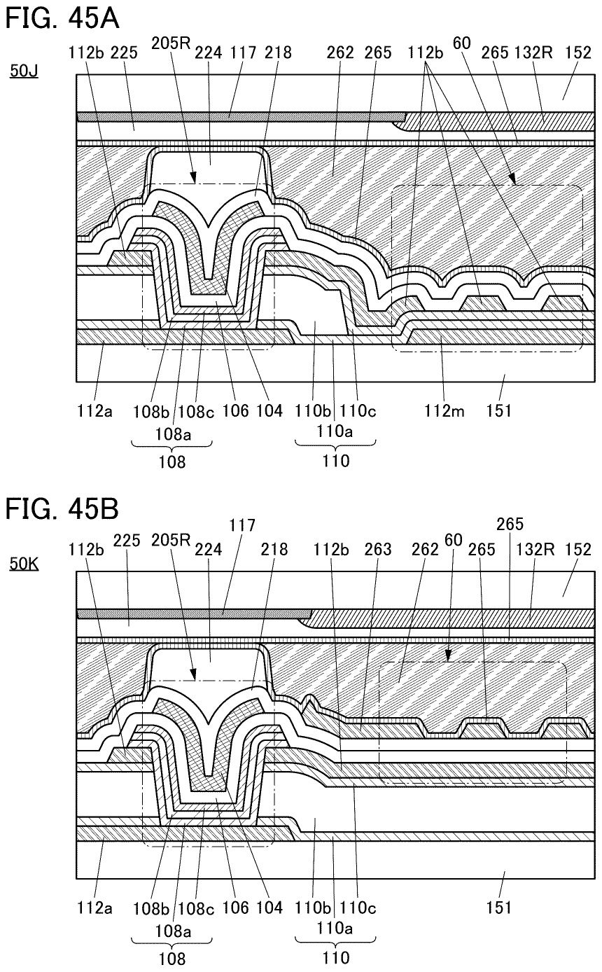

Note that an alignment film for controlling the alignment of the liquid crystal 262 may be provided on surfaces of the conductive layer 263, the insulating layer 218, and the like which are in contact with the liquid crystal 262 (see an alignment film 265 in FIG. 45A and FIG. 45B).

The conductive layer 112b and the conductive layer 263 transmit visible light. Thus, a transmissive liquid crystal display device can be obtained. For example, in the case where a backlight is placed on the substrate 152 side, light from the backlight which is polarized by the polarizing plate 260a passes through the substrate 152, the conductive layer 263, the liquid crystal 262, the conductive layer 112b, and the substrate 151, and then reaches the polarizing plate 260b. In this case, optical modulation of the light can be controlled by controlling the alignment of the liquid crystal 262 with a voltage applied between the conductive layer 112b and the conductive layer 263. In other words, the intensity of light emitted through the polarizing plate 260b can be controlled. Light other than one in a particular wavelength region of the incident light is absorbed by the coloring layer, and thus, extracted light is red light, for example.

Here, as the polarizing plate 260b, a linear polarizing plate may be used or a circularly polarizing plate can also be used. As a circularly polarizing plate, a stack including a linear polarizing plate and a quarter-wave retardation plate can be used. Reflection of external light can be reduced with a circularly polarizing plate used as the polarizing plate 260b.

Note that in the case where a circularly polarizing plate is used as the polarizing plate 260b, a circularly polarizing plate or a general linear polarizing plate may be used as the polarizing plate 260a. The cell gap, alignment, driving voltage, and the like of the liquid crystal element used as the liquid crystal element 60 are adjusted in accordance with the kinds of polarizing plates used as the polarizing plate 260a and the polarizing plate 260b so that desirable contrast can be obtained.

The conductive layer 263 is electrically connected to a conductive layer 166b provided on the substrate 151 side through a connector 223 in the connection portion 140. The conductive layer 166b is electrically connected to a conductive layer 165b through an opening provided in the insulating layer 110. Thus, a potential or a signal can be supplied to the conductive layer 263 from the FPC, the IC, or the like placed on the substrate 151 side. In the structure illustrated in FIG. 43, the conductive layer 165b is formed using the same material in the same step as the conductive layer 112a, and the conductive layer 166b is formed using the same material in the same step as the conductive layer 112b.

As the connector 223, a conductive particle can be used, for example. As the conductive particle, a particle of an organic resin, silica, or the like coated with a metal material can be used. It is preferable to use nickel or gold as the metal material because contact resistance can be reduced. It is also preferable to use a particle coated with layers of two or more kinds of metal materials, such as a particle coated with nickel and further with gold. For the connector 223, a material capable of elastic deformation or plastic deformation is preferably used. In this case, as illustrated in FIG. 43, the particle having a conduction property may have a shape that is vertically crushed. With the crushed shape, the contact area of the connector 223 and a conductive layer electrically connected thereto can be increased, whereby contact resistance can be reduced and occurrence of problems such as connection defects can be inhibited. The connector 223 is preferably provided to be covered with the adhesive layer 144. For example, the connectors 223 are preferably dispersed in the adhesive layer 144 before curing of the adhesive layer 144.

In a region near an end portion of the substrate 151, the connection portion 197 is provided. In the connection portion 197, a conductive layer 166a is electrically connected to the FPC 172 through the connection layer 242. The conductive layer 166a is electrically connected to a conductive layer 165a through an opening provided in the insulating layer 110. In the structure illustrated in FIG. 43, the conductive layer 165a is formed using the same material in the same step as the conductive layer 112a, and the conductive layer 166a is formed using the same material in the same step as the conductive layer 112b.

### [Display Device 50I]

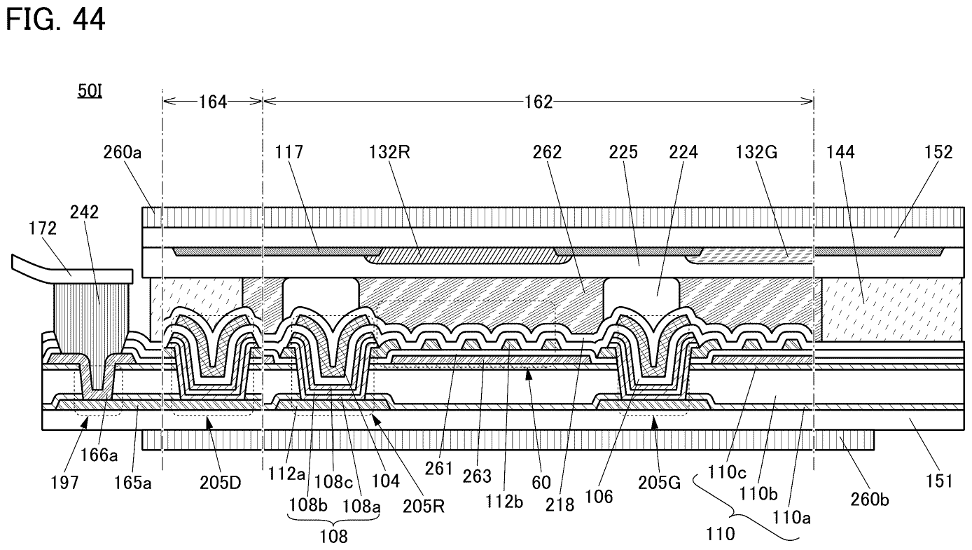

A display device 50I illustrated in FIG. 44 is a liquid crystal display device in an FFS mode. The display device 50I is different from the display device 50H mainly in the structure of the liquid crystal element 60.

The conductive layer 263 functioning as the common electrode of the liquid crystal element 60 is provided over the insulating layer 110, and an insulating layer 261 is provided over the conductive layer 263. The conductive layer 112b having a function of the other of the source electrode and the drain electrode of the transistor and a function of the pixel electrode of the liquid crystal element 60 is provided over the insulating layer 261. The insulating layer 218 is provided over the conductive layer 112b.

In a plan view, the conductive layer 112b has a comb-like shape or a shape with a slit. The conductive layer 263 is provided to overlap with the conductive layer 112b. There is a portion where the conductive layer 112b is not provided over the conductive layer 263 in a region overlapping with the coloring layer.

The conductive layer 112b and the conductive layer 263 are stacked with the insulating layer 261 therebetween, whereby a capacitor is formed. Thus, it is not necessary to provide a capacitor separately, and the aperture ratio of the pixel can be increased.

Note that in the liquid crystal element 60, both the conductive layer 112b and the conductive layer 263 may have a comb-like top surface shape. Meanwhile, when only one of the conductive layer 112b and the conductive layer 263 in the liquid crystal element 60 has a comb-like top surface shape as in the display device 50I, the conductive layer 112b and the conductive layer 263 partly overlap with each other. This allows the capacitance between the conductive layer 112b and the conductive layer 263 to be used as a storage capacitor; thus, a capacitor does not need to be provided separately, and the aperture ratio of the display device can be increased.

### [Display Device 50J]

In a display device 50J illustrated in FIG. 45A, a portion of the insulating layer 110b overlapping with the liquid crystal element 60 is removed by etching. The liquid crystal element 60 included in the display device 50J includes a portion where the insulating layer 110a, the insulating layer 110c, and the conductive layer 112b are stacked in this order. The liquid crystal element 60 and the insulating layer 110b do not overlap with each other, which enables not only an increase in the light transmittance but also a reduction in the number of interfaces positioned on the path of light from the light source; accordingly, the influences of interface reflection and interface scattering can be inhibited.

The conductive layer 112b functions as a pixel electrode of the liquid crystal element 60. A conductive layer 112m functions as a common electrode of the liquid crystal element 60. The conductive layer 112m and the conductive layer 112a are formed using the same conductive film.

Note that a portion of one or both of the insulating layer 106 and the insulating layer 218 that overlaps with the liquid crystal element 60 may be removed by etching. The insulating layer 218 is not necessarily provided. This facilitates transmission of electric fields of the conductive layer 112b and the conductive layer 112m to the liquid crystal 262, which enables high-speed operation of the liquid crystal element 60. Furthermore, the light transmittance of a portion overlapping with the liquid crystal element 60 can be increased and the influences of interface reflection and interface scattering can be inhibited. A portion of at least one of the insulating layer 110a and the insulating layer 110c overlapping with the liquid crystal element 60 may be removed by etching. This also facilitates transmission of the electric fields of the conductive layer 112b and the conductive layer 112m to the liquid crystal 262. Furthermore, the capacitance between the conductive layer 112b and the conductive layer 112m can be increased in some cases.

In the liquid crystal element 60, both the conductive layer 112b and the conductive layer 112m may have a comb-like top surface shape. Meanwhile, as illustrated in the display device 50J, only one of the conductive layer 112b and the conductive layer 112m has a comb-like top surface shape in the liquid crystal element 60, whereby the conductive layer 112b and the conductive layer 112m partly overlap with each other. With this structure, capacitance between the conductive layer 112b and the conductive layer 112m can be used as a storage capacitor, and thus a capacitor does not need to be provided additionally; accordingly, the aperture ratio of the display device can be increased.

### [Display Device 50K]

A display device 50K illustrated in FIG. 45B is different from the display device 50I mainly in that a common electrode is provided over a pixel electrode. The conductive layer 112b included in the transistor 100 functions as the pixel electrode of the liquid crystal element 60. The insulating layer 106 and the insulating layer 218 are provided over the conductive layer 112b, and the conductive layer 263 is provided over the insulating layer 218. The conductive layer 263 functions as the common electrode of the liquid crystal element 60. In a plan view, the conductive layer 263 has a comb-like shape or a shape with a slit.

This embodiment can be combined with the other embodiments as appropriate.

### Embodiment 4

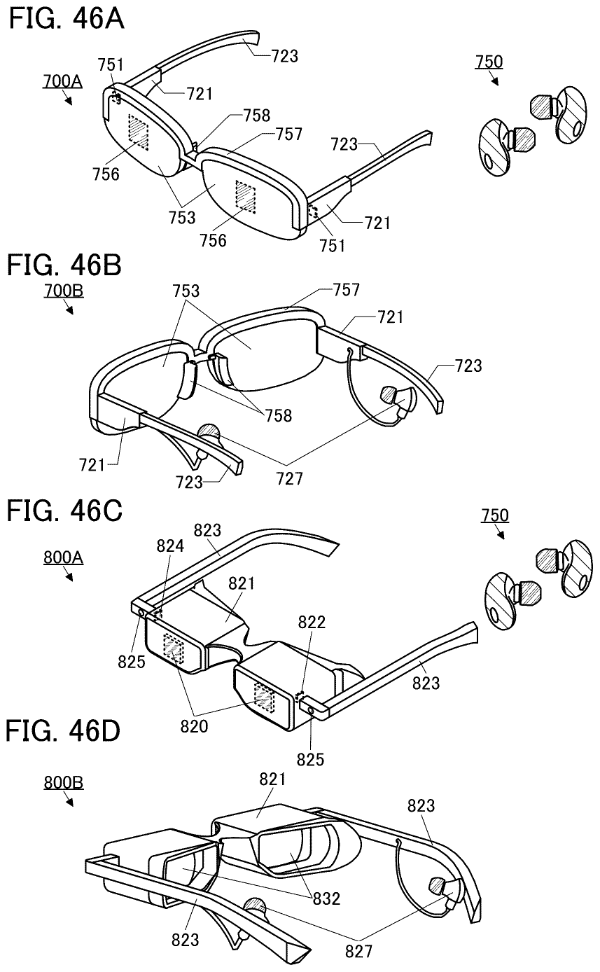

In this embodiment, electronic devices of one embodiment of the present invention will be described with reference to FIG. 46 to FIG. 48.

Electronic devices in this embodiment each include the display device of one embodiment of the present invention in a display portion. The display device of one embodiment of the present invention can be easily increased in definition and resolution. Thus, the display device of one embodiment of the present invention can be used for a display portion of a variety of electronic devices.

The semiconductor device of one embodiment of the present invention can also be applied to any other portion of an electronic device than a display portion. For example, the semiconductor device of one embodiment of the present invention is preferably used for a control portion or the like of an electronic device to enable lower power consumption.

Examples of the electronic device include a digital camera, a digital video camera, a digital photo frame, a mobile phone, a portable game console, a portable information terminal, and an audio reproducing device, in addition to electronic devices with a relatively large screen, such as a television device, a desktop or laptop computer, a monitor of a computer or the like, digital signage, and a large game machine such as a pachinko machine.

In particular, the display device of one embodiment of the present invention can have a high definition, and thus can be suitably used for an electronic device having a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The resolution of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a resolution of 4K, 8K, or higher is preferable. The pixel density (definition) of the display apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such high resolution and high definition can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head are described with reference to FIG. 46A to FIG. 46D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 46A and an electronic device 700B illustrated in FIG. 46B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with extremely high definition.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable supplied with a video signal and a power potential can be connected may be provided.

The electronic device 700A and the electronic device 700B are each provided with a battery (not illustrated) so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, processing such as a pause or a restart of a moving image can be executed by a tap operation, and processing such as fast forward or fast rewind can be executed by a slide operation. When the touch sensor module is provided in each of the two the housings 721, the range of the operation can be increased.

A variety of touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 46C and an electronic device 800B illustrated in FIG. 46D each include a pair of display portions 820, a housing 821, a communication portion 822, a pair of wearing portions 823, a control portion 824, a pair of image capturing portions 825, and a pair of lenses 832. Note that the display portions 820, the communication portion 822, and the image capturing portions 825 are omitted in FIG. 46D.

The display device of one embodiment of the present invention can be used in the display portions 820. Thus, the electronic device can perform display with extremely high definition. Such electronic devices provide a high sense of immersion to the user.

The display portions 820 are positioned inside the housing 821 so as to be seen through the lenses 832. When the pair of the display portions 820 display different images, three-dimensional display using parallax can be performed.

Each of the electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lenses 832 and the display portions 820 is preferably included.

The electronic device 800A or the electronic device 800B can be worn on the user's head with the wearing portions 823. FIG. 46C and the like illustrate examples in which the wearing portion has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. In other words, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as a bone-conduction earphone. For example, at least one of the display portion 820, the housing 821, and the wearing portion 823 can include the vibration mechanism. In that case, without additionally requiring an audio device such as headphones, earphones, or a speaker, the user can enjoy videos and sounds only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 46A has a function of transmitting information to the earphones 750 with the wireless communication function. As another example, the electronic device 800A illustrated in FIG. 46C has a function of transmitting information to the earphones 750 with the wireless communication function.

The electronic device may include an earphone portion. The electronic device 700B illustrated in FIG. 46B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B illustrated in FIG. 46D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

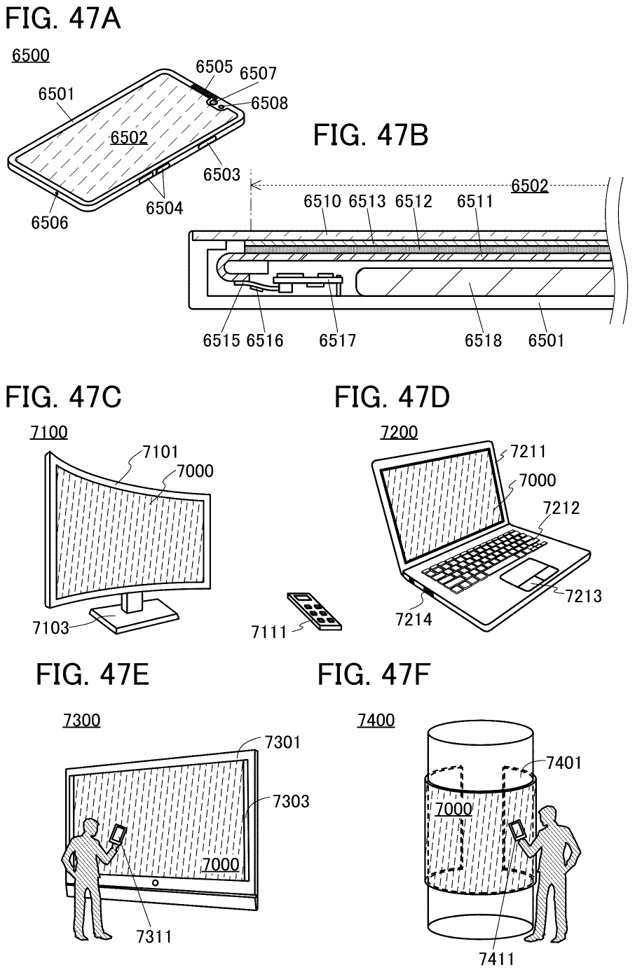

An electronic device 6500 illustrated in FIG. 47A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 47B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 47C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 47C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 47D illustrates an example of a laptop computer. A laptop computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIG. 47E and FIG. 47F illustrate examples of digital signage.

Digital signage 7300 illustrated in FIG. 47E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 47F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in FIG. 47E and FIG. 47F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 47E and FIG. 47F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

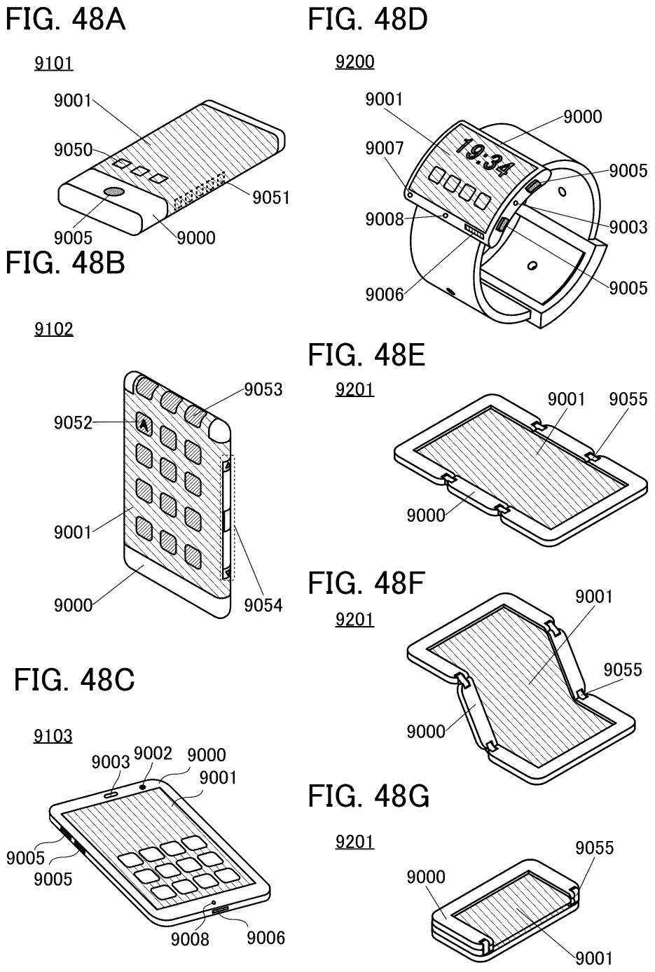

Electronic devices illustrated in FIG. 48A to FIG. 48G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display device of one embodiment of the present invention can be used for the display portion 9001 in FIG. 48A to FIG. 48G.

The electronic devices illustrated in FIG. 48A to FIG. 48G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions.

The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices illustrated in FIG. 48A to FIG. 48G are described in detail below.

FIG. 48A is a perspective view illustrating a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 48A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 48B is a perspective view illustrating a portable information terminal 9102. The portable information terminal 9102 has a function of displaying information on three or more surfaces of the display portion 9001. In the example illustrated here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 48C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 48D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 48E to FIG. 48G are perspective views illustrating a foldable portable information terminal 9201. FIG. 48E is a perspective view of an opened state of the portable information terminal 9201, FIG. 48G is a perspective view of a folded state thereof, and FIG. 48F is a perspective view of a state in the middle of change from one of FIG. 48E and FIG. 48G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### Example 1

In this example, the composition of metal oxides that can be used in a semiconductor device of one embodiment of the present invention was evaluated.

In this example, Sample A1 to Sample A11 each including a metal oxide film were fabricated. The formation conditions of the metal oxide film were varied among Sample A1 to Sample A11.

### <Sample Fabrication>

An approximately 20-nm-thick metal oxide film was formed over a glass substrate.

Each of the metal oxide film of Sample A1 to Sample A10 was formed by a sputtering method using an ITZO sputtering target with an atomic ratio of metal elements of In:Sn:Zn=40:1:10 (4:0.1:1). Each of the metal oxide film of Sample A1 to Sample A10 was formed using a sputtering apparatus including an AC power source. A mixed gas of an oxygen gas and an argon gas was used as a deposition gas. The substrate temperature and the oxygen flow rate ratio at the time of formation were varied among Sample A1 to Sample A10. In Sample A1, the substrate was not heated and the oxygen flow rate ratio was 10% at the time of formation. In Sample A2, the substrate was not heated and the oxygen flow rate ratio was 30% at the time of formation. In Sample A3, the substrate temperature was 100° C. and the oxygen flow rate ratio was 10%. In Sample A4, the substrate temperature was 100° C. and the oxygen flow rate ratio was 30%. In Sample A5, the substrate temperature was 150° C. and the oxygen flow rate ratio was 10%. In Sample A6, the substrate temperature was 150° C. and the oxygen flow rate ratio was 30%. In Sample A7, the substrate temperature was 170° C. and the oxygen flow rate ratio was 10%. In Sample A8, the substrate temperature was 170° C. and the oxygen flow rate ratio was 30%. In Sample A9, the substrate temperature was 200° C. and the oxygen flow rate ratio was 10%. In Sample A10, the substrate temperature was 200° C. and the oxygen flow rate ratio was 30%.

The metal oxide film of Sample A1 l was formed by a sputtering method using an IZO sputtering target with an atomic ratio of metal elements of In:Zn=4:1. The metal oxide film of Sample A11 was formed using a sputtering apparatus including a DC power source. The substrate temperature at the time of formation was 150° C., a mixed gas of an oxygen gas and an argon gas was used as a deposition gas, and the oxygen flow rate ratio was 30%.

### <X-Ray Diffraction Analysis>

Next, X-ray diffraction (XRD) analysis was performed on Sample A1 to Sample A11.

In the XRD analysis, a θ-2θ scanning method which is a kind of an out-of-plane method was used. The θ-2θ scanning method is a method in which X-ray diffraction intensity is measured while an incident angle of an X-ray is changed and the angle of a detector facing an X-ray source is set equal to the incident angle. The θ-2θ scanning method is called a powder method in some cases. In the XRD analysis, a Cu-Kα ray (λ=0.15418 nm) was used as an X-ray source, the scanning range at 2θ was 15 deg. to 50 deg., the step width was 0.01 deg., and the scanning speed was 6.0 deg./min.

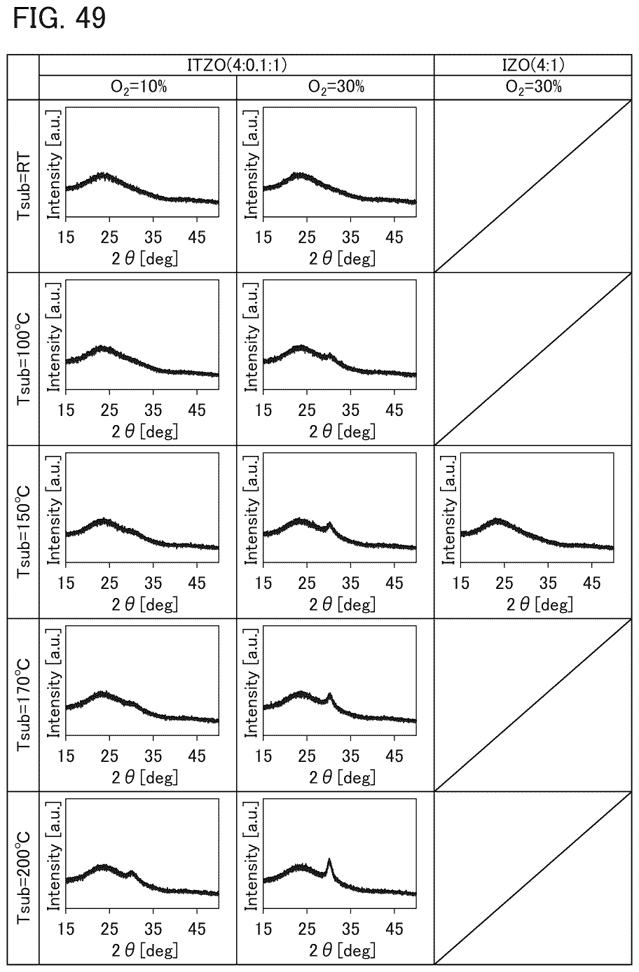

FIG. 49 shows XRD analysis results of Sample A1 to Sample A11. In FIG. 49, each horizontal axis represents a diffraction angle 2θ and each vertical axis represents the intensity of diffraction X-ray. Note that broad peaks where 2θ is at around 24 deg. are derived from the glass substrate. In FIG. 49, the condition using an ITZO sputtering target for forming the metal oxide film is denoted by “ITZO (4:0.1:1)”, and the condition using an IZO sputtering target for forming the metal oxide film is denoted by “IZO (4:1)”. Furthermore, the conditions of the substrate temperature (denoted by “Tsub”) and the oxygen flow rate ratio (denoted by “O₂”) are both shown and the condition where heating of the substrate was not performed at the time of formation is denoted by “Tsub=RT”.

As shown in FIG. 49, a peak was observed in each sample when 2θ was around=31 deg., which demonstrates that each sample has crystallinity. It is confirmed that when the substrate temperature or the oxygen flow rate ratio at the time of forming the metal oxide film are increased, the peak level is increased and crystallinity is increased.

### <Etching Rates>

Next, the etching rates of Sample A1 to Sample A11 were evaluated.

A chemical solution containing phosphoric acid, acetic acid, and nitric acid (also referred to as PAN) was used as an etchant, and the etchant temperature at the time of the etching was room temperature (approximately 25° C.).

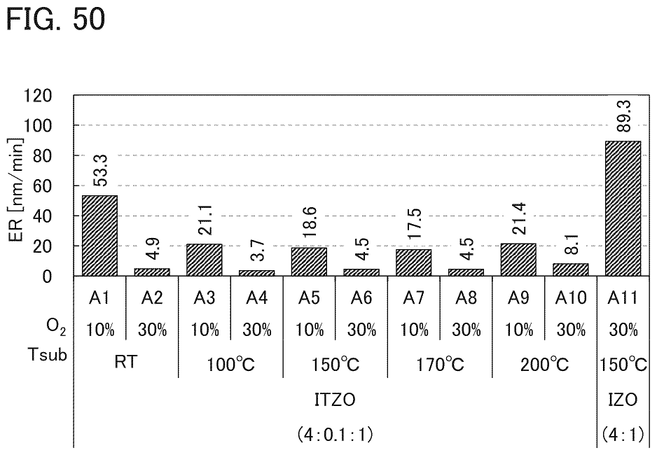

FIG. 50 shows the etching rates of Sample A1 to Sample A11. In FIG. 50, the horizontal axis represents the sample name and the formation condition of the metal oxide film, and the vertical axis represents the etching rate (ER). The etching rate was calculated by dividing a difference between the thickness of a target film before the etching and the thickness of the target film after the etching by the etching time.

As shown in FIG. 50, it was confirmed that the etching rate tends to be reduced by increasing one or both of the substrate temperature and the oxygen flow rate ratio at the time of forming the metal oxide film. It is considered that an increase in one or both of the substrate temperature and the oxygen flow rate ratio at the time of forming the metal oxide film increased the crystallinity, and accordingly the etching rate was reduced.

### <Hall Effect Measurement>

Next, the Hall effect measurement was performed on Sample A1 to Sample A11. Note that for the measurement, a sample where heat treatment was performed at 350° C. in a dry air atmosphere for one hour after the above-described formation of the metal oxide film and a titanium film was formed as an electrode was used. An oven apparatus was used for the heat treatment. The electrode was formed by a sputtering method using a metal mask.

Here, the Hall effect measurement is a method in which electrical characteristics such as carrier concentration, mobility, and resistivity are measured with the use of the Hall effect, which is a phenomenon where, when a magnetic field is applied to a sample through which a current flows in a direction perpendicular to the direction of the current, an electromotive force is produced in directions perpendicular to both the current and the magnetic field. Here, the Hall effect measurement using the Van der Pauw method was performed.

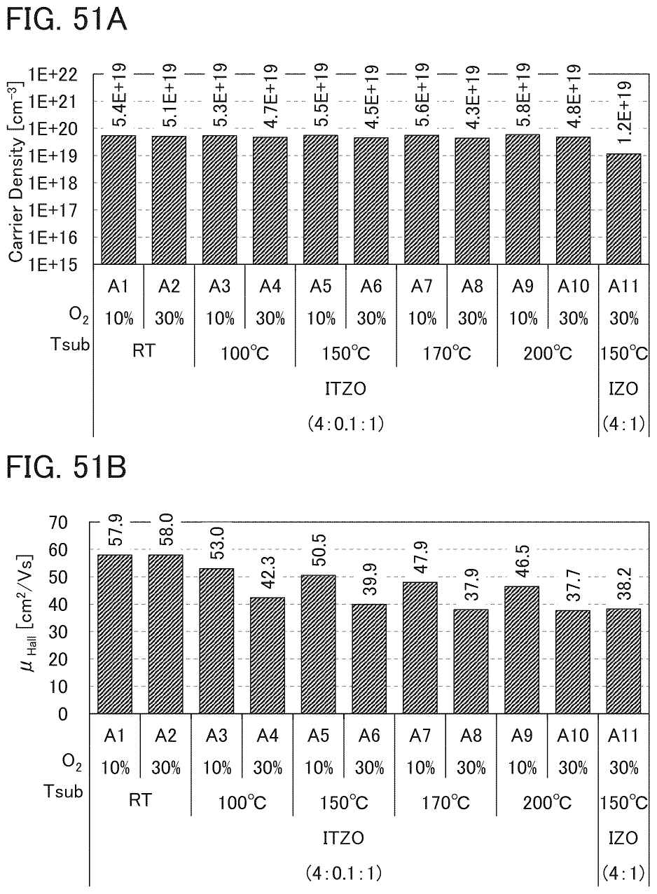

FIG. 51A shows the carrier concentrations of Sample A1 to Sample A11, and FIG. 51B shows the Hall effect mobilities. In FIG. 51A, the horizontal axis represents the sample name and the formation condition of the metal oxide film, and the vertical axis represents the carrier concentration (Carrier Density). In FIG. 51B, the horizontal axis represents the sample name and the formation condition of the metal oxide film, and the vertical axis represents the Hall effect mobility (μ_{Hall}).

As shown in FIG. 51A and FIG. 51B, it was found that Sample A1 to Sample A10 using an ITZO sputtering target for forming the metal oxide film tended to have a slightly higher carrier concentration than Sample A11 using an IZO sputtering target. It was also confirmed that the Hall effect mobilities of Sample A1 to Sample A10 was substantially the same as the Hall effect mobility of Sample A11.

### Example 2

In this example, metal oxide films that can be used in a semiconductor device of one embodiment of the present invention was evaluated.

In this example, Sample B1 to Sample B5 each including a metal oxide film were fabricated. The formation conditions of the metal oxide film were varied among Sample B1 to Sample B5.

### <Sample Fabrication>

An approximately 100-nm-thick metal oxide film was formed over a glass substrate.

Each of the metal oxide film of Sample B1 and Sample B2 was formed by a sputtering method using an IGZO sputtering target with an atomic ratio of metal elements of In:Ga:Zn=1:1:1. In Sample B1 and Sample B2, the substrate temperature was 200° C. A mixed gas of an oxygen gas and an argon gas was used as a deposition gas, and the oxygen flow rate ratio was varied between Sample B1 and Sample B2. In Sample B1, the oxygen flow rate ratio was 10%. In Sample B2, the oxygen flow rate ratio was 50%.

Each of the metal oxide film of Sample B3 to Sample B5 was formed by a sputtering method using an IGZO sputtering target with an atomic ratio of metal elements of In:Ga:Zn=1:3:4. A mixed gas of an oxygen gas and an argon gas was used as a deposition gas. The substrate temperature and the oxygen flow rate ratio at the time of formation were varied among Sample B3 to Sample B5. In Sample B3, the substrate was not heated and the oxygen flow rate ratio was 10% at the time of formation. In Sample B4, the substrate temperature was 200° C. and the oxygen flow rate ratio was 10%. In Sample B5, the substrate temperature was 200° C. and the oxygen flow rate ratio of was 50%.

### <X-Ray Diffraction Analysis>

Next, X-ray diffraction (XRD) analysis was performed on Sample B1 to Sample B5.

In the XRD analysis, a θ-2θ scanning method which is a kind of an out-of-plane method was used. In the XRD analysis, a Cu-Kα ray (λ=0.15418 nm) was used as an X-ray source, the scanning range at 2θ was 15 deg. to 50 deg., the step width was 0.01 deg., and the scanning speed was 6.0 deg./min.

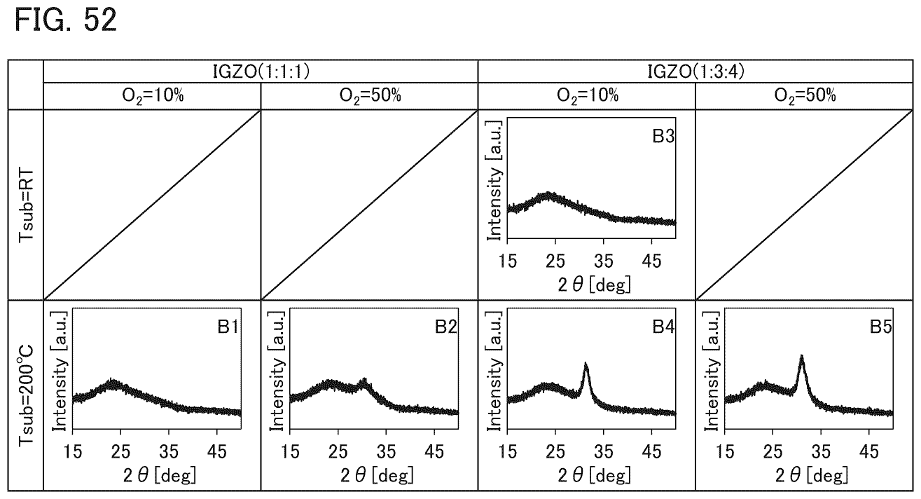

FIG. 52 shows results of XRD analysis of Sample B1 to Sample B5. In FIG. 52, each horizontal axis represents the diffraction angle 2θ and each vertical axis represents the intensity of diffraction X-ray. Note that broad peaks where 2θ is at around 24 deg. are derived from the glass substrate. In FIG. 52, both the conditions of the substrate temperature (denoted by “Tsub”) and the oxygen flow rate ratio (denoted by “02”) at the time of forming the metal oxide film are shown, and the condition where heating of the substrate was not performed at the time of formation is denoted by “Tsub=RT”.

As shown in FIG. 52, Sample B3 to Sample B5 each formed using an IGZO sputtering target with an atomic ratio of In:Ga:Zn=1:3:4 were found to have a higher peak level and higher crystallinity than Sample B1 and Sample B2 each formed using an IGZO sputtering target with an atomic ratio of In:Ga:Zn=1:1:1. It was also confirmed that when the substrate temperature or the oxygen flow rate ratio at the time of forming the metal oxide film is increased, the peak level is increased and the crystallinity is increased.

### <Band Gap>

Next, the band gaps of Sample B1 to Sample B5 were evaluated. Spectroscopic ellipsometry was used for the evaluation.

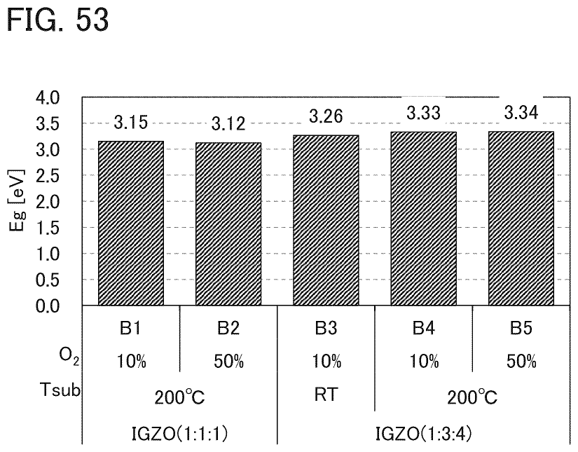

FIG. 53 shows the band gaps of Sample B1 to Sample B5. In FIG. 53, the horizontal axis represents the sample name and the formation condition of the metal oxide film, and the vertical axis represents the band gap (Eg).

As shown in FIG. 53, it was confirmed that Sample B3 to Sample B5 each formed using an IGZO sputtering target with an atomic ratio of In:Ga:Zn=1:3:4 have a wider band gap than Sample B1 and Sample B2 each formed using an IGZO sputtering target with an atomic ratio of In:Ga:Zn=1:1:1.

### Example 3

In this example, semiconductor devices including transistors of one embodiment of the present invention was fabricated and the electrical characteristics of the transistors were evaluated.

In this example, Sample C1 and Sample C2 were fabricated. For the structures of Sample C1 and Sample C2, the description of FIG. 9A and FIG. 9B can be referred to. Note that the conductive layer 112a had the structure illustrated in FIG. 6B. The above description in <Manufacturing method example 1> can be referred to for the fabrication method.

### <Sample Fabrication>

First, an approximately 300-nm-thick copper film to be the conductive layer 112a_1 was formed over the substrate 102 by a sputtering method, and then processed to form the conductive layer 112a_1. Then, an approximately 100-nm-thick In—Sn—Si oxide (ITSO) film to be the conductive layer 112a_2 was formed by a sputtering method, and then processed to form the conductive layer 112a_2, whereby the conductive layer 112a was obtained. A glass substrate with a size of 600 mm×720 mm was used as the substrate 102.

Next, an approximately 70-nm-thick silicon nitride film was formed as a first insulating film to be the insulating layer 110d, an approximately 100-nm-thick silicon nitride film was formed as a second insulating film (the insulating film 110af) to be the insulating layer 110a, and an approximately 500-nm-thick silicon oxynitride film was formed as a third insulating film (the insulating film 110bf) to be the insulating layer 110b. The first insulating film, the second insulating film, and the third insulating film were successively formed using the same apparatus by a PECVD method. Silane (SiH₄), nitrogen (N₂), and ammonia (NH₃) were used as a deposition gas used for forming the first insulating film, and silane (SiH₄) and nitrogen (N₂) were used as a deposition gas used for forming the second insulating film (the insulating film 110af). That is, the ammonia flow rate ratio at the time of forming the first insulating film was made higher than the ammonia flow rate ratio at the time of forming the second insulating film (the insulating film 110af).

Next, an approximately 20-nm-thick IGZO film was formed as the film 130 over the third insulating film (the insulating film 110bf). The film 130 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the film 130 was removed. The film 130 was removed by a wet etching method.

Next, an approximately 5-nm-thick IGZO film was formed as the film 139 over the third insulating film (the insulating film 110bf) by a sputtering method. The film 139 was formed using an IGZO sputtering target with an atomic ratio of metal elements of In:Ga:Zn=4:2:4.1.

Subsequently, plasma treatment was performed in an atmosphere containing oxygen. An ashing apparatus was used for the plasma treatment.

Next, the film 139 was removed. The film 139 was removed by a wet etching method.

Next, an approximately 50-nm-thick silicon nitride film was formed as a fourth insulating film (the insulating film 110cf) to be the insulating layer 110c over the third insulating film (the insulating film 110bf), and an approximately 100-nm-thick silicon nitride film was formed as a fifth insulating film to be the insulating layer 110e. The fourth insulating film and the fifth insulating film were successively formed using the same apparatus by a PECVD method. Silane (SiH₄) and nitrogen (N₂) were used as a deposition gas for forming the fourth insulating film (insulating film 110cf), and silane (SiH₄), nitrogen (N₂), and ammonia (NH₃) were used as a deposition gas for forming the fifth insulating film. That is, the ammonia flow rate ratio at the time of forming the fifth insulating film was made higher than the ammonia flow rate ratio at the time of forming the fourth insulating film (the insulating film 110cf).

Then, an approximately 100-nm-thick In—Sn—Si oxide (ITSO) film was formed as the conductive film 112bf over the fifth insulating film by a sputtering method.

Subsequently, the conductive film 112bf was processed to obtain the conductive layer 112B.

Next, the conductive layer 112B in a region overlapping with the conductive layer 112a was removed to form the conductive layer 112b including the opening 143, and the first insulating film to the fifth insulating film in a region overlapping with the conductive layer 112a were removed to form the insulating layer 110 including the opening 141. The conductive layer 112B was removed by a wet etching method. The first insulating film to the fifth insulating film were removed by a dry etching method. The top surface shapes of the opening 141 and the opening 143 were circles.

Subsequently, the metal oxide film 108f was formed to cover the opening 141 and the opening 143. As the metal oxide film 108f, an approximately 1-nm-thick metal oxide film 108af, an approximately 10-nm-thick metal oxide film 108bf over the metal oxide film 108af, and an approximately 5-nm-thick metal oxide film 108cf over the metal oxide film 108bf were formed.

The formation conditions of the metal oxide film 108af were varied between Sample C1 and Sample C2. The metal oxide film 108af of Sample C1 was formed by a sputtering method using an IGZO sputtering target with an atomic ratio of metal elements of In:Ga:Zn=1:1:1. The metal oxide film 108af of Sample C2 was formed by a sputtering method using an IGZO sputtering target with an atomic ratio of metal elements of In:Ga:Zn=1:3:4.

The metal oxide film 108bf of each of Sample C1 and Sample C2 was formed by a sputtering method using an IGZO sputtering target with an atomic ratio of metal elements of In:Zn=4:1.

The metal oxide layer 108cf in each of Sample C1 and Sample C2 was formed by a sputtering method using an IGZO sputtering target with an atomic ratio of metal elements of In:Ga:Zn=1:3:4.

Note that in each of Sample C1 and Sample C2, the surface of the metal oxide film 108af was exposed to the air after formation of the metal oxide film 108af, and then the metal oxide film 108bf was formed. The surface of the metal oxide film 108bf is exposed to the air after the formation of the metal oxide film 108bf, and then the metal oxide film 108cf is formed.

Then, the metal oxide film 108f was processed to obtain the semiconductor layer 108.

Next, heat treatment was performed at 350° C. in a dry air atmosphere for one hour. An oven apparatus was used for the heat treatment.

Next, an approximately 50-nm-thick silicon oxynitride film was deposited as the insulating layer 106 by a plasma CVD method.

Next, an approximately 50-nm-thick titanium film, an approximately 200-nm-thick aluminum film, and an approximately 50-nm-thick titanium film were each deposited by a sputtering method. After that, the conductive films were processed to obtain the conductive layer 104.

Thus, a transistor corresponding to the transistor 100 was formed.

Next, as the insulating layer 195, an approximately 300-nm-thick silicon nitride oxide film was formed by a plasma CVD method.

Then, heat treatment was performed at 300° C. in a dry air atmosphere for one hour. An oven apparatus was used for the heat treatment.

Next, an approximately 1.5-μm-thick polyimide film was formed as a protective layer.

Then, heat treatment was performed at 250° C. in a nitrogen atmosphere for one hour.

An oven apparatus was used for the heat treatment.

Through the above process, Sample C1 and Sample C2 were obtained.

### <Id-Vg Characteristics>

Then, the Id-Vg characteristics of the transistors in Sample C1 and Sample C2 fabricated above were measured.

For measuring the Id-Vg characteristics of the transistors, a voltage applied to a gate electrode (hereinafter also referred to as gate voltage (Vg)) was applied from −10 V to +10 V in increments of 0.1 V. Moreover, a voltage applied to a source electrode (hereinafter also referred to as source voltage (Vs)) was 0 V (comm), and a voltage applied to a drain electrode (hereinafter also referred to as drain voltage (Vd)) was 0.1 V and 5.1 V.

Here, the measurement was performed on the transistor with the channel width W100 of approximately 6.3 m (the width D141 of the opening 141 of 2.0 μm). The number of measurements was set to 20 in a substrate plane of 600 mm×720 mm. Note that the channel length L100 was approximately 0.5 μm.

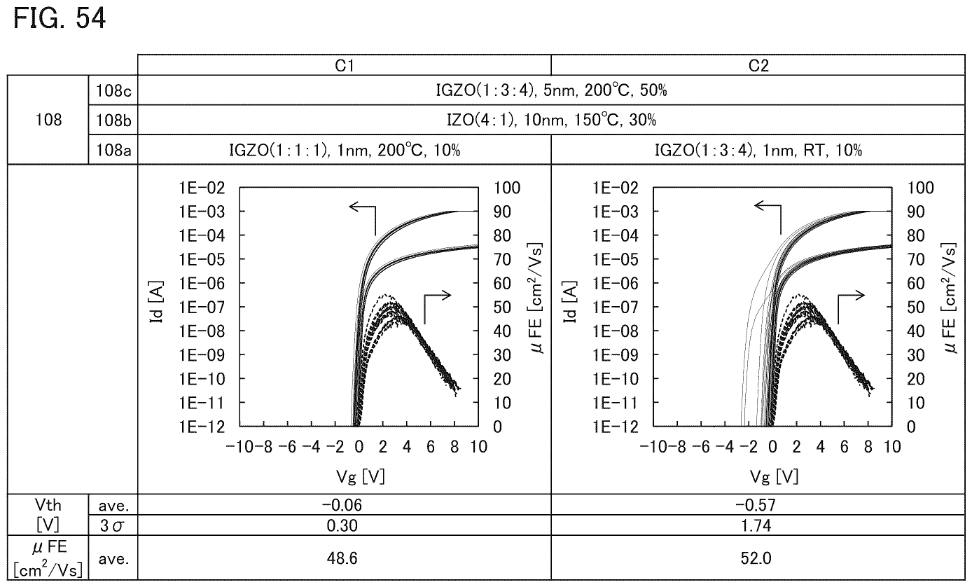

FIG. 54 shows the Id-Vg characteristics of Sample C1 and Sample C2. In FIG. 54, the Id-Vg characteristics of Sample C1 are shown on the left side, and the Id-Vg characteristics of Sample C2 are shown on the right side. The horizontal axis represents a gate voltage (Vg), the left vertical axis represents a drain current (Id), and the right vertical axis represents a field-effect mobility (FE) at a drain voltage (Vd) of 5.1 V. FIG. 54 shows superimposed Id-Vg characteristics of 20 transistors for each sample. In addition, the average value (ave.) of the threshold voltages (Vth), 3σ, and the average value (ave.) of the field-effect mobility (μFE), which are obtained from the Id-Vg characteristics, the sample name, and the conditions for the semiconductor layers 108 are also shown. Note that σ represents a standard deviation.

As shown in FIG. 54, it was found that all of a threshold voltage (Vth) close to 0 V, a high on-state current, and a low off-state current were achieved in Sample C1. In addition, it was confirmed that Sample C1 has a smaller in-plane variation in electrical characteristics than Sample C2.

### <Reliability>

Next, the reliability of Sample C1 and Sample C2 were evaluated.

To evaluate the reliability, a GBT (Gate Bias Temperature) stress test was performed. Specifically, a PBTS (Positive Bias Temperature Stress) test and an NBTIS (Negative Bias Temperature Illumination Stress) test were performed.

Note that a test in which a state where a positive potential (positive bias) relative to a source potential and a drain potential is supplied to a gate is maintained at high temperatures is referred to as a PBTS test, and a test in which a state where a negative potential (negative bias) is supplied to a gate is maintained at high temperatures is referred to as an NBTS (Negative Bias Temperature Stress) test. The PBTS test and the NBTS test performed in a state where irradiation with light is performed are respectively referred to as a PBTIS (Positive Bias Temperature Illumination Stress) test and an NBTIS test.

In the PBTS test, the substrate over which the transistors were formed was held at 60° C., a voltage of 0.1 V was applied to the source and the drain of each transistor, and a voltage of 15 V was applied to the gate thereof; this state was maintained for one hour. Note that the gate insulating layer had a thickness of approximately 50 nm, and a voltage at which the electric field intensity of the gate becomes approximately 3 MV/cm was applied to the gate. The test was performed in a dark environment.

In the NBTIS test, the substrate over which the transistors were formed was held at 60° C., a voltage of 0 V was applied to the source and the drain of each transistor and a voltage of −15 V was applied to the gate thereof in a state where irradiation with white LED light at 5000 lx was performed; this state was maintained for one hour. The irradiation with white LED light was performed from the glass substrate side.

In the PBTS test and the NBTIS test, the transistor with the channel width W100 of approximately 6.3 m (the width D141 of the opening 141 of 2.0 μm) was used. Note that the channel length L100 was approximately 0.5 μm.

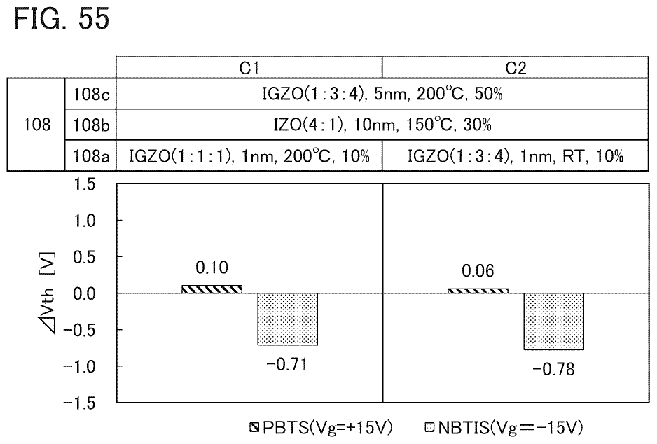

FIG. 55 shows the amounts of change (ΔVth) in threshold voltage of Sample C1 and Sample C2 between before and after the PBTS test and between before and after the NBTIS test. In FIG. 55, the amount of change in the threshold voltage of Sample C1 is shown on the left, and the amount of change in the threshold voltage of Sample C2 is shown on the right.

As shown in FIG. 55, it was confirmed that both the amounts of change in threshold voltage between before and after the PBTS test and between before and after the NBTIS test were small, indicating high reliability.

From the above results, it was confirmed that a transistor with a short channel length, favorable electrical characteristics, and high reliability was obtained.

### Example 4

In this example, semiconductor devices including transistors of one embodiment of the present invention was fabricated and the electrical characteristics of the transistors were evaluated.

In this example, Sample D1 to Sample D6 were fabricated. For the structures of Sample D1 to Sample D6, the description of the semiconductor device 10A illustrated in FIG. 9A and FIG. 9B can be referred to. Note that the conductive layer 112a had the structure illustrated in FIG. 6C. The insulating layer 110b had the structure illustrated in FIG. 10A to FIG. 10C. The above description in <Manufacturing method example 2> can be referred to for the fabrication method.

### <Sample Fabrication>

First, an approximately 10-nm-thick first In—Sn—Si oxide (ITSO) film to be the conductive layer 112a_3 was formed over the substrate 102 by a sputtering method. Next, an approximately 100-nm-thick copper film to be the conductive layer 112a_1 was formed over the first In—Sn—Si oxide (ITSO) film by a sputtering method, and then processed to form the conductive layer 112a_1. Then, an approximately 10-nm-thick second In—Sn—Si oxide (ITSO) film to be the conductive layer 112a_2 was formed by a sputtering method. Sequentially, the first In—Sn—Si oxide (ITSO) film and the second In—Sn—Si oxide (ITSO) film were processed to form the conductive layer 112a_3 and the conductive layer 112a_2, whereby the conductive layer 112a was obtained. A glass substrate with a size of 600 mm×720 mm was used as the substrate 102.

Next, an approximately 70-nm-thick silicon nitride film was formed as a first insulating film to be the insulating layer 110d, an approximately 100-nm-thick silicon nitride film was formed as a second insulating film (the insulating film 110af) to be the insulating layer 110a, an approximately 250-nm-thick silicon oxynitride film was formed as a third insulating film (the insulating film 110bf_1) to be the insulating layer 110b_1, plasma treatment is performed, and an approximately 250-nm-thick silicon oxynitride film was formed as a fourth insulating film (the insulating film 110bf_2) to be the insulating layer 110b_2. The formation of the first insulating film, the formation of the second insulating film, the formation of the third insulating film, the plasma treatment, and the formation of the fourth insulating film were performed successively using the same PECVD apparatus. Silane (SiH₄), nitrogen (N₂), and ammonia (NH₃) were used as a deposition gas used for forming the first insulating film, and silane (SiH₄) and nitrogen (N₂) were used as a deposition gas used for forming the second insulating film (the insulating film 110af). That is, the ammonia flow rate ratio at the time of forming the first insulating film was made higher than the ammonia flow rate ratio at the time of forming the second insulating film (the insulating film 110af). The plasma treatment was performed in a dinitrogen monoxide (N₂O) atmosphere.

Next, an approximately 20-nm-thick IGZO film was formed as the film 130 over the fourth insulating film (the insulating film 110bf_2). The film 130 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the film 130 was removed. The film 130 was removed by a wet etching method.

Next, an approximately 5-nm-thick IGZO film was formed as the film 139 over the fourth insulating film (the insulating film 110bf_2) by a sputtering method. The film 139 was formed using an IGZO sputtering target with an atomic ratio of metal elements of In:Ga:Zn=4:2:4.1.

Subsequently, plasma treatment was performed in an atmosphere containing oxygen. An ashing apparatus was used for the plasma treatment.

Next, the film 139 was removed. The film 139 was removed by a wet etching method.

Next, an approximately 50-nm-thick silicon nitride film was formed as the fifth insulating film (the insulating film 110cf) to be the insulating layer 110c over the fourth insulating film (the insulating film 110bf_2), and an approximately 100-nm-thick silicon nitride film was formed as a sixth insulating film to be the insulating layer 110e. The fifth insulating film and the sixth insulating film were successively formed using the same apparatus by a PECVD method. Silane (SiH₄) and nitrogen (N₂) were used as a deposition gas for forming the fifth insulating film (the insulating film 110cf), and silane (SiH₄), nitrogen (N₂), and ammonia (NH₃) were used as a deposition gas for forming the sixth insulating film. That is, the ammonia flow rate ratio at the time of forming the sixth insulating film was made higher than the ammonia flow rate ratio at the time of forming the fifth insulating film (the insulating film 110cf).

Then, an approximately 100-nm-thick In—Sn—Si oxide (ITSO) film was formed as the conductive film 112bf over the sixth insulating film by a sputtering method.

Subsequently, the conductive film 112bf was processed to obtain the conductive layer 112B.

Next, the conductive layer 112B in a region overlapping with the conductive layer 112a was removed to form the conductive layer 112b including the opening 143, and the first insulating film to the sixth insulating film in a region overlapping with the conductive layer 112a were removed to form the insulating layer 110 including the opening 141. The conductive layer 112B was removed by a wet etching method. The first insulating film to the sixth insulating film were removed by a dry etching method. The top surface shapes of the opening 141 and the opening 143 were circles.

Subsequently, the metal oxide film 108f was formed to cover the opening 141 and the opening 143. As the metal oxide film 108f, an approximately 1-nm-thick metal oxide film 108af, an approximately 9-nm-thick metal oxide film 108bf over the metal oxide film 108af, and an approximately 3-nm-thick metal oxide film 108cf over the metal oxide film 108bf were formed.

The metal oxide film 108af in each of Sample D1 to Sample D6 was formed by a sputtering method using an IGZO sputtering target with an atomic ratio of metal elements of In:Ga:Zn=1:1:1. In the formation of the metal oxide film 108af, a sputtering apparatus including an AC power source was used, and the substrate temperature at the time of the formation was 200° C. A mixed gas of an oxygen gas and an argon gas was used as a deposition gas, and the oxygen flow rate ratio was 10%.

The formation conditions of the metal oxide film 108bf were varied among Sample D1 to Sample D6.

Each of the metal oxide film 108bf in Sample D1 and Sample D5 was formed by a sputtering method using an ITZO sputtering target with an atomic ratio of metal elements of In:Sn:Zn=40:1:10 (4:0.1:1). For the formation of the metal oxide film 108bf in each of Sample D1 and Sample D5, a sputtering apparatus including an AC power source was used, and a mixed gas of an oxygen gas and an argon gas was used as a deposition gas. The substrate temperature and the oxygen flow rate ratio at the time of formation were varied among Sample D1 to Sample D5. In Sample D1, the substrate was not heated and the oxygen flow rate ratio was 10% at the time of formation. In Sample D2, the substrate temperature was 100° C. and the oxygen flow rate ratio was 10% at the time of formation. In Sample D3, the substrate temperature was 150° C. and the oxygen flow rate ratio was 10% at the time of formation. In Sample D4, the substrate temperature was 150° C. and the oxygen flow rate ratio was 30% at the time of formation. In Sample D5, the substrate temperature was 200° C. and the oxygen flow rate ratio was 10% at the time of formation.

The metal oxide film 108bf in Sample D6 was formed by a sputtering method using an IZO sputtering target with an atomic ratio of metal elements of In:Zn=4:1. For the formation of the metal oxide film 108af in Sample D6, a sputtering apparatus including a DC power source was used, and the substrate temperature at the time of the formation was 150° C. A mixed gas of an oxygen gas and an argon gas was used as a deposition gas, and the oxygen flow rate ratio was 30

The metal oxide film 108cf in each of Sample D1 to Sample D6 was formed by a sputtering method using an IGZO sputtering target with an atomic ratio of metal elements of In:Ga:Zn=1:3:4. The metal oxide film 108cf was formed using a sputtering apparatus including an AC power source, and the substrate temperature at the time of the formation was 200° C. A mixed gas of an oxygen gas and an argon gas was used as a deposition gas, and the oxygen flow rate ratio was 50%.

Note that in Sample D1 to Sample D5, the metal oxide film 108af, the metal oxide film 108bf, and the metal oxide film 108cf were successively formed with the same apparatus. That is, in Sample D1 to Sample D5, the metal oxide film 108bf was formed without exposure of the surface of the metal oxide film 108af to the air, and the metal oxide film 108cf was formed without exposure of the surface of the metal oxide film 108bf to the air. Meanwhile, in Sample D6, after formation of the metal oxide film 108af, the surface of the metal oxide film 108af was exposed to the air, and then the metal oxide film 108bf was formed. After formation of the metal oxide film 108bf, the surface of the metal oxide film 108bf was exposed to the air, and then the metal oxide film 108cf was formed.

Next, heat treatment was performed at 350° C. in a dry air atmosphere for one hour. An oven apparatus was used for the heat treatment.

Then, the metal oxide film 108f was processed to obtain the semiconductor layer 108.

Next, an approximately 50-nm-thick silicon oxynitride film was deposited as the insulating layer 106 by a plasma CVD method.

Next, an approximately 50-nm-thick titanium film, an approximately 200-nm-thick aluminum film, and an approximately 50-nm-thick titanium film were each deposited by a sputtering method. After that, the conductive films were processed to obtain the conductive layer 104.

Thus, a transistor corresponding to the transistor 100 was formed.

Next, as the insulating layer 195, an approximately 300-nm-thick silicon nitride oxide film was formed by a plasma CVD method.

Then, heat treatment was performed at 300° C. in a dry air atmosphere for one hour. An oven apparatus was used for the heat treatment.

Next, an approximately 1.5-μm-thick polyimide film was formed as a protective layer.

Then, heat treatment was performed at 250° C. in a nitrogen atmosphere for one hour.

An oven apparatus was used for the heat treatment.

Through the above steps, Sample D1 to Sample D6 were obtained.

### <Id-Vg Characteristics>

Next, the Id-Vg characteristics of the transistors in Sample D1 to Sample D6 fabricated above were measured.

For measuring the Id-Vg characteristics of the transistors, a voltage applied to a gate electrode (hereinafter also referred to as gate voltage (Vg)) was applied from −10 V to +10 V in increments of 0.1 V. Moreover, a voltage applied to a source electrode (hereinafter also referred to as source voltage (Vs)) was 0 V (comm), and a voltage applied to a drain electrode (hereinafter also referred to as drain voltage (Vd)) was 0.1 V and 5.1 V.

Here, the measurement was performed on the transistor with the channel width W100 of approximately 6.3 m (the width D141 of the opening 141 of 2.0 μm). The number of measurements was set to 20 in a substrate plane of 600 mm×720 mm. Note that the channel length L100 was approximately 0.5 μm.

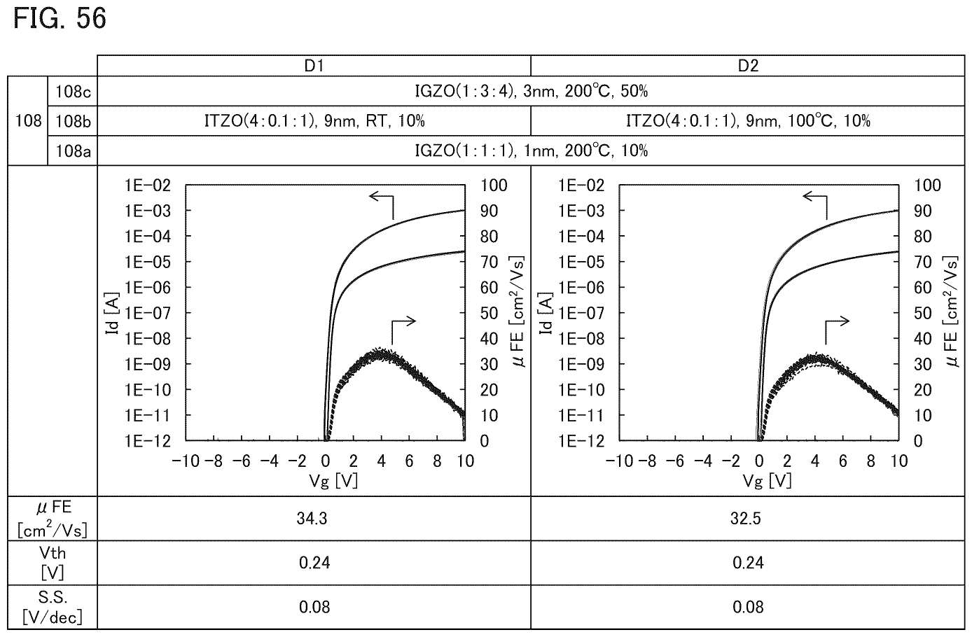

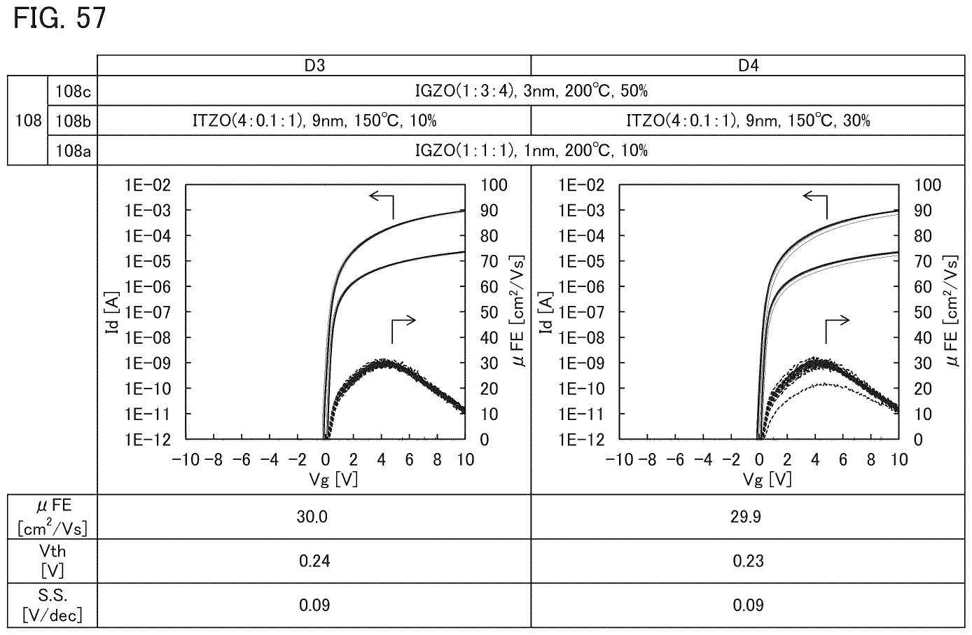

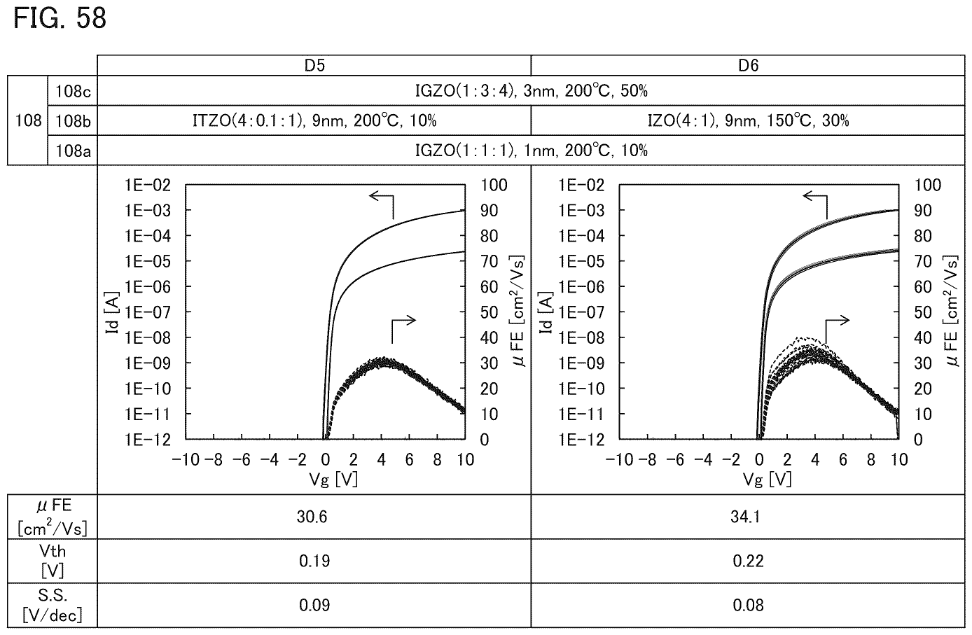

FIG. 56 shows the Id-Vg characteristics of Sample D1 and Sample D2, FIG. 57 shows the Id-Vg characteristics of Sample D3 and Sample D4, and FIG. 58 shows the Id-Vg characteristics of Sample D5 and Sample D6. In FIG. 56 to FIG. 58, the horizontal axis represents a gate voltage (Vg), the left vertical axis represents a drain current (Id), and the right vertical axis represents a field-effect mobility (FE) at a drain voltage (Vd) of 5.1 V. FIG. 56 to FIG. 58 show superimposed Id-Vg characteristics of 20 transistors for each sample. In addition, the average value of the field-effect mobility (FE), the average value of the threshold voltage (Vth), and the average value of the subthreshold swing value (S value), which are obtained from the Id-Vg characteristics, the sample name, and the conditions for the semiconductor layers 108 are also shown. Note that in FIG. 56 to FIG. 58, the subthreshold swing value is denoted by “S.S.”.

As shown in FIG. 56 to FIG. 58, it was confirmed that all of high electric effect mobility, a threshold voltage close to 0 V, and a small S value were achieved in each sample. In each of Sample D1 to Sample D5, when the substrate temperature at the time of forming the metal oxide film to be the semiconductor layer 108b was reduced, the field-effect mobility tended to increase. It is considered that reducing the substrate temperature at the time of forming the metal oxide film reduces the crystallinity of the semiconductor layer 108b and increases the electric conductivity of the semiconductor layer 108b, so that the field-effect mobility is increased.

### Example 5

In this example, semiconductor devices including transistors of one embodiment of the present invention was fabricated and the electrical characteristics of the transistors were evaluated.

In this example, Sample E1 and Sample E2 were fabricated. For the structures of Samples E1 and E2, the description of the semiconductor device 10C illustrated in FIG. 12A and FIG. 12B can be referred to. Note that the conductive layer 112a had the structure illustrated in FIG. 6C. The above description in <Manufacturing method example 1> can be referred to for the fabrication method.

### <Sample Fabrication>

First, as the insulating layer 109, an approximately 30-nm-thick silicon nitride film was formed by a PECVD method over the substrate 102. A glass substrate with a size of 600 mm×720 mm was used as the substrate 102.

Next, an approximately 10-nm-thick first ITSO film to be the conductive layer 112a_3 was formed by a sputtering method. Next, an approximately 100-nm-thick copper film to be the conductive layer 112a_1 was formed over the first ITSO film by a sputtering method, and then processed to form the conductive layer 112a_1. Next, an approximately 100-nm-thick second ITSO film to be the conductive layer 112a_2 was formed by a sputtering method. Next, the first ITSO film and the second ITSO film were processed to form the conductive layer 112a_3 and the conductive layer 112a_2, whereby the conductive layer 112a was obtained.

Next, an approximately 100-nm-thick silicon nitride film was formed as the first insulating film (the insulating film 110af) to be the insulating layer 110a, and an approximately 500-nm-thick silicon oxynitride film was formed as a second insulating film (the insulating film 110bf) to be the insulating layer 110b. Formation of the first insulating film and the second insulating film was performed successively using the same PECVD apparatus. Silane (SiH₄), nitrogen (N₂), and ammonia (NH₃) were used as a deposition gas used for forming the insulating layer 109, and silane (SiH₄) and nitrogen (N₂) were used as a deposition gas used for forming the first insulating film (the insulating film 110af). That is, the ammonia flow rate ratio at the time of forming the insulating layer 109 was made higher than the ammonia flow rate ratio at the time of forming the first insulating film (the insulating film 110af).

Next, an approximately 20-nm-thick IGZO film was formed as the film 130 over the second insulating film (the insulating film 110bf). The film 130 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the film 130 was removed. The film 130 was removed by a wet etching method.

Next, an approximately 5-nm-thick IGZO film was formed as the film 139 over the second insulating film (the insulating film 110bf) by a sputtering method. The film 139 was formed using an IGZO sputtering target with an atomic ratio of metal elements of In:Ga:Zn=1:1:1.

Subsequently, plasma treatment was performed in an atmosphere containing oxygen. An ashing apparatus was used for the plasma treatment.

Next, the film 139 was removed. The film 139 was removed by a wet etching method.

Next, an approximately 50-nm-thick silicon nitride film was formed as the third insulating film (the insulating film 110cf) to be the insulating layer 110c over the second insulating film (the insulating film 110bf), and an approximately 100-nm-thick silicon nitride film was formed as the fourth insulating film to be the insulating layer 110e. The third insulating film and the fourth insulating film were successively formed using the same apparatus by a PECVD method. Silane (SiH₄) and nitrogen (N₂) were used as a deposition gas for forming the third insulating film (the insulating film 110cf), and silane (SiH₄), nitrogen (N₂), and ammonia (NH₃) were used as a deposition gas for forming the fourth insulating film. That is, the ammonia flow rate ratio at the time of forming the fourth insulating film was made higher than the ammonia flow rate ratio at the time of forming the third insulating film (the insulating film 110cf).

Then, an approximately 100-nm-thick ITSO film was formed as the conductive film 112bf over the fourth insulating film by a sputtering method.

Subsequently, the conductive film 112bf was processed to obtain the conductive layer 112B.

Next, the conductive layer 112B in a region overlapping with the conductive layer 112a was removed to form the conductive layer 112b including the opening 143, and the first insulating film to the fourth insulating film in a region overlapping with the conductive layer 112a were removed to form the insulating layer 110 including the opening 141. The conductive layer 112B was removed by a wet etching method. The first insulating film to the fourth insulating film were removed by a dry etching method. The top surface shapes of the opening 141 and the opening 143 were circles.

Subsequently, the metal oxide film 108f was formed to cover the opening 141 and the opening 143. As the metal oxide film 108f, an approximately 1-nm-thick metal oxide film 108af, an approximately 9-nm-thick metal oxide film 108bf over the metal oxide film 108af, and an approximately 3-nm-thick metal oxide film 108cf over the metal oxide film 108bf were formed.

The metal oxide film 108af was formed by a sputtering method using an IGZO sputtering target with an atomic ratio of metal elements of In:Ga:Zn=1:1:1. The metal oxide film 108bf was formed by a sputtering method using an ITZO sputtering target with an atomic ratio of metal elements of In:Sn:Zn=40:1:10 (4:0.1:1). The metal oxide film 108cf was formed by a sputtering method using an IGZO sputtering target with an atomic ratio of metal elements of In:Ga:Zn=1:3:4.

Note that in Sample E1, after formation of the metal oxide film 108af, the surface of the metal oxide film 108af was exposed to the air, and then the metal oxide film 108bf was formed. After the formation of the metal oxide film 108bf, the surface of the metal oxide film 108bf was exposed to the air, and then the metal oxide film 108cf was formed. Meanwhile, in Sample E2, the metal oxide film 108af, the metal oxide film 108bf, and the metal oxide film 108cf were successively formed in the same apparatus. That is, in Sample E2, the metal oxide film 108bf was formed without exposure of the surface of the metal oxide film 108af to the air, and the metal oxide film 108cf was formed without exposure of the surface of the metal oxide film 108bf to the air.

Next, heat treatment was performed at 350° C. in a dry air atmosphere for one hour. An oven apparatus was used for the heat treatment.

Then, the metal oxide film 108f was processed to obtain the semiconductor layer 108.

Next, an approximately 50-nm-thick silicon oxynitride film was deposited as the insulating layer 106 by a plasma CVD method.

Next, an approximately 50-nm-thick titanium film, an approximately 200-nm-thick aluminum film, and an approximately 50-nm-thick titanium film were each deposited by a sputtering method. After that, the conductive films were processed to obtain the conductive layer 104.

Thus, a transistor corresponding to the transistor 100 was formed.

Next, as the insulating layer 195, an approximately 300-nm-thick silicon nitride oxide film was formed by a plasma CVD method.

Then, heat treatment was performed at 300° C. in a dry air atmosphere for one hour. An oven apparatus was used for the heat treatment.

Next, an approximately 1.5-μm-thick polyimide film was formed as a protective layer.

Then, heat treatment was performed at 250° C. in a nitrogen atmosphere for one hour. An oven apparatus was used for the heat treatment.

Through the above steps, Sample E1 and Sample E2 were obtained.

### <Id-Vg Characteristics>

Next, the Id-Vg characteristics of the transistors in Sample E1 and Sample E2 fabricated above were measured.

For measuring the Id-Vg characteristics of the transistors, a voltage applied to a gate electrode (hereinafter also referred to as gate voltage (Vg)) was applied from −10 V to +10 V in increments of 0.1 V. Moreover, a voltage applied to a source electrode (hereinafter also referred to as source voltage (Vs)) was 0 V (comm), and a voltage applied to a drain electrode (hereinafter also referred to as drain voltage (Vd)) was 0.1 V and 5.1 V.

Here, the measurement was performed on the transistor with the channel width W100 of approximately 6.3 m (the width D141 of the opening 141 of 2.0 μm). The number of measurements was set to 120 in a substrate plane of 600 mm×720 mm. Note that the channel length L100 was approximately 0.5 μm.

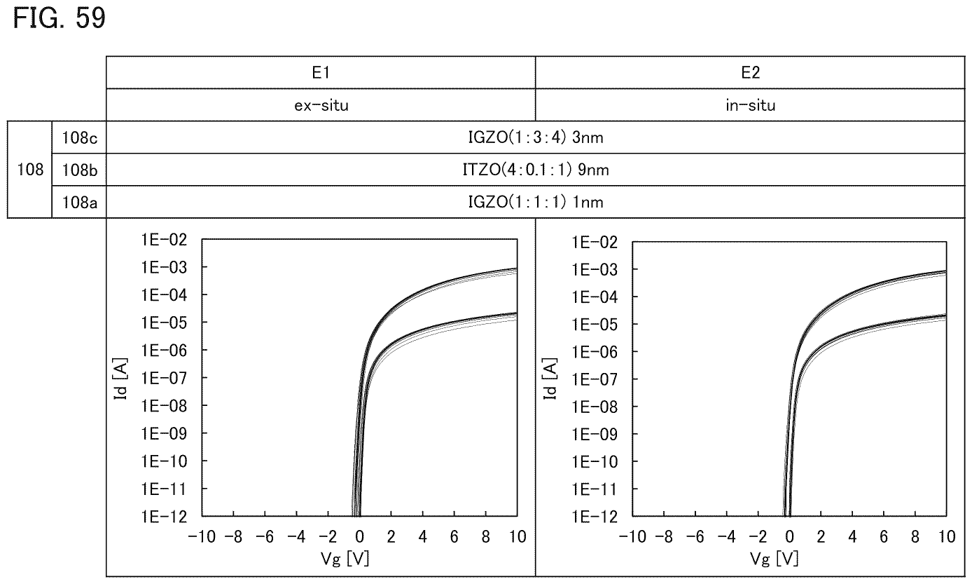

FIG. 59 shows the Id-Vg characteristics of Sample E1 and Sample E2. In FIG. 59, the horizontal axis represents the gate voltage (Vg) and the vertical axis represents the drain current (Id). FIG. 59 shows superimposed Id-Vg characteristics of 20 transistors for each sample. In addition, in FIG. 59, “ex-situ” and “in-situ” are written for Sample E1 and Sample E2, respectively, as well as the sample name and the conditions for the semiconductor layer 108.

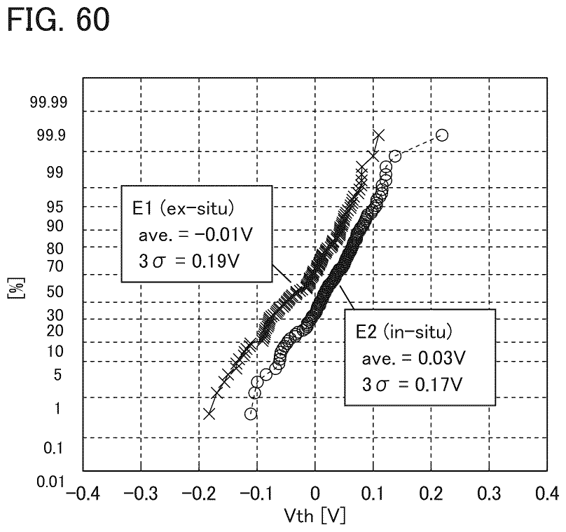

FIG. 60 shows probability distribution of the threshold voltage (Vth) obtained from the Id-Vg characteristics. In FIG. 60, the horizontal axis represents the threshold voltage (Vth) and the vertical axis represents the cumulative probability. FIG. 60 shows the values of the threshold voltages (Vth) of 120 transistors for each sample. FIG. 60 also shows the average value (ave.) and 3σ of the threshold voltage (Vth). Note that σ represents a standard deviation.

It was confirmed that favorable electrical characteristics can be obtained in all the samples as shown in FIG. 59 to FIG. 60. It was also confirmed that when Sample E1 and Sample E2 are compared, Sample E2 has a higher threshold voltage in the positive direction and a smaller variation of the threshold voltage in the negative direction than Sample E1. It is considered that the threshold voltage of Sample E2 was increased in the positive direction because impurities derived from the air are inhibited from attaching to the surface of the insulating film 110af and the surface of the insulating film 110bf by successive formation of the metal oxide film 108af, the metal oxide film 108bf, and the metal oxide film 108cf in vacuum.

### <Reliability>

Next, the reliabilities of Sample E1 and Sample E2 was evaluated.

For the reliability evaluation, a GBT stress test was performed. Specifically, the PBTS test and the NBTIS test were performed.

In the PBTS test, the substrate over which the transistors were formed was held at 60° C., a voltage of 0.1 V was applied to the source and the drain of each transistor, and a voltage of 15 V was applied to the gate thereof; this state was maintained for one hour. Note that the gate insulating layer had a thickness of approximately 50 nm, and a voltage at which the electric field intensity of the gate becomes approximately 3 MV/cm was applied to the gate. The test was performed in a dark environment.

In the NBTIS test, the substrate over which the transistors were formed was held at 60° C., a voltage of 0 V was applied to the source and the drain of each transistor and a voltage of −15 V was applied to the gate thereof in a state where irradiation with white LED light at 5000 lx was performed; this state was maintained for one hour. The irradiation with white LED light was performed from the glass substrate side.

In the PBTS test and the NBTIS test, the transistor with the channel width W100 of approximately 6.3 m (the width D141 of the opening 141 of 2.0 μm) was used. Note that the channel length L100 was approximately 0.5 μm.

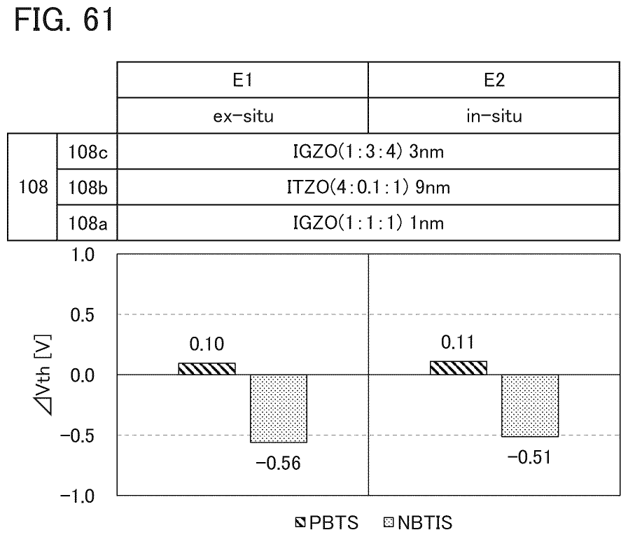

FIG. 61 shows the amounts of change in the threshold voltage (ΔVth) between before and after the PBTS test and between before and after the NBTIS test in Sample E1 and Sample E2.

As shown in FIG. 61, in both samples, the amount of change in the threshold voltage was small in both the PBTS test and the NBTIS test, which confirmed high reliability. Sample E2 had the smaller amount of change in the threshold voltage in the NBTIS test than Sample E1. It is considered that in Sample E2, attachment of impurities derived from the air to the surface of the insulating film 110af and the surface of the insulating film 110bf is inhibited, which leads to the inhibition of oxygen vacancies (Vo) generation in the semiconductor layer 108b.

From the above results, it was confirmed that a transistor with a short channel length, favorable electrical characteristics, and high reliability was obtained.

### Example 6

In this example, the composition of metal oxide films that can be used in a semiconductor device of one embodiment of the present invention was evaluated.

In this example, Sample F1 to Sample F3 were fabricated.

### <Sample Fabrication>

An approximately 35-nm-thick metal oxide film was formed over a silicon wafer.

The metal oxide film of Sample F1 was formed by a sputtering method using an IGZO sputtering target with an atomic ratio of metal elements of In:Ga:Zn=1:1:1. The substrate temperature at the time of formation was 200° C. A mixed gas of an oxygen gas and an argon gas was used as a deposition gas, and the oxygen flow rate ratio was 50%.

The metal oxide film of Sample F2 was formed by a sputtering method using an IGZO sputtering target with an atomic ratio of metal elements of In:Ga:Zn=1:3:4. The substrate temperature at the time of formation was 200° C. A mixed gas of an oxygen gas and an argon gas was used as a deposition gas, and the oxygen flow rate ratio was 50%.

The metal oxide film of Sample F3 was formed by a sputtering method using an ITZO sputtering target with an atomic ratio of metal elements of In:Sn:Zn=40:1:10 (4:0.1:1). The substrate temperature at the time of formation was 200° C. A mixed gas of an oxygen gas and an argon gas was used as a deposition gas, and the oxygen flow rate ratio was 10%.

Through the above process, Sample F1 to Sample F3 were obtained.

### <XPS Analysis>

Next, the compositions of Sample F1 to Sample F3 fabricated above were evaluated by X-ray photoelectron spectroscopy (XPS).

In the XPS analysis, monochromatic A1 Ku radiation (λ=1486.6 eV) was used as an X-ray source. The detection region was less than or equal to 8 mm square, and the extraction angle was 90°. The detection depth was estimated to be approximately 8 nm. The lower detection limit was approximately 1 atomic %.

Table 1 shows the atomic proportion of indium (In), gallium (Ga), zinc (Zn), and tin (Sn) in each sample, which was obtained from the XPS analysis. In Table 1, values normalized on the assumption that the atomic proportion of indium is 1.0 are shown for Sample F1 and Sample F2.

A value normalized on the assumption that the atomic proportion of indium is 4.0 is shown for Sample F3. In Table 1, “-” indicates that the atomic proportion was below the lower detection limit. Table 1 also shows the composition of a sputtering target used for forming the metal oxide film, in addition to the sample name. Note that since the In4d peak was removed by peak deconvolution in the quantification of gallium (Ga), the quantitative error is presumed to be made large. Accordingly, the gallium content percentage shown in Table 1 may have a large error.

TABLE 1

| | | In | Ga | Zn | Sn |
|---|---|---|---|---|---|
| F1 | IGZO(1:1:1) | 1.0 | 0.9 | 0.7 | — |
| F2 | IGZO(1:3:4) | 1.0 | 2.6 | 2.5 | — |
| F3 | ITZO(4:0.1:1) | 4.0 | — | 0.8 | 0.1 |

As shown in Table 1, it was confirmed that the atomic ratio of Sample F1 was In:Ga:Zn=1.0:0.9:0.7, the atomic ratio of Sample F2 was In:Ga:Zn=1.0:2.6:2.5, the atomic ratio of Sample F3 was In:Sn:Zn=4.0:0.1:0.8, and the content percentage of zinc (Zn) in the metal oxide film was lower than the content percentage of zinc (Zn) in the sputtering target. Specifically, it was confirmed that the content percentage of zinc (Zn) in the metal oxide film was reduced to approximately 63% to 80% of the content percentage of zinc (Zn) in the sputtering target.

### REFERENCE NUMERALS

10A: semiconductor device, 10B: semiconductor device, 10C: semiconductor device, 10D: semiconductor device, 10E: semiconductor device, 10F: semiconductor device, 10: semiconductor device, 11B: subpixel, 11G: subpixel, 11R: subpixel, 20A: semiconductor device, 20B: semiconductor device, 20C: semiconductor device, 20D: semiconductor device, 20E: semiconductor device, 20: semiconductor device, 30: semiconductor device, 40: semiconductor device, 50A: display device, 50B: display device, 50C: display device, 50D: display device, 50E: display device, 50F: display device, 50G: display device, 50H: display device, 501: display device, 50J: display device, 50K: display device, 60: liquid crystal element, 100_1: transistor, 100_2: transistor, 100_3: transistor, 100_4: transistor, 100_p: transistor, 100_q: transistor, 100A: transistor, 100B: transistor, 100C: transistor, 100: transistor, 102: substrate, 103: conductive layer, 104: conductive layer, 106a: insulating layer, 106b: insulating layer, 106: insulating layer, 107: insulating layer, 108_1: semiconductor layer, 108_2: semiconductor layer, 108_3: semiconductor layer, 108_4: semiconductor layer, 108a: semiconductor layer, 108af: metal oxide film, 108b: semiconductor layer, 108bf: metal oxide film, 108c: semiconductor layer, 108cf: metal oxide film, 108f: metal oxide film, 108: semiconductor layer, 109: insulating layer, 110a: insulating layer, 110af: insulating film, 110b: insulating layer, 110b_1: insulating layer, 110b_2: insulating layer, 110bf: insulating film, 110bf_1: insulating film, 110bf_2: insulating film, 110c: insulating layer, 110cf: insulating film, 110d: insulating layer, 110e: insulating layer, 110: insulating layer, 111B: pixel electrode, 111G: pixel electrode, 111R: pixel electrode, 111S: pixel electrode, 111: pixel electrode, 112a: conductive layer, 112a_1: conductive layer, 112a_2: conductive layer, 112a_3: conductive layer, 112B: conductive layer, 112b: conductive layer, 112bf: conductive film, 112c: conductive layer, 112d: conductive layer, 112e: conductive layer, 112m: conductive layer, 113B: EL layer, 113G: EL layer, 113R: EL layer, 113S: functional layer, 113: EL layer, 114: common layer, 115: common electrode, 117: light-blocking layer, 120a: insulating layer, 120b: insulating layer, 120: insulating layer, 123: conductive layer, 124B: conductive layer, 124G: conductive layer, 124R: conductive layer, 125: insulating layer, 126B: conductive layer, 126G: conductive layer, 126R: conductive layer, 127: insulating layer, 128: layer, 130B: light-emitting element, 130G: light-emitting element, 130R: light-emitting element, 130S: light-receiving element, 130: film, 131: protective layer, 132B: coloring layer, 132G: coloring layer, 132R: coloring layer, 133B: layer, 133G: layer, 133R: layer, 133: layer, 139: film, 140: connection portion, 141_1: opening, 141_4: opening, 141: opening, 142: adhesive layer, 143_1: opening, 143_2: opening, 143_3: opening, 143_4: opening, 143: opening, 144: adhesive layer, 146: opening, 147a: opening, 147b: opening, 148: opening, 149: opening, 150A: transistor, 150: transistor, 151: substrate, 152: substrate, 153: insulating layer, 162: display portion, 164: circuit portion, 165a: conductive layer, 165b: conductive layer, 165: conductive layer, 166a: conductive layer, 166b: conductive layer, 166: conductive layer, 172: FPC, 173: IC, 190: capacitor, 195: insulating layer, 197: connection portion, 200: transistor, 201: pixel, 202: conductive layer, 204: conductive layer, 205B: transistor, 205D: transistor, 205G: transistor, 205R: transistor, 205S: transistor, 208a: semiconductor layer, 208b: semiconductor layer, 208c: semiconductor layer, 208D: region, 208L: region, 208: semiconductor layer, 212a: conductive layer, 212b: conductive layer, 218: insulating layer, 223: connector, 224: spacer, 225: insulating layer, 235: insulating layer, 237: insulating layer, 241: opening, 242: connection layer, 243: opening, 250: transistor, 252: insulating layer, 253D: region, 253: semiconductor layer, 254: insulating layer, 255: conductive layer, 256: insulating layer, 257a: opening, 257b: opening, 258a: conductive layer, 258b: conductive layer, 259: conductive layer, 260a: polarizing plate, 260b: polarizing plate, 261: insulating layer, 262: liquid crystal, 263: conductive layer, 264: conductive layer, 265: alignment film, 352: finger, 353: layer, 355: circuit layer, 357: layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a transistor and a first insulating layer,
wherein the transistor comprises a first semiconductor layer, a second semiconductor layer, a third semiconductor layer, a first conductive layer, and a second conductive layer,
wherein the first insulating layer is provided over the first conductive layer,
wherein the second conductive layer is provided over the first insulating layer,
wherein the first insulating layer comprises a first opening reaching the first conductive layer,
wherein the second conductive layer comprises a second opening in a region overlapping with the first opening,
wherein in the first opening and the second opening, the first semiconductor layer is in contact with a top surface of the first conductive layer, a side surface of the first insulating layer, and a side surface of the second conductive layer,
wherein the second semiconductor layer is provided over the first semiconductor layer,
wherein the third semiconductor layer is provided over the second semiconductor layer,
wherein the first semiconductor layer comprises a first metal oxide,
wherein the second semiconductor layer comprises a second metal oxide,
wherein the third semiconductor layer comprises a third metal oxide,
wherein a band gap of the first metal oxide is larger than a band gap of the second metal oxide,
wherein a band gap of the third metal oxide is larger than the band gap of the first metal oxide,
wherein a thickness of the third semiconductor layer is larger than a thickness of the first semiconductor layer, and
wherein a thickness of the second semiconductor layer is larger than the thickness of the third semiconductor layer.

2. A semiconductor device comprising:
a transistor and a first insulating layer,
wherein the transistor comprises a first semiconductor layer, a second semiconductor layer, a third semiconductor layer, a first conductive layer, and a second conductive layer,
wherein the first insulating layer is provided over the first conductive layer,
wherein the second conductive layer is provided over the first insulating layer,
wherein the first insulating layer comprises a first opening reaching the first conductive layer,
wherein the second conductive layer comprises a second opening in a region overlapping with the first opening,
wherein in the first opening and the second opening, the first semiconductor layer is in contact with a top surface of the first conductive layer, a side surface of the first insulating layer, and a side surface of the second conductive layer,
wherein the second semiconductor layer is provided over the first semiconductor layer,
wherein the third semiconductor layer is provided over the second semiconductor layer,
wherein the first semiconductor layer comprises a first metal oxide,
wherein the second semiconductor layer comprises a second metal oxide,
wherein the third semiconductor layer comprises a third metal oxide,
wherein the first metal oxide comprises indium, a first element, and zinc,
wherein the second metal oxide comprises indium,
wherein the third metal oxide comprises indium, a second element, and zinc,
wherein the first element is one or more of gallium, aluminum, and tin,
wherein the second element is one or more of gallium, aluminum, and tin,
wherein a content percentage of the first element is higher than a sum of content percentages of gallium, aluminum, and tin in the second metal oxide,
wherein a content percentage of the second element is higher than the content percentage of the first element,
wherein a thickness of the third semiconductor layer is larger than a thickness of the first semiconductor layer, and
wherein a thickness of the second semiconductor layer is larger than the thickness of the third semiconductor layer.

3. A semiconductor device comprising:
a transistor and a first insulating layer,
wherein the transistor comprises a first semiconductor layer, a second semiconductor layer, a third semiconductor layer, a first conductive layer, and a second conductive layer,
wherein the first insulating layer is provided over the first conductive layer,
wherein the second conductive layer is provided over the first insulating layer,
wherein the first insulating layer comprises a first opening reaching the first conductive layer,
wherein the second conductive layer comprises a second opening in a region overlapping with the first opening,
wherein in the first opening and the second opening, the first semiconductor layer is in contact with a top surface of the first conductive layer, a side surface of the first insulating layer, and a side surface of the second conductive layer,
wherein the second semiconductor layer is provided over the first semiconductor layer,
wherein the third semiconductor layer is provided over the second semiconductor layer,
wherein the first semiconductor layer comprises a first metal oxide,
wherein the second semiconductor layer comprises a second metal oxide,
wherein the third semiconductor layer comprises a third metal oxide,
wherein the first metal oxide comprises indium, a first element, and zinc,
wherein the second metal oxide comprises indium and a second element,
wherein the third metal oxide comprises indium, a third element, and zinc,
wherein the first element is one or more of gallium, aluminum, and tin,
wherein the second element is one or more of gallium, aluminum, and tin,
wherein the third element is one or more of gallium, aluminum, and tin,
wherein a content percentage of the first element is higher than a content percentage of the second element,
wherein a content percentage of the third element is higher than the content percentage of the first element,
wherein a thickness of the third semiconductor layer is larger than a thickness of the first semiconductor layer, and
wherein a thickness of the second semiconductor layer is larger than the thickness of the third semiconductor layer.

4. The semiconductor device according to claim 1,
wherein the first conductive layer and the second conductive layer each comprise an oxide conductor.

5. The semiconductor device according to claim 1,
wherein the first insulating layer comprises a second insulating layer, a third insulating layer over the second insulating layer, and a fourth insulating layer over the third insulating layer,
wherein the third insulating layer comprises oxygen, and
wherein the second insulating layer and the fourth insulating layer each comprise nitrogen.

6. The semiconductor device according to claim 1,
wherein the first insulating layer comprises a second insulating layer, a third insulating layer over the second insulating layer, a fourth insulating layer over the third insulating layer, a fifth insulating layer over the fourth insulating layer, and a sixth insulating layer over the fifth insulating layer,
wherein the fourth insulating layer comprises oxygen,
wherein the second insulating layer, the third insulating layer, the fifth insulating layer, and the sixth insulating layer each comprise nitrogen,
wherein the second insulating layer comprises a region with a higher hydrogen content than the third insulating layer, and
wherein the sixth insulating layer comprises a region with a higher hydrogen content than the fifth insulating layer.

7. The semiconductor device according to claim 1, further comprising:
a second insulating layer,
wherein a top surface of the second insulating layer is in contact with a bottom surface of the first conductive layer,
wherein the first insulating layer comprises a third insulating layer, a fourth insulating layer over the third insulating layer, a fifth insulating layer over the fourth insulating layer, and a sixth insulating layer over the fifth insulating layer,
wherein the fourth insulating layer comprises oxygen,
wherein the second insulating layer, the third insulating layer, the fifth insulating layer, and the sixth insulating layer each comprise nitrogen,
wherein the second insulating layer comprises a region with a higher hydrogen content than the third insulating layer, and
wherein the sixth insulating layer comprises a region with a higher hydrogen content than the fifth insulating layer.
